(19) United States
(12) Patent Application Publication
(10) Pub. No.: US 2025/0040193 A1
(43) Pub. Date: Jan. 30, 2025

(54) SEMICONDUCTOR DEVICE AND STORAGE DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Hitoshi KUNITAKE, Machida (JP); Satoru SAITO, Yamato (JP); Masahiro TAKAHASHI, Atsugi (JP); Naoki OKUNO, Yamato (JP); Masashi OOTA, Isehara (JP)

(21) Appl. No.: 18/716,572

(22) PCT Filed: Nov. 28, 2022
(86) PCT No.: PCT/IB2022/061453

§ 371 Date: Jun. 5, 2024

(30) Foreign Application Priority Data
Dec. 29, 2021 (JP) 2021-215422
Dec. 29, 2021 (JP) 2021-215423
Feb. 4, 2022 (JP) 2022-016593
May 16, 2022 (JP) 2022-080149

(51) Int. Cl. H01L 29/786; H01L 21/324; H01L 21/8238; H01L 27/092; H01L 29/417; H01L 29/423; H01L 29/66; H01L 29/775; H01L 29/792; H10B 12/00; H10B 43/20; H10B 80/00

(52) U.S. Cl. CPC H01L 29/78696; H01L 27/092; H01L 29/41791; H01L 29/42392; H01L 29/775; H01L 21/324; H01L 21/8238; H01L 29/66439; H01L 29/7869; H01L 29/792; H10B 12/36; H10B 43/20; H10B 80/00

(57) ABSTRACT

A semiconductor device with a high on-state current is provided. A transistor included in the semiconductor device includes a first insulator; a first semiconductor layer over the first insulator; a second semiconductor layer including a channel formation region over the first semiconductor layer; a first conductor and a second conductor over the second semiconductor layer; a second insulator over the second semiconductor layer and between the first conductor and the second conductor; and a third conductor over the second insulator. In a cross-sectional view in a channel width direction of the transistor, the third conductor covers a side surface and a top surface of the second semiconductor layer. The second semiconductor layer has a higher permittivity than the first semiconductor layer. In the cross-sectional view in the channel width direction of the transistor, a length of an interface between the first semiconductor layer and the second semiconductor layer is greater than or equal to 1 nm and less than or equal to 20 nm, and a length from a bottom surface of the second semiconductor layer to a bottom surface of the third conductor in a region not overlapping with the second semiconductor layer is larger than a thickness of the second semiconductor layer.

### TECHNICAL FIELD

One embodiment of the present invention relates to a transistor, a semiconductor device, a storage device, a display device, and an electronic appliance. Another embodiment of the present invention relates to a method for manufacturing a semiconductor device and a method for manufacturing a display device. Another embodiment of the present invention relates to a semiconductor wafer and a module.

Note that in this specification and the like, a semiconductor device generally means a device that can function by utilizing semiconductor characteristics. A semiconductor element such as a transistor, a semiconductor circuit, an arithmetic device, and a storage device are each an embodiment of a semiconductor device. It can be sometimes said that a display device (a liquid crystal display device, a light-emitting display device, and the like), a projection device, a lighting device, an electro-optical device, a power storage device, a storage device, a semiconductor circuit, an image capturing device, an electronic appliance, and the like include a semiconductor device.

Note that one embodiment of the present invention is not limited to the above technical field. One embodiment of the invention disclosed in this specification and the like relates to an object, a method, or a manufacturing method. One embodiment of the present invention relates to a process, a machine, manufacture, or a composition of matter.

### BACKGROUND ART

In recent years, the development of semiconductor devices has progressed, and LSIs, CPUs, memories, and the like are mainly used as the semiconductor devices. A CPU is an aggregation of semiconductor elements; the CPU includes a semiconductor integrated circuit (including at least a transistor and a memory) formed into a chip by processing a semiconductor wafer, and is provided with an electrode that is a connection terminal.

A semiconductor circuit (IC chip) of an LSI, a CPU, a memory, or the like is mounted on a circuit board, for example, a printed wiring board, to be used as one of components of a variety of electronic appliances.

A technique by which a transistor is formed using a semiconductor thin film formed over a substrate having an insulating surface has been attracting attention. The transistor is used in a wide range of electronic devices such as an integrated circuit (IC) and an image display device (also simply referred to as a display device). A silicon-based semiconductor material is widely known as a semiconductor thin film applicable to the transistor and further, an oxide semiconductor has been attracting attention as another material.

It is known that a transistor using an oxide semiconductor has an extremely low off-state current in a non-conduction state. For example, Patent Document 1 discloses a low-power-consumption CPU utilizing a characteristically low off-state current of the transistor using an oxide semiconductor. Furthermore, for example, Patent Document 2 discloses a storage device that can retain stored contents for a long time by utilizing a characteristically low off-state current of the transistor using an oxide semiconductor.

### REFERENCES

### Patent Documents

[Patent Document 1] Japanese Published Patent Application No. 2012-257187
[Patent Document 2] Japanese Published Patent Application No. 2011-151383

### SUMMARY OF THE INVENTION

### Problems to be Solved by the Invention

In an integrated circuit including a transistor, the transistor needs to be miniaturized to achieve higher integration. However, a miniaturized transistor faces a problem of a short-channel effect (SCE). The short-channel effect refers to degradation of electrical characteristics that becomes obvious along with miniaturization of a transistor. Accordingly, inhibiting the short-channel effect is one of the issues in miniaturization of a transistor.

An object of one embodiment of the present invention is to provide a semiconductor device in which a short-channel effect does not appear or hardly appears. Another object is to provide a semiconductor device with a high on-state current. Another object of one embodiment of the present invention is to provide a semiconductor device that can be miniaturized or highly integrated. Another object is to provide a semiconductor device having favorable electrical characteristics. Another object is to provide a semiconductor device with a small variation in electrical characteristics of transistors. Another object is to provide a semiconductor device having high reliability. Another object is to provide a semiconductor device with low power consumption.

Note that the description of these objects does not preclude the existence of other objects. Note that one embodiment of the present invention does not need to achieve all of these objects. Note that other objects will be apparent from the description of the specification, the drawings, the claims, and the like, and other objects can be derived from the description of the specification, the drawings, the claims, and the like.

### Means for Solving the Problems

One embodiment of the present invention is a semiconductor device that includes a transistor. The transistor includes a first insulator; a first semiconductor layer over the first insulator; a second semiconductor layer over the first semiconductor layer; a first conductor and a second conductor over the second semiconductor layer; a second insulator over the second semiconductor layer and between the first conductor and the second conductor; and a third conductor over the second insulator. The second semiconductor layer includes a channel formation region. In a cross-sectional view in a channel width direction of the transistor, the third conductor covers a side surface and a top surface of the second semiconductor layer. A permittivity of the second semiconductor layer is higher than a permittivity of the first semiconductor layer. In the cross-sectional view in the channel width direction of the transistor, a length of an interface between the first semiconductor layer and the second semiconductor layer is greater than or equal to 1 nm and less than or equal to 20 nm. In the cross-sectional view in the channel width direction of the transistor, a length from a bottom surface of the second semiconductor layer to a bottom surface of the third conductor in a region not overlapping with the second semiconductor layer is larger than a thickness of the second semiconductor layer.

Another embodiment of the present invention is a semiconductor device that includes a transistor. The transistor includes a first insulator; a first semiconductor layer over the first insulator; a second semiconductor layer over the first semiconductor layer; a first conductor and a second conductor over the second semiconductor layer; a second insulator over the second semiconductor layer and between the first conductor and the second conductor; a third conductor over the second insulator; and a third insulator above the first conductor and the second conductor. The third insulator includes an opening. The opening includes a region that is between the first conductor and the second conductor and that overlaps with the second semiconductor layer. The second insulator and the third conductor are located in the opening. In a cross-sectional view in a channel width direction of the transistor, with reference to a bottom surface of the first insulator, a level of a bottom surface of the third conductor in a region not overlapping with the second semiconductor layer is lower than a level of a bottom surface of the second semiconductor layer. A permittivity of the second semiconductor layer is higher than a permittivity of the first semiconductor layer. In the cross-sectional view in the channel width direction of the transistor, a length of an interface between the first semiconductor layer and the second semiconductor layer is greater than or equal to 1 nm and less than or equal to 20 nm. In the cross-sectional view in the channel width direction of the transistor, a length from the bottom surface of the second semiconductor layer to the bottom surface of the third conductor in the region not overlapping with the second semiconductor layer is larger than a thickness of the second semiconductor layer.

In any of the above semiconductor devices, it is preferable that each of the first conductor and the second conductor include titanium and nitrogen and a thickness of each of the first conductor and the second conductor be greater than or equal to 5 nm and less than or equal to 30 nm.

Another embodiment of the present invention is a semiconductor device that includes a transistor. The transistor includes a first conductor; a first insulator over the first conductor; a first semiconductor layer over the first insulator; a second semiconductor layer over the first semiconductor layer; a second conductor and a third conductor over the second semiconductor layer; a second insulator over the second semiconductor layer and between the second conductor and the third conductor; and a fourth conductor over the second insulator. The fourth conductor includes a region overlapping with the second semiconductor layer with the second insulator therebetween. The first conductor is located to overlap with the second semiconductor layer and the fourth conductor. In a cross-sectional view in a channel width direction of the transistor, with reference to a bottom surface of the first insulator, a level of a bottom surface of the fourth conductor in a region not overlapping with the second semiconductor layer is lower than a level of a bottom surface of the second semiconductor layer. A permittivity of the second semiconductor layer is higher than a permittivity of the first semiconductor layer. In the cross-sectional view in the channel width direction of the transistor, a length of an interface between the first semiconductor layer and the second semiconductor layer is greater than or equal to 1 nm and less than or equal to 20 nm. In the cross-sectional view in the channel width direction of the transistor, a length from the bottom surface of the second semiconductor layer to the bottom surface of the fourth conductor in the region not overlapping with the second semiconductor layer is larger than a thickness of the second semiconductor layer.

In any of the above semiconductor devices, it is preferable that a band gap of the second semiconductor layer be wider than a band gap of silicon.

In the above semiconductor device, it is preferable that each of the first semiconductor layer and the second semiconductor layer include indium, zinc, and one or more selected from gallium, aluminum, and tin.

Another embodiment of the present invention is a semiconductor device that includes a first insulator; a first semiconductor layer and a second semiconductor layer over the first insulator; a third semiconductor layer over the first semiconductor layer; a first conductor and a second conductor over the third semiconductor layer; a fourth semiconductor layer over the second semiconductor layer; a third conductor and a fourth conductor over the fourth semiconductor layer; a second insulator over the third semiconductor layer and between the first conductor and the second conductor; and a fifth conductor over the second insulator. The fifth conductor includes a region overlapping with the third semiconductor layer with the second insulator therebetween. The second insulator and the fifth conductor extend in a direction in which the third semiconductor layer and the fourth semiconductor layer are arranged in parallel. The second insulator is over the fourth semiconductor layer and between the third conductor and the fourth conductor. The fifth conductor includes a region overlapping with the fourth semiconductor layer with the second insulator therebetween. In a cross-sectional view in the above direction, with reference to a bottom surface of the first insulator, a level of a bottom surface of the fifth conductor in a region not overlapping with the third semiconductor layer is lower than a level of a bottom surface of the third semiconductor layer. A permittivity of the third semiconductor layer is higher than a permittivity of the first semiconductor layer. In the cross-sectional view in the above direction, a length of an interface between the first semiconductor layer and the third semiconductor layer is greater than or equal to 1 nm and less than or equal to 20 nm. In the cross-sectional view in the above direction, a length from the bottom surface of the third semiconductor layer to the bottom surface of the fifth conductor in the region not overlapping with the third semiconductor layer is larger than a thickness of the third semiconductor layer.

In the above semiconductor device, it is preferable that the first conductor be electrically connected to one of the third conductor and the fourth conductor.

In the above semiconductor device, it is preferable that the first conductor be electrically connected to neither the third conductor nor the fourth conductor.

One embodiment of the present invention is a semiconductor device that includes a metal oxide including a channel formation region of a transistor; a first conductor and a second conductor over the metal oxide; a first insulator over the metal oxide and between the first conductor and the second conductor; a second insulator over the first insulator; a third insulator over the second insulator; a third conductor over the third insulator; a fourth insulator between the first conductor and the first insulator; a fifth insulator between the second conductor and the first insulator; and a sixth insulator above the first conductor and the second conductor. The sixth insulator includes an opening. The opening includes a region that is between the first conductor and the second conductor and that overlaps with the metal oxide. The first insulator, the second insulator, the third insulator, and the third conductor are located in the opening. The first insulator includes a region in contact with a top surface of the metal oxide, a region in contact with a side surface of the metal oxide, and a region in contact with a sidewall of the opening. The first insulator is a material that is less permeable to oxygen than the second insulator. The first insulator includes a region having a thickness greater than or equal to 1.0 nm and less than 3.0 nm. The first conductor and the second conductor each include a metal element. The fourth insulator and the fifth insulator include the metal element. The metal oxide includes indium, zinc, and one or more selected from gallium, aluminum, and tin. In the metal oxide, the atomic ratio of zinc is higher than the atomic ratio of indium. The transistor has normally-off characteristics.

Another embodiment of the present invention is a semiconductor device that includes a transistor. The transistor includes a first insulator; a first semiconductor layer over the first insulator; a second semiconductor layer over the first semiconductor layer; a first conductor and a second conductor over the second semiconductor layer; a second insulator over the second semiconductor layer and between the first conductor and the second conductor; a third conductor over the second insulator; and a third insulator above the first conductor and the second conductor. The third insulator includes an opening. The opening includes a region that is between the first conductor and the second conductor and that overlaps with the second semiconductor layer. The second insulator and the third conductor are located in the opening. In a cross-sectional view in a channel width direction of the transistor, with reference to a bottom surface of the first insulator, a level of a bottom surface of the third conductor in a region not overlapping with the second semiconductor layer is lower than a level of a bottom surface of the second semiconductor layer. A permittivity of the second semiconductor layer is higher than a permittivity of the first semiconductor layer. In the cross-sectional view in the channel width direction of the transistor, a length of an interface between the first semiconductor layer and the second semiconductor layer is greater than or equal to 1 nm and less than or equal to 20 nm. In the cross-sectional view in the channel width direction of the transistor, a length from the bottom surface of the second semiconductor layer to the bottom surface of the third conductor in the region not overlapping with the second semiconductor layer is larger than a thickness of the second semiconductor layer. The second semiconductor layer includes a metal oxide including indium, zinc, and one or more selected from gallium, aluminum, and tin. In the metal oxide, the atomic ratio of zinc is higher than the atomic ratio of indium. The transistor has normally-off characteristics.

One embodiment of the present invention is a storage device that includes any of the above semiconductor devices.

### Effect of the Invention

According to one embodiment of the present invention, a semiconductor device in which a short-channel effect does not appear or hardly appears can be provided. Alternatively, a semiconductor device with a high on-state current can be provided. Alternatively, a semiconductor device that can be miniaturized or highly integrated can be provided. Alternatively, a semiconductor device having favorable electrical characteristics can be provided. Alternatively, a semiconductor device with a small variation in electrical characteristics of transistors can be provided. Alternatively, a semiconductor device having high reliability can be provided. Alternatively, a semiconductor device with low power consumption can be provided.

Note that the description of these effects does not preclude the existence of other effects. Note that one embodiment of the present invention does not need to have all of these effects. Note that other effects will be apparent from the description of the specification, the drawings, the claims, and the like, and other effects can be derived from the description of the specification, the drawings, the claims, and the like.

### BRIEF DESCRIPTION OF THE DRAWINGS

FIG. 1A is a top view of a semiconductor device of one embodiment of the present invention.

FIG. 1B to FIG. 1D are cross-sectional views of the semiconductor device of one embodiment of the present invention.

FIG. 2A and FIG. 2B are cross-sectional views of a semiconductor device of one embodiment of the present invention.

FIG. 3A to FIG. 3C are cross-sectional views of semiconductor devices of embodiments of the present invention.

FIG. 4A is a top view of a semiconductor device of one embodiment of the present invention. FIG. 4B to FIG. 4D are cross-sectional views of the semiconductor device of one embodiment of the present invention.

FIG. 5A is a top view of a semiconductor device of one embodiment of the present invention. FIG. 5B to FIG. 5D are cross-sectional views of the semiconductor device of one embodiment of the present invention.

FIG. 6A is a top view of a semiconductor device of one embodiment of the present invention. FIG. 6B to FIG. 6E are cross-sectional views of the semiconductor device of one embodiment of the present invention.

FIG. 7A is a top view of a semiconductor device of one embodiment of the present invention. FIG. 7B to FIG. 7D are cross-sectional views of the semiconductor device of one embodiment of the present invention.

FIG. 8A is a top view of a semiconductor device of one embodiment of the present invention. FIG. 8B and FIG. 8C are cross-sectional views of the semiconductor device of one embodiment of the present invention.

FIG. 9A is a top view of a semiconductor device of one embodiment of the present invention. FIG. 9B and FIG. 9C are cross-sectional views of the semiconductor device of one embodiment of the present invention.

FIG. 10A is a top view of a semiconductor device of one embodiment of the present invention. FIG. 10B and FIG. 10C are cross-sectional views of the semiconductor device of one embodiment of the present invention.

FIG. 11A is a top view of a semiconductor device of one embodiment of the present invention. FIG. 11B and FIG. 11C are cross-sectional views of the semiconductor device of one embodiment of the present invention.

FIG. 12A to FIG. 12D are diagrams each illustrating a crystal included in a metal oxide.

FIG. 13A is a diagram illustrating a crystal included in a metal oxide. FIG. 13B to FIG. 13D are diagrams each illustrating a polyhedron included in the crystal.

FIG. 14A is a top view of a semiconductor device of one embodiment of the present invention. FIG. 14B to FIG. 14D are cross-sectional views of the semiconductor device of one embodiment of the present invention.

FIG. 15 is a cross-sectional view of a semiconductor device of one embodiment of the present invention.

FIG. 16A is a diagram showing relationship between a carrier concentration and the Fermi level. FIG. 16B is a schematic cross-sectional view of a transistor of one embodiment of the present invention. FIG. 16C is a schematic view of a conduction band offset.

FIG. 17A to FIG. 17E are cross-sectional views of semiconductor devices of embodiments of the present invention.

FIG. 18A to FIG. 18D are schematic views of aluminum concentration profiles in a metal oxide.

FIG. 19A and FIG. 19B are cross-sectional views of semiconductor devices of embodiments of the present invention.

FIG. 20A and FIG. 20B are cross-sectional views of semiconductor devices of embodiments of the present invention.

FIG. 21A is a top view illustrating a method for manufacturing a semiconductor device of one embodiment of the present invention. FIG. 21B to FIG. 21D are cross-sectional views illustrating the method for manufacturing a semiconductor device of one embodiment of the present invention.

FIG. 22A is a top view illustrating a method for manufacturing a semiconductor device of one embodiment of the present invention. FIG. 22B to FIG. 22D are cross-sectional views illustrating the method for manufacturing a semiconductor device of one embodiment of the present invention.

FIG. 23A is a top view illustrating a method for manufacturing a semiconductor device of one embodiment of the present invention. FIG. 23B to FIG. 23D are cross-sectional views illustrating the method for manufacturing a semiconductor device of one embodiment of the present invention.

FIG. 24A is a top view illustrating a method for manufacturing a semiconductor device of one embodiment of the present invention. FIG. 24B to FIG. 24D are cross-sectional views illustrating the method for manufacturing a semiconductor device of one embodiment of the present invention.

FIG. 25A is a top view illustrating a method for manufacturing a semiconductor device of one embodiment of the present invention. FIG. 25B to FIG. 25D are cross-sectional views illustrating the method for manufacturing a semiconductor device of one embodiment of the present invention.

FIG. 26A is a top view illustrating a method for manufacturing a semiconductor device of one embodiment of the present invention. FIG. 26B to FIG. 26D are cross-sectional views illustrating the method for manufacturing a semiconductor device of one embodiment of the present invention.

FIG. 27A is a top view illustrating a method for manufacturing a semiconductor device of one embodiment of the present invention. FIG. 27B to FIG. 27D are cross-sectional views illustrating the method for manufacturing a semiconductor device of one embodiment of the present invention.

FIG. 28A is a top view illustrating a method for manufacturing a semiconductor device of one embodiment of the present invention. FIG. 28B to FIG. 28D are cross-sectional views illustrating the method for manufacturing a semiconductor device of one embodiment of the present invention.

FIG. 29A is a top view illustrating a method for manufacturing a semiconductor device of one embodiment of the present invention. FIG. 29B to FIG. 29D are cross-sectional views illustrating the method for manufacturing a semiconductor device of one embodiment of the present invention.

FIG. 30A is a top view illustrating a method for manufacturing a semiconductor device of one embodiment of the present invention. FIG. 30B to FIG. 30D are cross-sectional views illustrating the method for manufacturing a semiconductor device of one embodiment of the present invention.

FIG. 31A is a top view illustrating a method for manufacturing a semiconductor device of one embodiment of the present invention. FIG. 31B to FIG. 31D are cross-sectional views illustrating the method for manufacturing a semiconductor device of one embodiment of the present invention.

FIG. 32 is a top view illustrating a microwave treatment apparatus of one embodiment of the present invention.

FIG. 33 is a schematic cross-sectional view illustrating a microwave treatment apparatus of one embodiment of the present invention.

FIG. 34 is a schematic cross-sectional view illustrating a microwave treatment apparatus of one embodiment of the present invention.

FIG. 35 is a schematic view illustrating a microwave treatment apparatus of one embodiment of the present invention.

FIG. 36A is a top view of a semiconductor device of one embodiment of the present invention. FIG. 36B to FIG. 36D are cross-sectional views of the semiconductor device of one embodiment of the present invention.

FIG. 37A is a top view of a semiconductor device of one embodiment of the present invention. FIG. 37B to FIG. 37D are cross-sectional views of the semiconductor device of one embodiment of the present invention.

FIG. 38A is a top view of a semiconductor device of one embodiment of the present invention. FIG. 38B to FIG. 38D are cross-sectional views of the semiconductor device of one embodiment of the present invention.

FIG. 39A is a top view of a semiconductor device of one embodiment of the present invention. FIG. 39B to FIG. 39D are cross-sectional views of the semiconductor device of one embodiment of the present invention.

FIG. 40A is a top view of a semiconductor device of one embodiment of the present invention. FIG. 40B and FIG. 40C are cross-sectional views of the semiconductor device of one embodiment of the present invention.

FIG. 41 is a cross-sectional view illustrating a structure of a storage device of one embodiment of the present invention.

FIG. 42 is a cross-sectional view illustrating a structure of a storage device of one embodiment of the present invention.

FIG. 43 is a cross-sectional view of a semiconductor device of one embodiment of the present invention.

FIG. 44A and FIG. 44B are cross-sectional views of semiconductor devices of embodiments of the present invention.

FIG. 45 is a cross-sectional view of a semiconductor device of one embodiment of the present invention.

FIG. 46A is a block diagram illustrating a structure example of a storage device of one embodiment of the present invention. FIG. 46B is a perspective view illustrating a structure example of the storage device of one embodiment of the present invention.

FIG. 47A to FIG. 47I are circuit diagrams illustrating structure examples of a storage device of one embodiment of the present invention.

FIG. 48A and FIG. 48B are schematic views of a semiconductor device of one embodiment of the present invention.

FIG. 49A and FIG. 49B are diagrams of examples of electronic components.

FIG. 50A to FIG. 50E are schematic views of storage devices of embodiments of the present invention.

FIG. 51A to FIG. 51H are diagrams illustrating electronic appliances of embodiments of the present invention.

FIG. 52 is a diagram illustrating an example of a device for space.

FIG. 53A is a phase diagram of In—Ga—Zn oxides. FIG. 53B is a diagram showing band gaps of the metal oxides.

FIG. 54 is a diagram showing dependence of a carrier concentration of a metal oxide on treatment temperature.

FIG. 55 is a bird's eye view of a transistor used for device simulation.

FIG. 56A to FIG. 56C are diagrams each showing Id-Vgs characteristics obtained by device simulation.

FIG. 57A is a diagram showing electron density distributions obtained by device simulation. FIG. 57B is a diagram showing comparison of energy at the conduction band minimum depending on ΔEc.

FIG. 58A to FIG. 58D are diagrams each showing electrical characteristics obtained by device simulation.

FIG. 59A and FIG. 59B are diagrams each showing an electric-field strength distribution obtained by device simulation.

FIG. 60A to FIG. 60D are diagrams each showing electrical characteristics obtained by device simulation.

FIG. 61A to FIG. 61E are diagrams each showing a potential distribution obtained by device simulation.

FIG. 62A and FIG. 62B are cross-sectional STEM images of a fabricated sample.

FIG. 63 is a diagram showing the transition of channel lengths or gate lengths of transistors.

FIG. 64 is a plan SEM image of a prototyped sample.

FIG. 65A and FIG. 65B show Id-Vgs characteristics of transistors.

FIG. 66A is a circuit diagram of a ring oscillator. FIG. 66B is a circuit diagram of an inverter.

FIG. 67A is a schematic view of a 3D layout of a ring oscillator. FIG. 67B is a cross-sectional TEM image of a sample.

FIG. 68A and FIG. 68B show output waveforms of a ring oscillator. FIG. 68C is a diagram showing dependence of delay time per stage on voltage applied to a power supply potential VBG.

FIG. 69A and FIG. 69B are diagrams illustrating fabrication methods of prototyped samples. FIG. 69C is a diagram showing carrier concentrations of metal oxides.

FIG. 70 shows Id-Vgs characteristics of a transistor.

FIG. 71 is a diagram showing layout areas of standard cells.

FIG. 72A is a circuit diagram of a ring oscillator. FIG. 72B1 and FIG. 72B2 are each a circuit diagram of an inverter.

FIG. 73A to FIG. 73C show output waveforms of ring oscillators.

### MODE FOR CARRYING OUT THE INVENTION

Embodiments are described below with reference to the drawings. Note that the embodiments can be implemented with many different modes, and it is readily understood by those skilled in the art that modes and details thereof can be changed in various ways without departing from the spirit and scope thereof. Thus, the present invention should not be construed as being limited to the description of the embodiments below.

In the drawings, the size, the layer thickness, or the region is exaggerated for clarity in some cases. Therefore, the size, the layer thickness, or the region is not limited to the illustrated scale. Note that the drawings schematically show ideal examples, and embodiments of the present invention are not limited to shapes or values shown in the drawings. For example, in the actual manufacturing process, a layer, a resist mask, or the like might be unintentionally reduced in size by treatment such as etching, which might not be reflected in the drawings for easy understanding. Furthermore, in the drawings, the same reference numerals are used in common for the same portions or portions having similar functions in different drawings, and repeated description thereof is omitted in some cases. The same hatching pattern is applied to portions having similar functions, and the portions are not especially denoted by reference numerals in some cases.

Furthermore, especially in a top view (also referred to as a “plan view”), a perspective view, or the like, the description of some components might be omitted for easy understanding of the invention. The description of some hidden lines and the like might also be omitted.

The ordinal numbers such as “first” and “second” in this specification and the like are used for convenience and do not denote the order of steps or the stacking order of layers. Therefore, for example, the term “first” can be replaced with the term “second”, “third”, or the like as appropriate. In addition, the ordinal numbers in this specification and the like do not sometimes correspond to the ordinal numbers that are used to specify one embodiment of the present invention.

Moreover, in this specification and the like, terms for describing arrangement, such as “over” and “under”, are used for convenience for describing the positional relationship between components with reference to drawings. The positional relationship between components changes as appropriate in accordance with the direction in which the components are described. Thus, without limitation to terms described in this specification, the description can be changed appropriately depending on the situation.

When this specification and the like explicitly state that X and Y are connected, for example, the case where X and Y are electrically connected, the case where X and Y are functionally connected, and the case where X and Y are directly connected are regarded as being disclosed in this specification and the like. Accordingly, without being limited to predetermined connection relationship, e.g., connection relationship shown in drawings or texts, connection relationship other than one shown in drawings or texts is regarded as being disclosed in the drawings or the texts. Here, X and Y each denote an object (e.g., a device, an element, a circuit, a wiring, an electrode, a terminal, a conductive film, or a layer).

In this specification and the like, a transistor is an element having at least three terminals including a gate, a drain, and a source. In addition, the transistor includes a region where a channel is formed (hereinafter also referred to as a channel formation region) between the drain (a drain terminal, a drain region, or a drain electrode) and the source (a source terminal, a source region, or a source electrode), and a current can flow between the source and the drain through the channel formation region. Note that in this specification and the like, a channel formation region refers to a region through which a current mainly flows.

Furthermore, functions of a source and a drain are sometimes interchanged with each other when transistors having different polarities are used or when the direction of a current is changed in a circuit operation, for example. Therefore, the terms “source” and “drain” can sometimes be interchanged with each other in this specification and the like.

Note that a channel length refers to, for example, a distance between a source (a source region or a source electrode) and a drain (a drain region or a drain electrode) in a region where a semiconductor (or a portion where a current flows in a semiconductor when a transistor is in an on state) and a gate electrode overlap with each other or in a channel formation region in a top view of the transistor. Note that in one transistor, channel lengths in all regions do not necessarily have the same value. In other words, the channel length of one transistor is not fixed to one value in some cases. Thus, in this specification, the channel length is any one of the values, the maximum value, the minimum value, or the average value in a channel formation region.

A channel width refers to, for example, the length of a channel formation region in a direction perpendicular to a channel length direction in a region where a semiconductor (or a portion where a current flows in a semiconductor when a transistor is in an on state) and a gate electrode overlap with each other or in a channel formation region in a top view of the transistor. Note that in one transistor, channel widths in all regions do not necessarily have the same value. In other words, the channel width of one transistor is not fixed to one value in some cases. Thus, in this specification, the channel width is any one of the values, the maximum value, the minimum value, or the average value in a channel formation region.

Note that in this specification and the like, depending on the transistor structure, a channel width in a region where a channel is actually formed (hereinafter also referred to as an “effective channel width”) is different from a channel width shown in a top view of a transistor (hereinafter also referred to as an “apparent channel width”) in some cases. For example, when a gate electrode covers a side surface of a semiconductor, the effective channel width is larger than the apparent channel width, and its influence cannot be ignored in some cases. For example, in a miniaturized transistor whose gate electrode covers a side surface of a semiconductor, the proportion of a channel formation region formed in the side surface of the semiconductor is high in some cases. In that case, the effective channel width is larger than the apparent channel width.

In such a case, the effective channel width is sometimes difficult to estimate by actual measurement. For example, estimation of an effective channel width from a design value requires assumption that the shape of a semiconductor is known. Accordingly, in the case where the shape of a semiconductor is not known accurately, it is difficult to measure the effective channel width accurately.

In this specification, the simple term “channel width” refers to an apparent channel width in some cases. Alternatively, in this specification, the simple term “channel width” refers to an effective channel width in some cases. Note that the value of a channel length, a channel width, an effective channel width, an apparent channel width, or the like can be determined, for example, by analyzing a cross-sectional TEM image.

In this specification, an apparent channel width is sometimes referred to as a gate width. A gate width sometimes refers to, in a cross-sectional view of a transistor in the channel width direction, the length of the top surface of a semiconductor, the length of the bottom surface of the semiconductor, or the length of the semiconductor at a freely selected position therein, for example. In the case where a semiconductor has a stacked-layer structure, the gate width sometimes refers to the length of the interface between a first layer and a second layer of the stacked-layer structure in a cross-sectional view of a transistor in the channel width direction, for example.

Note that impurities in a semiconductor refer to, for example, elements other than the main components of the semiconductor. For example, an element with a concentration lower than 0.1 atomic % can be regarded as an impurity. When an impurity is contained, for example, the density of defect states in a semiconductor increases and the crystallinity decreases in some cases. In the case where the semiconductor is an oxide semiconductor, examples of an impurity which changes the characteristics of the semiconductor include Group 1 elements, Group 2 elements, Group 13 elements, Group 14 elements, Group 15 elements, and transition metals other than the main components of the oxide semiconductor; hydrogen, lithium, sodium, silicon, boron, phosphorus, carbon, and nitrogen are given as examples. Note that water also serves as an impurity in some cases. In addition, oxygen vacancies (also referred to as Vo) are formed in an oxide semiconductor in some cases by entry of impurities, for example.

Note that in this specification and the like, silicon oxynitride has a composition in which the oxygen content is higher than the nitrogen content. Moreover, silicon nitride oxide has a composition in which the nitrogen content is higher than the oxygen content.

In this specification and the like, the term “insulator” can be replaced with an insulating film or an insulating layer. Furthermore, the term “conductor” can be replaced with a conductive film or a conductive layer. Moreover, the term “semiconductor” can be replaced with a semiconductor film or a semiconductor layer.

In this specification and the like, “parallel” indicates a state where two straight lines are placed at an angle greater than or equal to −10° and less than or equal to 10°. Accordingly, the case where the angle is greater than or equal to −5° and less than or equal to 5° is also included. Furthermore, “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Accordingly, the case where the angle is greater than or equal to 85° and less than or equal to 95° is also included. Furthermore, “substantially perpendicular” indicates a state where two straight lines are placed at an angle greater than or equal to 60° and less than or equal to 120°.

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like. For example, in the case where a metal oxide is used in a semiconductor layer of a transistor, the metal oxide is referred to as an oxide semiconductor in some cases. That is, an OS transistor can also be referred to as a transistor including a metal oxide or an oxide semiconductor.

In this specification and the like, “normally off” means that a drain current per micrometer of channel width flowing through a transistor when no potential is applied to a gate or the gate is supplied with a ground potential is lower than or equal to 1×10⁻²⁰ A at room temperature, lower than or equal to 1×10⁻¹⁸ A at 85° C., or lower than or equal to 1×10⁻¹⁶ A at 125° C.

Note that the above current values may be lower than or equal to the lower detection limits of some measurement apparatuses, in which case whether the transistor is normally-off cannot be determined. In that case, for example, an n-channel transistor whose gate voltage has a positive value when the drain current is 1×10⁻¹² A or when the drain current per micrometer of channel width is 5×10⁻¹¹ A in measurement of the drain current-gate voltage characteristics may be defined as a normally-off transistor.

In this specification and the like, “voltage” and “potential” can be replaced with each other as appropriate. “Voltage” refers to a potential difference from a reference potential, and when the reference potential is a ground potential, for example, “voltage” can be replaced with “potential”. Note that the ground potential does not necessarily mean 0 V. Moreover, potentials are relative values, and a potential supplied to a wiring, a potential applied to a circuit or the like, and a potential output from a circuit or the like, for example, change with a change in the reference potential.

In this specification and the like, when a plurality of components are denoted with the same reference numeral, and in particular need to be distinguished from each other, an identification sign such as “_1”, “[n]”, or “[m,n]” is sometimes added to the reference numeral.

In this specification, in the case where the maximum value and the minimum value are specified, a structure in which the maximum value and the minimum value are freely combined is also disclosed.

Note that in this specification and the like, the expression “level or substantially level” is used to describe a structure in which levels from a reference surface (e.g., a flat surface such as a substrate surface) are the same in a cross-sectional view. For example, in a manufacturing process of a semiconductor device, planarization treatment (typically, CMP treatment) is performed, whereby the surface(s) of a single layer or a plurality of layers are exposed in some cases. In this case, the surfaces on which the CMP treatment is performed are at the same level from a reference surface. Note that the plurality of layers are at different levels in some cases, depending on a treatment apparatus, a treatment method, or a material of the treated surfaces at the time when the CMP treatment is performed. This case is also described with the expression “level or substantially level” in this specification and the like. For example, the expression “level or substantially level” is also used to describe the case where layers having two levels with respect to the reference surface (here, given as a first layer and a second layer) are provided to have a difference less than or equal to 20 nm between the top-surface level of the first layer and the top-surface level of the second layer.

Note that in this specification and the like, the expression “end portions are aligned or substantially aligned” means that outlines of stacked layers at least partly overlap with each other in a top view. For example, the case of processing an upper layer and a lower layer with the use of the same mask pattern or mask patterns that are partly the same is included. Note that in some cases, the outlines do not exactly overlap with each other and the outline of the upper layer is located inward from the outline of the lower layer or the outline of the upper layer is located outward from the outline of the lower layer; such a case is also represented by the expression “end portions are aligned or substantially aligned”.

### Embodiment 1

In this embodiment, a semiconductor device of one embodiment of the present invention is described. The semiconductor device of one embodiment of the present invention includes a transistor.

The transistor preferably has excellent switching characteristics. Here, a transistor having excellent switching characteristics is, for example, a transistor in which the ratio of an on-state current to an off-state current (also referred to as an on-off ratio) is high. Thus, the transistor preferably has a high on-state current, for example. Furthermore, for example, the off-state current is preferably low. As an example of a means for increasing the on-state current of the transistor, a method for increasing the channel width of the transistor can be given. Note that an on-state current refers to a current that flows between a source electrode and a drain electrode when a transistor is in an on state (a conduction state). An off-state current refers to a current that flows between a source electrode and a drain electrode when a transistor is in an off state (a non-conduction state).

A transistor of one embodiment of the present invention has a structure in which a semiconductor layer is surrounded by an electric field of a gate electrode. Note that in a structure in which a semiconductor layer is surrounded by an electric field of a gate electrode, the electric field of the gate electrode acts on at least part of the top surface of the semiconductor layer, at least part of the side surface of the semiconductor layer, and at least part of the bottom surface of the semiconductor layer. As long as the semiconductor layer is surrounded by the electric field of the gate electrode, the gate electrode is not necessarily provided to be located at at least part of the top surface of the semiconductor layer, at least part of the side surface of the semiconductor layer, and at least part of the bottom surface of the semiconductor layer. For example, the gate electrode may be located at at least part of one or more selected from the top surface of the semiconductor layer, the side surface of the semiconductor layer, and the bottom surface of the semiconductor layer. This structure makes it possible to increase the channel width of the transistor without increasing the size thereof. Thus, the current that can flow through the transistor can be increased while miniaturization of the transistor is achieved.

### Structure Example of Semiconductor Device

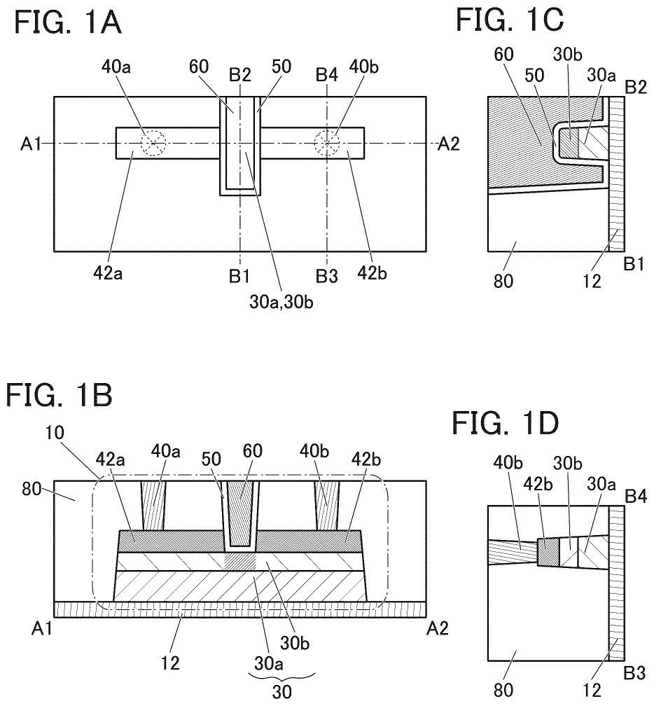

More specific structure examples of the semiconductor device will be described below with reference to FIG. 1A to FIG. 7D.

### Structure Example 1

A structure of a semiconductor device including a transistor 10 is described with reference to FIG. 1A to FIG. 1D. FIG. 1A to FIG. 1D are a top view and cross-sectional views of the semiconductor device including the transistor 10. FIG. 1A is a top view of the semiconductor device. FIG. 1B to FIG. 1D are cross-sectional views of the semiconductor device. Here, FIG. 1B is a cross-sectional view of a portion indicated by dashed-dotted line A1-A2 in FIG. 1A, and is a cross-sectional view of the transistor 10 in the channel length direction. FIG. 1C is a cross-sectional view of a portion indicated by dashed-dotted line B1-B2 in FIG. 1A, and is a cross-sectional view of the transistor 10 in the channel width direction. FIG. 1D is a cross-sectional view of a portion indicated by dashed-dotted line B3-B4 in FIG. 1A. Note that for clarity of the drawing, some components are omitted in the top view of FIG. 1A.

As illustrated in FIG. 1A to FIG. 1D, the transistor 10 includes an insulator 12 over a substrate (not illustrated), a semiconductor layer 30a over the insulator 12, a semiconductor layer 30b over the semiconductor layer 30a, a conductor 42a and a conductor 42b over the semiconductor layer 30b, an insulator 50 located over the semiconductor layer 30b and between the conductor 42a and the conductor 42b, a conductor 60 located over the insulator 50 and overlapping with part of the semiconductor layer 30b, and an insulator 80 located over the semiconductor layer 30a, the semiconductor layer 30b, the conductor 42a, and the conductor 42b.

Hereinafter, the semiconductor layer 30a and the semiconductor layer 30b are collectively referred to as a semiconductor layer 30 in some cases. The conductor 42a and the conductor 42b are collectively referred to as a conductor 42 in some cases.

The insulator 80 is located above the conductor 42a and the conductor 42b. An opening reaching the semiconductor layer 30b is provided in the insulator 80. That is, the opening includes a region that is between the conductor 42a and the conductor 42b and overlaps with the semiconductor layer 30b. The insulator 50 and the conductor 60 are located in the opening. That is, the conductor 60 includes a region overlapping with the semiconductor layer 30b with the insulator 50 therebetween. Furthermore, in the channel length direction of the transistor 10, the conductor 60 and the insulator 50 are provided between the conductor 42a and the conductor 42b. The insulator 50 includes a region in contact with the side surface of the conductor 60 and a region in contact with the bottom surface of the conductor 60.

The semiconductor layer 30b is formed into an island shape. Note that in this specification and the like, the term “island shape” refers to a state where two or more layers formed using the same material in the same step are physically separated from each other. The semiconductor layer 30a may be formed into an island shape.

The conductor 60 functions as a gate electrode, and the insulator 50 functions as a gate insulator. Note that the gate insulator is also referred to as a gate insulating layer or a gate insulating film in some cases. The conductor 42a functions as one of a source electrode and a drain electrode, and the conductor 42b functions as the other of the source electrode and the drain electrode. At least part of a region of the semiconductor layer 30b overlapping with the conductor 60 functions as a channel formation region.

In each of FIG. 1B and FIG. 1C, the diagonally shaded region of the semiconductor layer 30b is the channel formation region. The range of the channel formation region is difficult to detect clearly in some cases. Thus, FIG. 1B and FIG. 1C illustrate an example of the range of the channel formation region.

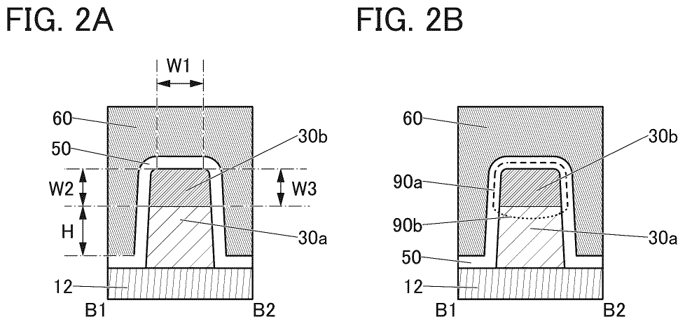

Here, FIG. 2A and FIG. 2B are enlarged views of the vicinity of the channel formation region in FIG. 1C. Note that FIG. 2A and FIG. 2B omit some components (e.g., the insulator 80) to avoid complexity of the drawings.

In a cross-sectional view in the channel width direction, the length of the top surface of the semiconductor layer 30b is a length W1. In the case where the shape of the top surface of the semiconductor layer 30b includes a curved surface or the like, the length W1 may be the length of the interface between the semiconductor layer 30a and the semiconductor layer 30b in a cross-sectional view in the channel width direction.

In a cross-sectional view in the channel width direction, the length of a first side surface of the semiconductor layer 30b is a length W2, and the length of a second side surface of the semiconductor layer 30b is a length W3. Note that the length W2 and the length W3 may each be the thickness of the semiconductor layer 30b. In that case, the length W2 and the length W3 can each be regarded as the distance from the top surface of the semiconductor layer 30b to the bottom surface of the semiconductor layer 30b. Note that the bottom surface of the semiconductor layer 30b can be rephrased as the interface between the semiconductor layer 30a and the semiconductor layer 30b.

As illustrated in FIG. 2A, there may be a curved surface between the side surface of the semiconductor layer 30b and the top surface of the semiconductor layer 30b. That is, an end portion of the side surface and an end portion of the top surface may be curved. In that case, the length W1 may be the length of a flat region of the top surface of the semiconductor layer 30b. The length W2 may be the sum of the length of the first side surface of the semiconductor layer 30b and the lengths of the curved surfaces of the first side surface and the top surface of the semiconductor layer 30b. The length W3 may be the sum of the length of the second side surface of the semiconductor layer 30b and the lengths of the curved surfaces of the second side surface and the top surface of the semiconductor layer 30b.

The length from the bottom surface of the semiconductor layer 30b to the lowermost surface of the conductor 60 is a length H. Note that the lowermost surface of the conductor 60 can be rephrased as the bottom surface of a region of the conductor 60 that does not overlap with the semiconductor layer 30b in a cross-sectional view in the channel width direction.

In a cross-sectional view of the transistor 10 in the channel width direction, the conductor 60 preferably covers the side surface and the top surface of the semiconductor layer 30b as illustrated in FIG. 1C. Specifically, in a cross-sectional view of the transistor 10 in the channel width direction, the conductor 60 preferably covers the side surface and the top surface of the channel formation region of the semiconductor layer 30b with the insulator 50 therebetween. That is, in a cross-sectional view of the transistor 10 in the channel width direction, with reference to the bottom surface of the insulator 12, the level of the lowermost surface of the conductor 60 is preferably lower than the level of the bottom surface of the semiconductor layer 30b. With such a structure, the electric field of the conductor 60 is likely to act on the channel formation region of the semiconductor layer 30b. Thus, the on-state current of the transistor 10 can be increased.

The permittivity of the semiconductor layer 30b is preferably higher than that of the semiconductor layer 30a.

Furthermore, the length W1 is preferably less than or equal to 20 nm, further preferably less than or equal to 10 nm. Specifically, the length W1 is greater than or equal to 1 nm and less than or equal to 20 nm, preferably greater than or equal to 1 nm and less than or equal to 15 nm, further preferably greater than or equal to 1 nm and less than or equal to 10 nm, still further preferably greater than or equal to 3 nm and less than or equal to 5 nm.

When the permittivities of the semiconductor layer 30a and the semiconductor layer 30b and the length W1 satisfy the above, the electric field of the conductor 60 on the first side surface side of the semiconductor layer 30b and the electric field of the conductor 60 on the second side surface side of the semiconductor layer 30b can be connected to each other below the semiconductor layer 30b. In other words, the electric field of the conductor 60 can surround the semiconductor layer 30b.

A dashed line 90a in FIG. 2B denotes the electric field of the conductor 60 on the top surface side of the semiconductor layer 30b, the electric field of the conductor 60 on the first side surface side of the semiconductor layer 30b, and the electric field of the conductor 60 on the second side surface side of the semiconductor layer 30b. A dotted line 90b in FIG. 2B conceptually shows connection of the electric field of the conductor 60 on the first side surface side of the semiconductor layer 30b and the electric field of the conductor 60 on the second side surface side of the semiconductor layer 30b below the semiconductor layer 30b. In the case where the electric field denoted by the dashed line 90a acts on the semiconductor layer 30b, the channel width is the sum of the length W1, the length W2, and the length W3. Meanwhile, in the case where the electric field denoted by the dashed line 90a and the electric field denoted by the dotted line 90b act on the semiconductor layer 30b, the channel width is larger than the sum of the length W1, the length W2, and the length W3. Specifically, the channel width is the length of the perimeter of the semiconductor layer 30b in a cross-sectional view in the channel width direction.

Accordingly, the electric field of the conductor 60 can act on the semiconductor layer 30b from the top surface, the first side surface, the second side surface, and the bottom surface thereof. That is, the electric field of the conductor 60 can act on the entire channel formation region of the semiconductor layer 30b. It is thus possible to increase the channel width of the transistor without increasing the size thereof. Thus, the on-state current of the transistor 10 can be increased while miniaturization of the transistor is achieved. The increase in on-state current of the transistor 10 can improve the frequency characteristics.

The transistor 10 has a structure in which the semiconductor layer 30b is surrounded by the electric field of the conductor 60 functioning as the gate electrode. Thus, the transistor 10 can be regarded as substantially having a GAA (Gate All Around) structure.

The length H is preferably larger than the length W2. The length H is preferably larger than the length W3. In other words, the length W2 and the length W3 are each preferably smaller than the length H. For example, the length W2 and the length W3 are each preferably less than or equal to 20 nm. Specifically, the length W2 and the length W3 are each greater than or equal to 1 nm and less than or equal to 20 nm, preferably greater than or equal to 3 nm and less than or equal to 10 nm, further preferably greater than or equal to 3 nm and less than or equal to 5 nm. The length H exceeds the length W2 and is less than or equal to 100 nm, preferably exceeds the length W2 and is less than or equal to 50 nm, further preferably exceeds the length W2 and is less than or equal to 30 nm. Such a structure facilitates connection of the electric field of the conductor 60 on the first side surface side of the semiconductor layer 30b and the electric field of the conductor 60 on the second side surface side of the semiconductor layer 30b below the semiconductor layer 30b. Accordingly, the on-state current of the transistor 10 can be increased.

In the case where the distance between a lower end portion of the conductor 42a and a lower end portion of the conductor 42b is regarded as the channel length of the transistor 10, the channel length of the transistor 10 is preferably substantially the same as the length W1. For example, the channel length of the transistor 10 is preferably less than or equal to 20 nm, further preferably less than or equal to 10 nm. Specifically, the channel length of the transistor 10 is greater than or equal to 1 nm and less than or equal to 20 nm, preferably greater than or equal to 1 nm and less than or equal to 15 nm, further preferably greater than or equal to 1 nm and less than or equal to 10 nm, still further preferably greater than or equal to 3 nm and less than or equal to 5 nm.

In the transistor 10, the semiconductor layer 30 (the semiconductor layer 30a and the semiconductor layer 30b) including the channel formation region preferably includes a semiconductor material having a wide band gap. For example, the band gap of the semiconductor material is preferably wider than the band gap of silicon. Specifically, the band gap of the semiconductor material is preferably wider than 1.1 eV, further preferably wider than or equal to 1.5 eV, still further preferably wider than or equal to 2.0 eV.

For example, in a transistor including silicon in its channel formation region (also referred to as a Si transistor), a short-channel effect appears as miniaturization of the transistor proceeds. This hinders miniaturization of a Si transistor. One factor in causing the short-channel effect is a narrow band gap of silicon. Thus, using a semiconductor material having a wide band gap sometimes makes it possible to inhibit a short-channel effect. In that case, a transistor with favorable electrical characteristics can be provided.

The short-channel effect refers to degradation of electrical characteristics that becomes obvious along with miniaturization of a transistor (a decrease in channel length). The short-channel effect results from the effect of the electric field of a drain on a source. Examples of the short-channel effect include drain-induced barrier lowering (DIBL), electron velocity saturation, and hot-carrier degradation. Specific examples of the short-channel effect include a decrease in threshold voltage, an increase in subthreshold swing value (sometimes referred to as S value or S.S.), and an increase in leakage current. Here, the S value refers to the amount of change in a gate voltage which makes the drain current change by one digit in a subthreshold region at a constant drain voltage.

The characteristic length is widely used as an indicator of resistance to a short-channel effect. The characteristic length is an indicator of curving of a potential in a channel formation region. The smaller the characteristic length is, the more sharply the potential rises; thus, a smaller characteristic length indicates higher resistance to a short-channel effect. Note that in this specification and the like, high resistance to a short-channel effect or high durability against a short-channel effect may be expressed using a phrase “a short-channel effect does not appear or hardly appears”.

The semiconductor layer 30 including the channel formation region can be formed using a metal oxide (also referred to as an oxide semiconductor) functioning as a semiconductor, for example.

The metal oxide functioning as a semiconductor preferably has a band gap wider than or equal to 2 eV, further preferably wider than or equal to 2.5 eV. With use of a metal oxide having a wide band gap, the off-state current of the transistor can be reduced.

For the semiconductor layer 30, a metal oxide such as indium oxide, gallium oxide, or zinc oxide is preferably used, for example. Alternatively, for the semiconductor layer 30, a metal oxide containing two or three selected from indium, an element M, and zinc is preferably used, for example. The element M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium. Specifically, the element M is preferably one or more selected from aluminum, gallium, yttrium, and tin. Note that a metal oxide containing indium, the element M, and zinc is referred to as an In-M-Zn oxide in some cases.

The semiconductor layer 30 preferably has a stacked-layer structure of a plurality of oxide layers with different chemical compositions. For example, the atomic ratio of the element M to a metal element that is a main component in the metal oxide used in the semiconductor layer 30b is preferably lower than the atomic ratio of the element M to a metal element that is a main component in the metal oxide used in the semiconductor layer 30a. Moreover, the atomic ratio of the element M to In in the metal oxide used in the semiconductor layer 30b is preferably lower than the atomic ratio of the element M to In in the metal oxide used in the semiconductor layer 30a. With such a structure, the permittivity of the semiconductor layer 30b can be higher than the permittivity of the semiconductor layer 30a.

The band gap of the metal oxide can be evaluated using one or more of optical evaluation with a spectrophotometer, spectroscopic ellipsometry, a photoluminescence method, X-ray photoelectron spectroscopy (XPS or ESCA: Electron Spectroscopy for Chemical Analysis), an X-ray absorption fine structure (XAFS), and the like.

The composition of the metal oxide can be evaluated using an inductively coupled plasma-mass spectrometry (ICP-MS), XPS, SEM (Scanning Electron Microscopy)-EDX (Energy Dispersive X-ray Spectroscopy), secondary ion mass spectrometry (SIMS), or the like.

In the case where an oxide semiconductor is used for the semiconductor layer 30, at least the semiconductor layer 30b preferably has crystallinity. It is particularly preferable to use a CAAC-OS (c-axis aligned crystalline oxide semiconductor) as the semiconductor layer 30b.

The CAAC-OS is an oxide semiconductor having a dense structure with high crystallinity and small amounts of impurities and defects (for example, oxygen vacancies). In particular, after the formation of an oxide semiconductor, heat treatment is performed at a temperature at which the oxide semiconductor does not become a polycrystal (e.g., higher than or equal to 400° C. and lower than or equal to 600° C.), whereby a CAAC-OS having a dense structure with higher crystallinity can be obtained. When the density of the CAAC-OS is increased in such a manner, diffusion of impurities or oxygen in the CAAC-OS can be further reduced.

A clear crystal grain boundary is difficult to observe in the CAAC-OS; thus, it can be said that a reduction in electron mobility due to the crystal grain boundary is less likely to occur. Thus, a metal oxide including the CAAC-OS is physically stable. Therefore, the metal oxide including the CAAC-OS is resistant to heat and has high reliability.

Note that the semiconductor material that can be used for the semiconductor layer 30 including the channel formation region is not limited to the above-described oxide semiconductors. For example, a compound semiconductor or a layered substance (also referred to as an atomic layer substance, a two-dimensional material, or the like) may be used for the semiconductor layer 30. Examples of the compound semiconductor include silicon carbide, silicon germanium, gallium arsenide, indium phosphide, zinc oxide, and gallium oxide.

Here, in this specification and the like, the layered substance generally refers to a group of materials having a layered crystal structure. In the layered crystal structure, layers formed by covalent bonding or ionic bonding are stacked with bonding such as the Van der Waals force, which is weaker than covalent bonding or ionic bonding. The layered substance has high electrical conductivity in a unit layer, that is, high two-dimensional electrical conductivity. When a material that functions as a semiconductor and has high two-dimensional electrical conductivity is used for a channel formation region, a transistor having a high on-state current can be provided.

Examples of the layered substance include graphene, silicene, and chalcogenide. Chalcogenide is a compound containing chalcogen. Chalcogen is a general term for elements belonging to Group 16 and includes oxygen, sulfur, selenium, tellurium, polonium, and livermorium. Examples of chalcogenide include transition metal chalcogenide and chalcogenide of Group 13 elements.

For the semiconductor layer 30, transition metal chalcogenide functioning as a semiconductor is preferably used, for example. Specific examples of the transition metal chalcogenide that can be used for the semiconductor layer 30 include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

A conductive material that is less likely to be oxidized, a conductive material having a function of inhibiting diffusion of oxygen, or the like is preferably used for the conductor 42a and the conductor 42b. Examples of the conductive material include a conductive material containing nitrogen, a conductive material containing oxygen, and the like. Using the conductive material can inhibit a reduction in the conductivity of the conductor 42a and the conductor 42b. In the case where a conductive material containing a metal element and nitrogen is used for the conductor 42a and the conductor 42b, the conductor 42a and the conductor 42b include at least the metal element and nitrogen.

As the conductor 42a and the conductor 42b, for example, a nitride containing tantalum, a nitride containing titanium, a nitride containing molybdenum, a nitride containing tungsten, a nitride containing tantalum and aluminum, or a nitride containing titanium and aluminum is preferably used. As another example, ruthenium oxide, ruthenium nitride, an oxide containing strontium and ruthenium, or an oxide containing lanthanum and nickel may be used. These materials are preferable because they are each a conductive material that is less likely to be oxidized or a material that maintains the conductivity even after absorbing oxygen.

In one embodiment of the present invention, a nitride containing tantalum or a nitride containing titanium is particularly preferably used for the conductor 42a and the conductor 42b. In this case, the conductor 42a and the conductor 42b include tantalum or titanium and nitrogen.

Note that hydrogen included in the semiconductor layer 30 or the like diffuses into the conductor 42a or the conductor 42b in some cases. In particular, when a nitride containing tantalum is used for the conductor 42a and the conductor 42b, hydrogen included in the semiconductor layer 30 or the like is likely to diffuse into the conductor 42a or the conductor 42b, and the diffused hydrogen is bonded to nitrogen included in the conductor 42a or the conductor 42b in some cases. That is, hydrogen included in the semiconductor layer 30 or the like is absorbed by the conductor 42a or the conductor 42b in some cases.

When heat treatment is performed in the state where the conductor 42a or the conductor 42b and the semiconductor layer 30 including an oxide semiconductor are in contact with each other, the sheet resistance of the semiconductor layer 30 in a region in contact with the conductor 42a or the conductor 42b decreases in some cases. Furthermore, the carrier concentration sometimes increases. Thus, the resistance of the semiconductor layer 30 in the region overlapping with the conductor 42a or the conductor 42b can be lowered in a self-aligned manner.

Although FIG. 1A to FIG. 1D illustrate a structure where each of the conductor 42a and the conductor 42b has a single-layer structure, the present invention is not limited to this structure, and a stacked-layer structure of two or more layers may be employed.

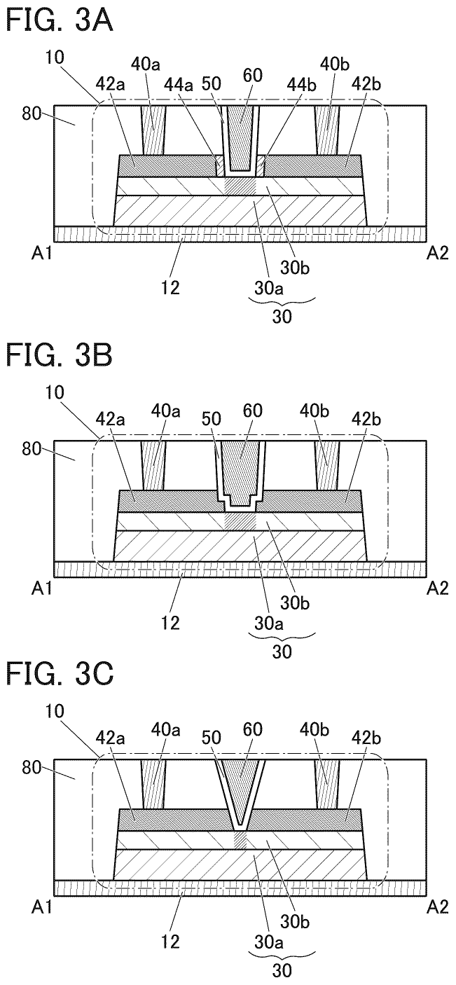

Note that a side surface of the conductor 42a on the conductor 60 side is oxidized to form an insulator in some cases. A side surface of the conductor 42b on the conductor 60 side is oxidized to form an insulator in some cases. FIG. 3A is a cross-sectional view of a semiconductor device in which these insulators are formed.

The semiconductor device illustrated in FIG. 3A includes an insulator 44a located between the conductor 42a and the insulator 50 and an insulator 44b located between the conductor 42b and the insulator 50. The insulator 44a is formed by oxidation of the side surface of the conductor 42a on the conductor 60 side. The insulator 44b is formed by oxidation of the side surface of the conductor 42b on the conductor 60 side.

Since the insulator 44a and the insulator 44b are formed, the distance between the conductor 42a and the conductor 60 and the distance between the conductor 42b and the conductor 60 can be increased, so that parasitic capacitance between the conductor 42a and the conductor 60 and parasitic capacitance between the conductor 42b and the conductor 60 can be reduced. Thus, the switching speed of the transistor 10 can be improved, and the transistor 10 can have high frequency characteristics.

As will be described in detail in Embodiment 3, the insulator 44a and the insulator 44b are formed in a self-aligned manner in a step of forming the conductor 42a and the conductor 42b or after forming the conductor 42a and the conductor 42b. Thus, parasitic capacitance between the conductor 42a and the conductor 60 and parasitic capacitance between the conductor 42b and the conductor 60 can be reduced in a self-aligned manner.

In the case where an oxide semiconductor is used for the semiconductor layer 30, an insulator that easily transmits oxygen is preferably used as the insulator 50. With such a structure, oxygen included in the insulator 80 can be supplied to the channel formation region of the semiconductor layer 30 through the insulator 50. As the insulator 50, for example, silicon oxide, silicon oxynitride, silicon oxide to which fluorine is added, silicon oxide to which carbon is added, silicon oxide to which carbon and nitrogen are added, porous silicon oxide, or the like can be used. In particular, silicon oxide and silicon oxynitride, which are thermally stable, are preferable. In this case, the insulator 50 includes at least oxygen and silicon.

The concentration of impurities such as water and hydrogen in the insulator 50 is preferably reduced.

The thickness of the insulator 50 is preferably greater than or equal to 0.1 nm and less than or equal to 20 nm, further preferably greater than or equal to 0.5 nm and less than or equal to 15 nm. In particular, in order to manufacture a minute transistor (e.g., a transistor with a gate length less than or equal to 10 nm), the thickness of the insulator 50 is preferably greater than or equal to 0.5 nm and less than or equal to 10 nm, further preferably greater than or equal to 0.5 nm and less than or equal to 5 nm. In the above case, at least part of the insulator 50 includes a region having a thickness like the above-described thickness.

Although FIG. 1A to FIG. 1D illustrate a single-layer structure of the insulator 50, the present invention is not limited to this structure, and a stacked-layer structure of two or more layers may be employed.

A conductive material containing tungsten, copper, or aluminum as its main component is preferably used for the conductor 60. The conductor 60 may have a stacked-layer structure; for example, a stack of the above conductive material and titanium or titanium nitride may be employed.

The insulator 12 preferably functions as a barrier insulating film inhibiting diffusion of impurities such as water and hydrogen into the transistor 10 from the substrate side. Thus, for the insulator 12, it is preferable to use an insulating material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), or a copper atom (an insulating material that is less permeable to the impurities). Alternatively, it is preferable to use an insulating material having a function of inhibiting diffusion of oxygen (e.g., at least one of an oxygen atom, an oxygen molecule, and the like) (an insulating material that is less permeable to the oxygen).

Note that in this specification, a barrier insulating film refers to an insulating film having a barrier property. A barrier property in this specification means a function of inhibiting diffusion of a targeted substance (also referred to as having low permeability). Alternatively, the barrier property means a function of capturing and fixing (also referred to as gettering) a targeted substance.

An insulator having a function of inhibiting diffusion of oxygen and impurities such as water and hydrogen is preferably used for the insulator 12; for example, aluminum oxide, magnesium oxide, hafnium oxide, gallium oxide, indium gallium zinc oxide, silicon nitride, silicon nitride oxide, or the like can be used for the insulator 12. An insulator having a higher hydrogen barrier property may be used for the insulator 12. For example, silicon nitride or the like is preferably used for the insulator 12. As the insulator 12, an insulator which has high hydrogen-trapping and hydrogen-fixing capabilities may be used. For example, aluminum oxide or magnesium oxide is preferably used as the insulator 12. In that case, impurities such as water and hydrogen can be inhibited from diffusing into the transistor 10 from the substrate side through the insulator 12. Alternatively, oxygen included in the semiconductor layer 30 can be inhibited from diffusing to the substrate side through the insulator 12. Therefore, these materials are suitable for the case where an oxide semiconductor is used for the semiconductor layer 30.

Here, an oxide having an amorphous structure is preferably used for the insulator 12. For example, a metal oxide such as AlOₓ (x is a given number greater than 0) or MgO_{y}. (y is a given number greater than 0) is preferably used. In such a metal oxide having an amorphous structure, an oxygen atom has a dangling bond and sometimes has a property of capturing or fixing hydrogen with the dangling bond. When such a metal oxide having an amorphous structure is used as the component of the transistor 10 or provided around the transistor 10, hydrogen included in the transistor 10 or hydrogen around the transistor 10 can be captured or fixed. In particular, hydrogen included in the channel formation region of the transistor 10 is preferably captured or fixed. When the metal oxide having an amorphous structure is used as a component of the transistor 10 or provided around the transistor 10, the transistor 10 and the semiconductor device which have favorable characteristics and high reliability can be manufactured.

Although the insulator 12 preferably has an amorphous structure, a region having a polycrystalline structure may be partly formed. The insulator 12 may have a multilayer structure in which a layer having an amorphous structure and a layer having a polycrystalline structure are stacked. For example, a stacked-layer structure in which a layer having a polycrystalline structure is formed over a layer having an amorphous structure may be employed.

Although FIG. 1A to FIG. 1D illustrate a single-layer structure of the insulator 12, the present invention is not limited to this structure, and a stacked-layer structure of two or more layers may be employed.

The insulator 80 is provided over the insulator 12, the semiconductor layer 30a, the semiconductor layer 30b, the conductor 42a, and the conductor 42b.

As the insulator 80, an insulator containing oxygen that is released by heating (hereinafter, sometimes referred to as excess oxygen) is preferably used. For the insulator 80, for example, an oxide containing silicon such as silicon oxide, silicon oxynitride, silicon oxide to which fluorine is added, silicon oxide to which carbon is added, silicon oxide to which carbon and nitrogen are added, or porous silicon oxide is preferably used. In particular, silicon oxide and silicon oxynitride, which are thermally stable, are preferable. A material such as silicon oxide, silicon oxynitride, or porous silicon oxide is preferably used, in which case a region including excess oxygen can be easily formed. These materials are suitable for the case where an oxide semiconductor is used for the semiconductor layer 30.

The insulator 80, which functions as an interlayer film, preferably has a low permittivity. When a material with a low permittivity is used for the interlayer film, parasitic capacitance generated between wirings can be reduced. The above-described oxide containing silicon is preferable because it is a material with a low permittivity.

The concentration of impurities such as water and hydrogen in the insulator 80 is preferably reduced.

The shape of the opening provided in the insulator 80 and reaching the semiconductor layer 30b and the shapes of the side surfaces of the conductor 42a and the conductor 42b are not limited to those illustrated in FIG. 1B. Semiconductor devices in each of which the shapes of the opening and the side surfaces are different from those illustrated in FIG. 1B are described with reference to FIG. 3B and FIG. 3C. FIG. 3B and FIG. 3C are cross-sectional views of the semiconductor devices.

In the semiconductor device illustrated in FIG. 3B, the side surface of the conductor 42a on the conductor 60 side and the side surface of the conductor 42b on the conductor 60 side each have a step. In other words, the side surface of the conductor 42a on the conductor 60 side and the side surface of the conductor 42b on the conductor 60 side each include a first side surface and a second side surface. Note that the angle formed by the first side surface and the top surface of the semiconductor layer 30b is substantially equal to the angle formed by the second side surface and the top surface of the semiconductor layer 30b. In other words, a region between the side surface of the conductor 42a on the conductor 60 side and the side surface of the conductor 42b on the conductor 60 side includes a first region where the distance between the side surface of the conductor 42a on the conductor 60 side and the side surface of the conductor 42b on the conductor 60 side is a first distance and a second region where the distance between the side surface of the conductor 42a on the conductor 60 side and the side surface of the conductor 42b on the conductor 60 side is a second distance. Note that the second distance is larger than the first distance, and the second region is located above the first region.

In the semiconductor device illustrated in FIG. 3C, the side surface of the conductor 42a on the conductor 60 side and the side surface of the conductor 42b on the conductor 60 side each have a tapered shape. Note that in this specification and the like, a tapered shape refers to a shape such that at least part of a side surface of a component is inclined to a substrate surface. For example, there is a region where the angle formed between the inclined side surface and the substrate surface (hereinafter, the angle is sometimes referred to as a taper angle) is less than 90°. The taper angle of each of the side surface of the conductor 42a on the conductor 60 side and the side surface of the conductor 42b on the conductor 60 side is preferably smaller than the taper angle of the side surface of the semiconductor layer 30b, for example. Specifically, the taper angle of each of the side surface of the conductor 42a on the conductor 60 side and the side surface of the conductor 42b on the conductor 60 side is preferably greater than or equal to 45° and less than 75°.

In the structures illustrated in FIG. 3B and FIG. 3C, no offset region is formed between the channel formation region and a source region or a drain region. Thus, an increase in on-state current, a reduction in threshold voltage, an increase in operating frequency, and the like can be achieved.

The semiconductor device illustrated in FIG. 1A to FIG. 1D includes a conductor 40a and a conductor 40b electrically connected to the transistor 10 and functioning as plugs.

The conductor 40a is provided in contact with the inner wall of an opening in the insulator 80, and the conductor 40b is provided in contact with the inner wall of an opening in the insulator 80. The conductor 40a includes a region in contact with part of the top surface of the conductor 42a, and the conductor 40b includes a region in contact with part of the top surface of the conductor 42b. The top surface of the conductor 40a and the top surface of the conductor 40b are each level or substantially level with the top surface of the insulator 80.

Although the conductor 40a and the conductor 40b in the transistor 10 are each a single layer, the present invention is not limited thereto. For example, the conductor 40a and the conductor 40b may each have a stacked-layer structure of two or more layers.

### <Component Material of Semiconductor Device>

Component materials that can be used for the semiconductor device are described below.

### <<Substrate>>

As a substrate where the transistor 10 is formed, an insulator substrate, a semiconductor substrate, or a conductor substrate is used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, or gallium oxide. Another example is a semiconductor substrate having an insulator region in the semiconductor substrate described above, e.g., an SOI (Silicon On Insulator) substrate. Examples of the conductor substrate include a graphite substrate, a metal substrate, an alloy substrate, and a conductive resin substrate. Other examples include a substrate including a metal nitride and a substrate including a metal oxide. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided for the substrate include a capacitor, a resistor, a switching element, a light-emitting element, and a storage element.

### <<Insulator>

Examples of the insulator include an insulating oxide, an insulating nitride, an insulating oxynitride, an insulating nitride oxide, an insulating metal oxide, an insulating metal oxynitride, and an insulating metal nitride oxide.

As miniaturization and high integration of transistors progress, for example, a problem such as a leakage current may arise because of a thinner gate insulator. When a high-k material is used for the insulator functioning as a gate insulator, the voltage at the time of the operation of the transistor can be reduced while the physical thickness is maintained. In contrast, when a material with a low relative permittivity is used for the insulator functioning as an interlayer film, parasitic capacitance generated between wirings can be reduced. Thus, a material is preferably selected depending on the function of the insulator.

Examples of the insulator with a high relative permittivity include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the insulator with a low relative permittivity include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

When a transistor including a metal oxide is surrounded by an insulator having a function of inhibiting passage of oxygen and impurities such as hydrogen, the transistor can have stable electrical characteristics. As the insulator having a function of inhibiting passage of oxygen and impurities such as hydrogen, a single layer or stacked layers of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum may be used. Specifically, as the insulator having a function of inhibiting passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be used.

The insulator functioning as the gate insulator preferably includes a region including excess oxygen. For example, when a structure is employed in which silicon oxide or silicon oxynitride that includes a region including excess oxygen is in contact with the semiconductor layer 30, oxygen vacancies included in the semiconductor layer 30 can be compensated for. Therefore, these materials are suitable for the case where an oxide semiconductor is used for the semiconductor layer 30.

### <<Conductor>>

As a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are conductive materials that are less likely to be oxidized or materials that maintain their conductivity even after absorbing oxygen. Alternatively, a semiconductor having high electrical conductivity, typified by polycrystalline silicon containing an impurity element such as phosphorus, or silicide such as nickel silicide may be used.

A stack of a plurality of conductive layers formed of the above materials may be used. For example, a stacked-layer structure combining a material containing the above metal element and a conductive material containing oxygen may be employed. In addition, a stacked-layer structure combining a material containing the above metal element and a conductive material containing nitrogen may be employed. Furthermore, a stacked-layer structure combining a material containing the above metal element, a conductive material containing oxygen, and a conductive material containing nitrogen may be employed.

In the case where an oxide is used for the channel formation region of the transistor, the conductor functioning as the gate electrode preferably employs a stacked-layer structure combining a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in the metal oxide where the channel is formed. A conductive material containing the above metal element and nitrogen may be used. For example, a conductive material containing nitrogen, such as titanium nitride or tantalum nitride, may be used. Indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from an external insulator or the like can be captured in some cases.

### <<Metal Oxide>>

The semiconductor layer 30 is preferably formed using a metal oxide (an oxide semiconductor) functioning as a semiconductor. A metal oxide that can be used for the semiconductor layer 30 according to the present invention is described below.

Examples of the metal oxide include indium oxide, gallium oxide, and zinc oxide. The metal oxide preferably contains two or three selected from indium, the element M, and zinc. The element M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium. In particular, the element M is preferably one or more selected from aluminum, gallium, yttrium, and tin.

It is particularly preferable to use an oxide containing indium (In), gallium (Ga), and zinc (Zn) (also referred to as IGZO) for the metal oxide. Alternatively, it is preferable to use an oxide containing indium, tin, and zinc (also referred to as ITZO (registered trademark)). Alternatively, it is preferable to use an oxide containing indium, gallium, tin, and zinc. Alternatively, an oxide containing indium (In), aluminum (Al), and zinc (Zn) (also referred to as IAZO) is preferably used. Alternatively, an oxide containing indium (In), aluminum (Al), gallium (Ga), and zinc (Zn) (IAGZO or IGAZO) is preferably used.

The metal oxide used in an OS transistor may include two or more metal oxide layers with different compositions. For example, a stacked-layer structure of a first metal oxide layer with a composition of In:M:Zn=1:3:4 [atomic ratio] or in the neighborhood thereof and a second metal oxide layer with a composition of In:M:Zn=1:1:1 [atomic ratio] or in the neighborhood thereof provided over the first metal oxide layer can be favorably employed.

Alternatively, a stacked-layer structure of one selected from indium oxide, indium gallium oxide, and IGZO, and one selected from IAZO, IAGZO, and ITZO (registered trademark) may be employed, for example.

Note that in this specification and the like, a metal oxide containing nitrogen is also collectively referred to as a metal oxide in some cases. A metal oxide containing nitrogen may be referred to as a metal oxynitride.

Hereinafter, an oxide containing indium (In), gallium (Ga), and zinc (Zn) is described as an example of the metal oxide. Note that an oxide containing indium (In), gallium (Ga), and zinc (Zn) may be referred to as In—Ga—Zn oxide.

### <Classification of Crystal Structure>

Amorphous (including completely amorphous), CAAC (c-axis-aligned crystalline), nc (nanocrystalline), CAC (cloud-aligned composite), single crystal, and polycrystalline (poly crystal) structures can be given as examples of a crystal structure of an oxide semiconductor.

Note that the crystal structure of a film or a substrate can be evaluated with an X-ray diffraction (XRD) spectrum. For example, evaluation is possible using an XRD spectrum that is obtained by GIXD (Grazing-Incidence XRD) measurement. Note that a GIXD method is also referred to as a thin film method or a Seemann-Bohlin method. Hereinafter, an XRD spectrum obtained from GIXD measurement is simply referred to as an XRD spectrum in some cases.

For example, the XRD spectrum of a quartz glass substrate shows a peak with a substantially bilaterally symmetrical shape. On the other hand, the peak of the XRD spectrum of an In—Ga—Zn oxide film having a crystal structure has a bilaterally asymmetrical shape. The bilaterally asymmetrical peak of the XRD spectrum clearly shows the existence of a crystal in the film or the substrate. In other words, the film or the substrate cannot be regarded as being in an amorphous state unless it has a bilaterally symmetrical peak in the XRD spectrum.

The crystal structure of a film or a substrate can be evaluated with a diffraction pattern observed by a nanobeam electron diffraction (NBED) method (such a pattern is also referred to as a nanobeam electron diffraction pattern). For example, a halo pattern is observed in the diffraction pattern of a quartz glass substrate, which indicates that quartz glass is in an amorphous state. Furthermore, not a halo pattern but a spot-like pattern is observed in the diffraction pattern of an In—Ga—Zn oxide film formed at room temperature. This suggests that the In—Ga—Zn oxide film formed at room temperature is in an intermediate state, which is neither a single crystal nor polycrystal nor an amorphous state, and it cannot be concluded that the In—Ga—Zn oxide film is in an amorphous state.

### <<Structure of Oxide Semiconductor>>

Note that oxide semiconductors might be classified in a manner different from the above-described one when classified in terms of the structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS are described in detail.

### [CAAC-OS]

The CAAC-OS is an oxide semiconductor that has a plurality of crystal regions each of which has c-axis alignment in a particular direction. Note that the particular direction refers to the thickness direction of a CAAC-OS film, the normal direction of the surface where the CAAC-OS film is formed, or the normal direction of the surface of the CAAC-OS film. The crystal region refers to a region having a periodic atomic arrangement. Note that when an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the orientation of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more minute crystals (crystals each of which has a maximum diameter less than 10 nm). In the case where the crystal region is formed of one minute crystal, the maximum diameter of the crystal region is less than 10 nm. In the case where the crystal region is formed of a large number of minute crystals, the maximum diameter of the crystal region may be approximately several tens of nanometers.

In the case of In—Ga—Zn oxide, the CAAC-OS tends to have a layered crystal structure (also referred to as a layered structure) in which a layer including indium (In) and oxygen (hereinafter, an In layer) and a layer including gallium (Ga), zinc (Zn), and oxygen (hereinafter, a (Ga,Zn) layer) are stacked. Note that indium and gallium can be replaced with each other. Therefore, indium may be included in the (Ga,Zn) layer. In addition, gallium may be included in the In layer. Note that zinc may be included in the In layer. Such a layered structure is observed as a lattice image in a high-resolution TEM (Transmission Electron Microscope) image, for example.

When the CAAC-OS film is subjected to structural analysis by Out-of-plane XRD measurement with an XRD apparatus using θ/2θ scanning, for example, a peak indicating c-axis alignment is detected at or around 2θ of 31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of an incident electron beam passing through a sample (also referred to as a direct spot) as a symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear grain boundary cannot be observed even in the vicinity of the distortion in the CAAC-OS. That is, formation of a crystal grain boundary is inhibited by the distortion of lattice arrangement. This is probably because the CAAC-OS can tolerate distortion owing to a low density of arrangement of oxygen atoms in the a-b plane direction, an interatomic bond distance changed by substitution of a metal atom, and the like.

Note that a crystal structure where a clear crystal grain boundary is observed is what is called polycrystal. It is highly probable that the crystal grain boundary becomes a recombination center and captures carriers and thus decreases the on-state current and field-effect mobility of a transistor, for example. Thus, the CAAC-OS in which no clear crystal grain boundary is observed is one of crystalline oxides having a crystal structure suitable for a semiconductor layer of a transistor. Note that Zn is preferably included to form the CAAC-OS. For example, In—Zn oxide and In—Ga—Zn oxide are suitable because they can inhibit generation of a crystal grain boundary as compared with In oxide.

The CAAC-OS is an oxide semiconductor with high crystallinity in which no clear crystal grain boundary is observed. Thus, in the CAAC-OS, a reduction in electron mobility due to the crystal grain boundary is unlikely to occur. Moreover, since the crystallinity of an oxide semiconductor might be reduced by entry of impurities, formation of defects, or the like, the CAAC-OS can also be regarded as an oxide semiconductor that has small amounts of impurities and defects (e.g., oxygen vacancies). Thus, the physical properties of an oxide semiconductor including the CAAC-OS are stable. Therefore, the oxide semiconductor including the CAAC-OS is resistant to heat and has high reliability. In addition, the CAAC-OS is also stable with respect to high temperatures in the manufacturing process (what is called thermal budget). Accordingly, the use of the CAAC-OS for the transistor including a metal oxide in its channel formation region (referred to as an OS transistor in some cases) can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a minute crystal. Note that the size of the minute crystal is, for example, greater than or equal to 1 nm and less than or equal to 10 nm, particularly greater than or equal to 1 nm and less than or equal to 3 nm; thus, the minute crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods. For example, when an nc-OS film is subjected to structural analysis by Out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter greater than the diameter of a nanocrystal (e.g., greater than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or less than the diameter of a nanocrystal (e.g., greater than or equal to 1 nm and less than or equal to 30 nm).

[a-like OS]

The a-like OS is an oxide semiconductor having a structure between those of the nc-OS and the amorphous oxide semiconductor. The a-like OS includes a void or a low-density region. That is, the a-like OS has lower crystallinity than the nc-OS and the CAAC-OS. Moreover, the a-like OS has a higher hydrogen concentration in the film than the nc-OS and the CAAC-OS.

### <<Structure of Oxide Semiconductor>>

Next, the above-described CAC-OS is described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state where one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter also referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Here, the atomic ratio of In, Ga, and Zn to the metal elements contained in the CAC-OS in In—Ga—Zn oxide are denoted by [In], [Ga], and [Zn], respectively. For example, the first region in the CAC-OS in the In—Ga—Zn oxide is a region having [In] higher than [In] in the composition of the CAC-OS film. Moreover, the second region is a region having [Ga] higher than [Ga] in the composition of the CAC-OS film. Alternatively, for example, the first region is a region having [In] higher than [In] in the second region and [Ga] lower than [Ga] in the second region. Moreover, the second region is a region having [Ga] higher than [Ga] in the first region and [In] lower than [In] in the first region.

Specifically, the first region is a region including indium oxide, indium zinc oxide, or the like as its main component. The second region is a region including gallium oxide, gallium zinc oxide, or the like as its main component. That is, the first region can be rephrased as a region including In as its main component. The second region can be rephrased as a region including Ga as its main component.

Note that a clear boundary between the first region and the second region cannot be observed in some cases.

In addition, in a material composition of a CAC-OS in In—Ga—Zn oxide that includes In, Ga, Zn, and O, there are regions including Ga as a main component in part of the CAC-OS and regions including In as a main component in another part of the CAC-OS. These regions are randomly present to form a mosaic pattern. Thus, it is suggested that the CAC-OS has a structure where metal elements are unevenly distributed.

The CAC-OS can be formed by a sputtering method under a condition where a substrate is not heated, for example. In addition, in the case of forming the CAC-OS by a sputtering method, one or more selected from an inert gas (typically, argon), an oxygen gas, and a nitrogen gas are used as a film formation gas. The proportion of the flow rate of an oxygen gas in the total flow rate of the film formation gas during film formation is preferably as low as possible. For example, the proportion of the flow rate of an oxygen gas in the total flow rate of the film formation gas during film formation is higher than or equal to 0% and lower than 30%, preferably higher than or equal to 0% and lower than or equal to 10%.

For example, energy dispersive X-ray spectroscopy (EDX) is used to obtain EDX mapping, and according to the EDX mapping, the CAC-OS in the In—Ga—Zn oxide has a structure where the region including In as its main component (the first region) and the region including Ga as its main component (the second region) are unevenly distributed and mixed.

Here, the first region is a region having higher conductivity than the second region. That is, when carriers flow through the first region, the conductivity of a metal oxide is exhibited. Accordingly, when the first regions are distributed in a metal oxide like a cloud, high field-effect mobility (μ) can be achieved.

On the other hand, the second region is a region having a higher insulating property than the first region. That is, when the second regions are distributed in a metal oxide, an off-state current can be inhibited.

Thus, in the case where the CAC-OS is used for a transistor, the complementary action of the conductivity due to the first region and the insulating property due to the second region enables the CAC-OS to have a switching function (On/Off function). That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, a high on-state current (Iₒₙ), a high field-effect mobility (μ), and favorable switching operation can be achieved.

A transistor using the CAC-OS has high reliability. Thus, the CAC-OS is most suitable for a variety of semiconductor devices such as a display device.

Oxide semiconductors have various structures with different properties. Two or more kinds among an amorphous oxide semiconductor, a polycrystalline oxide semiconductor, an a-like OS, a CAC-OS, an nc-OS, and a CAAC-OS may be included in an oxide semiconductor of one embodiment of the present invention.

### <Transistor Including Oxide Semiconductor>

Next, the case where the above oxide semiconductor is used for a transistor is described.

When the above oxide semiconductor is used for a transistor, a transistor with high field-effect mobility can be achieved. In addition, a transistor with high reliability can be achieved.

An oxide semiconductor having a low carrier concentration is preferably used for a transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet still further preferably lower than 1×10¹⁰ cm⁻³, and higher than or equal to 1×10⁻⁹ cm⁻³. In order to reduce the carrier concentration in an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film also be reduced. Examples of impurities include hydrogen, nitrogen, an alkali metal, an alkaline earth metal, iron, nickel, and silicon. Note that an impurity in an oxide semiconductor refers to, for example, an element other than the main components of the oxide semiconductor. For example, an element with a concentration lower than 0.1 atomic % can be regarded as an impurity.

### <Impurity>

Here, the influence of each impurity in the oxide semiconductor is described.

When silicon or carbon, which is one of Group 14 elements, is contained in the oxide semiconductor, defect states are formed in the oxide semiconductor. Thus, the concentration of silicon or carbon (the concentration obtained by SIMS) in the semiconductor is set lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics (characteristics with which, even when no voltage is applied to the gate electrode, the channel exists and a current flows through the transistor). Thus, the concentration of an alkali metal or an alkaline earth metal in the oxide semiconductor, which is obtained by SIMS, is set lower than or equal to 1×10¹⁸ atoms/cm³, preferably lower than or equal to 2×10¹⁶ atoms/cm³.

Furthermore, when the oxide semiconductor contains nitrogen, the oxide semiconductor easily becomes n-type by generation of electrons serving as carriers and an increase in carrier concentration. As a result, a transistor using an oxide semiconductor that contains nitrogen as a semiconductor is likely to have normally-on characteristics. Alternatively, when the oxide semiconductor contains nitrogen, trap states are sometimes formed. This might make the electrical characteristics of the transistor unstable. Therefore, the concentration of nitrogen in the oxide semiconductor, which is obtained by SIMS, is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor that contains hydrogen is likely to have normally-on characteristics. For this reason, hydrogen in the oxide semiconductor is preferably reduced as much as possible. Specifically, the concentration of hydrogen in the oxide semiconductor, which is obtained by SIMS, is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for the channel formation region of the transistor, the transistor can have stable electrical characteristics.

### Structure Example 2

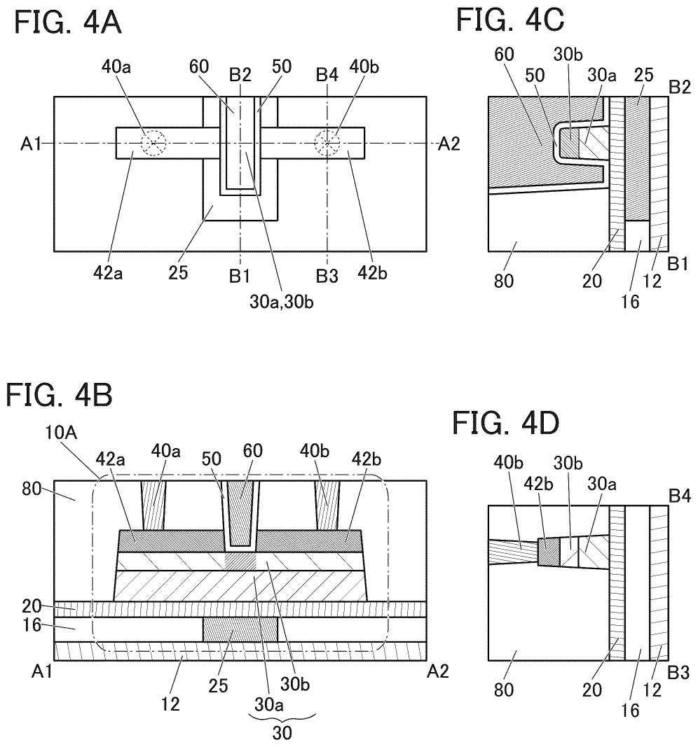

FIG. 4A to FIG. 4D illustrate a structure example different from the semiconductor device illustrated in FIG. 1A to FIG. 1D. FIG. 4A to FIG. 4D are a top view and cross-sectional views of a semiconductor device including a transistor 10A. FIG. 4A is a top view of the semiconductor device. FIG. 4B to FIG. 4D are cross-sectional views of the semiconductor device. Here, FIG. 4B is a cross-sectional view of a portion indicated by dashed-dotted line A1-A2 in FIG. 4A, and is a cross-sectional view of the transistor 10A in the channel length direction. FIG. 4C is a cross-sectional view of a portion indicated by dashed-dotted line B1-B2 in FIG. 4A, and is a cross-sectional view of the transistor 10A in the channel width direction. FIG. 4D is a cross-sectional view of a portion indicated by dashed-dotted line B3-B4 in FIG. 4A. Note that for clarity of the drawing, some components are omitted in the top view of FIG. 4A.

The semiconductor device illustrated in FIG. 4A to FIG. 4D is different from the semiconductor device illustrated in FIG. 1A to FIG. 1D mainly in including an insulator 16, a conductor 25, and an insulator 20. Differences from <Structure example 1> above are mainly described below, and common portions are not described.

The semiconductor device illustrated in FIG. 4A to FIG. 4D includes the insulator 16 over the insulator 12, the conductor 25 embedded in an opening provided in the insulator 16, and the insulator 20 over the insulator 16 and the conductor 25. The semiconductor layer 30a is provided over the insulator 20.

The conductor 25 is provided to overlap with the semiconductor layer 30 and the conductor 60.

In the transistor 10A, the conductor 60 functions as a first gate (also referred to as a top gate) electrode, and the conductor 25 functions as a second gate (also referred to as a back gate or a bottom gate) electrode. The insulator 50 functions as a first gate insulator, and the insulator 20 functions as a second gate insulator. The insulator 16 functions as an interlayer film.

As the conductor 25, a conductive material containing tungsten, copper, or aluminum as its main component is preferably used. The conductor 25 may have a stacked-layer structure; for example, a stack of the above conductive material and titanium or titanium nitride may be employed.

The conductor 25 sometimes functions as the second gate electrode. In that case, when the potential applied to the conductor 25 is the same as the potential applied to the conductor 60, the transistor 10A can be a Dual Gate driven transistor. At this time, the channel formation region is electrically surrounded, and thus, it can be said that the GAA structure is substantially achieved. Accordingly, the on-state current of the transistor 10A can be increased.

In the above structure, the channel formation region can be electrically surrounded even when the electric field of the conductor 60 on the first side surface side of the semiconductor layer 30b and the electric field of the conductor 60 on the second side surface side of the semiconductor layer 30b are not connected to each other below the semiconductor layer 30b. Thus, the length W1 is not necessarily in the above range. For example, the length W1 may be greater than 20 nm. Specifically, the length W1 may be greater than or equal to 1 nm and less than or equal to 100 nm, preferably greater than or equal to 1 nm and less than or equal to 60 nm, further preferably greater than or equal to 3 nm and less than or equal to 30 nm. The length W2 and the length W3 are not necessarily in the above ranges. For example, the length W2 and the length W3 may each be greater than 20 nm. Specifically, the length W2 and the length W3 may each be greater than or equal to 1 nm and less than or equal to 50 nm, preferably greater than or equal to 1 nm and less than or equal to 30 nm, further preferably greater than or equal to 3 nm and less than or equal to 15 nm.

In the case where the transistor 10A is a Dual Gate driven transistor, the conductor 60 may be electrically connected to the conductor 25.

Note that the potential applied to the conductor 25 may be different from the potential applied to the conductor 60. By changing the potential applied to the conductor 25 not in conjunction with but independently of the potential applied to the conductor 60, the threshold voltage (Vth) of the transistor 10A can be controlled. In particular, by applying a negative potential to the conductor 25, Vth of the transistor 10A can be higher, and its off-state current can be reduced. Thus, a drain current at the time when a potential applied to the conductor 60 is 0 V can be lower in the case where a negative potential is applied to the conductor 25 than in the case where the negative potential is not applied to the conductor 25.

The resistivity of the conductor 25 is designed in consideration of the potential applied to the conductor 25, and the thickness of the conductor 25 is set in accordance with the resistivity. The thickness of the insulator 16 is substantially equal to that of the conductor 25. Here, the conductor 25 and the insulator 16 are preferably as thin as possible in the allowable range of the design of the conductor 25. When the thickness of the insulator 16 is reduced, the absolute amount of impurities such as hydrogen included in the insulator 16 can be reduced, thereby reducing the amount of the impurities to be diffused into the semiconductor layer 30.

Note that as illustrated in FIG. 4A, the conductor 25 is preferably provided to be larger than a region of the semiconductor layer 30 that overlaps with the conductor 60. As illustrated in FIG. 4C, it is particularly preferable that the conductor 25 extend to a region outside an end portion of the semiconductor layer 30 in the channel width direction. That is, the conductor 25 and the conductor 60 preferably overlap with each other with the insulators therebetween on the outer side of the side surface of the semiconductor layer 30 in the channel width direction. With such a structure, the channel formation region of the semiconductor layer 30 can be electrically surrounded by the electric field of the conductor 60 functioning as the first gate electrode and the electric field of the conductor 25 functioning as the second gate electrode.

Furthermore, as illustrated in FIG. 4C, the conductor 25 is extended to function as a wiring as well. However, without limitation to this structure, a structure in which a conductor functioning as a wiring is provided below the conductor 25 may be employed. In addition, the conductor 25 is not necessarily provided in each transistor. For example, the conductor 25 may be shared by a plurality of transistors.

It is preferable that the insulator 20 have a function of inhibiting diffusion of hydrogen (e.g., at least one of a hydrogen atom, a hydrogen molecule, and the like). In addition, it is preferable that the insulator 20 have a function of inhibiting diffusion of oxygen (e.g., at least one of an oxygen atom, an oxygen molecule, and the like).

As the insulator 20, an insulator containing an oxide of one or both of aluminum and hafnium, which is an insulating material, is preferably used. For the insulator, aluminum oxide, hafnium oxide, an oxide containing aluminum and hafnium (hafnium aluminate), or the like is preferably used. Alternatively, an oxide containing hafnium and zirconium, e.g., hafnium zirconium oxide, is preferably used. In the case where the insulator 20 is formed using such a material, the insulator 20 functions as a layer that inhibits release of oxygen from the semiconductor layer 30 to the substrate side and diffusion of impurities such as hydrogen from the periphery of the transistor 10A into the semiconductor layer 30. Thus, providing the insulator 20 can inhibit diffusion of impurities such as hydrogen into the semiconductor layer 30 and inhibit generation of oxygen vacancies in the semiconductor layer 30. Moreover, the conductor 25 can be inhibited from reacting with oxygen included in the semiconductor layer 30. Therefore, these materials are suitable for the case where an oxide semiconductor is used for the semiconductor layer 30.

Alternatively, aluminum oxide, bismuth oxide, germanium oxide, niobium oxide, silicon oxide, titanium oxide, tungsten oxide, yttrium oxide, or zirconium oxide may be added to the above insulator, for example. Alternatively, these insulators may be subjected to nitriding treatment. A stack of silicon oxide, silicon oxynitride, or silicon nitride over the above insulator may be used for the insulator 20. For example, the insulator 20 can have a two-layer structure in which silicon nitride and silicon oxide are stacked in this order, or a three-layer structure in which silicon nitride, silicon oxide, and aluminum oxide are stacked in this order.

For example, a single layer or stacked layers of an insulator(s) containing what is called a high-k material such as aluminum oxide, hafnium oxide, tantalum oxide, zirconium oxide, or hafnium zirconium oxide may be used for the insulator 20. As miniaturization and high integration of transistors progress, a problem such as a leakage current may arise because of a thinner gate insulator. When a high-k material is used for the insulator functioning as a gate insulator, a gate potential at the time of the operation of the transistor can be reduced while the physical thickness is maintained. Furthermore, a substance with a high permittivity such as lead zirconate titanate (PZT), strontium titanate (SrTiO₃), or (Ba,Sr)TiO₃ (BST) can be used for the insulator 20 in some cases.

Although FIG. 4A to FIG. 4D illustrate a single-layer structure of the insulator 20, the present invention is not limited to this structure, and a stacked-layer structure of two or more layers may be employed. In that case, without limitation to a stacked-layer structure formed of the same material, a stacked-layer structure formed of different materials may be employed.

The permittivity of the insulator 16 is preferably lower than that of the insulator 20. When a material with a low permittivity is used for an interlayer film, parasitic capacitance generated between wirings can be reduced. For the insulator 16, silicon oxide, silicon oxynitride, silicon oxide to which fluorine is added, silicon oxide to which carbon is added, silicon oxide to which carbon and nitrogen are added, porous silicon oxide, or the like is used as appropriate, for example.

As illustrated in FIG. 4C, the insulator 50 includes a region in contact with part of the top surface of the insulator 20 in a region not overlapping with the semiconductor layer 30. In other words, in a region not overlapping with the semiconductor layer 30, the conductor 60 includes a region overlapping with the conductor 25 with the insulator 50 and the insulator 20 therebetween. Note that the present invention is not limited thereto.

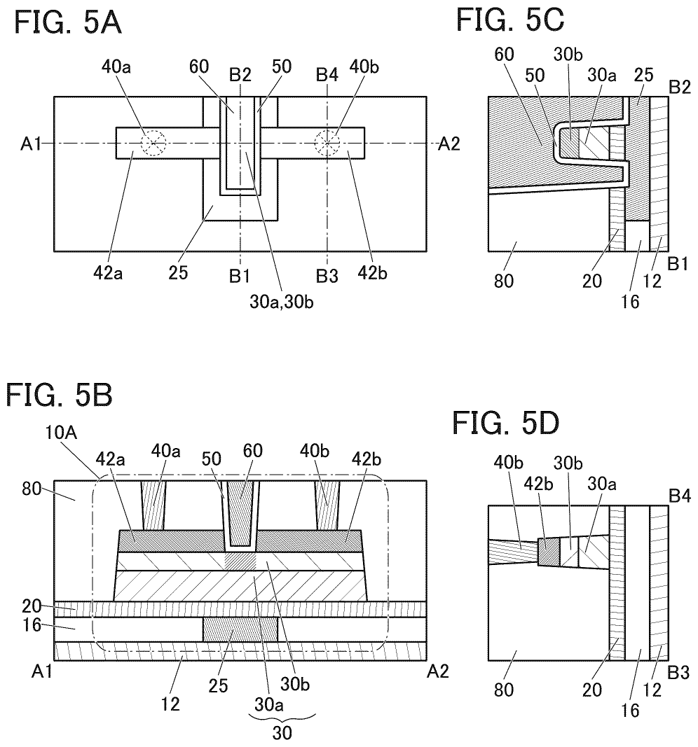

FIG. 5A to FIG. 5D are a top view and cross-sectional views of a semiconductor device whose structure is different from the structure illustrated in FIG. 4A to FIG. 4D. FIG. 5A is a top view of the semiconductor device. FIG. 5B to FIG. 5D are cross-sectional views of the semiconductor device. Here, FIG. 5B is a cross-sectional view of a portion indicated by dashed-dotted line A1-A2 in FIG. 5A, and is a cross-sectional view of the transistor 10A in the channel length direction. FIG. 5C is a cross-sectional view of a portion indicated by dashed-dotted line B1-B2 in FIG. 5A, and is a cross-sectional view of the transistor 10A in the channel width direction. FIG. 5D is a cross-sectional view of a portion indicated by dashed-dotted line B3-B4 in FIG. 5A. Note that for clarity of the drawing, some components are omitted in the top view of FIG. 5A.

The semiconductor device illustrated in FIG. 5A to FIG. 5D is a modification example of the semiconductor device illustrated in FIG. 4A to FIG. 4D. The shape of the insulator 20 in the semiconductor device illustrated in FIG. 5A to FIG. 5D is different from that in the semiconductor device illustrated in FIG. 4A to FIG. 4D. Differences from the semiconductor device illustrated in FIG. 4A to FIG. 4D will be mainly described below, and common portions are not described.

For example, as illustrated in FIG. 5C, the insulator 50 may include a region in contact with the conductor 25 in a region not overlapping with the semiconductor layer 30. In other words, in a region not overlapping with the semiconductor layer 30, the conductor 60 may include a region overlapping with the conductor 25 with the insulator 50 therebetween. In that case, the insulator 20 includes an opening in a region not overlapping with the semiconductor layer 30. In the opening, the insulator 50 is in contact with the conductor 25.

The above structure shortens the distance between the conductor 60 and the conductor 25 and allows the semiconductor layer 30b to be electrically surrounded by the electric fields of the conductor 60 and the conductor 25.

In FIG. 4A to FIG. 4D, the semiconductor layer 30a is formed into an island shape. Note that the present invention is not limited thereto.

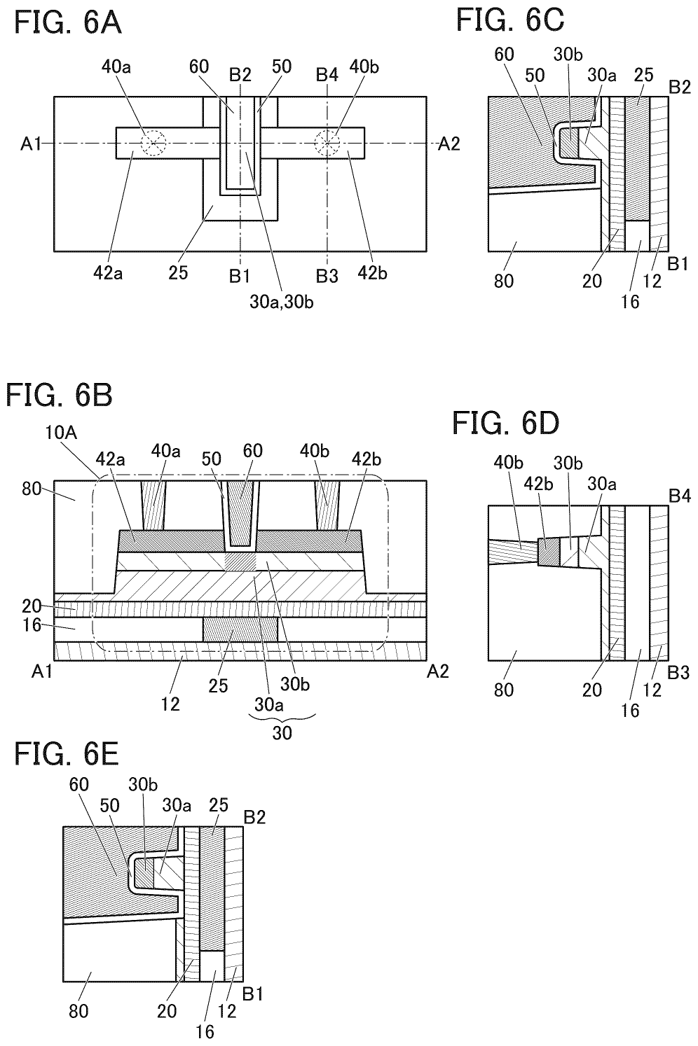

FIG. 6A to FIG. 6D are a top view and cross-sectional views of a semiconductor device whose structure is different from the structure illustrated in FIG. 4A to FIG. 4D. FIG. 6A is a top view of the semiconductor device. FIG. 6B to FIG. 6D are cross-sectional views of the semiconductor device. Here, FIG. 6B is a cross-sectional view of a portion indicated by dashed-dotted line A1-A2 in FIG. 6A, and is a cross-sectional view of the transistor 10A in the channel length direction. FIG. 6C is a cross-sectional view of a portion indicated by dashed-dotted line B1-B2 in FIG. 6A, and is a cross-sectional view of the transistor 10A in the channel width direction. FIG. 6D is a cross-sectional view of a portion indicated by dashed-dotted line B3-B4 in FIG. 6A. Note that some components are omitted in the top view of FIG. 6A for clarity of the drawing.

The semiconductor device illustrated in FIG. 6A to FIG. 6D is a modification example of the semiconductor device illustrated in FIG. 4A to FIG. 4D. The shape of the semiconductor layer 30a in the semiconductor device illustrated in FIG. 6A to FIG. 6D is different from that in the semiconductor device illustrated in FIG. 4A to FIG. 4D. Differences from the semiconductor device illustrated in FIG. 4A to FIG. 4D will be mainly described below, and common portions are not described.

For example, as illustrated in FIG. 6A to FIG. 6D, the semiconductor layer 30a may have a projecting portion. The semiconductor layer 30b is provided over the projecting portion. Note that the side surface of the projecting portion is aligned or substantially aligned with the side surface of the semiconductor layer 30b. The projecting portion includes a region overlapping with the conductor 60 and the conductor 25.

In FIG. 6C, the insulator 50 includes a region in contact with the semiconductor layer 30a in a region not overlapping with the semiconductor layer 30b. In other words, in a region not overlapping with the semiconductor layer 30b, the conductor 60 includes a region overlapping with the conductor 25 with the insulator 50, the semiconductor layer 30a, and the insulator 20 therebetween. As illustrated in FIG. 6E, the insulator 50 may include a region in contact with the insulator 20 in a region not overlapping with the semiconductor layer 30b. In other words, in a region not overlapping with the semiconductor layer 30b, the conductor 60 may include a region overlapping with the conductor 25 with the insulator 50 and the insulator 20 therebetween. In that case, the semiconductor layer 30a includes an opening in a region not overlapping with the semiconductor layer 30b. In the opening, the insulator 50 is in contact with the insulator 20.

### Structure Example 3

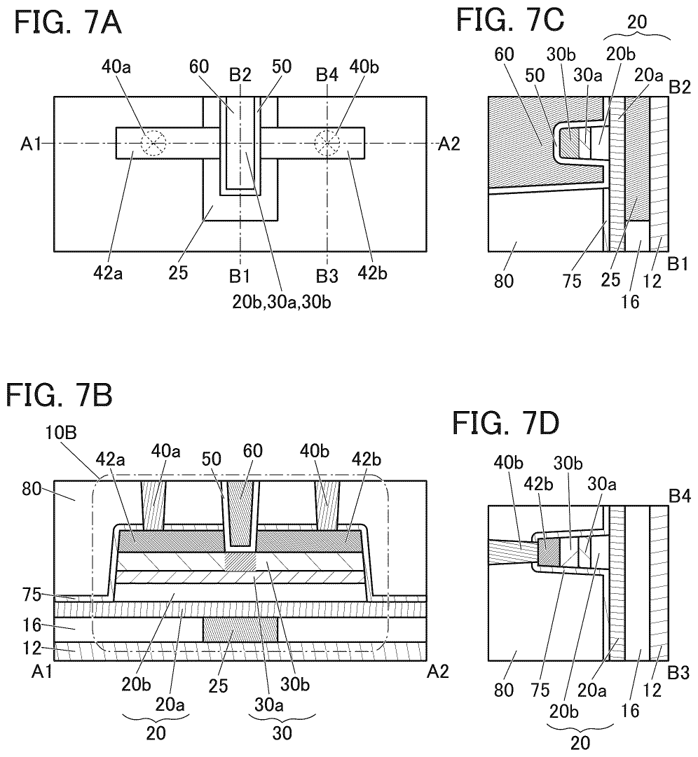

FIG. 7A to FIG. 7D illustrate a structure example different from the semiconductor device illustrated in FIG. 4A to FIG. 4D. FIG. 7A to FIG. 7D are a top view and cross-sectional views of a semiconductor device including a transistor 10B. FIG. 7A is a top view of the semiconductor device. FIG. 7B to FIG. 7D are cross-sectional views of the semiconductor device. Here, FIG. 7B is a cross-sectional view of a portion indicated by dashed-dotted line A1-A2 in FIG. 7A, and is a cross-sectional view of the transistor 10B in the channel length direction. FIG. 7C is a cross-sectional view of a portion indicated by dashed-dotted line B1-B2 in FIG. 7A, and is a cross-sectional view of the transistor 10B in the channel width direction. FIG. 7D is a cross-sectional view of a portion indicated by dashed-dotted line B3-B4 in FIG. 7A. Note that for clarity of the drawing, some components are omitted in the top view of FIG. 7A.

The semiconductor device illustrated in FIG. 7A to FIG. 7D is different from the semiconductor device illustrated in FIG. 4A to FIG. 4D mainly in that the insulator 20 has a stacked-layer structure of an insulator 20a and an insulator 20b. The semiconductor device illustrated in FIG. 7A to FIG. 7D is different from the semiconductor device illustrated in FIG. 4A to FIG. 4D mainly in including an insulator 75. Differences from <Structure example 2> above are mainly described below, and common portions are not described.

The insulator 20 included in the transistor 10B has a stacked-layer structure of the insulator 20a and the insulator 20b over the insulator 20a.

The insulator 20a is provided over the insulator 16 and the conductor 25. The insulator 20a is preferably provided using any of the above-described materials that can be used for the insulator 20, for example.

The insulator 20b is formed into an island shape. The semiconductor layer 30a is provided over the insulator 20b. The side surface of the insulator 20b is aligned or substantially aligned with the side surface of the semiconductor layer 30a. In the case where an oxide semiconductor is used for the semiconductor layer 30a, silicon oxide, silicon oxynitride, or the like may be used as appropriate for the insulator 20b in contact with the semiconductor layer 30a, for example.

Note that the shape of the insulator 20b is not limited to an island shape and may include a projecting portion. The semiconductor layer 30a is provided over the projecting portion. Note that the side surface of the projecting portion is aligned or substantially aligned with the side surface of the semiconductor layer 30a. The projecting portion includes a region overlapping with the conductor 60 and the conductor 25.

The transistor 10B includes the insulator 75 over the insulator 20a, the insulator 20b, the semiconductor layer 30a, the semiconductor layer 30b, the conductor 42a, and the conductor 42b. The insulator 75 includes an opening overlapping with the opening included in the insulator 80.

The insulator 75 is provided to cover the insulator 20a, the insulator 20b, the semiconductor layer 30a, the semiconductor layer 30b, the conductor 42a, and the conductor 42b. Specifically, the insulator 75 includes a region in contact with the top surface of the insulator 20a, a region in contact with the side surface of the insulator 20b, a region in contact with the side surface of the semiconductor layer 30a, a region in contact with the side surface of the semiconductor layer 30b, a region in contact with the side surface and the top surface of the conductor 42a, and a region in contact with the side surface and the top surface of the conductor 42b.

The insulator 75 preferably has a function of capturing and fixing hydrogen. In that case, the insulator 75 preferably includes an insulator such as silicon nitride or a metal oxide having an amorphous structure, e.g., aluminum oxide or magnesium oxide. Alternatively, for example, a stacked-layer film of aluminum oxide and silicon nitride over the aluminum oxide may be used as the insulator 75.

The insulator 75 preferably has a barrier property against oxygen. Accordingly, oxygen included in the insulator 80 can be inhibited from diffusing into the side surface of the conductor 42a on the side in contact with the insulator 75 and the side surface of the conductor 42b on the side in contact with the insulator 75. This can inhibit an increase in resistivity and a reduction in on-state current which are caused by oxidation of the side surface of the conductor 42a on the side in contact with the insulator 75 and the side surface of the conductor 42b on the side in contact with the insulator 75 by oxygen included in the insulator 80. Note that the insulator 75 is less permeable to oxygen than the insulator 80, for example. For the insulator 75, a material that is less permeable to oxygen than the insulator 80 is used, for example.

### Modification Example of Semiconductor Device

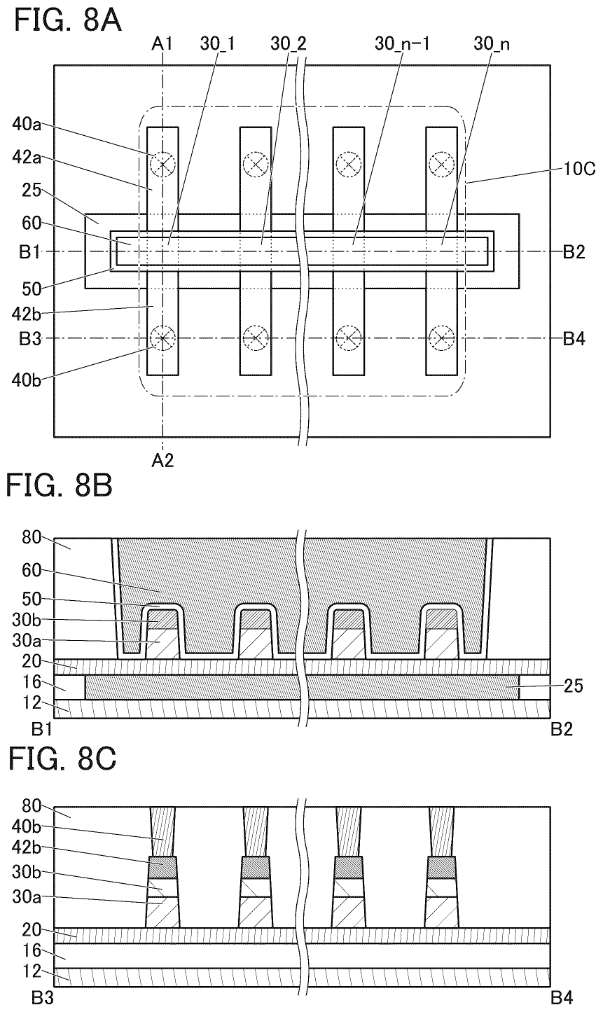

Examples of the semiconductor device of one embodiment of the present invention are described below with reference to FIG. 8A to FIG. 11C.

In FIG. 8A to FIG. 11C, A of each drawing is a top view of the semiconductor device. Moreover, B of each drawing is a cross-sectional view corresponding to a portion indicated by dashed-dotted line B1-B2 in A of each drawing. Furthermore, C of each drawing is a cross-sectional view corresponding to a portion indicated by dashed-dotted line B3-B4 in A of each drawing. For a cross-sectional view corresponding to a portion indicated by dashed-dotted line A1-A2 in A of each drawing, the cross-sectional view of the transistor 10A shown in FIG. 4B can be referred to. For clarity of the drawing, some components are omitted in the top view of A of each drawing.

Note that in the semiconductor devices illustrated in FIG. 8A to FIG. 11C, components having the same functions as the components included in the semiconductor device described in <Structure example 1>, <Structure example 2>, and the like are denoted by the same reference numerals. Note that the materials described in detail in <Structure example 1>, <Structure example 2>, and the like can be used as component materials of the semiconductor devices also in this section.

### Modification Example 1

The semiconductor device illustrated in FIG. 8A to FIG. 8C is a modification example of the semiconductor device illustrated in FIG. 4A to FIG. 4D. The semiconductor device illustrated in FIG. 8A to FIG. 8C includes a transistor 10C. The semiconductor device illustrated in FIG. 8A to FIG. 8C is different from the semiconductor device illustrated in FIG. 4A to FIG. 4D in including n (n is an integer greater than or equal to 1) of the semiconductor layers 30 (a semiconductor layer 30_1 to a semiconductor layer 30_n), n source electrodes, and n drain electrodes. Note that FIG. 8A illustrates the semiconductor layer 30_1, the semiconductor layer 30_2, the semiconductor layer 30_n−1, and the semiconductor layer 30_n among the n semiconductor layers 30.

Each of the semiconductor layer 30_1 to the semiconductor layer 30_n includes the semiconductor layer 30a and the semiconductor layer 30b over the semiconductor layer 30a. The conductor 42a provided over the semiconductor layer 30b is electrically connected to the conductor 40a. That is, the semiconductor device illustrated in FIG. 8A to FIG. 8C includes n of the conductors 40a. Similarly, the conductor 42b provided over the semiconductor layer 30b is electrically connected to the conductor 40b. That is, the semiconductor device illustrated in FIG. 8A to FIG. 8C includes n of the conductors 40b.

Although not illustrated in FIG. 8A to FIG. 8C, a conductor that is in contact with the top surface of the conductor 40a and functions as a wiring is provided over the insulator 80 and the conductor 40a. Similarly, a conductor that is in contact with the top surface of the conductor 40b and functions as a wiring is provided over the insulator 80 and the conductor 40b.

As illustrated in FIG. 8A to FIG. 8C, the transistor 10C includes the semiconductor layer 30_1 to the semiconductor layer 30_n. Note that the semiconductor layer 30_1 to the semiconductor layer 30_n each include a channel formation region. That is, the transistor 10C includes a plurality of channel formation regions. The conductor 60 is provided over the top surfaces and the side surfaces of the plurality of channel formation regions with the insulator 50 therebetween. The conductor that is in contact with the top surface of the conductor 40a and functions as a wiring includes a region extending in the B3-B4 direction and is electrically connected to the semiconductor layer 30_1 to the semiconductor layer 30_n through the n conductors 40a. Similarly, the conductor that is in contact with the top surface of the conductor 40b and functions as a wiring includes a region extending in the B3-B4 direction and is electrically connected to the semiconductor layer 30_1 to the semiconductor layer 30_n through the n conductors 40b.

That is, in the semiconductor device illustrated in FIG. 8A to FIG. 8C, the transistor 10C includes a plurality of channel formation regions for one gate electrode. By including the plurality of channel formation regions, the transistor 10C illustrated in FIG. 8A to FIG. 8C can have a high on-state current. Since each channel formation region is surrounded by the electric field of the conductor 60, a high on-state current can be obtained in each channel formation region.

Although the structure illustrated in FIG. 8A to FIG. 8C includes the n conductors 40a, the n conductors 40b, and the two conductors functioning as wirings, the present invention is not limited to this structure. For example, a structure may be employed which includes at least one of the conductors 40a, at least one of the conductors 40b, and the two conductors functioning as wirings. Alternatively, for example, a structure may be employed in which the conductor 40a and the conductor 40b function as wirings.

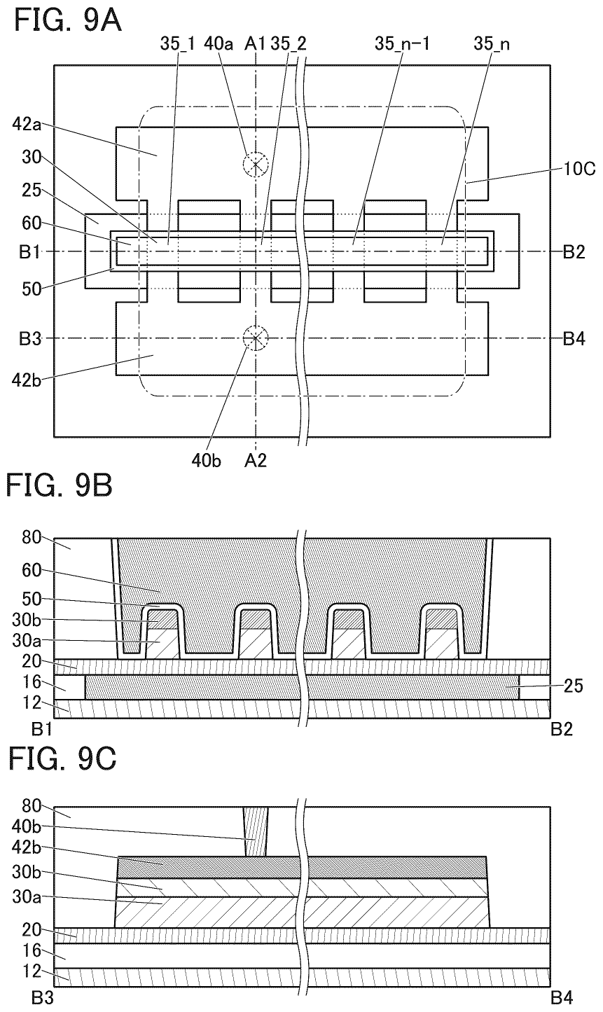

The semiconductor device illustrated in FIG. 9A to FIG. 9C is a modification example of the semiconductor device illustrated in FIG. 8A to FIG. 8C. The semiconductor device illustrated in FIG. 9A to FIG. 9C is different from the semiconductor device illustrated in FIG. 8A to FIG. 8C in that the semiconductor layer 30 includes n (n is an integer greater than or equal to 1) channel formation regions (a channel formation region 35_1 to a channel formation region 35_n). Note that FIG. 9A illustrates the channel formation region 35_1, the channel formation region 35_2, the channel formation region 35_n−1, and the channel formation region 35_n among the n channel formation regions.

The semiconductor device illustrated in FIG. 9A to FIG. 9C includes at least one of the conductors 40a and at least one of the conductors 40b. For simplicity of description, the transistor 10C illustrated in FIG. 9A to FIG. 9C includes one of the conductors 40a and one of the conductors 40b.

Although not illustrated in FIG. 9A to FIG. 9C, a conductor that is in contact with the top surface of the conductor 40a and functions as a wiring is provided over the insulator 80 and the conductor 40a. Similarly, a conductor that is in contact with the top surface of the conductor 40b and functions as a wiring is provided over the insulator 80 and the conductor 40b.

As illustrated in FIG. 9A to FIG. 9C, in the transistor 10C, the conductor 60 is provided over the top surfaces and the side surfaces of the channel formation region 35_1 to the channel formation region 35_n with the insulator 50 therebetween. The conductor that is in contact with the top surface of the conductor 40a and functions as a wiring includes a region extending in the B3-B4 direction and is electrically connected to the semiconductor layer 30 through the conductor 42a and at least one of the conductors 40a. Note that in the case where one of the conductors 40a is provided, the conductor functioning as a wiring does not necessarily include the region extending in the B3-B4 direction. Similarly, the conductor that is in contact with the top surface of the conductor 40b and functions as a wiring includes a region extending in the B3-B4 direction and is electrically connected to the semiconductor layer 30 through the conductor 42b and at least one of the conductors 40b. Note that in the case where one of the conductors 40b is provided, the conductor functioning as a wiring does not necessarily include the region extending in the B3-B4 direction.

That is, the n conductors 40a and the n conductors 40b are not necessarily provided in the transistor 10C including the n channel formation regions. The number of conductors 40a and the number of conductors 40b are each preferably greater than or equal to 1 and less than n for a transistor that includes the n channel formation regions.

Note that with miniaturization of the transistor, the size of a plug electrically connecting the transistor and a conductor functioning as a wiring also needs to be reduced. The wiring resistance tends to increase when a contact area between a conductor functioning as a plug and the conductor functioning as a wiring becomes small.

In the semiconductor device illustrated in FIG. 9A to FIG. 9C, the number of plugs provided in the transistor 10C, which includes the n channel formation regions, is less than n; thus, the sizes of the conductor 40a and the conductor 40b functioning as the plugs can be larger than those of the conductor 40a and the conductor 40b included in the semiconductor device illustrated in FIG. 8A to FIG. 8C, for example. Accordingly, power consumption can be reduced.

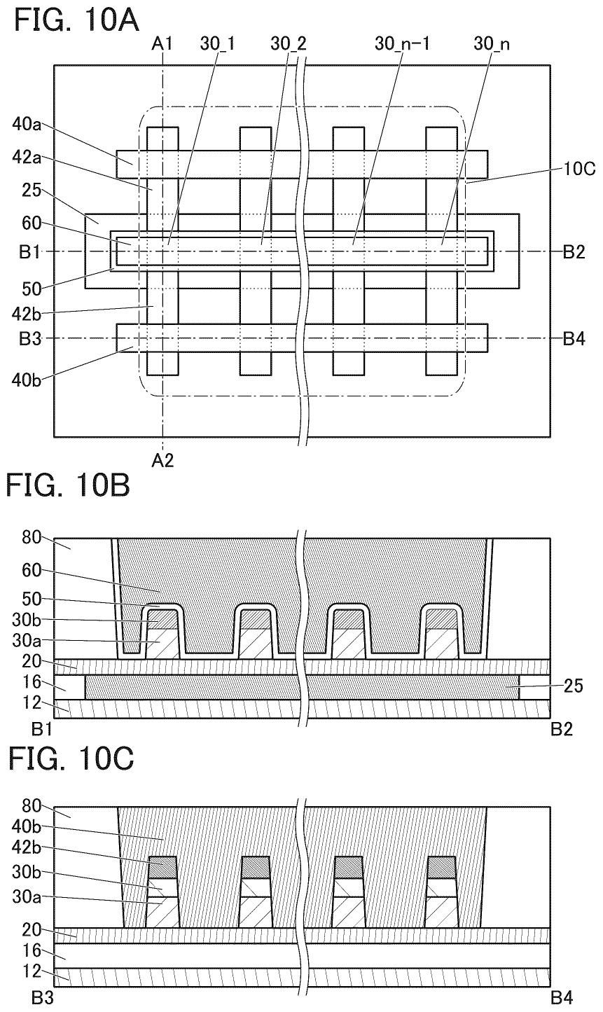

The semiconductor device illustrated in FIG. 10A to FIG. 10C is a modification example of the semiconductor device illustrated in FIG. 8A to FIG. 8C. The semiconductor device illustrated in FIG. 10A to FIG. 10C is different from the semiconductor device illustrated in FIG. 8A to FIG. 8C in including one of the conductors 40a and one of the conductors 40b.

The semiconductor device illustrated in FIG. 10A to FIG. 10C includes the one conductor 40a and the one conductor 40b. The conductor 40a and the conductor 40b function as wirings.

As illustrated in FIG. 10A to FIG. 10C, the transistor 10C includes the semiconductor layer 30_1 to the semiconductor layer 30_n. Note that the semiconductor layer 30_1 to the semiconductor layer 30_n each include a channel formation region. That is, the transistor 10C includes a plurality of channel formation regions. The conductor 60 is provided over the top surfaces and the side surfaces of the plurality of channel formation regions with the insulator 50 therebetween. The conductor 40a extends in the B3-B4 direction and is electrically connected to the semiconductor layer 30_1 to the semiconductor layer 30_n. Similarly, the conductor 40b extends in the B3-B4 direction and is electrically connected to the semiconductor layer 30_1 to the semiconductor layer 30_n.

That is, the n conductors 40a and the n conductors 40b are not necessarily provided in the transistor 10C including the n semiconductor layers 30.

For the other components, the structure of the semiconductor device illustrated in FIG. 4A to FIG. 4D can be referred to.

### Modification Example 2

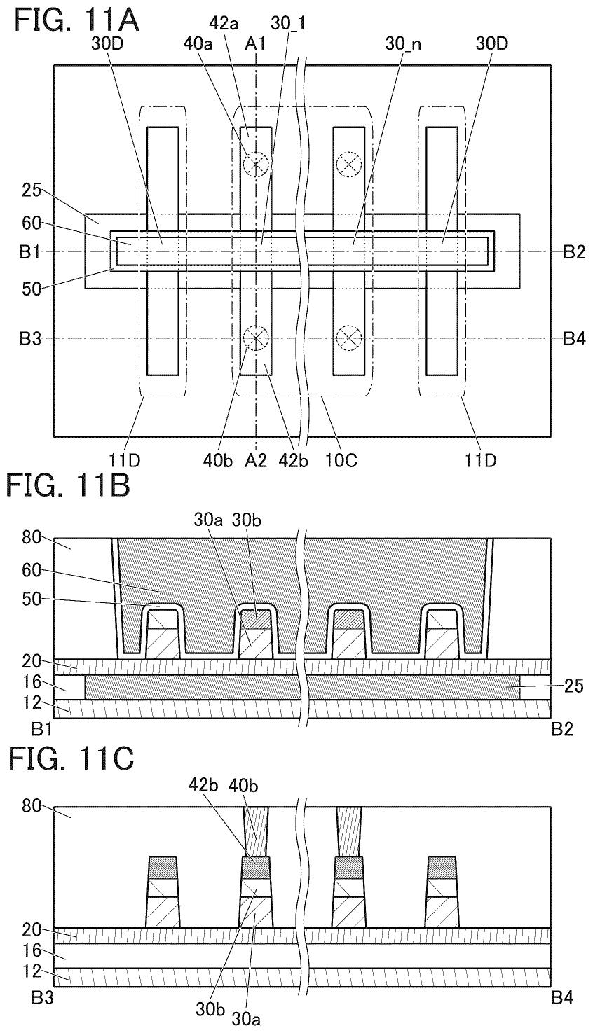

The semiconductor device illustrated in FIG. 11A to FIG. 11C is different from the semiconductor device illustrated in FIG. 8A to FIG. 8C mainly in including transistors 11D. Differences from <Modification example 1> above are mainly described below, and common portions are not described.

The semiconductor device illustrated in FIG. 11A to FIG. 11C includes the transistor 11D provided adjacent to the semiconductor layer 30_1 of the transistor 10C. Similarly, the semiconductor device includes the transistor 11D provided adjacent to the semiconductor layer 30_n of the transistor 10C.

That is, the semiconductor device illustrated in FIG. 11A to FIG. 11C is different from the semiconductor device illustrated in FIG. 8A to FIG. 8C in including the transistor(s) 11D on one or both end portions in the direction in which the plurality of channel formation regions of the transistor 10C are arranged in parallel. The transistor 11D includes at least a semiconductor layer 30D.

Here, the transistor 11D is not necessarily electrically connected to any one of or all of a gate wiring, a source wiring, and a drain wiring. In other words, the transistor 11D is provided in a state of not functioning as a transistor in some cases. Accordingly, the transistor 11D is referred to as a dummy transistor (a sacrificial transistor) in some cases.

The shortest distance between the semiconductor layer 30_1 and the semiconductor layer 30D adjacent to the semiconductor layer 30_1 is preferably substantially equal to the shortest distance between the semiconductor layer 30_1 and the semiconductor layer 30_2. Similarly, the shortest distance between the semiconductor layer 30_n and the semiconductor layer 30D adjacent to the semiconductor layer 30_n is preferably substantially equal to the shortest distance between the semiconductor layer 30_n−1 and the semiconductor layer 30_n. Note that in the case where n is 1, the shortest distance between one semiconductor layer 30D and the semiconductor layer 30_1 is preferably substantially equal to the shortest distance between the other semiconductor layer 30D and the semiconductor layer 30_1.

In the case where a plurality of the semiconductor layers 30 are formed in parallel, the shapes of the semiconductor layers 30 located on end portions are likely to be varied due to processing. In a process in which part of the insulator 80 is removed to form an opening and part of the top surface of the semiconductor layer 30 is exposed, variation in the area of the exposed top surface of the semiconductor layer 30 might occur due to the influence of the shape of an end portion of a region to be removed (also referred to as an opening), the distance from an end portion of the opening to the semiconductor layer 30, or the like.

Thus, by providing the transistors 11D as illustrated in FIG. 11A to FIG. 11C, even when a shape defect of the semiconductor layer 30D of the transistor 11D occurs or when a shape defect of the opening over the semiconductor layer 30D occurs, the shapes of the semiconductor layers 30 formed in a region sandwiched between the transistors 11D are uniform.

Thus, when the transistor 11D is provided adjacent to the transistor 10C, variation in characteristics of a plurality of transistors included in the transistor 10C can be reduced.

When the plurality of semiconductor layers 30 are provided at regular intervals in a region, designing of a circuit can be easily achieved by changing a wiring layout.

For the other components, the structure of the semiconductor device illustrated in FIG. 4A to FIG. 4D can be referred to.

According to one embodiment of the present invention, a semiconductor device with a high on-state current can be provided. A semiconductor device that can be miniaturized or highly integrated can be provided. A semiconductor device with favorable reliability can be provided. A semiconductor device with a small variation in electrical characteristics of transistors can be provided. A semiconductor device having favorable electrical characteristics can be provided. A semiconductor device with low power consumption can be provided.

The structure, method, and the like described in this embodiment can be used in an appropriate combination with other structures, methods, and the like described in this embodiment or the other embodiments.

### Embodiment 2

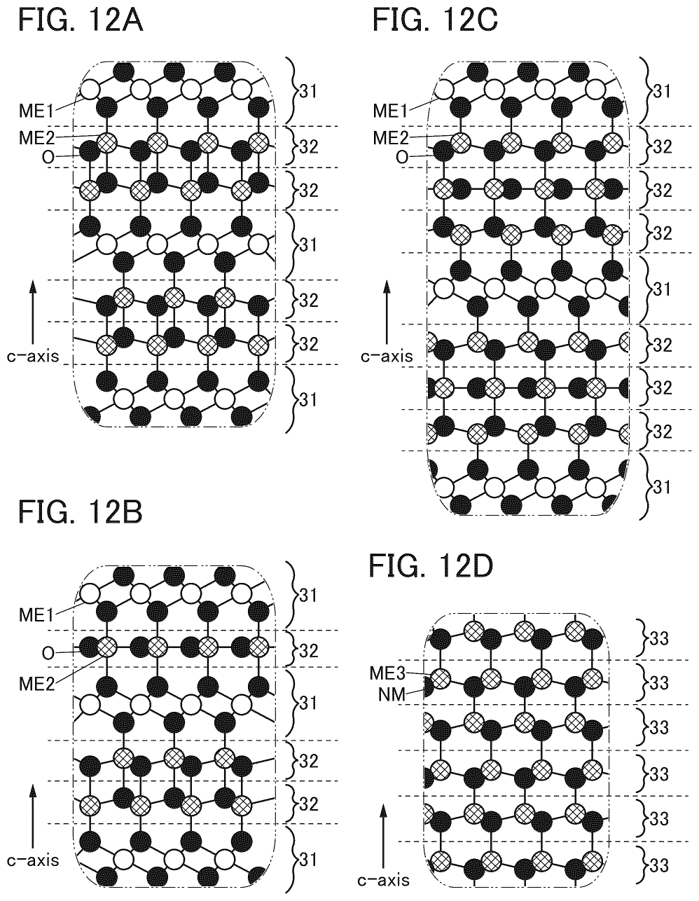

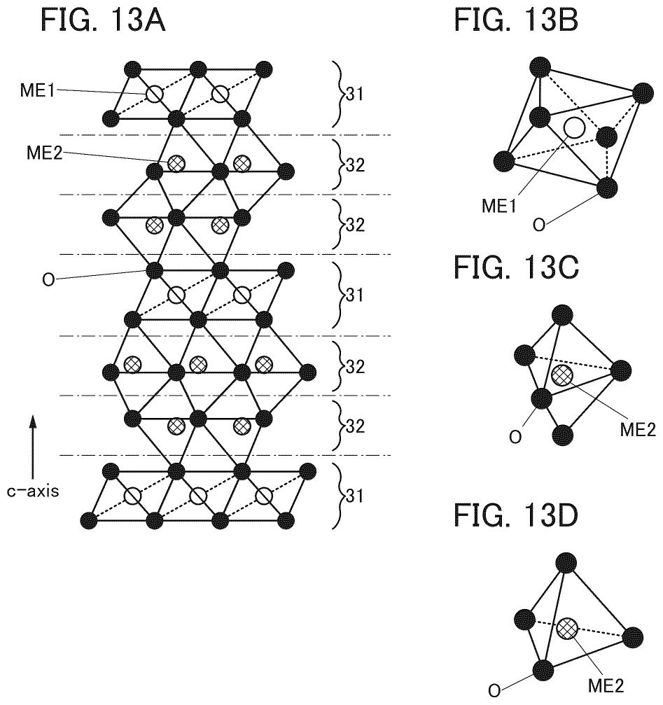

In this embodiment, a metal oxide (hereinafter, sometimes referred to as an oxide semiconductor) that is further preferably applied to a semiconductor layer of a transistor is described with reference to FIG. 12A to FIG. 13D. Note that the metal oxide of one embodiment of the present invention is not limited to being used in a semiconductor layer of a transistor and may be used as an insulating material or a conductive material, depending on the kinds, combination, compositions, and the like of elements constituting the metal oxide.

In particular, the electrical characteristics of a transistor whose semiconductor layer includes a metal oxide easily change when oxygen vacancies (Vo) and impurities exist in a channel formation region in the metal oxide, which might degrade the reliability. In some cases, hydrogen in the vicinity of an oxygen vacancy forms a defect that is an oxygen vacancy into which hydrogen enters (hereinafter, sometimes referred to as a VoH defect), which generates an electron serving as a carrier. Thus, when the channel formation region in the metal oxide includes oxygen vacancies, the transistor is likely to have normally-on characteristics. Therefore, oxygen vacancies and impurities are preferably reduced as much as possible in the channel formation region in the metal oxide. In other words, the channel formation region in the metal oxide preferably has a low carrier concentration.

In this embodiment, the case where the metal oxide is an In-M-Zn oxide containing indium, the element M, and zinc is considered. The element M is aluminum, gallium, yttrium, or tin. Other elements that can be used as the element M include boron, titanium, iron, nickel, germanium, zirconium, molybdenum, lanthanum, cerium, neodymium, hafnium, tantalum, tungsten, magnesium, and cobalt. Note that two or more of the above elements may be used in combination as the element M.

An oxygen atom in an In-M-Zn oxide is bonded to one or more of an indium atom, an element M atom, and a zinc atom. The bond between an element M atom and an oxygen atom tends to be stronger than the bond between an indium atom and an oxygen atom. The bond between an element M atom and an oxygen atom tends to be stronger than the bond between a zinc atom and an oxygen atom. It is thus presumable that an oxygen atom bonded to an indium atom and/or a zinc atom is likely to form a vacancy. In other words, it is presumable that an oxygen vacancy is likely to be formed near an indium atom or near a zinc atom.

Since VoH is formed by entry of a hydrogen atom into an oxygen vacancy, VoH is easily formed near an indium atom or a zinc atom. Here, VoH formed near an indium atom is referred to as InVoH. Furthermore, VoH formed near a zinc atom is referred to as ZnVoH.

It is presumable that InVoH is likely to generate electrons serving as carriers. Thus, when a metal oxide having a high indium content percentage is used in a channel formation region of a transistor, the transistor sometimes has normally-on characteristics. Meanwhile, it is presumable that ZnVoH is less likely to generate electrons serving as carriers than InVoH. Thus, when a metal oxide in which the zinc content percentage is higher than the indium content percentage is used in a channel formation region of a transistor, the transistor can presumably have normally-off characteristics.

Accordingly, the zinc content percentage is preferably higher than the indium content percentage in a metal oxide used in a semiconductor layer of a transistor.

A metal oxide sometimes includes a lattice defect. Examples of a lattice defect include point defects such as an atomic vacancy and an exotic atom, a line defect such as dislocation, a plane defect such as a crystal grain boundary, and a volume defect such as a void. Examples of a factor in generating a lattice defect include the deviation of the proportion of the number of atoms in constituent elements (excess or deficiency of constituent atoms) and an impurity.

In the case where a metal oxide is used in a semiconductor layer of a transistor, a lattice defect in the metal oxide may cause the generation, trapping, and the like of carriers. Thus, the use of a metal oxide with many lattice defects in a semiconductor layer of a transistor might lead to unstable electrical characteristics of the transistor. Hence, a metal oxide used in a semiconductor layer of a transistor preferably has a small number of lattice defects.

The kind of a lattice defect that is likely to exist in a metal oxide and the amount of lattice defects depend on the structure of a metal oxide, a method for forming a film of a metal oxide, and the like.

The structure of a metal oxide is classified into a single crystal structure and other structures (non-single-crystal structures). Examples of a non-single-crystal structure include a CAAC structure, a polycrystalline structure, an nc structure, an amorphous-like (a-like) structure, and an amorphous structure. The a-like structure has a structure between the nc structure and the amorphous structure. Note that the classification of crystal structures will be described later.

A metal oxide having the a-like structure and a metal oxide having the amorphous structure each include a void or a low-density region. That is, the metal oxide having the a-like structure and the metal oxide having the amorphous structure have low crystallinity as compared with a metal oxide having the nc structure and a metal oxide having the CAAC structure. Moreover, the metal oxide having the a-like structure has a higher hydrogen concentration in the metal oxide than the metal oxide having the nc structure and the metal oxide having the CAAC structure. Thus, a lattice defect is easily formed in the metal oxide having the a-like structure and the metal oxide having the amorphous structure.

In the case where the metal oxide is composed of a plurality of metal elements, one of the scattering factors that affect the carrier transfer is randomness in the arrangement of metal atoms in cation sites (what is called cation disorder). A metal oxide having lower crystallinity, in which cation disorder is more considerable, has lower mobility in some cases.

Thus, a metal oxide with high crystallinity is preferably used in a semiconductor layer of a transistor. For example, it is preferable to use the metal oxide having the CAAC structure or the metal oxide having the single crystal structure. The use of such a metal oxide for a transistor enables the transistor to have favorable electrical characteristics. In addition, the transistor can have high reliability.

Note that the metal oxide with high crystallinity does not include a metal oxide having the polycrystalline structure. The polycrystalline structure refers to a crystal structure in which a clear crystal grain boundary is observed. In the case where the metal oxide having the polycrystalline structure is used in a semiconductor layer of a transistor, it is highly probable that the crystal grain boundary serves as a recombination center and captures carriers, whereby the on-state current and field-effect mobility of the transistor decrease, for example.

Thus, a metal oxide with high crystallinity is preferably used in a semiconductor layer of a transistor. A crystal region included in the metal oxide preferably has a crystal structure in which a plurality of layers (for example, a first layer and a second layer) are stacked. That is, the crystal region has a layered crystal structure (also referred to as a layered crystal or a layered structure). At this time, the direction of the c-axis of the crystal region is the direction in which the plurality of layers are stacked. Examples of a metal oxide including the crystal region include a single crystal oxide semiconductor, a CAAC-OS which is described later, and the like.

The c-axis of the above crystal region is preferably aligned in the normal direction with respect to the formation surface or film surface of the metal oxide. This enables the plurality of layers to be placed substantially parallel to the formation surface or film surface of the metal oxide. In other words, each of the plurality of layers extends in the channel length direction.

Note that the layered crystal structure may be a structure in which layers formed by covalent bonding and/or ionic bonding are stacked with bonding such as the Van der Waals force, which is weaker than covalent bonding and/or ionic bonding. In this specification and the like, a material having such a structure is sometimes referred to as a layered substance (also referred to as an atomic layer substance, a two-dimensional material, or the like).

Examples of the above layered crystal structure include a YbFe₂O₄ type structure, a Yb₂Fe₃O₇ type structure, and a variant structure of these structures. An example of the variant structure is a crystal structure in which part of a YbFezO₄ type structure and part of a Yb₂Fe₃O₇ type structure are stacked.

The crystal structure of the metal oxide is not necessarily the layered crystal structure as long as the crystal in the crystal structure of the metal oxide is likely to have c-axis alignment. For example, the crystal structure of the metal oxide may each be a wurtzite type structure or the like.

The above structure can increase the crystallinity of the metal oxide, which leads to an increase in the mobility of the metal oxide. Thus, the use of the metal oxide for the channel formation region of the transistor increases the on-state current of the transistor, leading to an improvement in the electrical characteristics of the transistor.

The above structure can reduce the cation disorder in the metal oxide, which leads to an increase in the mobility of the metal oxide. Thus, the use of the metal oxide for the channel formation region of the transistor increases the on-state current of the transistor, leading to an improvement in the electrical characteristics of the transistor.

In the case where the metal oxide is an In-M-Zn oxide, increasing the zinc content percentage in the metal oxide can increase the crystallinity of the metal oxide. Thus, the aforementioned metal oxide in which the zinc content percentage is higher than the indium content percentage can be suitably used for a semiconductor layer of a transistor.

Here, the crystal structure of a crystal included in the metal oxide of one embodiment of the present invention will be described. Examples of the crystal structure include, as described above, a YbFe₂O₄ type structure, a Yb₂Fe₃O₇ type structure, and a variant structure of these structures.

FIG. 12A to FIG. 12C are diagrams illustrating the atomic arrangement in the crystal included in the metal oxide of one embodiment of the present invention. In each of FIG. 12A to FIG. 12C, an atom is represented by a sphere (a circle) and a bond between a metal atom and an oxygen atom is represented by a line, whereby the atomic arrangement in the crystal is illustrated.

In each of FIG. 12A to FIG. 12C, the arrow denotes the c-axis direction in the crystal structure of the In-M-Zn oxide. The direction perpendicular to the c-axis direction denoted by the arrow in each of FIG. 12A to FIG. 12C is the a-b plane direction in the crystal structure of the In-M-Zn oxide.

Here, an atom ME1 is an indium atom in most cases. Note that depending on the composition of the In-M-Zn oxide, some of the atoms ME1 may be element M atoms or zinc atoms. An atom ME2 is an element M atom or a zinc atom in most cases. Note that depending on the composition of the In-M-Zn oxide, some of the atoms ME2 may be indium atoms.

As illustrated in FIG. 12A, the crystal included in the metal oxide has a structure in which a layer 31 containing the atom ME1 and an oxygen atom (O) and a layer 32 containing the atom ME2 and an oxygen atom are stacked. Note that in the crystal structure illustrated in FIG. 12A, two of the layers 32 exist between two of the layers 31 close to each other in the c-axis direction. That is, the crystal structure illustrated in FIG. 12A is a YbFe₂O₄ type structure. For example, in the case where the composition of the metal oxide is In:M:Zn=1:1:1 [atomic ratio] or in the neighborhood thereof, this crystal structure is likely to be obtained.

The aforementioned first layer corresponds to the layer 31, and the aforementioned second layer corresponds to the layer 32. Thus, the layer 31 can be rephrased as the first layer. The layer 32 can be rephrased as the second layer.

Next, the atomic arrangement in the crystal is expressed as polyhedrons. FIG. 13A is a diagram in which the atomic arrangement in the crystal illustrated in FIG. 12A is expressed as polyhedrons. Note that the polyhedron included in the layer 31 is illustrated in FIG. 13B, and the polyhedron that can be included in the layer 32 is illustrated in FIG. 13C and FIG. 13D.

The polyhedron illustrated in FIG. 13B has an octahedral structure. The octahedral structure includes the atom ME1 (e.g., an indium atom) at the center and includes oxygen atoms at the vertexes. In the layer 31, such octahedral structures are edge-shared.

The polyhedron illustrated in FIG. 13C has a trigonal bipyramidal structure. The trigonal bipyramidal structure includes the atom ME2 (e.g., an element M atom or a zinc atom) at the center or in the vicinity thereof and includes oxygen atoms at the vertexes. The polyhedron illustrated in FIG. 13D has a tetrahedral structure. The tetrahedral structure includes the atom ME2 (e.g., an element M atom or a zinc atom) at the center and oxygen atoms at the vertexes. In the layer 32 illustrated in FIG. 13A, the trigonal bipyramidal structures are edge-shared. Note that the structure of the layer 32 may depend on the number of layers 32 existing between the two layers 31 close to each other in the c-axis direction. In the layer 32, for example, the trigonal bipyramidal structures are vertex-shared in some cases and the tetrahedral structures are vertex-shared in other cases.

In FIG. 13A, the layer 31 and the layer 32 are vertex-shared. The two layers 32 adjacent to each other in the c-axis direction are vertex-shared or edge-shared. Note that in FIG. 13A, the two layers 32 adjacent to each other in the c-axis direction are edge-shared.

Although the crystal structures of the In-M-Zn oxide with a composition of In:M:Zn=1:1:1 [atomic ratio] are shown as examples in FIG. 12A and FIG. 13A, the composition of the metal oxide of one embodiment of the present invention is not limited thereto. The metal oxide may be, for example, an In-M-Zn oxide whose composition formula is represented by In_{(1+α)}M₍₁₋ₐ₎O₃(ZnO)ₘ (α is a real number greater than −1 and less than 1 and m is a positive real number).

In the case where m is a real number greater than 0 and less than 1, the crystal included in the metal oxide sometimes includes a region where the two layers 32 exist between the two layers 31 close to each other in the c-axis direction and a region where one of the layers 32 exists between the two layers 31 close to each other in the c-axis direction (see FIG. 12B). Note that the crystal structure of the crystal included in the metal oxide illustrated in FIG. 12B is a Yb₂Fe₃O₇ type structure. In the case where the composition of the metal oxide is In:M:Zn=1:1:0.5 [atomic ratio], the crystal structure illustrated in FIG. 12B is likely to be obtained.

In the case where m is a real number greater than 1, the crystal included in the metal oxide sometimes includes three or more of the layers 32 between the two layers 31 close to each other in the c-axis direction. In the crystal structure illustrated in FIG. 12C, for example, three of the layers 32 exist between the two layers 31 close to each other in the c-axis direction. Note that in the case where the composition of the metal oxide is In:M:Zn=1:1:2 [atomic ratio] or in the neighborhood thereof, the crystal structure illustrated in FIG. 12C is likely to be obtained.

Note that the relationship between the stacked-layer structure of the layer 31 and the layer 32 and the composition of the metal oxide is not limited to the above. Even when the composition of the metal oxide is In:M:Zn=1:1:1 [atomic ratio] or in the neighborhood thereof, the one layer 32 or the three or more layers 32 may exist between the two layers 31 close to each other in the c-axis direction. The same applies to a crystal structure of the metal oxide having a composition other than In:M:Zn=1:1:1 [atomic ratio] or in the neighborhood thereof. Such a crystal structure is sometimes referred to as a variant structure.

In the case where α is a real number greater than 0 and less than 1, the layer 32 may include an indium atom in addition to an element M atom and a zinc atom. In the case where x is a real number greater than −1 and less than 0, the layer 31 may include an element M atom or a zinc atom in addition to an indium atom.

The crystal structure of the crystal included in the metal oxide may be a wurtzite type structure.

FIG. 12D is a diagram illustrating a wurtzite type structure. Note that in FIG. 12D, an atom is represented by a sphere (a circle), and a bond between an atom ME3 and an atom NM is represented by a line. The arrow in FIG. 12D denotes the c-axis direction in the wurtzite type structure. The direction perpendicular to the c-axis direction denoted by the arrow in FIG. 12D is the a-b plane direction in the wurtzite type structure.

A wurtzite type structure can be regarded as a structure in which layers 33 are stacked in the c-axis direction. Note that in the layers 33, the tetrahedral structures are vertex-shared.

The atom ME3 is a metal atom, and the atom NM is an atom of a nonmetallic element. In the case where an In-M-Zn oxide contains nitrogen, for example, the In-M-Zn oxide sometimes has a wurtzite type structure in which an indium atom, an element M atom, or a zinc atom exists at a position of the atom ME3 and an oxygen atom or a nitrogen atom exists at a position of the atom NM, depending on the nitrogen atom content. For another example, in the case where the indium content percentage and the element M content percentage are low in the In-M-Zn oxide, the In-M-Zn oxide sometimes has a wurtzite type structure in which an indium atom, an element M atom, or a zinc atom exists at a position of the atom ME3 and an oxygen atom exists at a position of the atom NM.

Here, the element M is assumed to be gallium. The octahedral structure illustrated in FIG. 13B includes one of the atoms ME1 at the center and includes oxygen atoms at the six vertexes. Since each oxygen atom is tetracoordinated, the charge of an oxygen atom per bond is assumed to have a valence of −0.5. In the octahedral structure illustrated in FIG. 13B, when the formal charge of the atom ME1 has a valence of +3, the charge of the octahedral structure can be regarded as having a valence of 0. Here, in the In—Ga—Zn oxide, the formal charge of each of an indium atom and a gallium atom has a valence of +3. Meanwhile, when the formal charge of the atom ME1 has a valence of +2, the charge of the octahedral structure can be regarded as having a valence of −1. Here, in the In—Ga—Zn oxide, the formal charge of a zinc atom has a valence of +2.

Note that in the case where the atom ME1 is an indium atom in the layer 31 formed by the above octahedral structure, the layer 31 can be regarded as maintaining electrical neutrality. Note that in the case where some of the atoms ME1 are zinc atoms, the layer 32 can be regarded as not maintaining electrical neutrality. At this time, the layer 31 has insufficient electrons.

The trigonal bipyramidal structure illustrated in FIG. 13C includes one of the atoms ME2 at the center and includes oxygen atoms at the five vertexes. Since each oxygen atom is tetracoordinated, the charge of an oxygen atom per bond is assumed to have a valence of −0.5. In the trigonal bipyramidal structure illustrated in FIG. 13C, when the formal charge of the atom ME2 has a valence of +3, the charge of the trigonal bipyramidal structure can be regarded as having a valence of +0.5. When the formal charge of the atom ME2 has a valence of +2, the charge of the trigonal bipyramidal structure can be regarded as having a valence of −0.5.

Note that in the case where the number of zinc atoms is equal to the sum of the number of indium atoms and the number of gallium atoms in the layer 32 formed by the above trigonal bipyramidal structure, the layer 32 can be regarded as maintaining electrical neutrality. Note that in the case where the sum of the number of indium atoms and the number of gallium atoms exceeds the number of zinc atoms, the layer 32 can be regarded as not maintaining electrical neutrality. At this time, the layer 32 has excess electrons.

For example, in a metal oxide in which the atomic ratio of indium to zinc is high, some of the atoms ME2 are indium atoms. That is, the metal oxide has excess electrons. Thus, a transistor whose semiconductor layer includes a metal oxide in which the atomic ratio of indium to zinc is high has normally-on characteristics in some cases. By contrast, in a metal oxide in which the atomic ratio of zinc to indium is high, some of the atoms ME1 are zinc atoms. That is, the metal oxide has insufficient electrons. Thus, a transistor whose semiconductor layer includes a metal oxide in which the atomic ratio of zinc to indium is high presumably has normally-off characteristics.

Accordingly, it is preferable that a metal oxide used in a semiconductor layer of a transistor have crystallinity and that the zinc content percentage be higher than the indium content percentage in the metal oxide.

Specifically, as the metal oxide, a metal oxide with a composition of In:M:Zn=1:1:1.2 [atomic ratio] or in the neighborhood thereof, a composition of In:M:Zn=1:1:2 [atomic ratio] or in the neighborhood thereof, a composition of In:M:Zn=1:2:8 [atomic ratio] or in the neighborhood thereof, a composition of In:M:Zn=1:3:2 [atomic ratio] or in the neighborhood thereof, or a composition of In:M:Zn=1:3:4 [atomic ratio] or in the neighborhood thereof may be used. Note that a composition in the neighborhood includes the range of +30% of an intended atomic ratio. Gallium, aluminum, yttrium, or tin is preferably used as the element M.

When a film of the metal oxide is formed by a sputtering method, the above atomic ratio is not limited to the atomic ratio of the formed film of the metal oxide and may be the atomic ratio of a sputtering target used for forming the film of the metal oxide.

The metal oxide described in this embodiment can be used for the semiconductor layer 30 described in Embodiment 1, for example. A transistor including the above-described metal oxide in the semiconductor layer 30 described in Embodiment 1 can have normally-off characteristics. Accordingly, a semiconductor device that has favorable electrical characteristics and high reliability can be provided.

When the metal oxide described in this embodiment is used for the semiconductor layer 30 included in the semiconductor device described in Embodiment 1, the conductor 25 functioning as the second gate electrode, the insulator 20 functioning as the second gate insulator, and the like can be omitted. Accordingly, the manufacturing process of the semiconductor device can be simplified, and the productivity can be improved.

The metal oxide described in this embodiment can be used for an oxide 230 described in Embodiment 3, for example. A transistor including the above-described metal oxide in the oxide 230 described in Embodiment 3 can have normally-off characteristics. Accordingly, a semiconductor device that has favorable electrical characteristics and high reliability can be provided.

This embodiment can be implemented in combination with any of the structures described in the other embodiments and the like, as appropriate.

### Embodiment 3

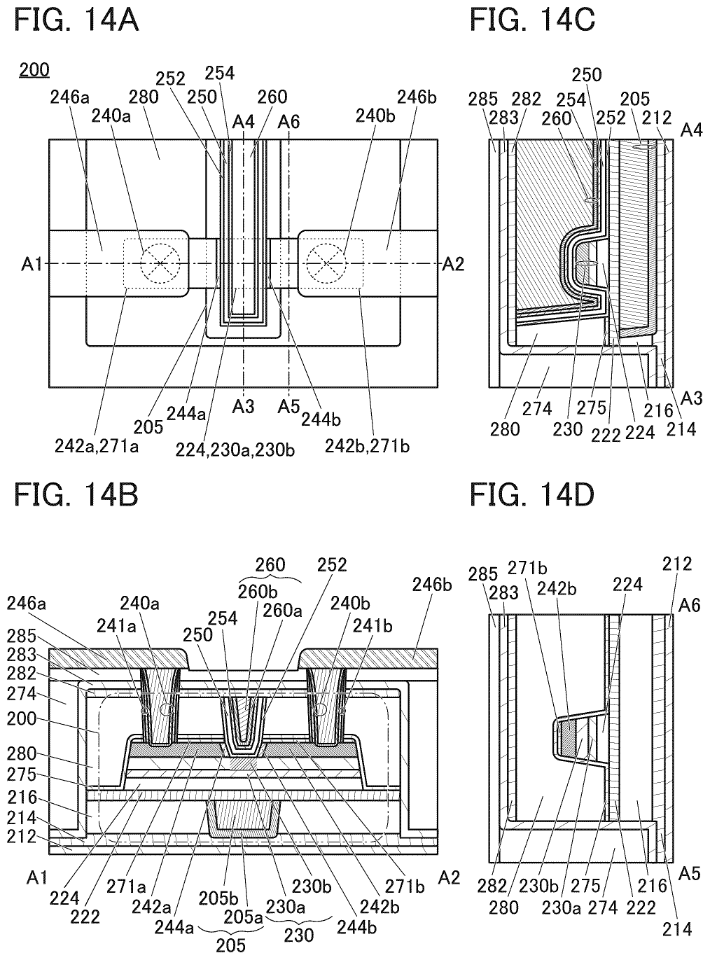

In this embodiment, an example of a semiconductor device of one embodiment of the present invention and a manufacturing method thereof are described with reference to FIG. 14A to FIG. 40C. The semiconductor device of one embodiment of the present invention includes a transistor.

### Structure Example of Semiconductor Device

A structure of a semiconductor device including a transistor 200 is described with reference to FIG. 14. FIG. 14A to FIG. 14D are a top view and cross-sectional views of the semiconductor device including the transistor 200. FIG. 14A is a top view of the semiconductor device. FIG. 14B to FIG. 14D are cross-sectional views of the semiconductor device. Here, FIG. 14B is a cross-sectional view of a portion indicated by dashed-dotted line A1-A2 in FIG. 14A, and is a cross-sectional view of the transistor 200 in the channel length direction. FIG. 14C is a cross-sectional view of a portion indicated by dashed-dotted line A3-A4 in FIG. 14A, and is a cross-sectional view of the transistor 200 in the channel width direction. FIG. 14D is a cross-sectional view of a portion indicated by dashed-dotted line A5-A6 in FIG. 14A. Note that for clarity of the drawing, some components are omitted in the top view of FIG. 14A.

The semiconductor device of one embodiment of the present invention includes an insulator 212 over a substrate (not illustrated), an insulator 214 over the insulator 212, the transistor 200 over the insulator 214, an insulator 280 over the transistor 200, an insulator 282 over the insulator 280, an insulator 283 over the insulator 282, an insulator 274 over the insulator 283, and an insulator 285 over the insulator 283 and the insulator 274. The insulator 212, the insulator 214, the insulator 280, the insulator 282, the insulator 283, the insulator 274, and the insulator 285 each function as an interlayer film. In addition, the semiconductor device also includes a conductor 240a and a conductor 240b that are electrically connected to the transistor 200 and function as plugs. Note that an insulator 241a is provided in contact with the side surface of the conductor 240a, and an insulator 241b is provided in contact with the side surface of the conductor 240b. A conductor 246a that is electrically connected to the conductor 240a is provided over the insulator 285 and the conductor 240a, and a conductor 246b that is electrically connected to the conductor 240b is provided over the insulator 285 and the conductor 240b. The insulator 283 is in contact with part of the top surface of the insulator 214, the side surface of the insulator 280, and the side surface and the top surface of the insulator 282.

The insulator 241a is provided in contact with the inner wall of an opening formed in the insulator 280, the insulator 282, the insulator 283, and the insulator 285, and the conductor 240a is provided in contact with the side surface of the insulator 241a. The insulator 241b is provided in contact with the inner wall of an opening formed in the insulator 280, the insulator 282, the insulator 283, and the insulator 285, and the conductor 240b is provided in contact with the side surface of the insulator 241b. Note that the insulator 241a and the insulator 241b each have a structure in which a first insulator is provided in contact with the inner wall of the opening and a second insulator is provided inward from the first insulator. The conductor 240a has a structure in which a first conductor is provided in contact with the side surface of the insulator 241a and a second conductor is provided inward from the first conductor. The conductor 240b has a structure in which a first conductor is provided in contact with the side surface of the insulator 241b and a second conductor is provided inward from the first conductor. Here, the top surface of the conductor 240a can be substantially level with the top surface of the insulator 285 in a region overlapping with the conductor 246a. Moreover, the top surface of the conductor 240b can be substantially level with the top surface of the insulator 285 in a region overlapping with the conductor 246b.

Although the insulator 241a and the insulator 241b in the transistor 200 each have a structure in which the first insulator and the second insulator are stacked, the present invention is not limited thereto. For example, the insulator 241a and the insulator 241b may each have a single-layer structure or a stacked-layer structure of three or more layers. Although the conductor 240a and the conductor 240b in the transistor 200 each have a structure in which the first conductor and the second conductor are stacked, the present invention is not limited thereto. For example, the conductor 240a and the conductor 240b may each have a single-layer structure or a stacked-layer structure of three or more layers. In the case where a component has a stacked-layer structure, layers may be distinguished by ordinal numbers corresponding to the formation order.

### [Transistor 200]

As illustrated in FIG. 14A to FIG. 14D, the transistor 200 includes an insulator 216 over the insulator 214, a conductor 205 (a conductor 205a and a conductor 205b) placed to be embedded in the insulator 216, an insulator 222 over the insulator 216 and the conductor 205, an insulator 224 over the insulator 222, an oxide 230a over the insulator 224, an oxide 230b over the oxide 230a, a conductor 242a and a conductor 242b over the oxide 230b, an insulator 271a over the conductor 242a, an insulator 271b over the conductor 242b, an insulator 252 located over the oxide 230b and between the conductor 242a and the conductor 242b, an insulator 250 over the insulator 252, an insulator 254 over the insulator 250, a conductor 260 (a conductor 260a and a conductor 260b) located over the insulator 254 and overlapping with part of the oxide 230b, and an insulator 275 placed over the insulator 222, the insulator 224, the oxide 230a, the oxide 230b, the conductor 242a, the conductor 242b, the insulator 271a, and the insulator 271b. The transistor 200 also includes an insulator 244a located between the conductor 242a and the insulator 252 and an insulator 244b located between the conductor 242b and the insulator 252.

Hereinafter, the oxide 230a and the oxide 230b are collectively referred to as an oxide 230 in some cases. The conductor 242a and the conductor 242b are collectively referred to as a conductor 242 in some cases. The insulator 271a and the insulator 271b are collectively referred to as an insulator 271 in some cases.

The insulator 280 is located over the insulator 275. Thus, it can be said that the insulator 280 is located above the conductor 242a and the conductor 242b. An opening reaching the oxide 230b is provided in the insulator 280 and the insulator 275. That is, it can be said that the opening includes a region that is between the conductor 242a and the conductor 242b and overlaps with the oxide 230b. It can also be said that the insulator 275 includes an opening overlapping with the opening included in the insulator 280. The insulator 252, the insulator 250, the insulator 254, and the conductor 260 are placed in the opening. That is, the conductor 260 includes a region overlapping with the oxide 230b with the insulator 252, the insulator 250, and the insulator 254 therebetween. The conductor 260, the insulator 252, the insulator 250, and the insulator 254 are provided between the insulator 271a and the conductor 242a, and the insulator 271b and the conductor 242b in the channel length direction of the transistor 200. The insulator 254 includes a region in contact with the side surface of the conductor 260 and a region in contact with the bottom surface of the conductor 260.

The conductor 260 functions as a first gate (also referred to as a top gate) electrode, and the conductor 205 functions as a second gate (also referred to as a back gate or a bottom gate) electrode. The insulator 252, the insulator 250, and the insulator 254 function as a first gate insulator, and the insulator 222 and the insulator 224 function as a second gate insulator. The conductor 242a functions as one of a source electrode and a drain electrode, and the conductor 242b functions as the other of the source electrode and the drain electrode. At least part of a region of the oxide 230 overlapping with the conductor 260 functions as a channel formation region.

To miniaturize or highly integrate transistors, a thinner gate insulator is needed. However, as the gate insulator becomes thinner, a problem such as increases in parasitic capacitance between the source electrode and the gate electrode and parasitic capacitance between the drain electrode and the gate electrode or increases in leakage current between the source electrode and the gate electrode and leakage current between the drain electrode and the gate electrode may arise.

Thus, in this embodiment, the insulator 244a is provided between the conductor 242a functioning as one of the source electrode and the drain electrode and the conductor 260 functioning as the top gate electrode, and the insulator 244b is provided between the conductor 242b functioning as the other of the source electrode and the drain electrode and the conductor 260. Since the insulator 244a and the insulator 244b are provided, the distance between the conductor 242a and the conductor 260 and the distance between the conductor 242b and the conductor 260 can be increased, so that parasitic capacitance between the conductor 242a and the conductor 260 and parasitic capacitance between the conductor 242b and the conductor 260 can be reduced. Thus, the switching speed of the transistor 200 can be improved, and the transistor can have high frequency characteristics.

In the transistor 200, a metal oxide functioning as a semiconductor (hereinafter also referred to as an oxide semiconductor) is preferably used for the oxide 230 including the channel formation region.

The metal oxide functioning as a semiconductor preferably has a band gap wider than or equal to 2 eV, further preferably wider than or equal to 2.5 eV. With use of a metal oxide having a wide band gap, the off-state current of the transistor can be reduced.

In the oxide 230, the channel formation region preferably has a low carrier concentration, whereas the source region and the drain region preferably have high carrier concentrations. With such a structure, a semiconductor device having favorable electrical characteristics can be provided. Note that at least part of the channel formation region in the oxide 230 overlaps with the conductor 260. In other words, the channel formation region is provided in a region between the conductor 242a and the conductor 242b. One of the source region and the drain region is provided to overlap with the conductor 242a, and the other of the source region and the drain region is provided to overlap with the conductor 242b.

Specifically, in a transistor with a short channel length, a source region with a high carrier concentration and a drain region with a high carrier concentration are likely to be short-circuited, which makes it difficult to achieve favorable switching characteristics. Thus, in a transistor with a short channel length, the carrier concentrations of a source region, a channel formation region, and a drain region need to be appropriately controlled.

A transistor using an oxide semiconductor is likely to have its electrical characteristics changed by impurities and oxygen vacancies in a channel formation region in the oxide semiconductor, which might degrade the reliability. In some cases, a defect that is an oxygen vacancy into which hydrogen enters (hereinafter sometimes referred to as VoH) is formed, which generates an electron serving as a carrier. Formation of VoH in the channel formation region may increase the donor concentration in the channel formation region. An increase in the donor concentration in the channel formation region may lead to a variation in threshold voltage. Therefore, when the channel formation region in the oxide semiconductor includes oxygen vacancies, the transistor is likely to have normally-on characteristics. Therefore, impurities, oxygen vacancies, and VoH are preferably reduced as much as possible in the channel formation region in the oxide semiconductor.

As a countermeasure against the above, an insulator containing excess oxygen is provided in the vicinity of the oxide semiconductor and heat treatment is performed, so that oxygen can be supplied from the insulator to the oxide semiconductor to reduce oxygen vacancies and VoH. However, supply of an excess amount of oxygen to the source region or the drain region might cause a decrease in the on-state current or field-effect mobility of the transistor. Furthermore, a variation of the amount of oxygen supplied to the source region or the drain region in the substrate plane leads to a variation in characteristics of the semiconductor device including the transistor. When oxygen supplied from the insulator to the oxide semiconductor diffuses into conductors such as the gate electrode, the source electrode, and the drain electrode, the conductors might be oxidized and the conductivity might be impaired, for example, so that the electrical characteristics and reliability of the transistor might be adversely affected.

Accordingly, oxygen vacancies and VoH are preferably reduced in the channel formation region. Thus, it is preferable that oxygen be supplied to the channel formation region and an excess amount of oxygen not be supplied to the source region or the drain region. Furthermore, it is preferable to inhibit diffusion of hydrogen into the channel formation region.

An insulator that easily transmits oxygen is preferably used as the insulator 250 to supply oxygen to the channel formation region. An insulator including excess oxygen is preferably used as the insulator 280. With such a structure, oxygen included in the insulator 280 can be supplied to the channel formation region of the oxide 230 through the insulator 250.

The insulator 250 is provided in contact with the top surface of the insulator 252.

Note that the insulator 250 corresponds to the insulator 50 described in Embodiment 1. Thus, the description of the insulator 50 in Embodiment 1 can be referred to for the material, the structure, and the like used for the insulator 250. The description of the insulator 250 in this embodiment can also be referred to for the material, the structure, and the like used for the insulator 50 described in Embodiment 1.

Note that the insulator 280 corresponds to the insulator 80 described in Embodiment 1. Thus, the description of the insulator 80 in Embodiment 1 can be referred to for the material, the structure, and the like used for the insulator 280. The description of the insulator 280 in this embodiment can also be referred to for the material, the structure, and the like used for the insulator 80 described in Embodiment 1.

Supply of an excess amount of oxygen to the channel formation region in the oxide 230 might cause excessive oxidation of the source region and the drain region through the channel formation region and cause a decrease in the on-state current or field-effect mobility of the transistor 200.

Thus, the insulator 252 having a barrier property against oxygen is preferably provided between the insulator 250 and the oxide 230b. The insulator 252 is provided in contact with the bottom surface of the insulator 250, the top surface of the oxide 230b, and the side surface of the oxide 230b. Since the insulator 252 has a barrier property against oxygen, oxygen included in the insulator 250 can be supplied to the channel formation region, while oxygen included in the insulator 250 can be inhibited from being excessively supplied to the channel formation region. Thus, it is possible to inhibit excessive supply of oxygen to the source region and the drain region through the channel formation region and a decrease in the on-state current or field-effect mobility of the transistor 200. In addition, it is possible to inhibit release of oxygen from the oxide 230 when heat treatment or the like is performed and inhibit formation of oxygen vacancies in the oxide 230. Accordingly, the transistor 200 can have favorable electrical characteristics and higher reliability.

The insulator 252 is provided between the insulator 280 and the insulator 250 and includes a region in contact with the sidewall of the opening included in the insulator 280. With such a structure, oxygen included in the insulator 280 can be supplied to the insulator 250, while oxygen included in the insulator 280 can be inhibited from being excessively supplied to the insulator 250.

An insulator including an oxide of one or both of aluminum and hafnium is preferably used as the insulator 252. As the insulator, aluminum oxide, hafnium oxide, an oxide containing aluminum and hafnium (hafnium aluminate), an oxide containing hafnium and silicon (hafnium silicate), or the like can be used. In this embodiment, aluminum oxide is used as the insulator 252. In this case, the insulator 252 includes at least oxygen and aluminum. Note that the insulator 252 is less permeable to oxygen than the insulator 250, for example. For the insulator 252, a material that is less permeable to oxygen than the insulator 250 is used, for example. As the insulator 252, magnesium oxide, gallium oxide, gallium zinc oxide, indium gallium zinc oxide, or the like may be used, for example.

Note that the thickness of the insulator 252 is preferably small. This is because the amount of oxygen supplied to the oxide 230 through the insulator 250 is reduced when the thickness of the insulator 252 is too large. The thickness of the insulator 252 is specifically greater than or equal to 0.1 nm and less than or equal to 5.0 nm, preferably greater than or equal to 0.5 nm and less than or equal to 3.0 nm, further preferably greater than or equal to 1.0 nm and less than 3.0 nm. In this case, at least part of the insulator 252 includes a region having a thickness like the above-described thickness. For example, the insulator 252 preferably includes a region having a thickness smaller than the thickness of the insulator 250. In this case, at least part of the insulator 252 includes a region having a thickness smaller than that of the insulator 250.

To form the insulator 252 having a small thickness as described above, an ALD method is preferably used for film formation. Examples of an ALD method include a thermal ALD method, in which a precursor and a reactant react with each other only by a thermal energy, and a PEALD (Plasma Enhanced ALD) method, in which a reactant excited by plasma is used. The use of plasma in a PEALD method is sometimes preferable because film formation at a lower temperature is possible.

An ALD method, which enables an atomic layer to be deposited one by one, has advantages such as formation of an extremely thin film, film formation on a component with a high aspect ratio, formation of a film with a small number of defects such as pinholes, film formation with excellent coverage, and low-temperature film formation. Therefore, the insulator 252 can be formed on the side surface of the opening formed in the insulator 280 and the like, with a small thickness like the above-described thickness and favorable coverage.

Note that some of precursors usable in an ALD method contain carbon or the like. Thus, in some cases, a film provided by an ALD method includes impurities such as carbon in a larger amount than a film provided by another film formation method. Note that impurities can be quantified by SIMS, XPS, or auger electron spectroscopy (AES).

When the thickness of the insulator 252 is reduced, the transistor 200 can be miniaturized. This is because the insulator 252 is provided in the opening formed in the insulator 280 and the like, together with the insulator 254, the insulator 250, and the conductor 260. With the above structure, a semiconductor device that can be miniaturized or highly integrated can be provided.

The insulator 252 is provided between the insulator 250 and the conductor 242a and between the insulator 250 and the conductor 242b. When the thickness of the insulator 252 is reduced, the side surface of the conductor 242a is oxidized to form the insulator 244a. Similarly, the side surface of the conductor 242b is oxidized to form the insulator 244b. In other words, the transistor 200 includes the insulator 244a located between the conductor 242a and the insulator 252 and the insulator 244b located between the conductor 242b and the insulator 252.

Note that the lengths of the insulator 244a and the insulator 244b in the channel length direction can be controlled by adjusting the thickness of the insulator 252. For example, when the thickness of the insulator 252 is increased, the amount of oxygen included in the insulator 250 and diffused into the conductor 242a and the conductor 242b is reduced, so that the side surfaces of the conductor 242a and the conductor 242b can be inhibited from being oxidized and the lengths of the insulator 244a and the insulator 244b in the channel length direction can be reduced. Accordingly, a decrease in the on-state current or field-effect mobility of the transistor 200 can be inhibited.

The insulator 244a includes an element included in the conductor 242a and oxygen. Similarly, the insulator 244b includes an element included in the conductor 242b and oxygen. For example, in the case where a material containing a metal element is used for the conductor 242a and the conductor 242b, the insulator 244a and the insulator 244b each include the metal element and oxygen. For another example, in the case where a conductive material containing a metal element and nitrogen is used for the conductor 242a and the conductor 242b, the insulator 244a and the insulator 244b each include the metal element, oxygen, and nitrogen.

Note that the insulator 244a and the insulator 244b respectively correspond to the insulator 44a and the insulator 44b described in Embodiment 1. Thus, the description of the insulator 44a and the insulator 44b in Embodiment 1 can be referred to for the material, the structure, and the like used for the insulator 244a and the insulator 244b. The description of the insulator 244a and the insulator 244b in this embodiment can also be referred to for the material, the structure, and the like used for the insulator 44a and the insulator 44b described in Embodiment 1.

In order to inhibit diffusion of hydrogen into the channel formation region, an insulator having a function of inhibiting hydrogen diffusion is preferably provided in the vicinity of the oxide 230. In the semiconductor device described in this embodiment, the insulator corresponds to the insulator 252 and the insulator 254, for example.

Aluminum oxide, which can be suitably used for the insulator 252, has a function of inhibiting diffusion of hydrogen (e.g., at least one of a hydrogen atom, a hydrogen molecule, and the like). Thus, diffusion of impurities included in the insulator 250, such as hydrogen, into the oxide 230 can be prevented. Note that the insulator 252 is less permeable to hydrogen than the insulator 250, for example. The insulator 252 is a material that is less permeable to hydrogen than the insulator 250, for example.

The insulator 254 preferably has a barrier property against hydrogen. Accordingly, diffusion of impurities included in the conductor 260, such as hydrogen, into the insulator 250 and the oxide 230 can be prevented. As the insulator 254, a film of silicon nitride formed by a PEALD method is used, for example. In this case, the insulator 254 includes at least nitrogen and silicon. As the insulator 254, aluminum oxide, magnesium oxide, hafnium oxide, gallium oxide, indium gallium zinc oxide, silicon nitride oxide, or the like may be used, for example. Note that the insulator 254 is less permeable to hydrogen than the insulator 250, for example. For the insulator 254, a material that is less permeable to hydrogen than the insulator 250 is used, for example.

The insulator 254 may further have a barrier property against oxygen. The insulator 254 is provided between the insulator 250 and the conductor 260. Thus, diffusion of oxygen included in the insulator 250 into the conductor 260 can be prevented, so that oxidation of the conductor 260 can be inhibited. A reduction in the amount of oxygen supplied to the oxide 230 can be inhibited. Note that the insulator 254 is less permeable to oxygen than the insulator 250, for example. For the insulator 254, a material that is less permeable to oxygen than the insulator 250 is used, for example.

The insulator 254 needs to be provided in the opening formed in the insulator 280 and the like, together with the insulator 252, the insulator 250, and the conductor 260. The thickness of the insulator 254 is preferably small for miniaturization of the transistor 200. The thickness of the insulator 254 is greater than or equal to 0.1 nm and less than or equal to 5.0 nm, preferably greater than or equal to 0.5 nm and less than or equal to 3.0 nm, further preferably greater than or equal to 1.0 nm and less than or equal to 3.0 nm. In this case, at least part of the insulator 254 includes a region having a thickness like the above-described thickness. The thickness of the insulator 254 is preferably smaller than the thickness of the insulator 250. In this case, at least part of the insulator 254 includes a region having a thickness smaller than that of the insulator 250.

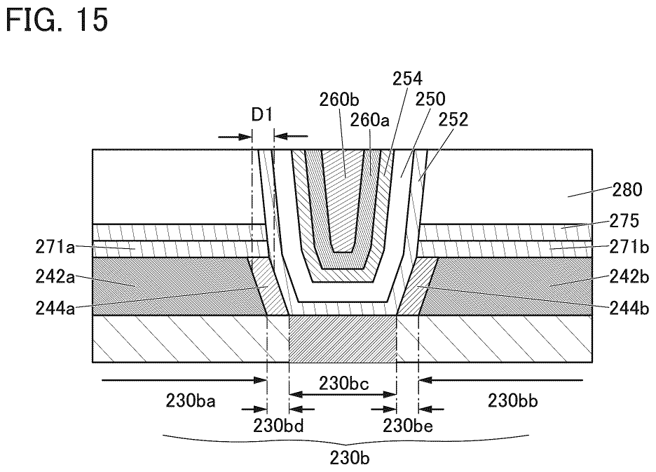

Here, FIG. 15 is an enlarged view of the vicinity of the channel formation region in FIG. 14B. As illustrated in FIG. 15, the length of the insulator 244a in the channel length direction is referred to as a length D1. Note that the length D1 is also a distance from the conductor 242a to the insulator 252 in a cross-sectional view in the channel length direction. The length D1 is also a distance from the side surface of the conductor 242a to a surface of the insulator 252 in contact with the insulator 244a. For example, the length D1 refers to a difference of the position of the interface between the insulator 244a and the insulator 252 from the position of the interface between the conductor 242a and the insulator 244a. The length of the insulator 244b in the channel length direction is equal to or substantially equal to the length D1.

The length D1 is preferably greater than or equal to 1 nm, greater than or equal to 3 nm, or greater than or equal to 5 nm and less than or equal to 20 nm, less than or equal to 15 nm, or less than or equal to 10 nm. Alternatively, the length D1 is preferably greater than or equal to the thickness of the insulator 252 and less than or equal to a distance from the conductor 260 to the oxide 230. Here, the distance from the conductor 260 to the oxide 230b refers to, for example, a distance from the bottom surface of the conductor 260a to the top surface of the oxide 230b in the cross-sectional view in the channel length direction. Note that the distance from the conductor 260 to the oxide 230b is also the sum of the thickness of the insulator 252, the thickness of the insulator 250, and the thickness of the insulator 254. That is, it can also be said that the distance from the conductor 260 to the oxide 230b is the physical thickness of the first gate insulator. With this structure, the transistor 200 can have favorable electrical characteristics.

Note that the length D1 can be measured by observing a cross-sectional shape of the insulator 244a and its vicinity with a transmission electron microscope (TEM) or the like in some cases.

Furthermore, the length D1 can sometimes be calculated by composition line analysis of the insulator 244a and its vicinity with energy dispersive X-ray spectroscopy (EDX). For example, as a method for calculating the length D1, first, EDX line analysis is performed with the channel length direction regarded as a depth direction. Next, in the profile of quantitative values of elements in the depth direction, which is obtained from the analysis, the depth (position) of the interface between the insulator 244a and the insulator 252 is regarded as a depth at which the quantitative value of an element that is the main component of the insulator 252 but is not the main component of the conductor 242a becomes half. Moreover, the depth (position) of the interface between the conductor 242a and the insulator 244a is regarded as a depth at which the quantitative value of oxygen becomes half. In this manner, the length D1 can be calculated.

As illustrated in FIG. 15, the oxide 230b includes a region 230bc functioning as the channel formation region of the transistor 200 and a region 230ba and a region 230bb that are provided to sandwich the region 230bc and function as a source region and a drain region. At least part of the region 230bc overlaps with the conductor 260. In other words, the region 230bc is provided in a region between the conductor 242a and the conductor 242b. The region 230ba is provided to overlap with the conductor 242a, and the region 230bb is provided to overlap with the conductor 242b.

The region 230bc has a smaller amount of oxygen vacancies or a lower impurity concentration than the region 230ba and the region 230bb, and thus is a high-resistance region with a low carrier concentration. In other words, the region 230bc has a lower carrier concentration than the region 230ba and the region 230bb.

The region 230ba and the region 230bb have a large amount of oxygen vacancies or a high concentration of an impurity such as hydrogen, nitrogen, or a metal element, and thus are each a low-resistance region with an increased carrier concentration. In other words, the region 230ba and the region 230bb have a higher carrier concentration than the region 230bc.

In obtaining favorable switching characteristics of a transistor having a short channel length, relieving a drain electric field and increasing controllability of a top gate electrode are important.

Since the transistor 200 includes the insulator 244a, a region 230bd is formed in the oxide 230b below the insulator 244a. The region 230bd is a region having a carrier concentration lower than or substantially equal to the carrier concentration of the region 230ba and higher than or substantially equal to the carrier concentration of the region 230bc. The region 230bd is located between the region 230bc and the region 230ba and thus functions as a junction region or an offset region between the region 230bc and the region 230ba. The region 230bd has a hydrogen concentration lower than or substantially equal to the hydrogen concentration of the region 230ba and higher than or substantially equal to the hydrogen concentration of the region 230bc in some cases. Similarly, since the transistor 200 includes the insulator 244b, a region 230be is formed in the oxide 230b below the insulator 244b. Like the region 230bd, the region 230be functions as a junction region or an offset region between the region 230bc and the region 230bb.

Since the region 230bd is located below the insulator 244a, oxygen included in the insulator 250 or the like is sometimes supplied to the region 230bd through the insulator 244a. Thus, the amount of oxygen vacancies in the region 230bd is smaller than or substantially equal to the amount of oxygen vacancies in the region 230ba and larger than or substantially equal to the amount of oxygen vacancies in the region 230bc in some cases. Similarly, the amount of oxygen vacancies in the region 230be is smaller than or substantially equal to the amount of oxygen vacancies in the region 230bb and larger than or substantially equal to the amount of oxygen vacancies in the region 230bc in some cases.

Although FIG. 15 illustrates an example where the region 230ba, the region 230bb, the region 230bc, the region 230bd, and the region 230be are formed in the oxide 230b, the present invention is not limited thereto. For example, the above regions may be formed not only in the oxide 230b but also in the oxide 230a.

In the oxide 230, the range of each region is difficult to detect clearly in some cases. The concentrations of a metal element and impurity elements such as hydrogen and nitrogen, which are detected in each region, may be not only gradually changed between the regions but also continuously changed in each region. That is, the region closer to the channel formation region has lower concentrations of impurity elements such as hydrogen and nitrogen.

For example, in the case where the carrier concentration of the region 230bd and the carrier concentration of the region 230be are substantially the same as the carrier concentration of the region 230bc, the boundary between the region 230bd and the region 230bc and the boundary between the region 230be and the region 230bc cannot be clearly detected in some cases. In the case where the carrier concentration of the region 230bd is substantially the same as the carrier concentration of the region 230ba, the boundary between the region 230bd and the region 230ba cannot be clearly detected in some cases. In the case where the carrier concentration of the region 230be is substantially the same as the carrier concentration of the region 230bb, the boundary between the region 230be and the region 230bb cannot be clearly detected in some cases.

Here, the carrier concentration of the region 230bc is preferably lower than or equal to 1×10¹⁸ cm⁻³, further preferably lower than 1×10¹⁷ cm⁻³, still further preferably lower than 1×10¹⁶ cm⁻³, yet still further preferably lower than 1×10¹³ cm⁻³, and yet still further preferably lower than 1×10¹² cm⁻³. Note that the lower limit of the carrier concentration of the region 230bc functioning as the channel formation region is not particularly limited and can be, for example, 1×10⁻⁹ cm⁻³.

Here, the relationship between carrier concentration and the Fermi level is described. The relationship between the carrier concentration n and the Fermi level energy Ef is expressed by Formula (1) below.

[Formula 1]

n=Nc×exp(Ef−Ec/k_{B}T (1)

In Formula (1) above, Nc is the density of states in the conduction band, Ec is the energy at the conduction band minimum, k_{B} is a Boltzmann constant, and T is an absolute temperature.

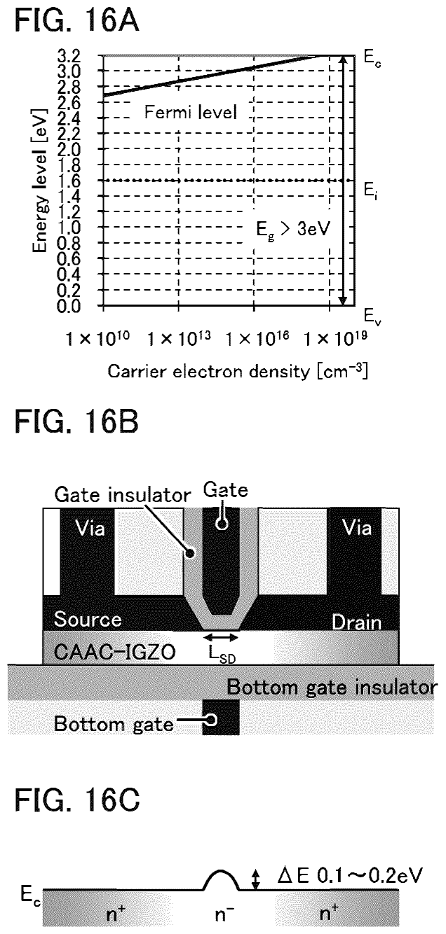

FIG. 16A shows the relationship between carrier concentration and the Fermi level when the density of states Nc in the conduction band is set to 5×10¹⁸ cm⁻³. In FIG. 16A, the vertical axis represents an energy level (Energy level) [eV] and the horizontal axis represents carrier concentration (Carrier electron density) [cm⁻³]. Furthermore, Ec in FIG. 16A is the energy at the conduction band minimum, Ei in FIG. 16A is the energy of the intrinsic level, and Ev in FIG. 16A is the energy at the valence band maximum. Hereinafter, “Fermi level position” refers to the position of the Fermi level relative to the conduction band minimum. The Fermi level position is sometimes represented by a difference ΔE(=Ec−Ef) between the energy Ec at the conduction band minimum and the Fermi level energy Ef.

From FIG. 16A, the Fermi level position (ΔE) at a carrier concentration of 1×10¹⁶ cm⁻³ is approximately 0.2 eV. Since the Fermi level at a carrier concentration of 1×10¹⁶ cm⁻³ is relatively close to the conduction band minimum, a region having a carrier concentration of approximately 1×10¹⁶ cm⁻³ can be regarded as an n−-type region (also referred to as an n− region). A region having a carrier concentration equal to, substantially equal to, or higher than the density of states in the conduction band can be regarded as an n+-type region (also referred to as an n+ region). A region having a sufficiently low carrier concentration (e.g., a region having a carrier concentration lower than 1×10¹³ cm⁻³) can be regarded as an i-type or substantially i-type region (also referred to as an i region).

Note that the carrier concentrations of the i region, the n− region, and the n+ region are not necessarily in the above ranges because the relationship between the carrier concentration and the Fermi level changes depending on the density of states Nc in the conduction band, the energy Ec at the conduction band minimum, and the absolute temperature T.

Accordingly, when the region 230bc is an i-type or substantially i-type region or an n−-type region and the region 230ba and the region 230bb are n+-type regions, the transistor 200 can achieve normally-off characteristics.

FIG. 16B is a schematic cross-sectional view of the transistor 200 illustrated in FIG. 14A to FIG. 14D in the channel length direction, and FIG. 16C is a schematic view of a conduction band offset in the channel length direction. FIG. 16B shows a state where the carrier concentration continuously changes between the regions and in each region.

The transistor illustrated in FIG. 16B includes a gate electrode (Gate), a gate insulating film (Gate insulator), a source electrode (Source), a drain electrode (Drain), In—Ga—Zn oxide having a CAAC structure (CAAC-IGZO), a bottom gate insulating film (Bottom gate insulator), a bottom gate electrode (Bottom gate), and a conductor (Via) connected to the source electrode or the drain electrode. Furthermore, L_{SD} shown in FIG. 16B refers to the shortest distance between the source electrode and the drain electrode.

As illustrated in FIG. 16C, even in the case where the carrier concentration of the channel formation region is lowered to a level that allows the channel formation region to be regarded as an i-type or substantially i-type region, the conduction band minimum of the channel formation region of a short-channel transistor is lowered (changes in the direction away from the intrinsic level) owing to the Conduction-Band-Lowering (CBL) effect, and thus, the offset of the conduction band between the source region and the channel formation region and the offset of the conduction band between the drain region and the channel formation region decrease. For example, the offset of the conduction band between the source region and the channel formation region and the offset of the conduction band between the drain region and the channel formation region are each 0.1 eV to 0.2 eV. Note that the offset of the conduction band between the source region and the channel formation region and the offset of the conduction band between the drain region and the channel formation region correspond to the aforementioned ΔE.

Accordingly, a transistor including a metal oxide in its channel formation region (OS transistor) can be regarded as an n+/n−/n+ accumulation-type junction-less transistor, in which the channel formation region is an n−-type region and the source region and the drain region are n+-type regions. In a junction-less transistor, the difference in Fermi level is small between the source region and the channel formation region, and the difference in Fermi level is small between the drain region and the channel formation region.

Note that an OS transistor is an accumulation-type transistor. Thus, the characteristic length between the source region and the channel formation region and the characteristic length between the drain region and the channel formation region in an OS transistor are shorter than those in an inversion-type Si transistor; thus, an OS transistor can have favorable switching characteristics regardless of being a junction-less transistor with a short channel.

In an OS transistor, holes are minority carriers. In metal oxides such as IGZO, IAZO, and IAGZO, each of which has a wide band gap, the hole concentration in the valence band is extremely low. In these metal oxides, each of which has a large hole effective mass, the hole mobility is low. In other words, holes do not move or do not easily move. Accordingly, the OS transistor can be regarded as including no or substantially no holes as carriers. This is also probably one of the factors in achieving favorable switching characteristics with a short channel.

As illustrated in FIG. 14C, the insulator 252 is provided in contact with the top surface and the side surface of the oxide 230b, the side surface of the oxide 230a, the side surface of the insulator 224, and the top surface of the insulator 222. That is, the regions of the oxide 230a, the oxide 230b, and the insulator 224 that overlap with the conductor 260 are covered with the insulator 252 in a cross section in the channel width direction. The insulator 252 includes a region in contact with the side surface of the insulator 271a, a region in contact with the side surface of the insulator 271b, and a region in contact with the sidewall of the opening included in the insulator 275.

With the above structure, the region 230bc functioning as the channel formation region can be an i-type or substantially i-type region, and the region 230ba and the region 230bb functioning as the source region and the drain region can be n-type regions. Parasitic capacitance between the conductor 260 and the conductor 242a and parasitic capacitance between the conductor 260 and the conductor 242b can be reduced in a self-aligned manner. Thus, a semiconductor device with favorable electrical characteristics can be provided. The semiconductor device with the above structure can have favorable electrical characteristics even when miniaturized or highly integrated. For example, the semiconductor device can have favorable electrical characteristics even when a gate length is less than or equal to 20 nm, less than or equal to 15 nm, less than or equal to 10 nm, or less than or equal to 7 nm and greater than or equal to 1 nm, greater than or equal to 3 nm, or greater than or equal to 5 nm. Note that the gate length will be described later.

Miniaturization of the transistor 200 can improve the high frequency characteristics. Specifically, the cutoff frequency can be improved. When the gate length is within any of the above ranges, the cutoff frequency of the transistor can be greater than or equal to 50 GHz or greater than or equal to 100 GHz at room temperature, for example.

In the case where aluminum oxide is used for the insulator 252, silicon oxide or silicon oxynitride is used for the insulator 250, and silicon nitride is used for the insulator 254, the insulator 252 and the insulator 250 each include oxygen, and the insulator 250 and the insulator 254 each include silicon. When layers in contact with each other include a common element as a main component, the density of defect states at the interface between the layers can be reduced. Thus, carrier traps or the like due to the defect states are reduced, so that the transistor 200 and the semiconductor device which have favorable characteristics and high reliability can be manufactured.

Furthermore, in the case where titanium nitride or tantalum nitride is used for the conductor 260a, the insulator 254 and the conductor 260a each include nitrogen. With such a structure, the transistor 200 and the semiconductor device which have favorable characteristics and high reliability can be manufactured as described above.

Note that since the oxide 230b includes oxygen as a main component, the density of defect states at the interface between the oxide 230b and the insulator 252 can be reduced. Thus, carrier traps or the like due to the defect states are reduced, so that the transistor 200 and the semiconductor device which have favorable characteristics and high reliability can be manufactured.

In the cross-sectional view in the channel length direction, the bottom surface of the conductor 260a is preferably located between the bottom surface and the top surface of the conductor 242a. With such a structure, the electric field of the conductor 260 is likely to act on the channel formation region of the oxide 230b. Thus, the on-state current of the transistor 200 can be increased, and the frequency characteristics of the transistor 200 can be improved. Note that the bottom surface of the conductor 260a is sometimes located below the bottom surface of the conductor 242a or located above the top surface of the conductor 242a in the cross-sectional view in the channel length direction, depending on the thickness of the gate insulator, the amount of removal of the upper portion of the oxide 230b, or the like.

Here, the above-described gate length is described.

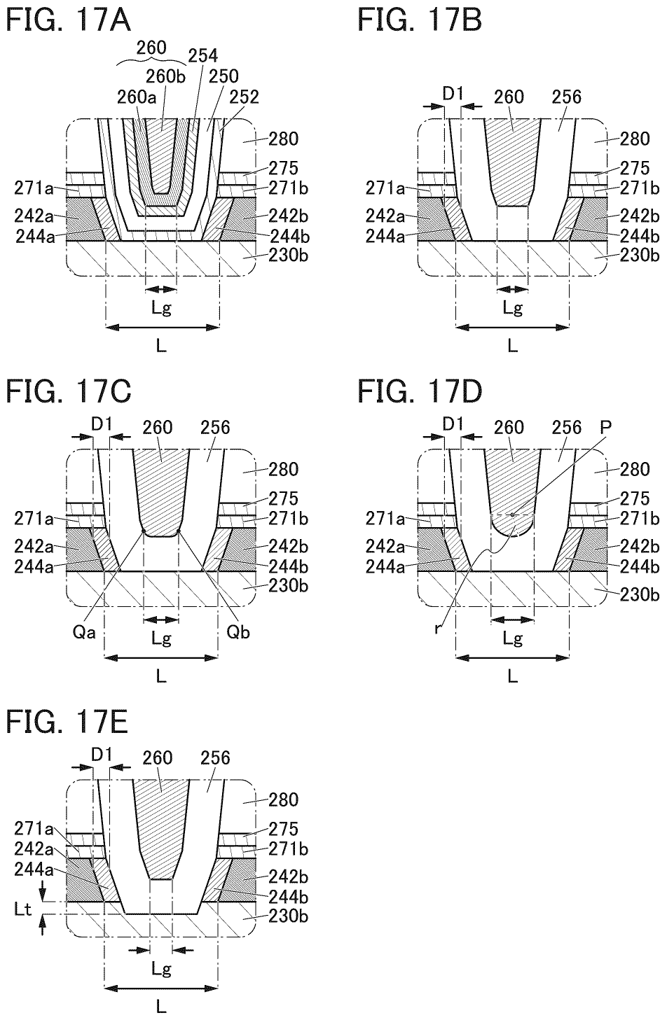

FIG. 17A is an enlarged view of the vicinity of the channel formation region in FIG. 14B. FIG. 17A is a cross-sectional view of the transistor 200 in the channel length direction. As described above, the insulator 252, the insulator 250, and the insulator 254 function as the first gate insulator.

Hereinafter, the insulator 252, the insulator 250, and the insulator 254 are collectively referred to as an insulator 256 in some cases. In this case, the insulator 256 includes the insulator 252, the insulator 250 over the insulator 252, and the insulator 254 over the insulator 250. In addition, the insulator 256 functions as the first gate insulator.

FIG. 17B is a cross-sectional view in which the insulator 252, the insulator 250, and the insulator 254 included in FIG. 17A are replaced with the insulator 256. In FIG. 17B, the conductor 260 is illustrated as a single layer for simplification of the drawing. Note that the conductor 260 may have a stacked-layer structure of the conductor 260a and the conductor 260b as described above or a stacked-layer structure of three or more layers.

A width Lg illustrated in FIG. 17A and FIG. 17B is the width of the bottom surface of the conductor 260 in a region overlapping with the oxide 230b in a cross-sectional view in the channel length direction. Hereinafter, the bottom surface of the conductor 260 in the region overlapping with the oxide 230b in a cross-sectional view in the channel length direction is simply referred to as the bottom surface of the conductor 260 in the region overlapping with the oxide 230b in some cases. That is, the bottom surface of the conductor 260 in the region overlapping with the oxide 230b in the following description can be rephrased as the bottom surface of the conductor 260 in the region overlapping with the oxide 230b in a cross-sectional view in the channel length direction in some cases.

The gate length refers to the length of a gate electrode in a direction in which carriers move inside a channel formation region during operation of the transistor and to the width of the bottom surface of the gate electrode in a top view of the transistor. In this specification and the like, the gate length is the width of the bottom surface of the conductor 260 in the region overlapping with the oxide 230b in a cross-sectional view in the channel length direction. That is, the gate length is the width Lg illustrated in FIG. 17A and FIG. 17B. Note that the conductor 260 is provided in the opening included in the insulator 275 and the insulator 280. The sidewall of the opening is perpendicular to a substrate surface or inclined to the substrate surface. In particular, in the case where the angle formed between the sidewall of the opening and the substrate surface is less than or equal to 90°, the minimum width of the conductor 260 in the region overlapping with the oxide 230b is the width Lg. Thus, the conductor 260 can be regarded as having a region with the width Lg in a cross-sectional view in the channel length direction.

The bottom surface of the conductor 260 in the region overlapping with the oxide 230b preferably includes a flat region. As illustrated in FIG. 17A and FIG. 17B, in the case where the bottom surface of the conductor 260 in the region overlapping with the oxide 230b includes a flat region, the width Lg is the width of the flat region. When the bottom surface of the conductor 260 in the region overlapping with the oxide 230b includes the flat region, an electric field can be uniformly generated in the channel formation region of the oxide 230.

Although FIG. 17A and FIG. 17B each illustrate a structure in which the bottom surface of the conductor 260 in the region overlapping with the oxide 230b includes the flat region, the present invention is not limited thereto. In a cross-sectional view in the channel length direction, the bottom surface of the conductor 260 in the region overlapping with the oxide 230b may have a curve.

FIG. 17C illustrates a modification example of the transistor 200 in FIG. 17B. FIG. 17C is a cross-sectional view of the transistor 200 in the channel length direction. For example, as illustrated in FIG. 17C, the bottom surface of the conductor 260 in the region overlapping with the oxide 230b may include a flat region and a region having a curve. Note that the region having a curve is located at an end portion on each side of the bottom surface. Here, a point where the curve of the bottom surface on the conductor 242a side is in contact with the side surface of the conductor 260 on the conductor 242a side is referred to as a point Qa. A point where the curve of the bottom surface on the conductor 242b side is in contact with the side surface of the conductor 260 on the conductor 242b side is referred to as a point Qb. In this structure, the width Lg is the length of a line segment connecting the point Qa and the point Qb.

FIG. 17D illustrates a modification example of the transistor 200 in FIG. 17B. FIG. 17D is a cross-sectional view of the transistor 200 in the channel length direction. For example, as illustrated in FIG. 17D, the bottom surface of the conductor 260 may have an arc shape. Note that the arc has a radius r and a curvature center P located in the conductor 260. In this structure, the width Lg is the width of a region where a straight line that includes the curvature center P and is parallel to the bottom surface of the oxide 230b overlaps with the conductor 260 in a cross-sectional view in the channel length direction. In other words, the width Lg is twice as long as the radius r. Note that the straight line indicated by a dashed line in FIG. 17D is the straight line that includes the curvature center P and is parallel to the bottom surface of the oxide 230b.

Note that in the case where the radius r is large (e.g., the case where the radius r is larger than the channel length) in the shape of the bottom surface of the conductor 260 illustrated in FIG. 17D, the distance is large from the curvature center P to the channel formation region of the oxide 230b. At this time, the width Lg illustrated in FIG. 17C may be used as the gate length of the shape. That is, the width Lg may be calculated by determining the point Qa and the point Qb in the shape of the bottom surface of the conductor 260 illustrated in FIG. 17D.

It is sometimes difficult to determine the point Qa and the point Qb in the shape of the bottom surface of the conductor 260 illustrated in FIG. 17C. At this time, the width Lg illustrated in FIG. 17D may be used as the gate length of the shape. That is, the width Lg may be calculated by determining the curvature center P in the shape of the bottom surface of the conductor 260 illustrated in FIG. 17C.

The above is the description of the gate length. Next, the channel length is described.

The insulator 244a has lower conductivity than the conductor 242a, and the insulator 244b has lower conductivity than the conductor 242b. Accordingly, in the case where the transistor 200 includes the insulator 244a and the insulator 244b, the distance between a lower end portion of the conductor 242a and a lower end portion of the conductor 242b can be regarded as the channel length as illustrated in FIG. 17A to FIG. 17D. That is, when the insulator 244a and the insulator 244b are formed, the channel length can be increased. Thus, the source-drain breakdown voltage of the transistor 200 can be improved, so that the transistor can be highly reliable. Therefore, the transistor can have favorable electrical characteristics even when miniaturized. Note that the distance between the lower end portion of the conductor 242a and the lower end portion of the conductor 242b is a distance L.

The channel length is set in accordance with a material used for the conductor 260, the gate length, a material used for the first gate insulator, the thickness thereof, and the like. In the case where the gate length is within any of the above ranges, the channel length is less than or equal to 60 nm, less than or equal to 50 nm, less than or equal to 40 nm, or less than or equal to 30 nm and greater than or equal to 5 nm, greater than or equal to 10 nm, greater than or equal to 15 nm, or greater than or equal to 20 nm, for example.

The length D1 of the insulator 244a in the channel length direction is preferably smaller than the width Lg and is preferably within any of the above ranges. With this structure, even when the gate length is within any of the above ranges, the transistor 200 can have favorable electrical characteristics. Note that in the case where the width Lg is significantly small (e.g., the case where the width Lg is less than 5 nm), the length D1 is larger than the width Lg in some cases.

When the opening is formed in the insulator 280 and the insulator 275, an upper portion of the oxide 230b in a region overlapping with the opening is removed in some cases. At this time, as illustrated in FIG. 17E, the thickness of the oxide 230b in a region overlapping with the conductor 260 is smaller than the thickness of the oxide 230b in a region overlapping with the conductor 242a. Note that the transistor 200 illustrated in FIG. 17E is a modification example of the transistor 200 illustrated in FIG. 17B. FIG. 17E is a cross-sectional view of the transistor 200 in the channel length direction.

As illustrated in FIG. 17E, a difference between the thickness of the oxide 230b in the region overlapping with the conductor 260 and the thickness of the oxide 230b in the region overlapping with the conductor 242a is referred to as a difference Lt. When the difference Lt is small, the distance L may be regarded as the channel length.

Accordingly, a semiconductor device having favorable reliability can be provided. A semiconductor device having favorable electrical characteristics can be provided. A semiconductor device that can be miniaturized or highly integrated can be provided. A semiconductor device that has favorable electrical characteristics and can be miniaturized or highly integrated can be provided.

In this embodiment, microwave treatment is performed in an atmosphere containing oxygen in a state where the conductor 242a and the conductor 242b are provided over the oxide 230b so that oxygen vacancies and VoH in the region 230bc can be reduced. Note that the microwave treatment will be described in detail later in <Method for manufacturing semiconductor device>.

At least one of the insulator 212, the insulator 214, the insulator 271, the insulator 275, the insulator 282, the insulator 283, and the insulator 285 preferably functions as a barrier insulating film, which inhibits diffusion of impurities such as water and hydrogen into the transistor 200 from the substrate side or from above the transistor 200. Thus, for at least one of the insulator 212, the insulator 214, the insulator 271, the insulator 275, the insulator 282, the insulator 283, and the insulator 285, it is preferable to use an insulating material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), or a copper atom (an insulating material that is less permeable to the impurities). Alternatively, it is preferable to use an insulating material having a function of inhibiting diffusion of oxygen (e.g., at least one of an oxygen atom, an oxygen molecule, and the like) (an insulating material that is less permeable to the oxygen).

An insulator having a function of inhibiting diffusion of oxygen and impurities such as water and hydrogen is preferably used for the insulator 212, the insulator 214, the insulator 271, the insulator 275, the insulator 282, the insulator 283, and the insulator 285; for example, aluminum oxide, magnesium oxide, hafnium oxide, gallium oxide, indium gallium zinc oxide, silicon nitride, silicon nitride oxide, or the like can be used. For example, silicon nitride or the like, which has a higher hydrogen barrier property, is preferably used for the insulator 212, the insulator 275, and the insulator 283. For example, aluminum oxide, magnesium oxide, or the like, which has a function of capturing and fixing hydrogen well, is preferably used for the insulator 214, the insulator 271, the insulator 282, and the insulator 285. In this case, impurities such as water and hydrogen can be inhibited from diffusing to the transistor 200 side from the substrate side through the insulator 212 and the insulator 214. Alternatively, impurities such as water and hydrogen can be inhibited from diffusing to the transistor 200 side from an interlayer insulating film and the like which are placed outside the insulator 285 through the insulator 283 and the insulator 282. Alternatively, oxygen included in the insulator 224 and the like can be inhibited from diffusing to the substrate side through the insulator 212 and the insulator 214. Alternatively, oxygen included in the insulator 280 and the like can be inhibited from diffusing to above the transistor 200 through the insulator 282 and the like. In this manner, it is preferable that the transistor 200 be surrounded by the insulator 212, the insulator 214, the insulator 271, the insulator 275, the insulator 282, the insulator 283, and the insulator 285, which have a function of inhibiting diffusion of oxygen and impurities such as water and hydrogen. When the transistor 200 is surrounded by the insulator 212, the insulator 214, the insulator 271, the insulator 275, the insulator 282, the insulator 283, and the insulator 285, entry of hydrogen, which is a ubiquitous element, into the transistor 200 can be inhibited. Thus, the transistor can have high reliability.

Here, an oxide having an amorphous structure is preferably used for the insulator 212, the insulator 214, the insulator 271, the insulator 275, the insulator 282, the insulator 283, and the insulator 285. For example, a metal oxide such as AlOₓ (x is a given number greater than 0) or MgO_{y} (y is a given number greater than 0) is preferably used. In such a metal oxide having an amorphous structure, an oxygen atom has a dangling bond and sometimes has a property of capturing or fixing hydrogen with the dangling bond. When such a metal oxide having an amorphous structure is used as a component of the transistor 200 or provided around the transistor 200, hydrogen included in the transistor 200 or hydrogen around the transistor 200 can be captured or fixed. In particular, hydrogen included in the channel formation region of the transistor 200 is preferably captured or fixed. When the metal oxide having an amorphous structure is used as a component of the transistor 200 or provided around the transistor 200, the transistor 200 and the semiconductor device which have favorable characteristics and high reliability can be manufactured.

Although the insulator 212, the insulator 214, the insulator 271, the insulator 275, the insulator 282, the insulator 283, and the insulator 285 preferably have an amorphous structure, a region having a polycrystalline structure may be partly formed. The insulator 212, the insulator 214, the insulator 271, the insulator 275, the insulator 282, the insulator 283, and the insulator 285 may have a multilayer structure in which a layer having an amorphous structure and a layer having a polycrystalline structure are stacked. For example, a stacked-layer structure in which a layer having a polycrystalline structure is formed over a layer having an amorphous structure may be employed.

The insulator 212, the insulator 214, the insulator 271, the insulator 275, the insulator 282, the insulator 283, and the insulator 285 are formed by a sputtering method, for example. Since a sputtering method does not need to use a molecule containing hydrogen as a film formation gas, the hydrogen concentrations in the insulator 212, the insulator 214, the insulator 271, the insulator 275, the insulator 282, the insulator 283, and the insulator 285 can be reduced. Note that the film formation method is not limited to a sputtering method, and a CVD method, an MBE method, a PLD method, an ALD method, or the like may be used as appropriate.

The resistivity of each of the insulator 212, the insulator 275, and the insulator 283 is preferably low in some cases. For example, by setting the resistivity of each of the insulator 212, the insulator 275, and the insulator 283 to approximately 1×10¹³ Ωcm, the insulator 212, the insulator 275, and the insulator 283 can sometimes reduce charge up of the conductor 205, the conductor 242, the conductor 260, the conductor 246a, or the conductor 246b in treatment using plasma or the like in the manufacturing process of the semiconductor device. The resistivity of each of the insulator 212, the insulator 275, and the insulator 283 is preferably higher than or equal to 1×10¹⁰ Ωcm and lower than or equal to 1×10¹⁵ Ωcm.

The insulator 216, the insulator 274, the insulator 280, and the insulator 285 each preferably have a lower permittivity than the insulator 214. When a material with a low permittivity is used for an interlayer film, parasitic capacitance generated between wirings can be reduced. For the insulator 216, the insulator 274, the insulator 280, and the insulator 285, silicon oxide, silicon oxynitride, silicon oxide to which fluorine is added, silicon oxide to which carbon is added, silicon oxide to which carbon and nitrogen are added, porous silicon oxide, or the like is used as appropriate, for example.

Note that the insulator 212 and the insulator 216 respectively correspond to the insulator 12 and the insulator 16 described in Embodiment 1. Thus, the description of the insulator 12 and the insulator 16 in Embodiment 1 can be referred to for the materials, the structures, and the like used for the insulator 212 and the insulator 216. The description of the insulator 212 and the insulator 216 in this embodiment can also be referred to for the materials, the structures, and the like used for the insulator 12 and the insulator 16 described in Embodiment 1.

The conductor 205 is placed to overlap with the oxide 230 and the conductor 260. Here, the conductor 205 is preferably provided to be embedded in an opening formed in the insulator 216. Part of the conductor 205 is embedded in the insulator 214 in some cases.

The conductor 205 includes the conductor 205a and the conductor 205b. The conductor 205a is provided in contact with the bottom surface and the sidewall of the above opening. The conductor 205b is provided to be embedded in a depressed portion formed in the conductor 205a. Here, the top surface of the conductor 205b is level or substantially level with the top surface of the conductor 205a and the top surface of the insulator 216.

Here, for the conductor 205a, it is preferable to use a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), and a copper atom. Alternatively, it is preferable to use a conductive material having a function of inhibiting diffusion of oxygen (e.g., at least one of an oxygen atom, an oxygen molecule, and the like).

When a conductive material having a function of inhibiting diffusion of hydrogen is used for the conductor 205a, impurities such as hydrogen included in the conductor 205b can be prevented from diffusing into the oxide 230 through the insulator 216, the insulator 224, and the like. When a conductive material having a function of inhibiting diffusion of oxygen is used for the conductor 205a, the conductivity of the conductor 205b can be inhibited from being lowered because of oxidation. Examples of the conductive material having a function of inhibiting diffusion of oxygen include titanium, titanium nitride, tantalum, tantalum nitride, ruthenium, and ruthenium oxide. Thus, a single layer or a stacked layer of the above conductive material is preferably used for the conductor 205a. For example, titanium nitride is used for the conductor 205a.

A conductive material containing tungsten, copper, or aluminum as its main component is preferably used for the conductor 205b. For example, tungsten is used for the conductor 205b.

The conductor 205 sometimes functions as the second gate electrode. In that case, by changing the potential applied to the conductor 205 not in conjunction with but independently of the potential applied to the conductor 260, the threshold voltage (Vth) of the transistor 200 can be controlled. In other words, Vth of the transistor 200 can be shifted and adjusted to a desired value. In particular, by applying a negative potential to the conductor 205, Vth of the transistor 200 can be higher, and its off-state current can be reduced. Thus, a drain current at the time when a potential applied to the conductor 260 is 0 V can be lower in the case where a negative potential is applied to the conductor 205 than in the case where the negative potential is not applied to the conductor 205.

As illustrated in FIG. 14A, the conductor 205 is preferably provided to be larger than a region of the oxide 230 that does not overlap with the conductor 242a or the conductor 242b. As illustrated in FIG. 14C, it is particularly preferable that the conductor 205 extend to a region outside an end portion of the oxide 230 in the channel width direction. That is, the conductor 205 and the conductor 260 preferably overlap with each other with the insulators therebetween on the outer side of the side surface of the oxide 230 in the channel width direction. With this structure, the channel formation region of the oxide 230 can be electrically surrounded by the electric field of the conductor 260 functioning as the first gate electrode and the electric field of the conductor 205 functioning as the second gate electrode.

In this specification and the like, a transistor structure in which a channel formation region is electrically surrounded by at least the electric field of a first gate electrode is referred to as a surrounded channel (S-channel) structure. The S-channel structure disclosed in this specification and the like has a structure different from a Fin-type structure and a planar structure. Meanwhile, the S-channel structure disclosed in this specification and the like can also be regarded as a kind of the Fin-type structure. In this specification and the like, the Fin-type structure refers to a structure where at least two surfaces (specifically, two surfaces, three surfaces, four surfaces, or the like) of a channel are covered with a gate electrode. With the Fin-type structure and the S-channel structure, resistance to a short-channel effect can be enhanced; that is, a transistor in which a short-channel effect is less likely to occur can be provided.

When the transistor 200 has the above-described S-channel structure, the channel formation region can be electrically surrounded. Since the S-channel structure is a structure with the electrically surrounded channel formation region, the S-channel structure can be regarded as being substantially equivalent to the GAA structure or a LGAA (Lateral Gate All Around) structure. When the transistor 200 has the S-channel structure, the GAA structure, or the LGAA structure, the channel formation region that is formed at the interface between the oxide 230 and the gate insulator or in the vicinity of the interface can be formed in the entire bulk of the oxide 230. Accordingly, the density of current flowing in the transistor can be improved, which can be expected to improve the on-state current of the transistor or increase the field-effect mobility of the transistor.

Although FIG. 14B illustrates a transistor with the S-channel structure as the transistor 200, the semiconductor device of one embodiment of the present invention is not limited thereto. For example, a transistor structure that can be used in one embodiment of the present invention may be one or more selected from the planar structure, the Fin-type structure, and the GAA structure.

Furthermore, as illustrated in FIG. 14C, the conductor 205 is extended to function as a wiring as well. However, without limitation to this structure, a structure in which a conductor functioning as a wiring is provided below the conductor 205 may be employed. In addition, the conductor 205 is not necessarily provided in each transistor. For example, the conductor 205 may be shared by a plurality of transistors.

Although the transistor 200 having a structure in which the conductor 205 is a stack of the conductor 205a and the conductor 205b is described, the present invention is not limited thereto. For example, the conductor 205 may be provided to have a single-layer structure or a stacked-layer structure of three or more layers.

Note that the conductor 205 corresponds to the conductor 25 described in Embodiment 1. Thus, the description of the conductor 25 in Embodiment 1 can be referred to for the material, the structure, and the like used for the conductor 205. The description of the conductor 205 in this embodiment can also be referred to for the material, the structure, and the like used for the conductor 25 described in Embodiment 1.

It is preferable that the insulator 222 have a function of inhibiting diffusion of hydrogen (e.g., at least one of a hydrogen atom, a hydrogen molecule, and the like). In addition, it is preferable that the insulator 222 have a function of inhibiting diffusion of oxygen (e.g., at least one of an oxygen atom, an oxygen molecule, and the like). For example, the insulator 222 preferably has a function of inhibiting diffusion of one or both of hydrogen and oxygen more than the insulator 224.

Silicon oxide or silicon oxynitride, for example, is used as appropriate for the insulator 224 that is in contact with the oxide 230.

Note that one or both of the insulator 222 and the insulator 224 may have a stacked-layer structure of two or more layers. In that case, without limitation to a stacked-layer structure formed of the same material, a stacked-layer structure formed of different materials may be employed. The insulator 224 may be formed into an island shape so as to overlap with the oxide 230a. In this case, the insulator 275 is in contact with the side surface of the insulator 224 and the top surface of the insulator 222.

Note that the insulator 222 and the insulator 224 respectively correspond to the insulator 20a and the insulator 20b described in Embodiment 1. Thus, the description of the insulator 20a and the insulator 20b in Embodiment 1 can be referred to for the materials, the structures, and the like used for the insulator 222 and the insulator 224. The description of the insulator 222 and the insulator 224 in this embodiment can also be referred to for the materials, the structures, and the like used for the insulator 20a and the insulator 20b described in Embodiment 1.

Examples of the oxide 230 include indium oxide, gallium oxide, and zinc oxide. The metal oxide preferably contains two or three selected from indium, the element M, and zinc. The element M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium. In particular, the element M is preferably one or more selected from aluminum, gallium, yttrium, and tin. Note that a metal oxide containing indium, the element M, and zinc is referred to as an In-M-Zn oxide in some cases.

The oxide 230 preferably has a stacked-layer structure of a plurality of oxide layers with different chemical compositions. For example, the atomic ratio of the element M to a metal element that is a main component in the metal oxide used as the oxide 230a is preferably higher than the atomic ratio of the element M to a metal element that is a main component in the metal oxide used as the oxide 230b. Moreover, the atomic ratio of the element M to In in the metal oxide used as the oxide 230a is preferably higher than the atomic ratio of the element M to In in the metal oxide used as the oxide 230b. With this structure, impurities and oxygen can be inhibited from diffusing into the oxide 230b from the components formed below the oxide 230a. In this case, the oxide 230a can be regarded as a buffer layer provided between the oxide 230b and the insulator 224.

Furthermore, the atomic ratio of In to the element M in the metal oxide used as the oxide 230b is preferably higher than the atomic ratio of In to the element M in the metal oxide used as the oxide 230a. With this structure, the transistor 200 can have a high on-state current and high frequency characteristics.

When the oxide 230a and the oxide 230b include a common element as the main component besides oxygen, the density of defect states at the interface between the oxide 230a and the oxide 230b can be reduced. Thus, the influence of interface scattering on carrier conduction is small, and the transistor 200 can have a high on-state current and high frequency characteristics.

The electron affinity of the oxide 230a is preferably lower than the electron affinity of the oxide 230b. Here, the value obtained by subtracting the electron affinity of the oxide 230b from the electron affinity of the oxide 230a is ΔEc. ΔEc is preferably greater than 0 eV, further preferably greater than or equal to 0.2 eV, for example. Although there is no particular limitation on the upper limit of ΔEc, ΔEc is lower than or equal to 1.5 eV, lower than or equal to 1.0 eV, or lower than or equal to 0.5 eV when the oxide 230a and the oxide 230b include a common element as the main component besides oxygen.

In the case where the oxide 230a and the oxide 230b form a heterojunction, electrons easily move to the oxide that has higher electron affinity. That is, with the above structure, electrons serving as carriers can be efficiently transferred to the oxide 230b. Thus, the carrier control of the oxide 230 by the electric field of the conductor 260 is performed on the oxide 230b, and the controllability of the top gate electrode can be increased. In that case, the interface at which an electron trap is easily formed can be limited only to a top gate insulator side, so that the influence of the electron trap during circuit operation can be small.

Specifically, as the oxide 230a, a metal oxide with a composition of In:M:Zn=1:3:4 [atomic ratio] or in the neighborhood thereof, a composition of In:M:Zn=1:3:2 [atomic ratio] or in the neighborhood thereof, or a composition of In:M:Zn=1:1:0.5 [atomic ratio] or in the neighborhood thereof is used. As the oxide 230b, a metal oxide with a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, a composition of In:M:Zn=4:2:3 [atomic ratio] or in the neighborhood thereof, or a composition of In:M:Zn=5:1:3 [atomic ratio] or in the neighborhood thereof is used. Note that a composition in the neighborhood includes the range of +30% of an intended atomic ratio. Gallium or aluminum is preferably used as the element M.

When a film of the metal oxide is formed by a sputtering method, the above atomic ratio is not limited to the atomic ratio of the formed film of the metal oxide and may be the atomic ratio of a sputtering target used for forming the film of the metal oxide.

In the case where the transistor 200 is used in, for example, a pixel circuit of a display device, part of light (stray light) emitted by a light-emitting element in the display device might enter the transistor 200. In that case, the stray light sometimes causes a degradation in transistor characteristics and adversely affects pixel operation.

Note that the amount of stray-light-induced degradation of transistor characteristics can be evaluated using the amount of change in the threshold voltage or the amount of change in the shift voltage (Vsh) of the transistor measured in an NBTIS (Negative Bias Temperature Illumination Stress) test of the transistor, for example. Note that the shift voltage (Vsh) is defined as Vg at which, in a drain current (Id)-gate voltage (Vg) curve of a transistor, the tangent at a point where the slope of the curve is the steepest intersects the straight line of Id=1 pA. Here, the degradation of change in the threshold voltage or degradation of change in Vsh of the transistor in the NBTIS test is referred to as negative-bias photodegradation in some cases.

Accordingly, in the case where the transistor 200 is used in, for example, a pixel circuit of a display device, it is preferable to reduce the influence of stray light on the transistor 200. For example, it is preferable to reduce the stray-light-induced degradation of transistor characteristics for the transistor 200. Specifically, the transistor 200 preferably has high resistance to the NBTIS test (negative-bias photodegradation in the transistor 200 is preferably reduced).

Thus, in the case where the transistor 200 is used for the pixel circuit of the display device, for example, the metal oxide functioning as a semiconductor of the transistor 200 preferably has a band gap wider than or equal to 3.1 eV, further preferably wider than or equal to 3.3 eV. The energy of light having a wavelength greater than or equal to 400 nm is less than or equal to 3.1 eV. That is, even when light having a wavelength greater than or equal to 400 nm enters the metal oxide, electrons in the valence band are less likely to be excited into the conduction band. Thus, when a metal oxide having a wider band gap is used in the channel formation region of the transistor, the resistance to the NBTIS test can be increased. That is, with use of a metal oxide having a wider band gap in the channel formation region of the transistor, the influence of stray light can be reduced even when a light-blocking layer or the like is not provided, so that degradation of the transistor characteristics can be inhibited.

Specifically, as the oxide 230, a metal oxide with a composition of In:M:Zn=2:6:5 [atomic ratio] or in the neighborhood thereof, a metal oxide with a composition of In:M:Zn=1:3:4 [atomic ratio] or in the neighborhood thereof, a metal oxide with a composition of In:M:Zn=1:1:1 [atomic ratio] or in the neighborhood thereof, or a metal oxide with a composition of In:M:Zn=1:4:5 [atomic ratio] or in the neighborhood thereof is used.

For example, when the atomic ratio is described as In:M:Zn=2:6:5 or a composition in the neighborhood thereof, the case is included where M is greater than or equal to 4 and less than or equal to 8 and Zn is greater than or equal to 3 and less than or equal to 7.5 with In being 2. When the atomic ratio is described as In:M:Zn=1:1:1 or a composition in the neighborhood thereof, the case is included where M is greater than 0.1 and less than or equal to 2 and Zn is greater than 0.1 and less than or equal to 2 with In being 1.

The oxide 230b preferably has crystallinity. It is particularly preferable to use a CAAC-OS as the oxide 230b.

When an oxide having crystallinity, such as CAAC-OS, is used as the oxide 230b, oxygen extraction from the oxide 230b by the conductor 242a or the conductor 242b can be inhibited. This can reduce oxygen extraction from the oxide 230b even when heat treatment is performed; thus, the transistor 200 is stable with respect to high temperatures in the manufacturing process (what is called thermal budget). Furthermore, it is possible to inhibit a reduction in the conductivity of the conductor 242a and the conductor 242b.

When the oxide 230a and the oxide 230b include a common element as the main component besides oxygen, the oxide 230b can have high crystallinity. As a result, the transistor 200 is stable with respect to high temperatures in the manufacturing process as described above.

As illustrated in FIG. 14C, a curved surface may be provided between the side surface of the oxide 230b and the top surface of the oxide 230b in a cross-sectional view of the transistor 200 in the channel width direction. That is, an end portion of the side surface and an end portion of the top surface may be curved (hereinafter also referred to as rounded).

The radius of curvature of the curved surface is preferably greater than 0 nm and less than the thickness of the oxide 230b in a region overlapping with the conductor 242, or less than half of the length of a region that does not have the curved surface. Specifically, the radius of curvature of the curved surface is greater than 0 nm and less than or equal to 20 nm, preferably greater than or equal to 1 nm and less than or equal to 15 nm, further preferably greater than or equal to 2 nm and less than or equal to 10 nm. Such a shape can improve the coverage of the oxide 230b with the insulator 252, the insulator 250, the insulator 254, and the conductor 260.

When aluminum oxide is used as the insulator 252, aluminum is added to a region of the oxide 230b in contact with the insulator 252 and to the vicinity thereof in some cases. Note that addition of aluminum to the region of the oxide 230b in contact with the insulator 252 and to the vicinity thereof is caused by a step of the formation of an insulating film to be the insulator 252 or a later step, such as the formation of the insulating film, the formation of a film over the insulating film, or heat treatment in or after the formation of the insulating film.

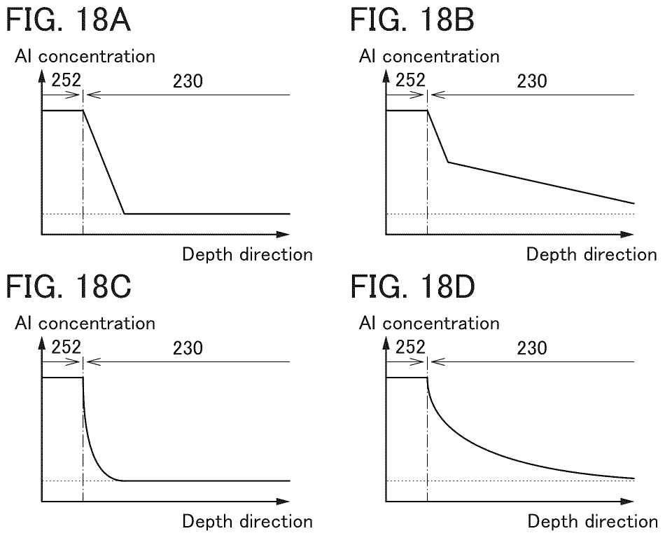

FIG. 18A to FIG. 18D schematically show aluminum concentration profiles in depth direction in the insulator 252 and the oxide 230. In FIG. 18A to FIG. 18D, the vertical axis represents the aluminum (Al) concentration and the horizontal axis represents the depth. Note that the depth can be rephrased as a film thickness.

Note that in the case where a metal oxide not containing aluminum is used as the oxide 230 before addition of aluminum, dotted lines shown in FIG. 18A to FIG. 18D represent the lower detection limit of the aluminum concentration. In the case where a metal oxide containing aluminum is used as the oxide 230 before addition of aluminum, the dotted lines shown in FIG. 18A to FIG. 18D represent the aluminum concentration of the oxide 230 in the vicinity of the insulator 224.

As shown in FIG. 18A to FIG. 18D, the oxide 230 has a concentration gradient in which the aluminum concentration increases from the bottom surface of the oxide 230 to the top surface of the oxide 230. In other words, the oxide 230 has a concentration gradient in which the aluminum concentration increases toward the insulator 252 in the film thickness direction.

In some cases, as shown in FIG. 18A, the oxide 230 includes a region in which the aluminum concentration decreases monotonously from the peak at the interface between the insulator 252 and the oxide 230 and a region in which the aluminum concentration is constant. In that case, the region in which the aluminum concentration decreases monotonously is located close to the insulator 252, compared with the region in which the aluminum concentration is constant.

As shown in FIG. 18B, the oxide 230 includes a first region in which the aluminum concentration decreases monotonously from the peak at the interface between the insulator 252 and the oxide 230 and a second region in which the aluminum concentration decreases monotonously, in some cases. In that case, the first region is located close to the insulator 252, compared with the second region.

As shown in FIG. 18C, the oxide 230 includes a region in which the aluminum concentration decreases exponentially from the peak at the interface between the insulator 252 and the oxide 230 and a region in which the aluminum concentration is constant, in some cases. In that case, the region in which the aluminum concentration decreases exponentially is located close to the insulator 252, compared with the region in which the aluminum concentration is constant.

As shown in FIG. 18D, the aluminum concentration of the oxide 230 decreases exponentially from the peak at the interface between the insulator 252 and the oxide 230 in some cases.

The addition of aluminum to the region of the oxide 230b in contact with the insulator 252 and to the vicinity thereof can inhibit the formation of oxygen vacancies in the region and in the vicinity thereof. Since a channel is easily formed in the region of the oxide 230b and the vicinity thereof, oxygen vacancies in the channel formation region can be reduced with this structure. Accordingly, a change in the electrical characteristics of the transistor 200 can be inhibited, and thus a variation in the electrical characteristics of the transistors 200 in the substrate plane can be inhibited. In the case where an In-M-Zn oxide is used as the oxide 230b before addition of aluminum, the oxide 230b includes at least indium (In), aluminum (Al), and zinc (Zn). Furthermore, the oxide 230b includes indium (In), the element M, aluminum (Al), and zinc (Zn).

The insulator 252 including aluminum oxide or the like is provided in contact with the top surface and the side surface of the oxide 230, whereby indium included in the oxide 230 is unevenly distributed, in some cases, at the interface between the oxide 230 and the insulator 252 and in its vicinity. Accordingly, the vicinity of the surface of the oxide 230 has an atomic ratio close to that of indium oxide or that of In—Zn oxide. Such an increase in the atomic ratio of indium in the vicinity of the surface of the oxide 230, especially the oxide 230b, can increase the field-effect mobility of the transistor 200.

Although a structure in which two layers, the oxide 230a and the oxide 230b, are stacked as the oxide 230 in the transistor 200 is described, the present invention is not limited thereto. For example, the oxide 230 may be provided as a single layer of the oxide 230a, a single layer of the oxide 230b, or a stacked-layer structure of three or more layers, or the oxide 230a and the oxide 230b may each have a stacked-layer structure.

For example, in the case where a layer having a function of inhibiting diffusion of impurities and oxygen into the oxide 230b is provided between the insulator 224 and the oxide 230, the oxide 230 may be a single layer of the oxide 230b. In other words, in the case where this layer is provided, the oxide 230a is not necessarily provided. Alternatively, the thickness of the oxide 230a may be small. For this layer, an insulator that can be used as the insulator 252 can be used.

Note that the oxide 230a and the oxide 230b respectively correspond to the semiconductor layer 30a and the semiconductor layer 30b described in Embodiment 1. Thus, the description of the semiconductor layer 30a and the semiconductor layer 30b in Embodiment 1 can be referred to for the materials, the structures, and the like used for the oxide 230a and the oxide 230b. The description of the oxide 230a and the oxide 230b in this embodiment can also be referred to for the materials, the structures, and the like used for the semiconductor layer 30a and the semiconductor layer 30b described in Embodiment 1.

The metal oxide functioning as a semiconductor and described in Embodiment 1 may be used as the oxide 230. Alternatively, the metal oxide described in Embodiment 2 may be used as the oxide 230. The transistor 200 in which the metal oxide described in Embodiment 2 is used as the oxide 230 can have normally-off characteristics. Accordingly, a semiconductor device that has favorable electrical characteristics and high reliability can be provided.

The conductor 242a and the conductor 242b are provided in contact with the top surface of the oxide 230b.

No curved surface is preferably formed between the side surface of the conductor 242 and the top surface of the conductor 242. When no curved surface is formed in the conductor 242, the conductor 242 can have a large cross-sectional area in the channel width direction as illustrated in FIG. 14D. Accordingly, the contact resistance between the conductor 242 and the conductor 240 can be reduced, so that the on-state current of the transistor 200 can be increased.

When heat treatment is performed in the state where the conductor 242a and the oxide 230b are in contact with each other, the sheet resistance of the oxide 230b in the region overlapping with the conductor 242a decreases in some cases. Furthermore, the carrier concentration sometimes increases. Thus, the resistance of the oxide 230b in the region overlapping with the conductor 242a can be lowered in a self-aligned manner. Similarly, when heat treatment is performed in the state where the conductor 242b and the oxide 230b are in contact with each other, the sheet resistance of the oxide 230b in a region overlapping with the conductor 242b decreases in some cases. Furthermore, the carrier concentration sometimes increases. Thus, the resistance of the oxide 230b in the region overlapping with the conductor 242b can be lowered in a self-aligned manner.

The conductor 242a and the conductor 242b are preferably formed using a conductive film having compressive stress. This can form distortion extended in the tensile direction (hereinafter, such distortion is sometimes referred to as tensile distortion) in the region 230ba and the region 230bb. When VoH is stably formed by the tensile distortion, the region 230ba and the region 230bb can be stable n-type regions. Note that the compressive stress of the conductor 242a refers to stress for relaxing the compressive shape of the conductor 242a that has a vector in a direction from a center portion to an end portion of the conductor 242a. The same applies to the compressive stress of the conductor 242b.

The level of the compressive stress of the conductor 242a is, for example, higher than or equal to 500 MPa, preferably higher than or equal to 1000 MPa, further preferably higher than or equal to 1500 MPa, still further preferably higher than or equal to 2000 MPa. Note that the level of the stress of the conductor 242a may be determined from the measured stress of a sample fabricated by forming a conductive film to be used for the conductor 242a on a substrate. The same applies to the level of the compressive stress of the conductor 242b.

Due to the action of the compressive stress in the conductor 242a and the conductor 242b, distortion is formed in each of the region 230ba and the region 230bb. The distortion is distortion (tensile distortion) extended in the tensile direction by the action of the compressive stress in the conductor 242a and the conductor 242b. In the case where the region 230ba and the region 230bb have a CAAC structure, the distortion corresponds to extension in the direction perpendicular to the c-axis of the CAAC structure. When the CAAC structure is extended in the direction perpendicular to the c-axis of the CAAC structure, oxygen vacancies are likely to be formed in the distortion. Furthermore, hydrogen is likely to be taken in the distortion, so that VoH is likely to be formed. Thus, oxygen vacancies and VoH are likely to be formed in the distortion and likely to have a stable structure. Thus, the region 230ba and the region 230bb can be stable n-type regions with high carrier concentrations.

Note that although the distortion formed in the oxide 230b is described above, the present invention is not limited thereto. In some cases, a similar distortion is formed in the oxide 230a.

In one embodiment of the present invention, a nitride containing tantalum or a nitride containing titanium is particularly preferably used for the conductor 242a and the conductor 242b. In this case, the conductor 242a and the conductor 242b include tantalum or titanium and nitrogen.

In particular, when a nitride containing tantalum is used for the conductor 242a and the conductor 242b, the sheet resistance of the oxide 230b in the region overlapping with the conductor 242a or the conductor 242b can be lowered as long as the thickness of each of the conductor 242a and the conductor 242b is larger than or equal to a certain thickness. In addition, the carrier concentration can be increased. Specifically, when the thickness of each of the conductor 242a and the conductor 242b is greater than or equal to 1 nm, preferably greater than or equal to 5 nm, further preferably greater than or equal to 10 nm, the sheet resistance of the oxide 230b in the region overlapping with the conductor 242a or the conductor 242b can be lowered. In addition, the carrier concentration can be increased. Although there is no particular limitation on the upper limit on the thickness of each of the conductor 242a and the conductor 242b, for miniaturization or high integration of the semiconductor device, increased productivity of the semiconductor device, and the like, the thickness of each of the conductor 242a and the conductor 242b is preferably less than or equal to 50 nm, less than or equal to 40 nm, or less than or equal to 30 nm.

With the above structure, the resistance of the oxide 230b in the region overlapping with the conductor 242a can be lowered in a self-aligned manner. Similarly, the resistance of the oxide 230b in the region overlapping with the conductor 242b can be lowered in a self-aligned manner.

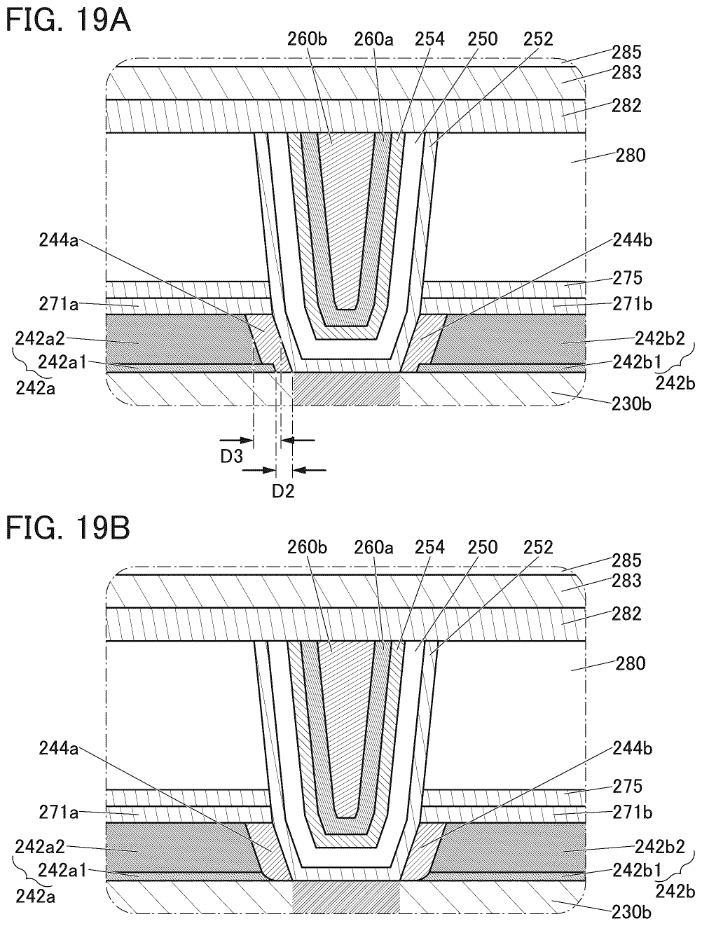

Although FIG. 14A to FIG. 14D and the like illustrate a single-layer structure of the conductor 242, the present invention is not limited to this structure, and a stacked-layer structure of two or more layers may be employed. For example, as illustrated in FIG. 19A, the conductor 242a may have a stacked-layer structure of two layers of a conductor 242a1 and a conductor 242a2 over the conductor 242a1, and the conductor 242b may have a stacked-layer structure of two layers of a conductor 242b1 and a conductor 242b2 over the conductor 242b1. In that case, the conductor 242a1 and the conductor 242b1 are placed on the side in contact with the oxide 230b.

Hereinafter, the conductor 242a1 and the conductor 242b1 are collectively referred to as a lower layer of the conductor 242 in some cases. The conductor 242a2 and the conductor 242b2 are collectively referred to as an upper layer of the conductor 242 in some cases.

The lower layer (the conductor 242a1 and the conductor 242b1) of the conductor 242 is preferably formed using a conductive material having a property of being less likely to be oxidized. This can inhibit the oxidation of the lower layer of the conductor 242 and a reduction in the conductivity of the conductor 242. Note that the lower layer of the conductor 242 may have a property of being likely to absorb (extract) hydrogen. Accordingly, hydrogen in the oxide 230 is diffused into the lower layer of the conductor 242, so that the hydrogen concentration of the oxide 230 can be reduced. Thus, the transistor 200 can have stable electrical characteristics.

The upper layer of the conductor 242 (the conductor 242a2 and the conductor 242b2) is preferably formed using a conductive material having higher conductivity than the lower layer of the conductor 242 (the conductor 242a1 and the conductor 242b1). In this case, at least part of the upper layer of the conductor 242 includes a region having higher conductivity than the lower layer of the conductor 242. Alternatively, the upper layer of the conductor 242 is preferably formed using a conductive material having lower resistivity than the lower layer of the conductor 242. Accordingly, a semiconductor device with reduced wiring delay can be manufactured.

Note that the upper layer of the conductor 242 may have a property of being likely to absorb hydrogen. Accordingly, hydrogen absorbed by the lower layer of the conductor 242 is also diffused into the upper layer of the conductor 242, so that the hydrogen concentration in the oxide 230 can be further reduced. Thus, the transistor 200 can have stable electrical characteristics.

Here, for the lower layer of the conductor 242 and the upper layer of the conductor 242, conductive materials containing the same constituent elements and having different chemical compositions are preferably used. In this case, the lower layer of the conductor 242 and the upper layer of the conductor 242 can be formed successively without being exposed to an atmospheric environment. By the formation without exposure to the atmosphere, impurities or moisture from the atmospheric environment can be prevented from being attached onto the surface of the lower layer of the conductor 242, so that the vicinity of the interface between the lower layer of the conductor 242 and the upper layer of the conductor 242 can be kept clean.

In addition, a nitride containing tantalum with a high atomic ratio of nitrogen to tantalum is preferably used for the lower layer of the conductor 242, and a nitride containing tantalum with a low atomic ratio of nitrogen to tantalum is preferably used for the upper layer of the conductor 242. For example, a nitride containing tantalum with an atomic ratio of nitrogen to tantalum being greater than or equal to 1.0 and less than or equal to 2.0, preferably greater than or equal to 1.1 and less than or equal to 1.8, further preferably greater than or equal to 1.2 and less than or equal to 1.5 is used for the lower layer of the conductor 242. In addition, for example, a nitride containing tantalum with an atomic ratio of nitrogen to tantalum being greater than or equal to 0.3 and less than or equal to 1.5, preferably greater than or equal to 0.5 and less than or equal to 1.3, further preferably greater than or equal to 0.6 and less than or equal to 1.0 is used for the upper layer of the conductor 242.

The high atomic ratio of nitrogen to tantalum in a nitride containing tantalum can inhibit oxidation of the nitride containing tantalum. In addition, the oxidation resistance of the nitride containing tantalum can be improved. Moreover, the diffusion of oxygen into the nitride containing tantalum can be inhibited. Hence, the nitride containing tantalum with a high atomic ratio of nitrogen to tantalum is preferably used for the lower layer of the conductor 242. It is thus possible to prevent an oxide layer from being formed between the lower layer of the conductor 242 and the oxide 230 or reduce the thickness of the oxide layer.

The low atomic ratio of nitrogen to tantalum in a nitride containing tantalum can reduce the resistivity of the nitride. Hence, the nitride containing tantalum with a low atomic ratio of nitrogen to tantalum is preferably used for the upper layer of the conductor 242. Accordingly, a semiconductor device with reduced wiring delay can be manufactured.

When the lower layer of the conductor 242 is formed using a conductive material having a property of being less likely to be oxidized and the upper layer of the conductor 242 is formed using a conductive material having higher conductivity than the lower layer of the conductor 242, the insulator 244a and the insulator 244b each include regions having different lengths in the channel length direction as illustrated in FIG. 19A. Here, a distance from the lower layer of the conductor 242 to the insulator 252 is referred to as a length D2, and a distance from the upper layer of the conductor 242 to the insulator 252 is referred to as a length D3. In this case, it can be said that the insulator 244a and the insulator 244b each include a first region whose length in the channel length direction is the length D2 and a second region whose length in the channel length direction is the length D3 over the first region. With this structure, parasitic capacitance between the conductor 242a and the conductor 260 and parasitic capacitance between the conductor 242b and the conductor 260 can be reduced, and an increase in the channel length can be inhibited. Thus, the switching speed of the transistor 200 can be improved, and the transistor can have high frequency characteristics. In addition, a decrease in the on-state current or field-effect mobility of the transistor 200 can be inhibited.

Although FIG. 19A illustrates the structure in which the lengths of the insulator 244a and the insulator 244b in the channel length direction are discontinuous at the boundary between the upper layer of the conductor 242 and the lower layer of the conductor 242, the lengths of the insulator 244a and the insulator 244b in the channel length direction may be continuously changed at the boundary between the upper layer of the conductor 242 and the lower layer of the conductor 242 as illustrated in FIG. 19B. In this case, the side surface of the insulator 244a in contact with the conductor 242a has a curve in a cross-sectional view. Similarly, the side surface of the insulator 244b in contact with the conductor 242b has a curve in a cross-sectional view. Also with this structure, parasitic capacitance between the conductor 242a and the conductor 260 and parasitic capacitance between the conductor 242b and the conductor 260 can be reduced, and an increase in the channel length can be inhibited.

Note that even when the conductor 242a is a single layer, the side surface of the insulator 244a in contact with the conductor 242a has a curve in some cases. Similarly, even when the conductor 242b is a single layer, the side surface of the insulator 244b in contact with the conductor 242b has a curve in some cases.

Note that the boundary between the upper layer and the lower layer of the conductor 242 is difficult to detect clearly in some cases. In the case where a nitride containing tantalum is used for the conductor 242, the tantalum concentration and the nitrogen concentration detected in each layer may gradually change within each layer or may change continuously (or in a gradation manner) in a region between the upper layer and the lower layer. That is, the atomic ratio of nitrogen to tantalum is higher in the region of the conductor 242 that is closer to the oxide 230. Thus, the atomic ratio of nitrogen to tantalum in a lower region of the conductor 242 is preferably higher than the atomic ratio of nitrogen to tantalum in an upper region of the conductor 242.

The thickness of the lower layer of the conductor 242 is greater than or equal to 0.1 nm and less than or equal to 5.0 nm, preferably greater than or equal to 0.5 nm and less than or equal to 3.0 nm, further preferably greater than or equal to 1.0 nm and less than or equal to 3.0 nm. In this case, at least part of the lower layer of the conductor 242 includes a region having a thickness like the above-described thickness. The thickness of the lower layer of the conductor 242 is preferably smaller than the thickness of the upper layer of the conductor 242. In this case, at least part of the lower layer of the conductor 242 includes a region having a thickness smaller than that of the upper layer of the conductor 242.

In the example described above, conductive materials containing the same constituent elements and having different chemical compositions are used for the lower layer of the conductor 242 and the upper layer of the conductor 242; however, the present invention is not limited thereto, and the lower layer of the conductor 242 and the upper layer of the conductor 242 may be formed using different conductive materials.

Note that the structures of the lower layer of the conductor 242 and the upper layer of the conductor 242 are not limited to the above. For example, one or more selected from the constituent elements, chemical composition, and film formation conditions may be different between the lower layer of the conductor 242 and the upper layer of the conductor 242. For example, a nitride containing tantalum may be used for the lower layer of the conductor 242, and a nitride containing titanium may be used for the upper layer of the conductor 242.

Note that the conductor 242a and the conductor 242b respectively correspond to the conductor 42a and the conductor 42b described in Embodiment 1. Thus, the description of the conductor 42a and the conductor 42b in Embodiment 1 can be referred to for the material, the structure, and the like used for the conductor 242a and the conductor 242b. The description of the conductor 242a and the conductor 242b in this embodiment can also be referred to for the material, the structure, and the like used for the conductor 42a and the conductor 42b described in Embodiment 1.

The insulator 271a is provided in contact with the top surface of the conductor 242a, and the insulator 271b is provided in contact with the top surface of the conductor 242b. The insulator 271 preferably functions as at least a barrier insulating film against oxygen. Thus, the insulator 271 preferably has a function of inhibiting oxygen diffusion. For example, the insulator 271 preferably has a function of inhibiting diffusion of oxygen more than the insulator 280. As the insulator 271, an insulator such as silicon nitride, aluminum oxide, or magnesium oxide is used, for example.

The insulator 275 is provided to cover the insulator 224, the oxide 230a, the oxide 230b, the conductor 242a, the conductor 242b, the insulator 271a, and the insulator 271b. Specifically, the insulator 275 includes a region in contact with the side surface of the insulator 224, a region in contact with the side surface of the oxide 230a, a region in contact with the side surface of the oxide 230b, a region in contact with the side surface of the conductor 242a, a region in contact with the side surface of the conductor 242b, a region in contact with the side surface and the top surface of the insulator 271a, and a region in contact with the side surface and the top surface of the insulator 271b.

When the insulator 271 and the insulator 275 are provided as described above, the conductor 242 can be surrounded by the insulators having a barrier property against oxygen. That is, oxygen included in the insulator 280 can be prevented from diffusing into the conductor 242. As a result, the conductor 242 can be inhibited from being directly oxidized by oxygen included in the insulator 280, so that an increase in resistivity and a reduction in on-state current can be inhibited.

Note that the insulator 275 corresponds to the insulator 75 described in Embodiment 1. Thus, the description of the insulator 75 in Embodiment 1 can be referred to for the material, the structure, and the like used for the insulator 275. The description of the insulator 275 in this embodiment can also be referred to for the material, the structure, and the like used for the insulator 75 described in Embodiment 1.

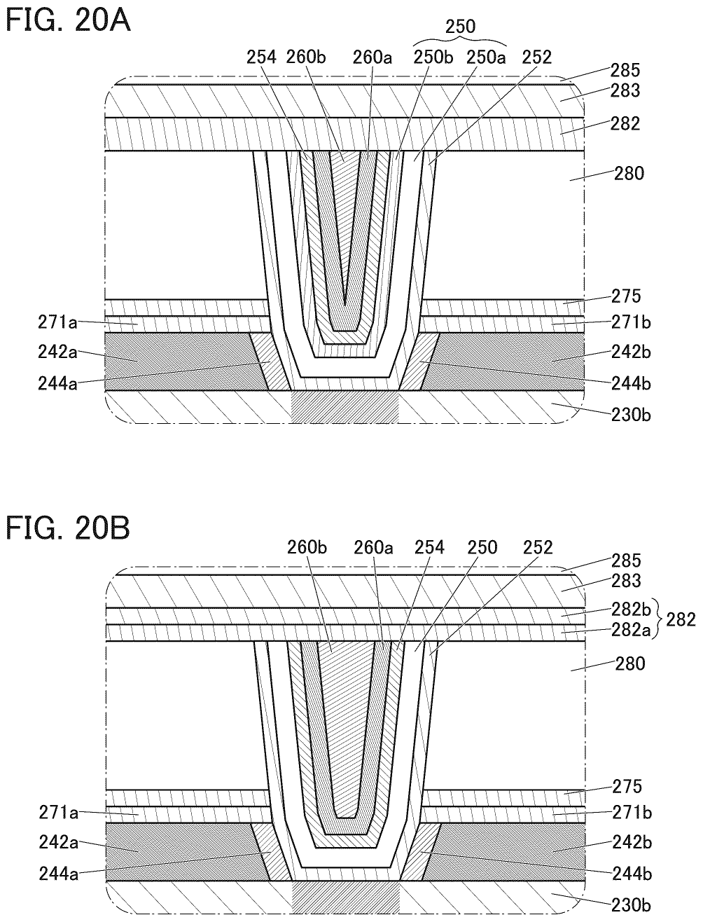

The insulator 250 functions as part of the gate insulator. Although FIG. 14A to FIG. 14D and the like illustrate a single-layer structure of the insulator 250, the present invention is not limited to this structure, and a stacked-layer structure of two or more layers may be employed. For example, as illustrated in FIG. 20A, the insulator 250 may have a stacked-layer structure of two layers of an insulator 250a and an insulator 250b over the insulator 250a.

In the case where the insulator 250 has a stacked-layer structure of two layers as illustrated in FIG. 20A, it is preferable that the insulator 250a be formed using an insulator that easily transmits oxygen and the insulator 250b be formed using an insulator having a function of inhibiting oxygen diffusion. With such a structure, oxygen included in the insulator 250a can be inhibited from diffusing into the conductor 260. That is, a reduction in the amount of oxygen supplied to the oxide 230 can be inhibited. In addition, oxidation of the conductor 260 due to oxygen included in the insulator 250a can be inhibited. For example, it is preferable that the insulator 250a be provided using any of the above-described materials that can be used for the insulator 250 and the insulator 250b be provided using an insulator containing an oxide of one or both of aluminum and hafnium. As the insulator, aluminum oxide, hafnium oxide, an oxide containing aluminum and hafnium (hafnium aluminate), an oxide containing hafnium and silicon (hafnium silicate), or the like can be used. In this embodiment, hafnium oxide is used as the insulator 250b. In this case, the insulator 250b includes at least oxygen and hafnium. The thickness of the insulator 250b is greater than or equal to 0.5 nm and less than or equal to 5.0 nm, preferably greater than or equal to 1.0 nm and less than or equal to 5.0 nm, further preferably greater than or equal to 1.0 nm and less than or equal to 3.0 nm. In that case, at least part of the insulator 250b includes a region having a thickness like the above-described thickness.

In the case where silicon oxide, silicon oxynitride, or the like is used for the insulator 250a, the insulator 250b may be formed using an insulating material that is a high-k material having a high relative permittivity. The gate insulator having a stacked-layer structure of the insulator 250a and the insulator 250b can be thermally stable and can have a high relative permittivity. Accordingly, a gate potential applied during the operation of the transistor can be reduced while the physical thickness of the gate insulator is maintained. In addition, the equivalent oxide thickness (EOT) of the insulator functioning as the gate insulator can be reduced. Therefore, the breakdown voltage of the insulator 250 can be increased.

Note that in the case where the insulator 250 has a stacked-layer structure of two layers as illustrated in FIG. 20A, an insulator having a function of inhibiting the passage of oxygen and impurities such as hydrogen, e.g., hafnium oxide, is used as the insulator 250b, whereby the insulator 250b can also have the function of the insulator 254. In such a case, the structure without the insulator 254 enables simplification of the manufacturing process and the improvement in productivity of the semiconductor device.

The conductor 260 functions as the first gate electrode of the transistor 200. The conductor 260 preferably includes the conductor 260a and the conductor 260b placed over the conductor 260a. For example, the conductor 260a is preferably placed to cover the bottom surface and the side surface of the conductor 260b. As illustrated in FIG. 14B and FIG. 14C, the top surface of the conductor 260 is level or substantially level with the uppermost portion of the insulator 254, the uppermost portion of the insulator 250, the uppermost portion of the insulator 252, and the top surface of the insulator 280. Although the conductor 260 has a two-layer structure of the conductor 260a and the conductor 260b in FIG. 14B and FIG. 14C, the conductor 260 may have a single-layer structure or a stacked-layer structure of three or more layers.

For the conductor 260a, it is preferable to use a conductive material having a function of inhibiting diffusion of impurities such as a hydrogen atom, a hydrogen molecule, a water molecule, a nitrogen atom, a nitrogen molecule, a nitrogen oxide molecule, and a copper atom. Alternatively, it is preferable to use a conductive material having a function of inhibiting diffusion of oxygen (e.g., at least one of an oxygen atom, an oxygen molecule, and the like).

In addition, when the conductor 260a has a function of inhibiting diffusion of oxygen, the conductivity of the conductor 260b can be inhibited from being lowered because of oxidation due to oxygen included in the insulator 250. As the conductive material having a function of inhibiting diffusion of oxygen, for example, titanium, titanium nitride, tantalum, tantalum nitride, ruthenium, or ruthenium oxide is preferably used. In the case where titanium nitride or tantalum nitride is used for the conductor 260a, the conductor 260a includes titanium or tantalum and nitrogen.

The conductor 260 also functions as a wiring and thus is preferably formed using a conductor having high conductivity. For example, a conductive material containing tungsten, copper, or aluminum as its main component can be used for the conductor 260b. The conductor 260b may have a stacked-layer structure; for example, a stacked-layer structure of the conductive material and titanium or titanium nitride may be employed.

In the transistor 200, the conductor 260 is formed in a self-aligned manner to fill the opening formed in the insulator 280 and the like. The formation of the conductor 260 in this manner allows the conductor 260 to be placed properly in a region between the conductor 242a and the conductor 242b without alignment. That is, the transistor structure of the transistor 200 can be referred to as a TGSA (Trench Gate Self Align) structure.

As illustrated in FIG. 14C, in the channel width direction of the transistor 200, with reference to the bottom surface of the insulator 222, the level of the bottom surface of the conductor 260 in a region not overlapping with the oxide 230b is preferably lower than the level of the bottom surface of the oxide 230b. When the conductor 260 functioning as the gate electrode covers the side surface and the top surface of the channel formation region of the oxide 230b with the insulator 250 and the like therebetween, the electric field of the conductor 260 is likely to act on the entire channel formation region of the oxide 230b. Thus, the on-state current of the transistor 200 can be increased, and the frequency characteristics of the transistor 200 can be improved. With reference to the bottom surface of the insulator 222, the difference between the level of the bottom surface of the conductor 260 in the region not overlapping with the oxide 230b and the level of the bottom surface of the oxide 230b is greater than or equal to 0 nm and less than or equal to 100 nm, preferably greater than or equal to 3 nm and less than or equal to 50 nm, further preferably greater than or equal to 5 nm and less than or equal to 20 nm.

Note that the conductor 260 corresponds to the conductor 60 described in Embodiment 1. Thus, the description of the conductor 60 in Embodiment 1 can be referred to for the material, the structure, and the like used for the conductor 260. The description of the conductor 260 in this embodiment can also be referred to for the material, the structure, and the like used for the conductor 60 described in Embodiment 1.

The insulator 282 is in contact with at least parts of the top surfaces of the conductor 260, the insulator 252, the insulator 250, the insulator 254, and the insulator 280, as illustrated in FIG. 14B.

The insulator 282 preferably functions as a barrier insulating film that inhibits impurities such as water and hydrogen from diffusing into the insulator 280 from above and preferably has a function of capturing impurities such as hydrogen. The insulator 282 preferably functions as a barrier insulating film that inhibits passage of oxygen. For the insulator 282, an insulator such as a metal oxide having an amorphous structure, e.g., aluminum oxide, may be used. In that case, the insulator 282 includes at least oxygen and aluminum. When the insulator 282, which has a function of capturing impurities such as hydrogen, is provided in contact with the insulator 280 in a region sandwiched between the insulator 212 and the insulator 283, impurities such as hydrogen included in the insulator 280 and the like can be captured and the amount of hydrogen in the region can be constant. It is preferable to use, in particular, aluminum oxide having an amorphous structure for the insulator 282, in which case hydrogen can be captured or fixed more effectively in some cases. Accordingly, the transistor 200 and the semiconductor device which have favorable characteristics and high reliability can be manufactured.

The insulator 282 provided over the insulator 280 is preferably formed by a method in which oxygen can be added to the insulator 280. Thus, excess oxygen can be included in the insulator 280. As the insulator 282, a film of aluminum oxide is preferably formed by a sputtering method, and a film of aluminum oxide is further preferably formed by a pulsed DC sputtering method using an aluminum target in an atmosphere containing an oxygen gas. The use of a pulsed DC sputtering method can achieve more uniform film thickness and improve the sputtering rate and film quality. Here, RF (Radio Frequency) power may be applied to the substrate. The amount of oxygen implanted into a layer below the insulator 282 can be controlled depending on the amount of the RF power applied to the substrate. For example, the amount of oxygen implanted into the layer below the insulator 282 decreases as the RF power decreases, and the amount of oxygen is easily saturated even when the insulator 282 has a small thickness. Moreover, the amount of oxygen implanted into the layer below the insulator 282 increases as the RF power increases.

The RF power is higher than or equal to 0 W/cm² and lower than or equal to 1.86 W/cm², for example. In other words, the amount of oxygen to be implanted can be changed to be appropriate for the characteristics of the transistor, with the RF power used at the time of forming the insulator 282. Accordingly, an appropriate amount of oxygen for improving the reliability of the transistor can be implanted.

The RF frequency is preferably higher than or equal to 10 MHz. The typical frequency is 13.56 MHz. The higher the RF frequency is, the less damage the substrate receives.

Although FIG. 14A to FIG. 14D and the like illustrate a single-layer structure of the insulator 282, the present invention is not limited to this structure, and a stacked-layer structure of two or more layers may be employed. For example, as illustrated in FIG. 20B, the insulator 282 may have a stacked-layer structure of two layers of an insulator 282a and an insulator 282b over the insulator 282a.

The insulator 282a and the insulator 282b are preferably formed using the same material by different methods. For example, when a film of aluminum oxide is formed as the insulator 282 by a pulsed DC sputtering method using an aluminum target in an atmosphere containing an oxygen gas, RF power applied to the substrate in the formation of the insulator 282a and RF power applied to the substrate in the formation of the insulator 282b are preferably different from each other, and the RF power applied to the substrate in the formation of the insulator 282a is preferably lower than the RF power applied to the substrate in the formation of the insulator 282b. Specifically, the insulator 282a is formed with the RF power applied to the substrate being higher than or equal to 0 W/cm² and lower than or equal to 0.62 W/cm², and the insulator 282b is formed with the RF power applied to the substrate being lower than or equal to 1.86 W/cm². More specifically, the insulator 282a is formed with the RF power applied to the substrate being 0 W/cm², and the insulator 282b is formed with the RF power applied to the substrate being 0.31 W/cm². With this structure, the insulator 282 can have an amorphous structure, and the amount of oxygen supplied to the insulator 280 can be adjusted.

Note that the RF power applied to the substrate in the formation of the insulator 282a may be higher than the RF power applied to the substrate in the formation of the insulator 282b. Specifically, the insulator 282a is formed with the RF power applied to the substrate being lower than or equal to 1.86 W/cm², and the insulator 282b is formed with the RF power applied to the substrate being higher than or equal to 0 W/cm² and lower than or equal to 0.62 W/cm². More specifically, the insulator 282a is formed with the RF power applied to the substrate being 1.86 W/cm², and the insulator 282b is formed with the RF power applied to the substrate being 0.62 W/cm². With this structure, the amount of oxygen supplied to the insulator 280 can be increased.

The thickness of the insulator 282a is greater than or equal to 1 nm and less than or equal to 20 nm, preferably greater than or equal to 1.5 nm and less than or equal to 15 nm, further preferably greater than or equal to 2 nm and less than or equal to 10 nm, still further preferably greater than or equal to 3 nm and less than or equal to 8 nm. With such a structure, the insulator 282a can have an amorphous structure regardless of the RF power. When the insulator 282a has an amorphous structure, the insulator 282b is likely to have an amorphous structure, so that the insulator 282 can have an amorphous structure.

Although the insulator 282a and the insulator 282b described above form the stacked-layer structure of the same material, the present invention is not limited thereto. The insulator 282a and the insulator 282b may form a stacked-layer structure of different materials.

The insulator 283 is in contact with part of the top surface of the insulator 214, the side surface of the insulator 216, the side surface of the insulator 222, the side surface of the insulator 275, the side surface of the insulator 280, and the side surface and the top surface of the insulator 282.

The insulator 283 functions as a barrier insulating film that inhibits impurities such as water and hydrogen from diffusing into the insulator 280 from above. The insulator 283 is placed over the insulator 282. The insulator 283 is preferably formed using a nitride containing silicon such as silicon nitride or silicon nitride oxide. For example, a film of silicon nitride formed by a sputtering method is used for the insulator 283. When the insulator 283 is formed by a sputtering method, a high-density silicon nitride film can be formed. As the insulator 283, a film of silicon nitride formed by a PEALD method or a CVD method may be stacked over a film of silicon nitride formed by a sputtering method.

For the conductor 240a and the conductor 240b, a conductive material containing tungsten, copper, or aluminum as its main component is preferably used. The conductor 240a and the conductor 240b may each have a stacked-layer structure.

In the case where the conductor 240a and the conductor 240b each have a stacked-layer structure, a conductive material having a function of inhibiting passage of impurities such as water and hydrogen is preferably used for the first conductor placed in the vicinity of the insulator 285, the insulator 283, the insulator 282, the insulator 280, the insulator 275, and the insulator 271. For example, tantalum, tantalum nitride, titanium, titanium nitride, ruthenium, ruthenium oxide, or the like is preferably used. The conductive material having a function of inhibiting passage of impurities such as water and hydrogen may be used as a single layer or stacked layers. Moreover, impurities such as water and hydrogen included in a layer above the insulator 283 can be inhibited from entering the oxide 230 through the conductor 240a and the conductor 240b.

Note that the conductor 240a and the conductor 240b respectively correspond to the conductor 40a and the conductor 40b described in Embodiment 1. Thus, the description of the conductor 40a and the conductor 40b in Embodiment 1 can be referred to for the material, the structure, and the like used for the conductor 240a and the conductor 240b. The description of the conductor 240a and the conductor 240b in this embodiment can also be referred to for the material, the structure, and the like used for the conductor 40a and the conductor 40b described in Embodiment 1.

For the insulator 241a and the insulator 241b, a barrier insulating film that can be used for the insulator 275 or the like is used. For the insulator 241a and the insulator 241b, for example, an insulator such as silicon nitride, aluminum oxide, or silicon nitride oxide is used. Since the insulator 241a and the insulator 241b are provided in contact with the insulator 283, the insulator 282, the insulator 275, and the insulator 271, impurities such as water and hydrogen included in the insulator 280 and the like can be inhibited from entering the oxide 230 through the conductor 240a and the conductor 240b. In particular, silicon nitride is suitable because of its high blocking property against hydrogen. Furthermore, oxygen included in the insulator 280 can be prevented from being absorbed by the conductor 240a and the conductor 240b.

When the insulator 241a and the insulator 241b each have a stacked-layer structure as illustrated in FIG. 14B, the first insulator in contact with the inner wall of the opening formed in the insulator 280 and the like and the second insulator located inward from the first insulator are preferably formed using a combination of a barrier insulating film against oxygen and a barrier insulating film against hydrogen.

For example, a film of aluminum oxide formed by an ALD method may be used as the first insulator, and a film of silicon nitride formed by a PEALD method is used as the second insulator. With such a structure, oxidation of the conductor 240a and the conductor 240b can be inhibited, and hydrogen can be inhibited from entering the conductor 240a and the conductor 240b.

The conductor 246a functioning as a wiring may be placed in contact with the top surface of the conductor 240a, and the conductor 246b functioning as a wiring may be placed in contact with the top surface of the conductor 240b. For the conductor 246a and the conductor 246b, a conductive material containing tungsten, copper, or aluminum as its main component is preferably used. The conductors may each have a stacked-layer structure; for example, a stack of the above conductive material and titanium or titanium nitride may be employed. Note that the conductors may be formed so as to be embedded in an opening provided in an insulator.

The above structure enables providing the transistor 200 that can be regarded as a junction-less transistor. The above structure can relieve the drain electric field and enhance the controllability of the top gate electrode. Thus, the present invention can achieve a junction-less transistor in which a short-channel effect does not appear or hardly appears.

### <Method for Manufacturing Semiconductor Device>

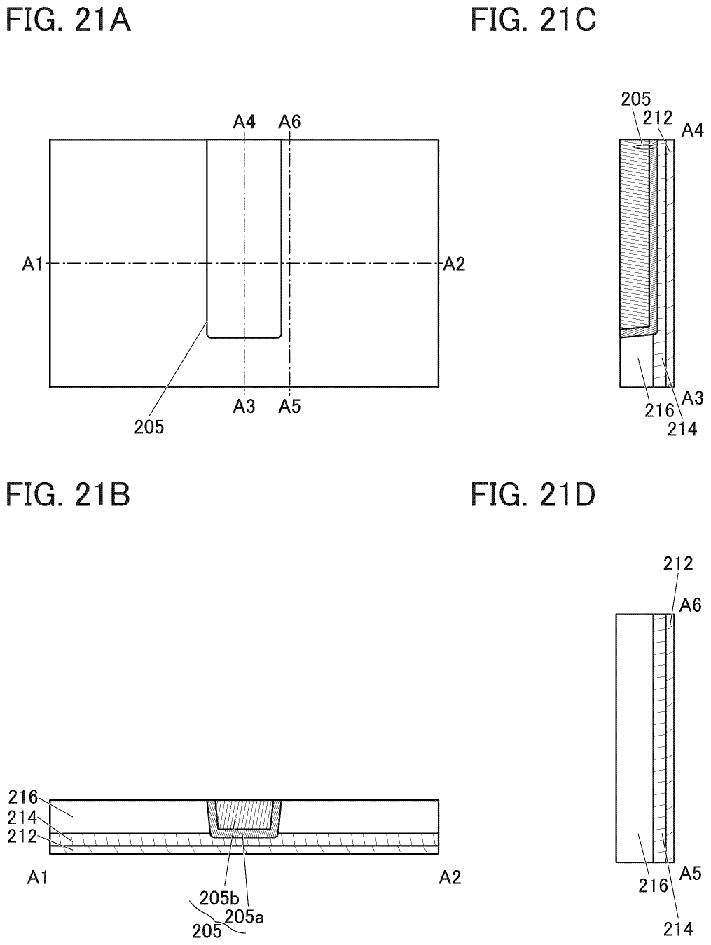

Next, a method for manufacturing the semiconductor device of one embodiment of the present invention illustrated in FIG. 14A to FIG. 14D is described with reference to FIG. 21A to FIG. 31D.

In FIG. 21A to FIG. 31D, A of each drawing is a top view. Moreover, B of each drawing is a cross-sectional view corresponding to a portion indicated by the dashed-dotted line A1-A2 in A of each drawing, and is also a cross-sectional view of the transistor 200 in the channel length direction. Furthermore, C of each drawing is a cross-sectional view corresponding to a portion indicated by the dashed-dotted line A3-A4 in A of each drawing, and is also a cross-sectional view of the transistor 200 in the channel width direction. Furthermore, D of each drawing is a cross-sectional view of a portion indicated by the dashed-dotted line A5-A6 in A of each drawing. Note that for clarity of the drawing, some components are omitted in the top view of A of each drawing.

Hereinafter, a film of an insulating material for forming an insulator, a film of a conductive material for forming a conductor, or a film of a semiconductor material for forming a semiconductor can be formed by a sputtering method, a CVD method, an MBE method, a PLD method, an ALD method, or the like as appropriate.

Examples of a sputtering method include an RF sputtering method in which a high-frequency power source is used as a sputtering power source, a DC sputtering method in which a DC power source is used, and a pulsed DC sputtering method in which a voltage applied to an electrode is changed in a pulsed manner. An RF sputtering method is mainly used in the case where an insulating film is formed, and a DC sputtering method is mainly used in the case where a metal conductive film is formed. A pulsed DC sputtering method is mainly used in the case where a film of a compound such as an oxide, a nitride, or a carbide is formed by a reactive sputtering method.

Note that a CVD method can be classified into a plasma CVD method, a thermal CVD method, a photo CVD method, and the like. Moreover, a CVD method can be classified into a metal CVD method and a metal organic CVD method depending on a source gas to be used.

A high-quality film can be obtained at a relatively low temperature by a plasma CVD method. Furthermore, a thermal CVD method is a film formation method that does not use plasma and thus enables less plasma damage to an object. For example, a wiring, an electrode, an element (a transistor, a capacitor, or the like), or the like included in a semiconductor device may be charged up by receiving charge from plasma. In that case, accumulated charge may break the wiring, the electrode, the element, or the like included in the semiconductor device. In contrast, such plasma damage is not caused in the case of a thermal CVD method, which does use plasma, and thus the yield of the semiconductor device can be increased. In addition, a thermal CVD method does not cause plasma damage during film formation, so that a film with few defects can be obtained.

As an ALD method, a thermal ALD method, in which a precursor and a reactant react with each other only by a thermal energy, a PEALD method, in which a reactant excited by plasma is used, or the like can be used.

A CVD method and an ALD method are different from a sputtering method in which particles ejected from a target or the like are deposited. Thus, a CVD method and an ALD method are film formation methods that enable favorable step coverage almost regardless of the shape of an object. In particular, an ALD method enables excellent step coverage and excellent thickness uniformity and thus is suitable for covering a surface of an opening portion with a high aspect ratio, for example. On the other hand, an ALD method has a relatively low film formation rate, and thus is preferably used in combination with another film formation method with a high film formation rate, such as a CVD method, in some cases.

By a CVD method, a film with a certain composition can be formed depending on the flow rate ratio of the source gases. For example, by a CVD method, a film whose composition is continuously changed can be formed by changing the flow rate ratio of the source gases during film formation. In the case where the film is formed while the flow rate ratio of the source gases is changed, as compared with the case where the film is formed using a plurality of film formation chambers, the time taken for the film formation can be shortened because the time taken for transfer or pressure adjustment is not required. Thus, the productivity of the semiconductor device can be increased in some cases.

By an ALD method, a film with a freely selected composition can be formed by concurrently introducing different kinds of precursors. In the case where different kinds of precursors are introduced, a film with a freely selected composition can be formed by controlling the number of cycles for each of the precursors.

First, a substrate (not illustrated) is prepared, and the insulator 212 is formed over the substrate (see FIG. 21A to FIG. 21D). The insulator 212 is preferably formed by a sputtering method. By using a sputtering method that does not need to use a molecule containing hydrogen as a film formation gas, the hydrogen concentration in the insulator 212 can be reduced. Without limitation to a sputtering method, the insulator 212 may be formed by a CVD method, an MBE method, a PLD method, an ALD method, or the like as appropriate.

In this embodiment, as the insulator 212, a film of silicon nitride is formed by a pulsed DC sputtering method using a silicon target in an atmosphere containing a nitrogen gas. The use of a pulsed DC sputtering method can inhibit generation of particles due to arcing on the target surface, achieving more uniform film thickness. In addition, by using the pulsed voltage, rising and falling in discharge can be made steep as compared with the case where a high-frequency voltage is used. As a result, power can be supplied to an electrode more efficiently to improve the sputtering rate and film quality.

The use of an insulator that is less permeable to impurities such as water and hydrogen, e.g., silicon nitride, can inhibit diffusion of impurities such as water and hydrogen included in a layer below the insulator 212. When an insulator that is less permeable to copper, such as silicon nitride, is used for the insulator 212, even in the case where a metal that is likely to diffuse, such as copper, is used for a conductor (not illustrated) in a layer below the insulator 212, upward diffusion of the metal through the insulator 212 can be inhibited.

Next, the insulator 214 is formed over the insulator 212 (see FIG. 21A to FIG. 21D). The insulator 214 is preferably formed by a sputtering method. By using a sputtering method that does not need to use a molecule containing hydrogen as a film formation gas, the hydrogen concentration in the insulator 214 can be reduced. Without limitation to a sputtering method, the insulator 214 may be formed by a CVD method, an MBE method, a PLD method, an ALD method, or the like as appropriate.

A metal oxide having an amorphous structure and an excellent function of capturing and fixing hydrogen, such as aluminum oxide, is preferably used for the insulator 214. In this case, the insulator 214 captures or fixes hydrogen included in the insulator 216 and the like and prevents the hydrogen from diffusing into the oxide 230. Aluminum oxide having an amorphous structure or amorphous aluminum oxide is particularly preferably used for the insulator 214, in which case hydrogen can sometimes be captured or fixed more effectively. Accordingly, the transistor 200 and the semiconductor device which have favorable characteristics and high reliability can be manufactured.

In this embodiment, as the insulator 214, a film of aluminum oxide is formed by a pulsed DC sputtering method using an aluminum target in an atmosphere containing an oxygen gas. The use of a pulsed DC sputtering method can achieve more uniform film thickness and improve the sputtering rate and film quality. Here, RF power may be applied to the substrate. The amount of oxygen implanted into a layer below the insulator 214 can be controlled depending on the amount of the RF power applied to the substrate. The RF power is higher than or equal to 0 W/cm² and lower than or equal to 1.86 W/cm². In other words, the amount of oxygen to be implanted can be changed to be appropriate for the characteristics of the transistor, with the RF power used at the time of forming the insulator 214. Accordingly, an appropriate amount of oxygen for improving the reliability of the transistor can be implanted. The RF frequency is preferably higher than or equal to 10 MHz. The typical frequency is 13.56 MHz. The higher the RF frequency is, the less damage the substrate receives.

Next, the insulator 216 is formed over the insulator 214. The insulator 216 is preferably formed by a sputtering method. By using a sputtering method that does not need to use a molecule containing hydrogen as a film formation gas, the hydrogen concentration in the insulator 216 can be reduced. Without limitation to a sputtering method, the insulator 216 may be formed by a CVD method, an MBE method, a PLD method, an ALD method, or the like as appropriate.

In this embodiment, as the insulator 216, a film of silicon oxide is formed by a pulsed DC sputtering method using a silicon target in an atmosphere containing an oxygen gas. The use of a pulsed DC sputtering method can achieve more uniform film thickness and improve the sputtering rate and film quality.

The insulator 212, the insulator 214, and the insulator 216 are preferably successively formed without exposure to the air. For example, a multi-chamber film formation apparatus is used. As a result, the amounts of hydrogen in the formed insulator 212, insulator 214, and insulator 216 can be reduced, and furthermore, entry of hydrogen into the films in intervals between film formation steps can be inhibited.

Then, an opening reaching the insulator 214 is formed in the insulator 216. Examples of the opening include a groove and a slit. A region where an opening is formed is referred to as an opening portion in some cases. Wet etching may be used for the formation of the opening; however, dry etching is preferably used for microfabrication. As the insulator 214, it is preferable to select an insulator that functions as an etching stopper film in forming the opening by etching the insulator 216. For example, in the case where silicon oxide or silicon oxynitride is used for the insulator 216 in which the opening is to be formed, silicon nitride, aluminum oxide, or hafnium oxide is preferably used for the insulator 214.

As a dry etching apparatus, a capacitively coupled plasma (CCP) etching apparatus including parallel plate electrodes can be used. The capacitively coupled plasma etching apparatus including parallel plate electrodes may have a structure in which a high-frequency voltage is applied to one of the parallel plate electrodes. Alternatively, a structure may be employed in which different high-frequency voltages are applied to one of the parallel plate electrodes. Alternatively, a structure may be employed in which high-frequency voltages with the same frequency are applied to the parallel plate electrodes. Alternatively, a structure may be employed in which high-frequency voltages with different frequencies are applied to the parallel plate electrodes. Alternatively, a dry etching apparatus including a high-density plasma source can be used. As the dry etching apparatus including a high-density plasma source, an inductively coupled plasma (ICP) etching apparatus or the like can be used, for example.

After the formation of the opening, a conductive film to be the conductor 205a is formed. The conductive film desirably includes a conductor having a function of inhibiting passage of oxygen. For example, tantalum nitride, tungsten nitride, or titanium nitride can be used. Alternatively, a stacked-layer film of the conductor having a function of inhibiting passage of oxygen and tantalum, tungsten, titanium, molybdenum, aluminum, copper, or a molybdenum-tungsten alloy can be used. The conductive film can be formed by a sputtering method, a CVD method, an MBE method, a PLD method, an ALD method, or the like.

In this embodiment, a film of titanium nitride is formed as the conductive film to be the conductor 205a. When such a metal nitride is used for a layer below the conductor 205b, oxidation of the conductor 205b by the insulator 216 or the like can be inhibited. Furthermore, even when a metal that is likely to diffuse, such as copper, is used for the conductor 205b, the metal can be prevented from diffusing to the outside through the conductor 205a.

Next, a conductive film to be the conductor 205b is formed. Tantalum, tungsten, titanium, molybdenum, aluminum, copper, a molybdenum-tungsten alloy, or the like can be used for the conductive film. The conductive film can be formed by a plating method, a sputtering method, a CVD method, an MBE method, a PLD method, an ALD method, or the like. In this embodiment, a film of tungsten is formed as the conductive film.

Next, by performing CMP treatment, the conductive film to be the conductor 205a and the conductive film to be the conductor 205b are partly removed to expose the insulator 216 (see FIG. 21A to FIG. 21D). As a result, the conductor 205a and the conductor 205b remain only in the opening portion. Note that the insulator 216 is partly removed by the CMP treatment in some cases.

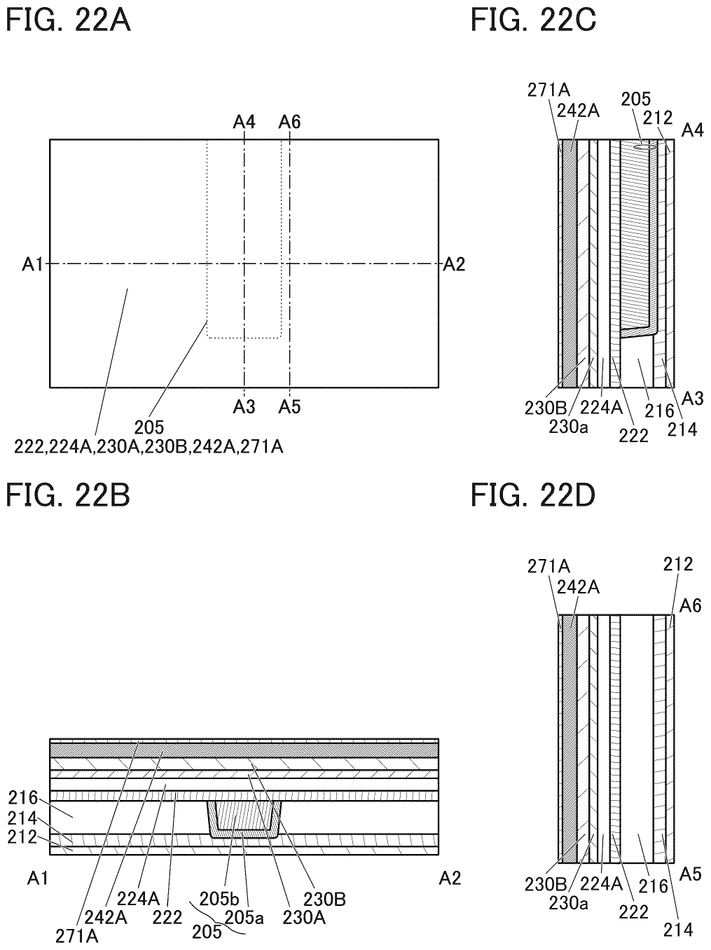

Next, the insulator 222 is formed over the insulator 216 and the conductor 205 (see FIG. 22A to FIG. 22D). A film of an insulator containing an oxide of one or both of aluminum and hafnium is preferably formed as the insulator 222. Note that as the insulator containing an oxide of one or both of aluminum and hafnium, aluminum oxide, hafnium oxide, an oxide containing aluminum and hafnium (hafnium aluminate), or the like is preferably used. Alternatively, hafnium-zirconium oxide is preferably used. The insulator containing an oxide of one or both of aluminum and hafnium has a barrier property against oxygen, hydrogen, and water. When the insulator 222 has a barrier property against hydrogen and water, hydrogen and water included in components provided around the transistor 200 are inhibited from diffusing into the transistor 200 through the insulator 222, and generation of oxygen vacancies in the oxide 230 can be inhibited.

The insulator 222 can be formed by a sputtering method, a CVD method, an MBE method, a PLD method, an ALD method, or the like. In this embodiment, as the insulator 222, a film of hafnium oxide is formed by an ALD method.

Subsequently, heat treatment is preferably performed. The heat treatment is performed at higher than or equal to 250° C. and lower than or equal to 650° C., preferably higher than or equal to 300° C. and lower than or equal to 500° C., further preferably higher than or equal to 320° C. and lower than or equal to 450° C. Note that the heat treatment is performed in a nitrogen gas or inert gas atmosphere, or an atmosphere containing an oxidizing gas at higher than or equal to 10 ppm, higher than or equal to 1%, or higher than or equal to 10%. For example, in the case where the heat treatment is performed in a mixed atmosphere of a nitrogen gas and an oxygen gas, the proportion of the oxygen gas is approximately 20%. The heat treatment may be performed under reduced pressure. Alternatively, the heat treatment may be performed in an atmosphere containing an oxidizing gas at higher than or equal to 10 ppm, higher than or equal to 1%, or higher than or equal to 10% in order to compensate for oxygen released, after heat treatment is performed in a nitrogen gas or inert gas atmosphere.

The gas used in the above heat treatment is preferably highly purified. For example, the amount of moisture contained in the gas used in the above heat treatment is less than or equal to 1 ppb, preferably less than or equal to 0.1 ppb, further preferably less than or equal to 0.05 ppb. The heat treatment performed using a highly purified gas can prevent entry of moisture or the like into the insulator 222 and the like as much as possible.

In this embodiment, as the heat treatment, treatment is performed at 400° C. for one hour with a flow rate ratio of a nitrogen gas to an oxygen gas being 4:1 after the formation of the insulator 222. Through the heat treatment, impurities such as water and hydrogen included in the insulator 222 can be removed, for example. In the case where an oxide containing hafnium is used for the insulator 222, the insulator 222 is partly crystallized by the heat treatment in some cases. The heat treatment can also be performed after the formation of an insulating film to be the insulator 224, for example.

Next, an insulating film 224A is formed over the insulator 222 (see FIG. 22A to FIG. 22D). The insulating film 224A can be formed by a sputtering method, a CVD method, an MBE method, a PLD method, an ALD method, or the like. In this embodiment, for the insulating film 224A, a film of silicon oxide is formed by a sputtering method. By using a sputtering method that does not need to use a molecule containing hydrogen as a film formation gas, the hydrogen concentration in the insulating film 224A can be reduced. The hydrogen concentration in the insulating film 224A is preferably reduced in this manner because the insulating film 224A is in contact with the oxide 230a in a later step.

Next, an oxide film 230A and an oxide film 230B are formed in this order over the insulating film 224A (see FIG. 22A to FIG. 22D). Note that the oxide film 230A and the oxide film 230B are preferably formed successively without being exposed to an atmospheric environment. By the film formation without exposure to the atmosphere, impurities or moisture from the atmospheric environment can be prevented from being attached onto the oxide film 230A and the oxide film 230B, so that the vicinity of the interface between the oxide film 230A and the oxide film 230B can be kept clean.

The oxide film 230A and the oxide film 230B can be formed by a sputtering method, a CVD method, an MBE method, a PLD method, an ALD method, or the like. In this embodiment, the oxide film 230A and the oxide film 230B are formed by a sputtering method.

For example, in the case where the oxide film 230A and the oxide film 230B are formed by a sputtering method, oxygen or a mixed gas of oxygen and a noble gas is used as a sputtering gas. Increasing the proportion of oxygen contained in the sputtering gas can increase the amount of excess oxygen in the formed oxide films. In the case where the oxide films are formed by a sputtering method, the above In-M-Zn oxide target or the like can be used.

In particular, when the oxide film 230A is formed, part of oxygen contained in the sputtering gas is supplied to the insulator 224 in some cases. Thus, the proportion of oxygen contained in the sputtering gas is higher than or equal to 70%, preferably higher than or equal to 80%, further preferably 100%.

In the case where the oxide film 230B is formed by a sputtering method and the proportion of oxygen contained in the sputtering gas for film formation is higher than 30% and lower than or equal to 100%, preferably higher than or equal to 70% and lower than or equal to 100%, an oxygen-excess oxide semiconductor is formed. In a transistor including an oxygen-excess oxide semiconductor for its channel formation region, relatively high reliability can be obtained. Note that one embodiment of the present invention is not limited thereto. In the case where the oxide film 230B is formed by a sputtering method and the proportion of oxygen contained in the sputtering gas for film formation is higher than or equal to 1% and lower than or equal to 30%, preferably higher than or equal to 5% and lower than or equal to 20%, an oxygen-deficient oxide semiconductor is formed. In a transistor including an oxygen-deficient oxide semiconductor for its channel formation region, relatively high field-effect mobility can be obtained. Furthermore, when the film formation is performed while the substrate is being heated, the crystallinity of the oxide film can be improved.

In this embodiment, the oxide film 230A is formed by a sputtering method using an oxide target with In:Ga:Zn=1:3:4 [atomic ratio]. In addition, the oxide film 230B is formed by a sputtering method using an oxide target with In:Ga:Zn=4:2:4.1 [atomic ratio], an oxide target with In:Ga:Zn=1:1:1 [atomic ratio], an oxide target with In:Ga:Zn=1:1:1.2 [atomic ratio], or an oxide target with In:Ga:Zn=1:1:2 [atomic ratio]. Note that each of the oxide films is preferably formed so as to have characteristics required for the oxide 230a and the oxide 230b by selecting the film formation conditions and the atomic ratios as appropriate.

Note that the insulating film 224A, the oxide film 230A, and the oxide film 230B are preferably formed by a sputtering method without exposure to the air. For example, a multi-chamber film formation apparatus is used. As a result, entry of hydrogen into the insulating film 224A, the oxide film 230A, and the oxide film 230B in intervals between film formation steps can be inhibited.

Next, heat treatment is preferably performed. The heat treatment is performed in a temperature range where the oxide film 230A and the oxide film 230B do not become polycrystals, i.e., at higher than or equal to 250° C. and lower than or equal to 650° C., preferably higher than or equal to 400° C. and lower than or equal to 600° C. Note that the heat treatment is performed in a nitrogen gas or inert gas atmosphere, or an atmosphere containing an oxidizing gas at higher than or equal to 10 ppm, higher than or equal to 1%, or higher than or equal to 10%. For example, the heat treatment is preferably performed in an oxygen atmosphere. Accordingly, oxygen can be supplied to the oxide film 230A and the oxide film 230B to reduce oxygen vacancies. For example, in the case where the heat treatment is performed in a mixed atmosphere of a nitrogen gas and an oxygen gas, the proportion of the oxygen gas is approximately 20%. The heat treatment may be performed under reduced pressure. Alternatively, the heat treatment may be performed in an atmosphere containing an oxidizing gas at higher than or equal to 10 ppm, higher than or equal to 1%, or higher than or equal to 10% in order to compensate for oxygen released, after heat treatment is performed in a nitrogen gas or inert gas atmosphere. Alternatively, the heat treatment may be performed in a nitrogen gas or inert gas atmosphere successively after heat treatment is performed in an atmosphere containing an oxidizing gas at higher than or equal to 10 ppm, higher than or equal to 1%, or higher than or equal to 10%.

Note that by oxygen adding treatment performed on the oxide 230, oxygen vacancies in the oxide 230 can be repaired with supplied oxygen. Furthermore, hydrogen remaining in the oxide 230 reacts with supplied oxygen, so that the hydrogen can be removed as H₂O (dehydration). This can inhibit recombination of hydrogen remaining in the oxide 230 with oxygen vacancies and formation of VoH.

The gas used in the above heat treatment is preferably highly purified. For example, the amount of moisture contained in the gas used in the above heat treatment is less than or equal to 1 ppb, preferably less than or equal to 0.1 ppb, further preferably less than or equal to 0.05 ppb. The heat treatment performed using a highly purified gas can prevent entry of moisture or the like into the oxide film 230A, the oxide film 230B, and the like as much as possible.

In this embodiment, as the heat treatment, treatment is performed at 400° C. for one hour with a flow rate ratio of a nitrogen gas to an oxygen gas being 4:1. Through such heat treatment using the oxygen gas, impurities such as water and hydrogen in the oxide film 230A and the oxide film 230B can be reduced, for example. The reduction of impurities in the films in this manner improves the crystallinity of the oxide film 230B, thereby offering a dense structure with a higher density. Thus, crystalline regions in the oxide film 230A and the oxide film 230B are expanded, so that in-plane variations of the crystalline regions in the oxide film 230A and the oxide film 230B can be reduced. Accordingly, an in-plane variation of electrical characteristics of the transistor 200 can be reduced.

By performing the heat treatment, hydrogen in the insulator 216, the insulating film 224A, the oxide film 230A, and the oxide film 230B moves into the insulator 222 and is absorbed by the insulator 222. In other words, hydrogen in the insulator 216, the insulating film 224A, the oxide film 230A, and the oxide film 230B diffuses into the insulator 222. Accordingly, the hydrogen concentration in the insulator 222 increases, while the hydrogen concentrations in the insulator 216, the insulating film 224A, the oxide film 230A, and the oxide film 230B decrease.

In particular, the insulating film 224A functions as a gate insulator of the transistor 200, and the oxide film 230A and the oxide film 230B function as the channel formation region of the transistor 200. Thus, the transistor 200 preferably includes the insulating film 224A, the oxide film 230A, and the oxide film 230B with reduced hydrogen concentrations to have favorable reliability.

Next, a conductive film 242A is formed over the oxide film 230B (see FIG. 22A to FIG. 22D). The conductive film 242A can be formed by a sputtering method, a CVD method, an MBE method, a PLD method, an ALD method, or the like. For example, as the conductive film 242A, a tantalum nitride film is formed by a sputtering method. Note that heat treatment may be performed before the formation of the conductive film 242A. This heat treatment may be performed under reduced pressure, and the conductive film 242A may be successively formed without exposure to the air. Such treatment can remove moisture and hydrogen adsorbed onto the surface of the oxide film 230B, and further can reduce the moisture concentration and the hydrogen concentration in the oxide film 230A and the oxide film 230B. The heat treatment is preferably performed at a temperature higher than or equal to 100° C. and lower than or equal to 400° C. In this embodiment, the heat treatment is performed at 200° C.

Next, an insulating film 271A is formed over the conductive film 242A (see FIG. 22A to FIG. 22D). The insulating film 271A can be formed by a sputtering method, a CVD method, an MBE method, a PLD method, an ALD method, or the like. As the insulating film 271A, an insulating film having a function of inhibiting passage of oxygen is preferably used. For example, as the insulating film 271A, an aluminum oxide film or a silicon nitride film is formed by a sputtering method. Alternatively, for example, a silicon nitride film and a silicon oxide film over the silicon nitride film may be formed as the insulating film 271A by a sputtering method.

Note that the conductive film 242A and the insulating film 271A are preferably formed by a sputtering method without exposure to the air. For example, a multi-chamber film formation apparatus is used. As a result, the amounts of hydrogen in the conductive film 242A and the insulating film 271A can be reduced, and furthermore, entry of hydrogen into the films in intervals between film formation steps can be inhibited. In the case where a hard mask is provided over the insulating film 271A, a film to be the hard mask is successively formed without exposure to the air.

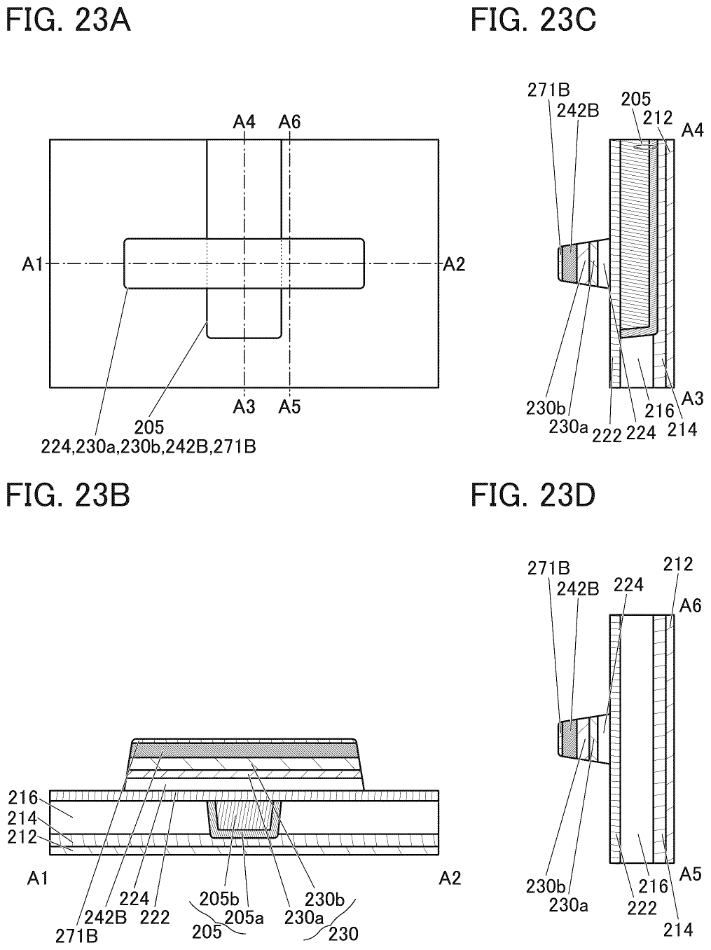

Next, the insulating film 224A, the oxide film 230A, the oxide film 230B, the conductive film 242A, and the insulating film 271A are processed into island shapes by a lithography method to form the insulator 224, the oxide 230a, the oxide 230b, a conductive layer 242B, and an insulating layer 271B (see FIG. 23A to FIG. 23D). Here, the insulator 224, the oxide 230a, the oxide 230b, the conductive layer 242B, and the insulating layer 271B are formed to at least partly overlap with the conductor 205. A dry etching method or a wet etching method can be used for the processing. Processing by a dry etching method is suitable for microfabrication. The insulating film 224A, the oxide film 230A, the oxide film 230B, the conductive film 242A, and the insulating film 271A may be processed under different conditions.

Note that in a lithography method, first, a resist is exposed to light through a mask. Next, a region exposed to light is removed or left using a developing solution, so that a resist mask is formed. Then, etching treatment through the resist mask is conducted, whereby a conductor, a semiconductor, an insulator, or the like can be processed into a desired shape. The resist mask is formed through, for example, exposure of the resist to KrF excimer laser light, ArF excimer laser light, EUV (Extreme Ultraviolet) light, or the like. A liquid immersion technique may be employed in which a gap between a substrate and a projection lens is filled with a liquid (e.g., water) in light exposure. An electron beam or an ion beam may be used instead of the light. Note that a mask is unnecessary in the case of using an electron beam or an ion beam. Note that the resist mask can be removed by dry etching treatment such as ashing, wet etching treatment, wet etching treatment after dry etching treatment, or dry etching treatment after wet etching treatment.

In addition, a hard mask formed of an insulator or a conductor may be used under the resist mask. In the case of using a hard mask, a hard mask with a desired shape can be formed in the following manner: an insulating film or a conductive film that is the material of the hard mask is formed over the conductive film 242A, a resist mask is formed thereover, and then the hard mask material is etched. The etching of the conductive film 242A and the like may be performed after removing the resist mask or with the resist mask remaining. In the latter case, the resist mask sometimes disappears during the etching. The hard mask may be removed by etching after the etching of the conductive film 242A and the like. Meanwhile, the hard mask is not necessarily removed when the hard mask material does not affect later steps or can be utilized in later steps. In this embodiment, the insulating layer 271B is used as a hard mask.

Here, the insulating layer 271B functions as a mask for the conductive layer 242B; thus, as illustrated in FIG. 23B to FIG. 23D, the conductive layer 242B does not have a curved surface between the side surface and the top surface. Thus, end portions at the intersections of the side surfaces and the top surfaces of the conductor 242a and the conductor 242b illustrated in FIG. 14B and FIG. 14D are angular. The cross-sectional area of the conductor 242 is larger in the case where the end portion at the intersection of the side surface and the top surface of the conductor 242 is angular than that in the case where the end portion is rounded. Accordingly, the resistance of the conductor 242 is reduced, so that the on-state current of the transistor 200 can be increased.

Furthermore, as illustrated in FIG. 23B to FIG. 23D, the side surfaces of the insulator 224, the oxide 230a, the oxide 230b, the conductive layer 242B, and the insulating layer 271B may have tapered shapes. The side surfaces of the insulator 224, the oxide 230a, the oxide 230b, the conductive layer 242B, and the insulating layer 271B have a taper angle greater than or equal to 60° and less than 90°, for example. With such tapered shapes of the side surfaces, the coverage with the insulator 275 and the like can be improved in a later step, so that defects such as a void can be reduced.

Not being limited to the above, the insulator 224, the oxide 230a, the oxide 230b, the conductive layer 242B, and the insulating layer 271B may be processed to have side surfaces that are substantially perpendicular to the top surface of the insulator 222. With such a structure, a plurality of the transistors 200 can be provided with high density in a small area.

A by-product generated in the above etching step is sometimes formed in a layered manner on the side surfaces of the insulator 224, the oxide 230a, the oxide 230b, the conductive layer 242B, and the insulating layer 271B. In this case, the layered by-product is formed between the insulator 275 and the insulator 224, the oxide 230a, the oxide 230b, the conductive layer 242B, and the insulating layer 271B. Hence, the layered by-product formed in contact with the top surface of the insulator 222 is preferably removed.

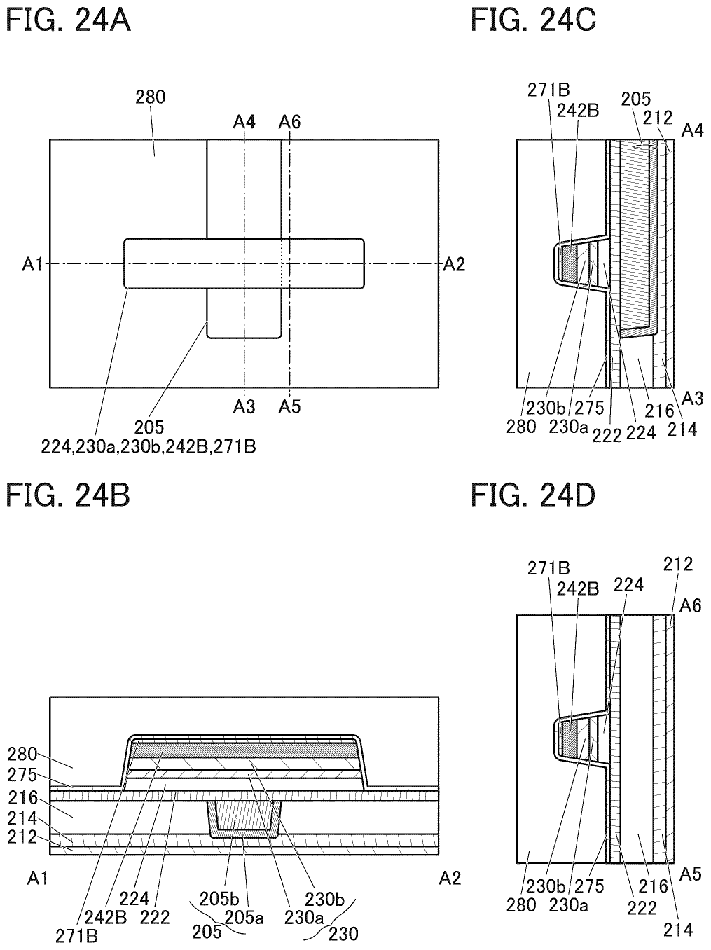

Next, the insulator 275 is formed to cover the insulator 224, the oxide 230a, the oxide 230b, the conductive layer 242B, and the insulating layer 271B (see FIG. 24A to FIG. 24D). Here, it is preferable that the insulator 275 be in contact with the top surface of the insulator 222 and the side surface of the insulator 224. The insulator 275 can be formed by a sputtering method, a CVD method, an MBE method, a PLD method, an ALD method, or the like. As the insulator 275, an insulating film having a function of inhibiting passage of oxygen is preferably used. For example, a film of silicon nitride is formed as the insulator 275 by an ALD method. Alternatively, as the insulator 275, a film of aluminum oxide is formed by a sputtering method, and a film of silicon nitride is formed thereover by a PEALD method. When the insulator 275 has such a stacked-layer structure, the function of inhibiting diffusion of oxygen and impurities such as water and hydrogen is improved in some cases.

In this manner, the insulator 224, the oxide 230a, the oxide 230b, and the conductive layer 242B can be covered with the insulator 275 and the insulating layer 271B, which have a function of inhibiting diffusion of oxygen. This can reduce direct diffusion of oxygen from the insulator 280 into the insulator 224, the oxide 230a, the oxide 230b, and the conductive layer 242B in a later step.

Next, an insulating film to be the insulator 280 is formed over the insulator 275. The insulating film can be formed by a sputtering method, a CVD method, an MBE method, a PLD method, an ALD method, or the like. A silicon oxide film is formed by a sputtering method as the insulating film, for example. When the insulating film is formed by a sputtering method in an oxygen-containing atmosphere, the insulator 280 including excess oxygen can be formed. By using a sputtering method that does not need to use a molecule containing hydrogen as a film formation gas, the hydrogen concentration in the insulator 280 can be reduced. Note that heat treatment may be performed before the formation of the insulating film. The heat treatment may be performed under reduced pressure, and the insulating film may be successively formed without exposure to the air. Such treatment can remove moisture and hydrogen adsorbed onto the surface of the insulator 275 and the like, and further can reduce the moisture concentration and the hydrogen concentration in the oxide 230a, the oxide 230b, and the insulator 224. For the heat treatment, the above heat treatment conditions can be used.

Next, the insulating film to be the insulator 280 is subjected to CMP treatment, so that the insulator 280 with a flat top surface is formed (see FIG. 24A to FIG. 24D). Note that, for example, a film of silicon nitride may be formed over the insulator 280 by a sputtering method and CMP treatment may be performed on the silicon nitride until the insulator 280 is reached.

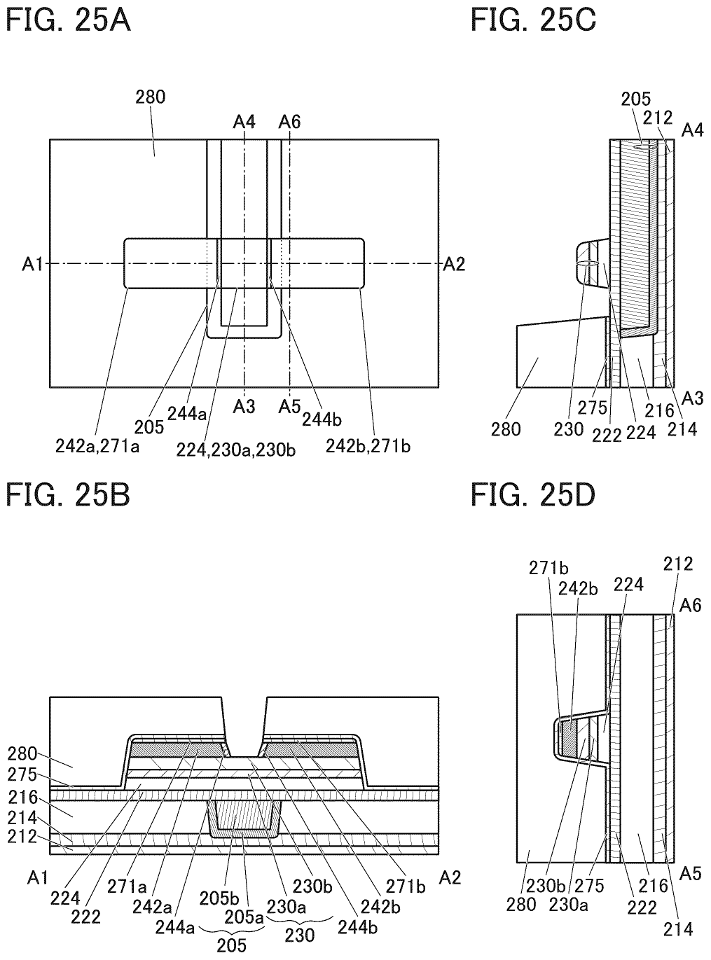

Then, part of the insulator 280, part of the insulator 275, part of the insulating layer 271B, and part of the conductive layer 242B are processed to form an opening reaching the oxide 230b. The opening is preferably formed to overlap with the conductor 205. The insulator 271a, the insulator 271b, the conductor 242a, and the conductor 242b are formed through the formation of the opening (see FIG. 25A to FIG. 25D).

Here, as illustrated in FIG. 25B and FIG. 25C, the side surfaces of the insulator 280, the insulator 275, the insulator 271, and the conductor 242 may have tapered shapes. The taper angle of the insulator 280 is larger than that of the conductor 242 in some cases. Although not illustrated in FIG. 25A to FIG. 25C, the upper portion of the oxide 230b is removed in some cases when the opening is formed. When part of the oxide 230b is removed, a groove portion is sometimes formed in the oxide 230b.

The part of the insulator 280, the part of the insulator 275, the part of the insulating layer 271B, and the part of the conductive layer 242B can be processed by a dry etching method or a wet etching method. Processing by a dry etching method is suitable for microfabrication. The processing may be performed under different conditions. For example, the part of the insulator 280 may be processed by a dry etching method, the part of the insulator 275 and the part of the insulating layer 271B may be processed by a wet etching method, and the part of the conductive layer 242B may be processed by a dry etching method.

In forming the above opening, the side surface of the conductor 242a is oxidized to form the insulator 244a in some cases. Furthermore, the side surface of the conductor 242b is oxidized to form the insulator 244b in some cases. Note that the lengths of the insulator 244a and the insulator 244b in the channel length direction change depending on the processing conditions for forming the opening.

A dry etching apparatus used for forming the conductor 242a and the conductor 242b has a function of eliminating static electricity accumulated on a substrate during etching. That is, plasma treatment is performed with power lower than that in the formation of the conductor 242a and the conductor 242b after the etching treatment for forming the conductor 242a and the conductor 242b is completed, whereby static electricity accumulated on the substrate is eliminated. This plasma treatment is referred to as static neutralization plasma treatment. For example, in the case where nitrogen is used in the static neutralization plasma treatment, the lengths of the insulator 244a and the insulator 244b in the channel length direction tend to be smaller than those in the case where oxygen is used in the static neutralization plasma treatment.

Here, impurities are attached onto the side surface of the oxide 230a, the top surface and the side surface of the oxide 230b, the side surface of the conductor 242, the side surface of the insulator 280, and the like or the impurities might be diffused thereinto in some cases. A step of removing such impurities may be performed. In addition, a damaged region might be formed on the surface of the oxide 230b by the above dry etching. Such a damaged region may be removed. The impurities come from components included in the insulator 280, the insulator 275, part of the insulating layer 271B, and the conductive layer 242B; components included in a member of an apparatus used to form the opening; and components contained in a gas or a liquid used for etching, for instance. Examples of the impurities include hafnium, silicon, tantalum, fluorine, and chlorine.

In particular, impurities such as silicon might reduce the crystallinity of the oxide 230b. Thus, it is preferable that impurities such as silicon be removed from the surface of the oxide 230b and the vicinity thereof. The concentration of the impurities is preferably reduced. For example, the concentration of silicon atoms at the surface of the oxide 230b and the vicinity thereof is lower than or equal to 5.0 atomic %, preferably lower than or equal to 2.0 atomic %, further preferably lower than or equal to 1.5 atomic %, still further preferably lower than or equal to 1.0 atomic %, and yet still further preferably lower than 0.3 atomic %.

Note that since the density of a crystal structure is reduced in a low-crystallinity region of the oxide 230b due to impurities such as silicon, a large amount of VoH is formed; thus, the transistor is likely to be normally on. Hence, the low-crystallinity region of the oxide 230b is preferably reduced or removed.

In contrast, the oxide 230b preferably has a layered CAAC structure. In particular, the CAAC structure preferably reaches a lower end portion of a drain in the oxide 230b. Here, in the transistor 200, the conductor 242a or the conductor 242b, and its vicinity function as a drain. In other words, the oxide 230b in the vicinity of the lower end portion of the conductor 242a or the conductor 242b preferably has a CAAC structure. In this manner, the low-crystallinity region of the oxide 230b is removed and the CAAC structure is formed also in the end portion of the drain, which significantly affects the drain breakdown voltage, so that a variation in electrical characteristics of the transistor 200 can be further suppressed. In addition, the reliability of the transistor 200 can be improved.

In order to remove impurities and the like attached to the surface of the oxide 230b in the above etching step, cleaning treatment is performed. Examples of the cleaning method include wet cleaning using a cleaning solution or the like (which can also be referred to as wet etching treatment), plasma treatment using plasma, and cleaning by heat treatment, and any of these cleanings may be performed in appropriate combination. Note that the cleaning treatment sometimes makes the groove portion deeper.

The wet cleaning may be performed using an aqueous solution in which ammonia water, oxalic acid, phosphoric acid, hydrofluoric acid, or the like is diluted with carbonated water or pure water; pure water; carbonated water; or the like. Alternatively, ultrasonic cleaning using such an aqueous solution, pure water, or carbonated water may be performed. Alternatively, such cleaning methods may be performed in combination as appropriate.

Note that in this specification and the like, in some cases, an aqueous solution in which hydrofluoric acid is diluted with pure water is referred to as diluted hydrofluoric acid, and an aqueous solution in which ammonia water is diluted with pure water is referred to as diluted ammonia water. The concentration, temperature, and the like of the aqueous solution are adjusted as appropriate in accordance with an impurity to be removed, the structure of a semiconductor device to be cleaned, or the like. The concentration of ammonia in the diluted ammonia water is higher than or equal to 0.01% and lower than or equal to 5%, preferably higher than or equal to 0.1% and lower than or equal to 0.5%. The concentration of hydrogen fluoride in the diluted hydrofluoric acid is higher than or equal to 0.01 ppm and lower than or equal to 100 ppm, preferably higher than or equal to 0.1 ppm and lower than or equal to 10 ppm.

For the ultrasonic cleaning, a frequency higher than or equal to 200 kHz is preferable, and a frequency higher than or equal to 900 kHz is further preferable. Damage to the oxide 230b and the like can be reduced with this frequency.

The cleaning treatment may be performed a plurality of times, and the cleaning solution may be changed in every cleaning treatment. For example, first cleaning treatment may use diluted hydrofluoric acid or diluted ammonia water, and second cleaning treatment may use pure water or carbonated water.

As the cleaning treatment in this embodiment, wet cleaning using diluted ammonia water is performed. The cleaning treatment can remove impurities that are attached onto the surfaces of the oxide 230a, the oxide 230b, and the like or diffused into the oxide 230a, the oxide 230b, and the like. Removal of the low-crystallinity region can increase the crystallinity of the oxide 230b.

After the etching or the cleaning, heat treatment may be performed. The heat treatment is performed at higher than or equal to 100° C. and lower than or equal to 450° C., preferably higher than or equal to 350° C. and lower than or equal to 400° C. Note that the heat treatment is performed in a nitrogen gas or inert gas atmosphere, or an atmosphere containing an oxidizing gas at higher than or equal to 10 ppm, higher than or equal to 1%, or higher than or equal to 10%. For example, the heat treatment is preferably performed in an oxygen atmosphere. Accordingly, oxygen can be supplied to the oxide 230a and the oxide 230b to reduce oxygen vacancies. In addition, the crystallinity of the oxide 230b can be improved by such heat treatment. The heat treatment may be performed under reduced pressure. Alternatively, heat treatment may be performed in an oxygen atmosphere, and then heat treatment may be successively performed in a nitrogen atmosphere without exposure to the air.

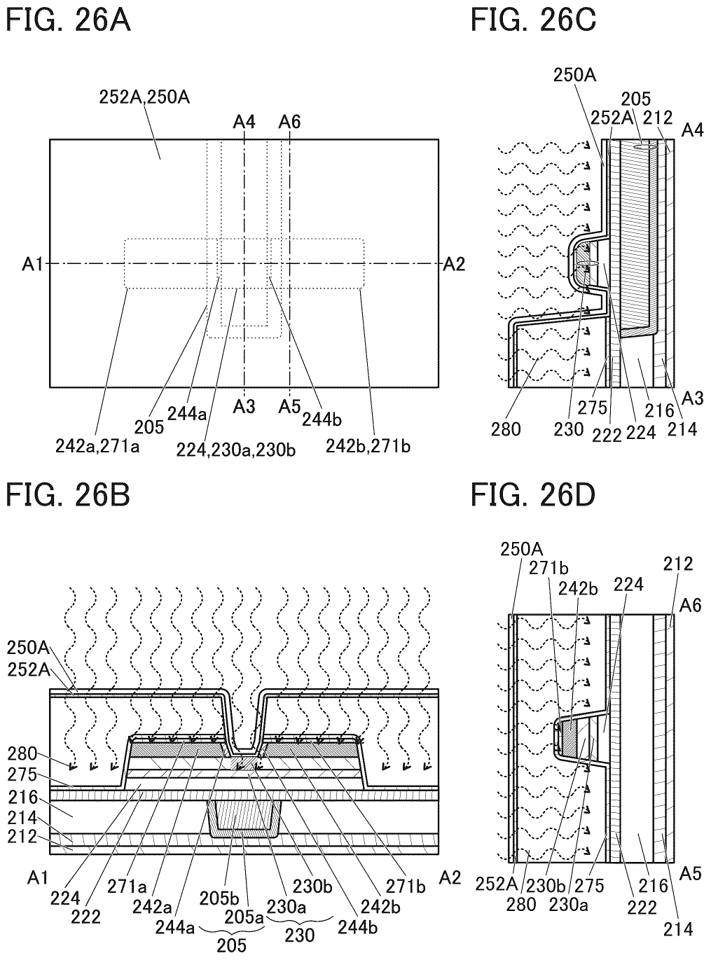

Next, an insulating film 252A is formed (see FIG. 26A to FIG. 26D). The insulating film 252A can be formed by a sputtering method, a CVD method, an MBE method, a PLD method, an ALD method, or the like. The insulating film 252A is preferably formed by an ALD method. As described above, it is preferable to form the insulating film 252A to have a small thickness, and a variation in the film thickness needs to be reduced. Since an ALD method is a film formation method in which a precursor and a reactant (e.g., oxidizer) are alternately introduced and the film thickness can be adjusted with the number of repetition times of the cycle, accurate control of the film thickness is possible. Furthermore, as illustrated in FIG. 26B and FIG. 26C, the insulating film 252A needs to be formed on the bottom surface and the side surface of the opening formed in the insulator 280 and the like so as to have good coverage. In particular, it is preferable that the insulating film 252A be formed on the top surface and the side surface of the oxide 230 and the side surface of the conductor 242, with good coverage. An atomic layer can be deposited one by one on the bottom surface and the side surface of the opening, whereby the insulating film 252A can be formed in the opening with good coverage.

When the insulating film 252A is formed by an ALD method, ozone (O₃), oxygen (O₂), water (H₂O), or the like can be used as the oxidizer. When an oxidizer without hydrogen, such as ozone (O₃) or oxygen (O₂), is used, the amount of hydrogen diffusing into the oxide 230b can be reduced.

In this embodiment, a film of aluminum oxide is formed as the insulating film 252A by a thermal ALD method.

Note that the lengths of the insulator 244a and the insulator 244b in the channel length direction are increased by the formation of the insulating film 252A in some cases. Note that in the case where the insulator 244a and the insulator 244b are not formed before the formation of the insulating film 252A, the side surface of the conductor 242a is oxidized during the formation of the insulating film 252A to form the insulator 244a in some cases. Furthermore, the side surface of the conductor 242b is oxidized to form the insulator 244b in some cases.

Next, an insulating film 250A is formed (see FIG. 26A to FIG. 26D). Heat treatment may be performed before the formation of the insulating film 250A; the heat treatment may be performed under reduced pressure, and the insulating film 250A may be successively formed without exposure to the air. The heat treatment is preferably performed in an oxygen-containing atmosphere. Such treatment can remove moisture and hydrogen adsorbed onto the surface of the insulating film 252A and the like, and further can reduce the moisture concentration and the hydrogen concentration in the oxide 230a and the oxide 230b. The heat treatment is preferably performed at a temperature higher than or equal to 100° C. and lower than or equal to 400° C.

The insulating film 250A can be formed by a sputtering method, a CVD method, a PECVD method, an MBE method, a PLD method, an ALD method, or the like. The insulating film 250A is preferably formed by a film formation method using a gas in which hydrogen atoms are reduced or removed. This can reduce the hydrogen concentration in the insulating film 250A. The hydrogen concentration in the insulating film 250A is preferably reduced because the insulating film 250A becomes the insulator 250 that faces the oxide 230b with the insulator 252 with a small thickness therebetween, in a later step.

In this embodiment, a film of silicon oxynitride is formed as the insulating film 250A by a PECVD method.

Note that the lengths of the insulator 244a and the insulator 244b in the channel length direction are increased by the formation of the insulating film 250A in some cases. Note that in the case where the insulator 244a and the insulator 244b are not formed before the formation of the insulating film 250A, the side surface of the conductor 242a is oxidized during the formation of the insulating film 250A to form the insulator 244a in some cases. Furthermore, the side surface of the conductor 242b is oxidized to form the insulator 244b in some cases.

Next, it is preferable to perform microwave treatment in an atmosphere containing oxygen. Here, the microwave treatment refers to, for example, treatment using an apparatus including a power source that generates high-density plasma with the use of a microwave. In this specification and the like, a microwave refers to an electromagnetic wave having a frequency higher than or equal to 300 MHz and lower than or equal to 300 GHz.

Dotted lines in FIG. 26B to FIG. 26D indicate high-frequency waves such as microwaves or RF, oxygen plasma, oxygen radicals, or the like. The microwave treatment is preferably performed with a microwave treatment apparatus including a power source for generating high-density plasma using microwaves, for example. Here, the frequency of the microwave treatment apparatus is set to higher than or equal to 300 MHz and lower than or equal to 300 GHz, preferably higher than or equal to 2.4 GHz and lower than or equal to 2.5 GHz, for example, 2.45 GHz. Oxygen radicals at a high density can be generated with high-density plasma. The electric power of the power source that applies microwaves of the microwave treatment apparatus is set to higher than or equal to 1000 W and lower than or equal to 10000 W, preferably higher than or equal to 2000 W and lower than or equal to 5000 W. The microwave treatment apparatus may be provided with a power source that applies RF to the substrate side. Furthermore, application of RF to the substrate side allows oxygen ions generated by the high-density plasma to be introduced into the oxide 230b efficiently.

The microwave treatment is preferably performed under reduced pressure, and the pressure is set to higher than or equal to 10 Pa and lower than or equal to 1000 Pa, preferably higher than or equal to 300 Pa and lower than or equal to 700 Pa. The treatment temperature is set to lower than or equal to 750° C., preferably lower than or equal to 500° C., and is approximately 250° C., for example. The oxygen plasma treatment may be followed successively by heat treatment without exposure to air. For example, the temperature is set to higher than or equal to 100° C. and lower than or equal to 750° C., preferably higher than or equal to 300° C. and lower than or equal to 500° C.

Furthermore, the microwave treatment is performed using an oxygen gas and an argon gas, for example. Here, the oxygen flow rate ratio (O₂/(O₂+Ar)) is higher than 0% and lower than or equal to 100%, preferably higher than 0% and lower than or equal to 50%, further preferably higher than or equal to 10% and lower than or equal to 40%, or still further preferably higher than or equal to 10% and lower than or equal to 30%. The carrier concentration in the region 230bc can be reduced by thus performing the microwave treatment in an atmosphere containing oxygen. In addition, the carrier concentrations in the region 230ba and the region 230bb can be prevented from being excessively reduced by preventing an excess amount of oxygen from being introduced into the chamber in the microwave treatment.

As illustrated in FIG. 26B to FIG. 26D, the microwave treatment in an oxygen-containing atmosphere can convert an oxygen gas into plasma using a high-frequency wave such as a microwave or RF, and apply the oxygen plasma to a region of the oxide 230b which is between the conductor 242a and the conductor 242b. At this time, the region 230bc can also be irradiated with the high-frequency wave such as a microwave or RF. In other words, the high-frequency wave such as a microwave or RF, the oxygen plasma, or the like can be applied to the region 230bc illustrated in FIG. 15. By the effect of the plasma, the microwave, or the like, VoH in the region 230bc can be divided into an oxygen vacancy (Vo) and hydrogen (H). That is, the reaction “VoH→H+Vo” occurs in the region 230bc, so that VoH included in the region 230bc can be reduced. In addition, oxygen radicals generated by the oxygen plasma or oxygen included in the insulator 250 can be supplied to oxygen vacancies in the region 230bc, thereby reducing oxygen vacancies in the region 230bc. That is, the reaction “Vo+O→null” can be promoted. In addition, hydrogen in the region 230bc is drifted (diffused) into distortion formed in the region 230ba and the region 230bb by the effect of compressive stress of the conductor 242a and the conductor 242b. Thus, the hydrogen concentration in the region 230bc can be reduced. Accordingly, VoH, oxygen vacancies, and the hydrogen concentration in the region 230bc can be reduced to lower the carrier concentration. In this manner, the region 230bc can be an i-type or substantially i-type region.

The conductor 242a and the conductor 242b are respectively provided over the region 230ba and the region 230bb illustrated in FIG. 15. Here, the conductor 242 preferably functions as a blocking film preventing the effect caused by the high-frequency wave such as a microwave or RF, the oxygen plasma, or the like in the microwave treatment in an atmosphere containing oxygen. Therefore, the conductor 242 preferably has a function of blocking an electromagnetic wave of higher than or equal to 300 MHz and lower than or equal to 300 GHz, for example, higher than or equal to 2.4 GHz and lower than or equal to 2.5 GHz.

As illustrated in FIG. 26B to FIG. 26D, in the microwave treatment in an oxygen-containing atmosphere, the effect of the high-frequency wave such as a microwave or RF, the oxygen plasma, or the like is blocked by the conductor 242a and the conductor 242b and does not affect the region 230ba or the region 230bb. In addition, the above effect can be reduced by the insulator 271 and the insulator 280 that are provided to cover the oxide 230b and the conductor 242. In the region 230ba and the region 230bb, oxygen vacancies and hydrogen diffused from the region 230bc react with each other to form VoH. Hence, a reduction in VoH and supply of an excess amount of oxygen do not occur in the region 230ba or the region 230bb in the microwave treatment, preventing a decrease in carrier concentration. In this manner, the region 230ba and the region 230bb can be n-type regions.

The effect of the high-frequency wave such as a microwave or RF, the oxygen plasma, or the like is reduced but not blocked by the insulator 244a and the insulator 244b as much as by the conductor 242a and the conductor 242b. Accordingly, the effect on the region 230bd and the region 230be is weaker than that on the region 230bc and stronger than that on the region 230ba and the region 230bb. Thus, the carrier concentrations of the region 230bd and the region 230be due to the microwave treatment are lower than those of the region 230ba and the region 230bb and are not as low as that of the region 230bc.

Furthermore, the insulator 252 having a barrier property against oxygen is provided in contact with the side surfaces of the conductor 242a and the conductor 242b. This can inhibit supply of an excess amount of oxygen to the side surfaces of the conductor 242a and the conductor 242b by the microwave treatment.

Furthermore, the insulator 275 having a barrier property against oxygen is provided above the conductor 242a and the conductor 242b and in contact with the side surface of the conductor 242a and the side surface of the conductor 242b. This can inhibit oxidation of the top surfaces and the side surfaces of the conductor 242a and the conductor 242b by the microwave treatment. As illustrated in FIG. 26D, the insulator 275 is in contact with the side surface of the oxide 230b in the region overlapping with the conductor 242a or the conductor 242b. Thus, the insulator 275 can inhibit supply of an excess amount of oxygen to the side surface of the oxide 230b in the region, preventing a decrease in carrier concentration.

Microwave treatment is preferably performed in an oxygen-containing atmosphere after the formation of the insulating film 252A or after the formation of the insulating film 250A. By performing the microwave treatment in an oxygen-containing atmosphere through the insulating film 252A or the insulating film 250A in such a manner, oxygen can be efficiently implanted into the region 230bc. In addition, the insulating film 252A is placed in contact with the surface of the region 230bc, thereby inhibiting more than a necessary amount of oxygen from being implanted into the region 230bc. Furthermore, the insulating film 252A is placed in the vicinity of the side surface of the conductor 242, thereby inhibiting excessive oxidation of the side surface of the conductor 242.

The oxygen implanted into the region 230bc is in any of a variety of forms such as an oxygen atom, an oxygen molecule, and an oxygen ion (a charged oxygen atom or a charged oxygen molecule), an oxygen radical (also referred to as O radical, which is an oxygen atom, an oxygen molecule, or an oxygen ion having an unpaired electron). Note that the oxygen implanted into the region 230bc is in any one or more of the above forms, and is particularly suitably an oxygen radical.

Furthermore, the film quality of the insulator 252 and the insulator 250 can be improved, leading to higher reliability of the transistor 200.

In the above manner, oxygen vacancies and VoH can be selectively removed from the region 230bc in the oxide semiconductor, whereby the region 230bc can be an i-type or substantially i-type region. Furthermore, supply of an excess amount of oxygen to the region 230ba and the region 230bb functioning as the source region and the drain region can be inhibited, and the state of the n-type regions before the microwave treatment is performed can be maintained. Moreover, the region 230bd and the region 230be can function as LDD (Lightly Doped Drain) regions. In that case, the transistor 200 can have a reduced off-state current and higher breakdown voltage (higher reliability). Moreover, a change in the electrical characteristics of the transistor 200 can be inhibited, and thus a variation in the electrical characteristics of the transistors 200 in the substrate plane can be inhibited. Note that the LDD region may be referred to as a junction region or an offset region.

When the region 230bd and the region 230be function as the LDD regions, the drain electric field can be relieved. When the length D1 is in any of the above ranges, the drain electric field can be relieved. Accordingly, the transistor can achieve favorable switching characteristics even when having a short channel length. In addition, effects such as a reduced S value and increased (positively shifted) Vth are achieved.

The microwave treatment is a significantly effective method for making the region 230bc i-type or substantially i-type and making the region 230ba and the region 230bb n-type. With the microwave treatment, the transistor 200 can be manufactured to be minute with a gate length of 6 nm or even 3 nm.

In the microwave treatment, thermal energy is directly transmitted to the oxide 230b in some cases owing to an electromagnetic interaction between the microwave and a molecule in the oxide 230b. The oxide 230b may be heated by this thermal energy. Such heat treatment is sometimes referred to as microwave annealing. When microwave treatment is performed in an atmosphere containing oxygen, an effect equivalent to that of oxygen annealing is sometimes obtained. That is, oxygen vacancies can be repaired (nullified) by the microwave annealing. In the case where hydrogen is included in the oxide 230b, it is probable that the thermal energy is transmitted to the hydrogen in the oxide 230b and the hydrogen activated by the energy is released from the oxide 230b.

Note that the lengths of the insulator 244a and the insulator 244b in the channel length direction are increased by the microwave treatment in some cases. Note that in the case where the insulator 244a and the insulator 244b are not formed before the microwave treatment, the side surface of the conductor 242a is oxidized during the microwave treatment to form the insulator 244a in some cases. Furthermore, the side surface of the conductor 242b is oxidized to form the insulator 244b in some cases.

Appropriate adjustment of the formation condition of the insulating film 250A, the condition of the microwave treatment performed in an oxygen-containing atmosphere, the amount of oxygen added to the insulator 280 by the formation of the insulator 282, and the like can reduce oxygen vacancies and VoH in the region 230bc and inhibit supply of excess oxygen to the region 230ba and the region 230bb in some cases. In such a case, the insulator 252 is not necessarily provided. Accordingly, the manufacturing process of the semiconductor device can be simplified, and the productivity can be improved.

The microwave treatment may be performed after the formation of the insulating film 252A. Alternatively, microwave treatment may be performed after the formation of the insulating film 252A, without the microwave treatment performed after the formation of the insulating film 250A.

In the case where the insulator 250 has a stacked-layer structure of two layers as illustrated in FIG. 20A, an insulating film to be the insulator 250b is formed after the formation of the above insulating film 250A. The insulating film to be the insulator 250b can be formed by a sputtering method, a CVD method, an MBE method, a PLD method, an ALD method, or the like. The insulating film to be the insulator 250b is preferably formed using an insulator having a function of inhibiting diffusion of oxygen. With such a structure, oxygen included in the insulator 250a can be inhibited from diffusing into the conductor 260. That is, a reduction in the amount of oxygen supplied to the oxide 230 can be inhibited. In addition, oxidation of the conductor 260 due to oxygen included in the insulator 250a can be inhibited. The insulating film to be the insulator 250b can be provided using a material similar to that for the insulator 222. For example, a film of hafnium oxide is formed by a thermal ALD method as the insulating film to be the insulator 250b.

Note that in the case where the insulator 250 has a stacked-layer structure of two layers as illustrated in FIG. 20A, the microwave treatment is preferably performed after the formation of the insulating film 250A. Alternatively, microwave treatment may be performed after the formation of the insulating film to be the insulator 250b, without the microwave treatment performed after the formation of the insulating film 250A.

After the microwave treatment, heat treatment may be performed with the reduced pressure being maintained. Such treatment enables hydrogen in the oxide 230b and the oxide 230a to be removed efficiently. In addition, hydrogen in the insulating film formed before the microwave treatment among the insulating film 252A, the insulating film 250A, and the insulating film to be the insulator 250b can be removed efficiently. Part of hydrogen is gettered by the conductor 242a and the conductor 242b in some cases. Alternatively, the step of performing microwave treatment and then performing heat treatment with the reduced pressure being maintained may be repeated a plurality of cycles. The repetition of the heat treatment enables hydrogen in the oxide 230b and the oxide 230a to be removed more efficiently. In addition, hydrogen in the insulating film formed before the microwave treatment among the insulating film 252A, the insulating film 250A, and the insulating film to be the insulator 250b can be removed more efficiently. Note that the temperature of the heat treatment is preferably higher than or equal to 300° C. and lower than or equal to 500° C. The microwave treatment, i.e., the microwave annealing may also serve as the heat treatment. The heat treatment is not necessarily performed in the case where the oxide 230b and the like are adequately heated by the microwave annealing.

Furthermore, the microwave treatment improves the film quality of one or more of the insulating film 252A, the insulating film 250A, and the insulating film to be the insulator 250b, thereby inhibiting diffusion of hydrogen, water, impurities, and the like. Accordingly, hydrogen, water, impurities, and the like can be inhibited from diffusing into the oxide 230b, the oxide 230a, and the like through the insulator 252 in a later step such as formation of a conductive film to be the conductor 260 or later treatment such as heat treatment.

Note that through the foregoing steps, the insulator 244a is formed on the side surface of the conductor 242a, and the insulator 244b is formed on the side surface of the conductor 242b. In other words, the insulator 244a and the insulator 244b are formed in any one of the step of processing part of the insulator 280 and the like to form the opening reaching the oxide 230b, the step of forming the insulating film 252A, the step of forming the insulating film 250A, and the step of performing the microwave treatment. That is, the insulator 244a and the insulator 244b are formed in a self-aligned manner in the manufacturing process of the semiconductor device.

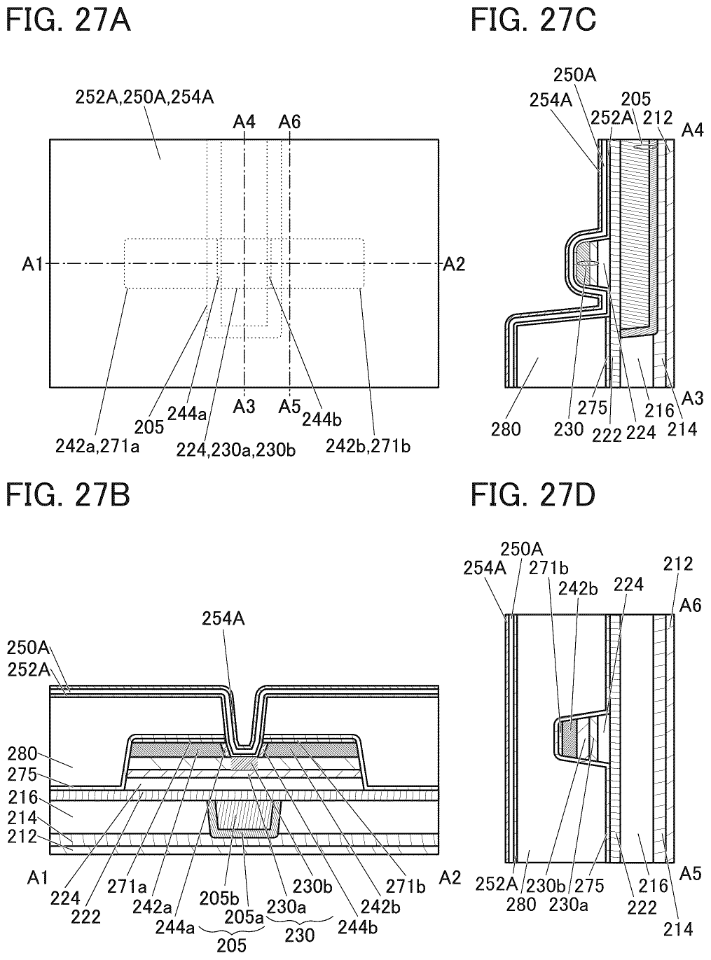

Next, an insulating film 254A is formed (see FIG. 27A to FIG. 27D). The insulating film 254A can be formed by a sputtering method, a CVD method, an MBE method, a PLD method, an ALD method, or the like. Like the insulating film 252A, the insulating film 254A is preferably formed by an ALD method. By an ALD method, the insulating film 254A can be formed to have a small thickness and good coverage. In this embodiment, as the insulating film 254A, a silicon nitride film is formed by a PEALD method.

Next, a conductive film to be the conductor 260a and a conductive film to be the conductor 260b are formed in this order. The conductive film to be the conductor 260a and the conductive film to be the conductor 260b can be formed by a sputtering method, a CVD method, an MBE method, a PLD method, an ALD method, or the like. In this embodiment, a titanium nitride film is formed by an ALD method as the conductive film to be the conductor 260a, and a tungsten film is formed by a CVD method as the conductive film to be the conductor 260b.

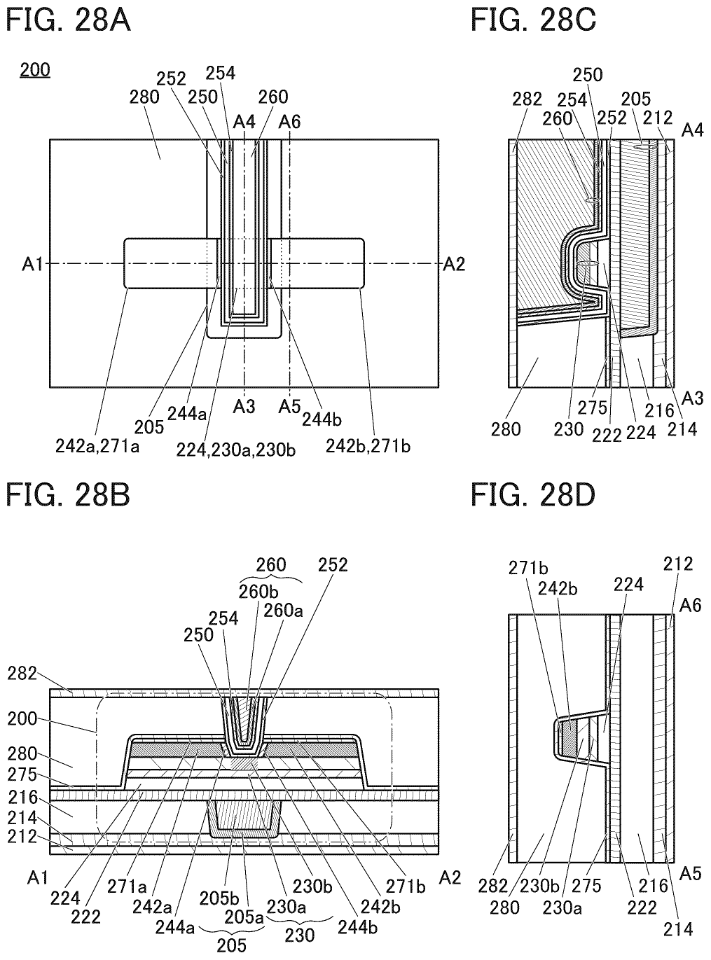

Then, the insulating film 252A, the insulating film 250A, the insulating film 254A, the conductive film to be the conductor 260a, and the conductive film to be the conductor 260b are polished by CMP treatment until the insulator 280 is exposed, whereby the insulator 252, the insulator 250, the insulator 254, and the conductor 260 (the conductor 260a and the conductor 260b) are formed (see FIG. 28A to FIG. 28D). Accordingly, the insulator 252 is placed to cover the opening reaching the oxide 230b. The conductor 260 is placed to fill the opening with the insulator 252, the insulator 250, and the insulator 254 therebetween.

Then, heat treatment may be performed under conditions similar to those for the above heat treatment. In this embodiment, treatment is performed at 400° C. for one hour in a nitrogen atmosphere. The heat treatment can reduce the moisture concentration and the hydrogen concentration in the insulator 250 and the insulator 280. After the heat treatment, the insulator 282 may be successively formed without exposure to the air.

Next, the insulator 282 is formed over the insulator 252, the insulator 250, the insulator 254, the conductor 260, and the insulator 280 (see FIG. 28A to FIG. 28D). The insulator 282 can be formed by a sputtering method, a CVD method, an MBE method, a PLD method, an ALD method, or the like. The insulator 282 is preferably formed by a sputtering method. By using a sputtering method that does not need to use a molecule containing hydrogen as a film formation gas, the hydrogen concentration in the insulator 282 can be reduced.

In this embodiment, as the insulator 282, a film of aluminum oxide is formed by a pulsed DC sputtering method using an aluminum target in an atmosphere containing an oxygen gas. The RF power applied to the substrate is lower than or equal to 1.86 W/cm², preferably higher than or equal to 0 W/cm² and lower than or equal to 0.62 W/cm². With low RF power, the amount of oxygen implanted into the insulator 280 can be reduced. Alternatively, the insulator 282 may be formed to have a stacked-layer structure of two layers. In that case, the lower layer of the insulator 282 is formed with an RF power of 0 W/cm² applied to the substrate, and the upper layer of the insulator 282 is formed with an RF power of 0.62 W/cm² applied to the substrate.

When the insulator 282 is formed by a sputtering method in an oxygen-containing atmosphere, oxygen can be added to the insulator 280 during the formation. Thus, excess oxygen can be included in the insulator 280. At this time, the insulator 282 is preferably formed while the substrate is being heated.

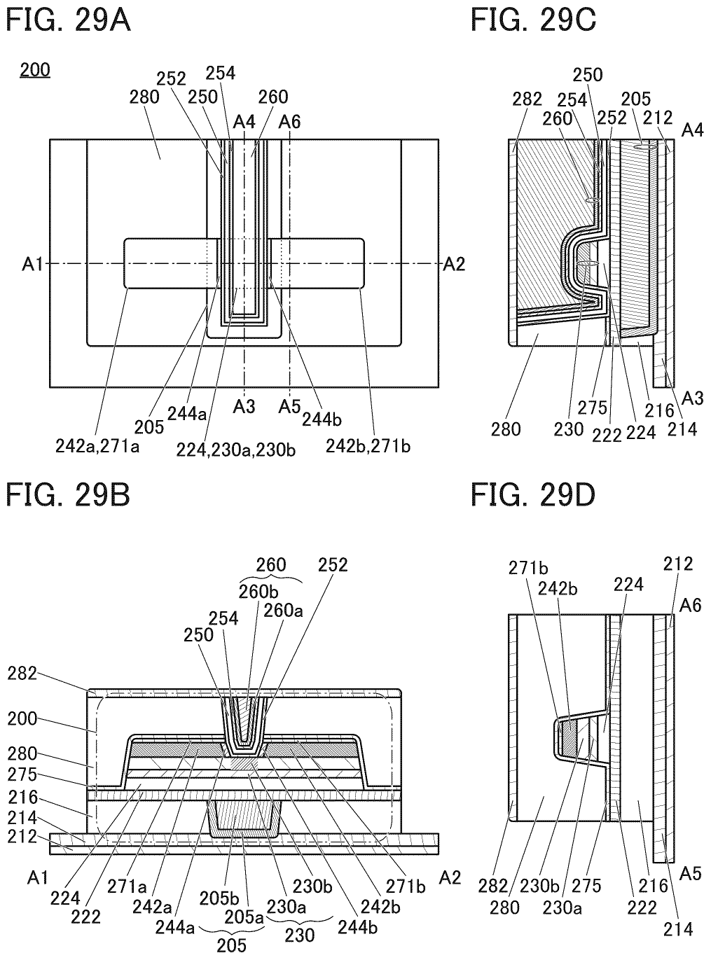

Next, an etching mask is formed over the insulator 282 by a lithography method, and part of the insulator 282, part of the insulator 280, part of the insulator 275, part of the insulator 222, and part of the insulator 216 are processed until the top surface of the insulator 214 is exposed (see FIG. 29A to FIG. 29D). Wet etching may be used for the processing; however, dry etching is preferably used for microfabrication.

Next, heat treatment may be performed. The heat treatment is performed at higher than or equal to 250° C. and lower than or equal to 650° C., preferably higher than or equal to 350° C. and lower than or equal to 600° C. The heat treatment is preferably performed at a temperature lower than that of the heat treatment performed after the formation of the oxide film 230B. Note that the heat treatment is performed in a nitrogen gas or inert gas atmosphere. By the heat treatment, part of oxygen added to the insulator 280 is diffused into the oxide 230 through the insulator 250 and the like.

By the heat treatment, oxygen included in the insulator 280 and hydrogen bonded to the oxygen can be released to the outside from the side surface of the insulator 280 formed by the above processing. Note that the hydrogen bonded to oxygen is released as water. Thus, excessive oxygen and hydrogen included in the insulator 280 can be reduced.

In a region of the oxide 230 that overlaps with the conductor 260, the insulator 252 is provided to be in contact with the top surface and the side surface of the oxide 230. Since the insulator 252 has a barrier property against oxygen, diffusion of an excess amount of oxygen into the oxide 230 can be reduced. Thus, oxygen can be supplied to the region 230bc and the vicinity thereof such that an excess amount of oxygen is not supplied thereto. Accordingly, oxygen vacancies and VoH in the region 230bc can be reduced, and excess oxygen can be inhibited from being supplied to the region 230ba and the region 230bb. Thus, the transistor 200 can have favorable electrical characteristics and higher reliability.

On the other hand, in the case where the transistors 200 are integrated at a high density, the volume of the insulator 280 per the transistor 200 becomes excessively small in some cases. In this case, the amount of oxygen diffusing into the oxide 230 in the heat treatment becomes significantly small. When the oxide 230 is heated while being in contact with the oxide insulator (e.g., the insulator 250) which does not include sufficient oxygen, oxygen included in the oxide 230 might be released. However, in the transistor 200 described in this embodiment, the insulator 252 is provided in contact with the top surface and the side surface of the oxide 230 in the region of the oxide 230 that overlaps with the conductor 260. Since the insulator 252 has a barrier property against oxygen, release of oxygen from the oxide 230 can be reduced also in the heat treatment. This can inhibit formation of oxygen vacancies and VoH in the region 230bc. Thus, the transistor 200 can have favorable electrical characteristics and higher reliability.

As described above, in either case of a large or small amount of oxygen supplied from the insulator 280 in the semiconductor device according to this embodiment, a transistor having favorable electrical characteristics and favorable reliability can be formed. Thus, a semiconductor device with a reduced variation in electrical characteristics of the transistors 200 in the substrate plane can be provided.

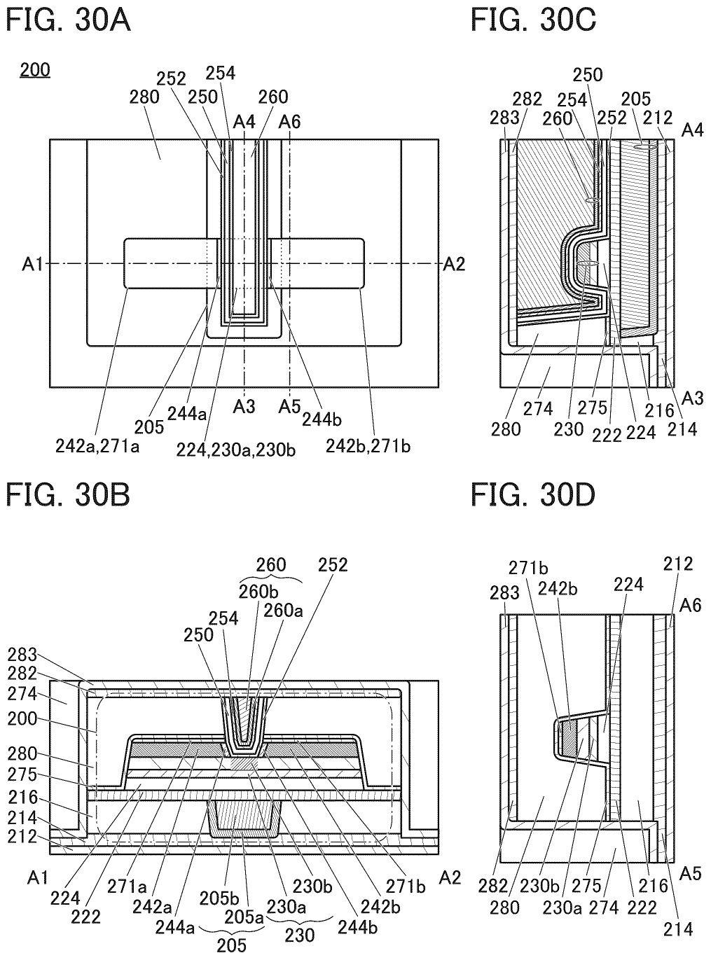

Next, the insulator 283 is formed over the insulator 282 (see FIG. 30A to FIG. 30D). The insulator 283 can be formed by a sputtering method, a CVD method, an MBE method, a PLD method, an ALD method, or the like. The insulator 283 is preferably formed by a sputtering method. By using a sputtering method that does not need to use a molecule containing hydrogen as a film formation gas, the hydrogen concentration in the insulator 283 can be reduced. The insulator 283 may have a multilayer structure. For example, a film of silicon nitride may be formed by a sputtering method, and a film of silicon nitride may be formed over the silicon nitride by an ALD method. Surrounding the transistor 200 by the insulator 283 and the insulator 214 that have a high barrier property can prevent entry of moisture and hydrogen from the outside.

Next, an insulating film to be the insulator 274 is formed over the insulator 283. The insulating film can be formed by a sputtering method, a CVD method, an MBE method, a PLD method, an ALD method, or the like. In this embodiment, a silicon oxide film is formed by a CVD method as the insulating film.

Next, the insulating film to be the insulator 274 is polished by CMP treatment until the insulator 283 is exposed, whereby the top surface of the insulating film is planarized; thus, the insulator 274 is formed (see FIG. 30A to FIG. 30D). The top surface of the insulator 283 is partly removed by the CMP treatment in some cases.

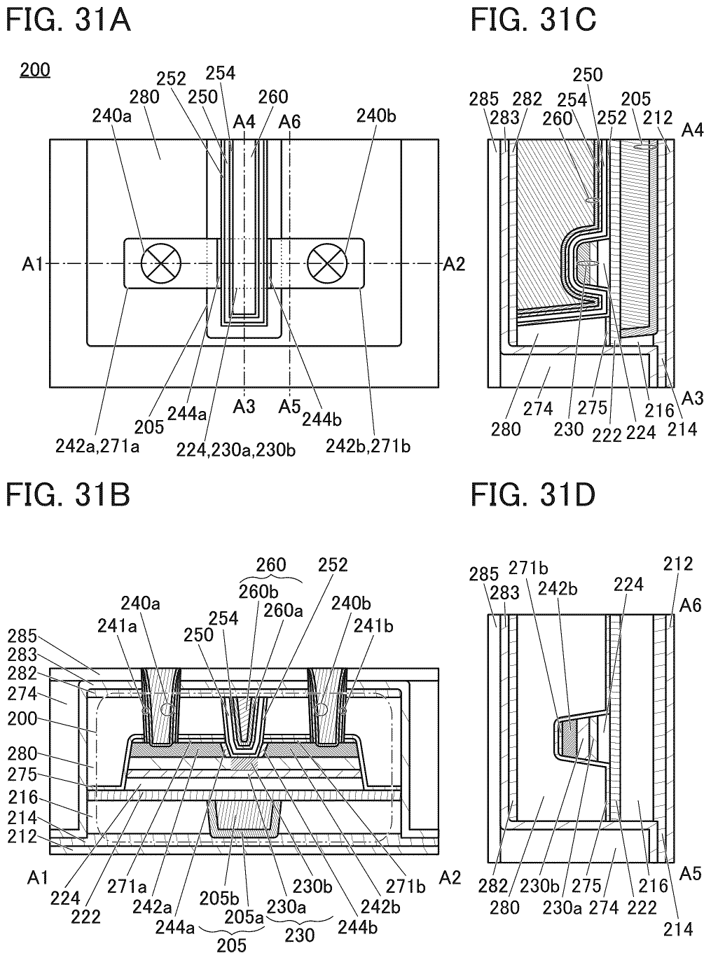

Next, the insulator 285 is formed over the insulator 274 and the insulator 283 (see FIG. 31A to FIG. 31D). The insulator 285 can be formed by a sputtering method, a CVD method, an MBE method, a PLD method, an ALD method, or the like. The insulator 285 is preferably formed by a sputtering method. By using a sputtering method that does not need to use a molecule containing hydrogen as a film formation gas, the hydrogen concentration in the insulator 285 can be reduced.

In this embodiment, as the insulator 285, a film of silicon oxide is formed by a sputtering method.

Subsequently, openings reaching the conductor 242 are formed in the insulator 271, the insulator 275, the insulator 280, the insulator 282, the insulator 283, and the insulator 285 (see FIG. 31A and FIG. 31B). The openings are formed by a lithography method. Note that the openings in the top view in FIG. 31A have a circular shape; however, the shapes of the openings are not limited thereto. For example, the openings in the top view may have a substantially circular shape such as an elliptical shape, a polygonal shape such as a quadrangular shape, or a polygonal shape such as a quadrangular shape with rounded corners.

Next, an insulating film to be the insulator 241a and the insulator 241b is formed, and the insulating film is subjected to anisotropic etching, so that the insulator 241a and the insulator 241b are formed (see FIG. 31B). The insulating film can be formed by a sputtering method, a CVD method, an MBE method, a PLD method, an ALD method, or the like. As the insulating film, an insulating film having a function of inhibiting passage of oxygen is preferably used. For example, preferably, an aluminum oxide film is formed by an ALD method, and a silicon nitride film is formed thereover by a PEALD method. Silicon nitride is preferable because of its high blocking property against hydrogen.

For the anisotropic etching of the insulating film to be the insulator 241a and the insulator 241b, a dry etching method is employed, for example. Providing the insulator 241a and the insulator 241b on the sidewall portions of the openings can inhibit passage of oxygen from the outside and can prevent oxidation of the conductor 240a and the conductor 240b to be formed next. Furthermore, impurities such as water and hydrogen included in the insulator 280 or the like can be prevented from diffusing into the conductor 240a and the conductor 240b.

Next, a conductive film to be the conductor 240a and the conductor 240b is formed. The conductive film desirably has a stacked-layer structure which includes a conductor having a function of inhibiting passage of impurities such as water and hydrogen. For example, a stacked layer of tantalum nitride, titanium nitride, or the like and tungsten, molybdenum, copper, or the like can be employed. The conductive film can be formed by a sputtering method, a CVD method, an MBE method, a PLD method, an ALD method, or the like.

Next, by performing CMP treatment, the conductive film to be the conductor 240a and the conductor 240b is partly removed to expose the top surface of the insulator 285. As a result, the conductive film remains only in the openings, so that the conductor 240a and the conductor 240b having flat top surfaces can be formed (see FIG. 31A to FIG. 31D). Note that the top surface of the insulator 285 is partly removed by the CMP treatment in some cases.

Next, a conductive film to be the conductor 246a and the conductor 246b is formed. The conductive film can be formed by a sputtering method, a CVD method, an MBE method, a PLD method, an ALD method, or the like.

Next, the conductive film to be the conductor 246a and the conductor 246b is processed by a lithography method to form the conductor 246a in contact with the top surface of the conductor 240a and the conductor 246b in contact with the top surface of the conductor 240b. At this time, part of the insulator 285 in a region where the insulator 285 does not overlap with the conductor 246a or the conductor 246b is sometimes removed.

Through the above process, the semiconductor device including the transistor 200 illustrated in FIG. 14A to FIG. 14D can be manufactured. As illustrated in FIG. 21A to FIG. 31D, the transistor 200 can be manufactured with the use of the method for manufacturing the semiconductor device described in this embodiment.

### <Microwave Treatment Apparatus>

A microwave treatment apparatus that can be used for the above method for manufacturing the semiconductor device is described below.

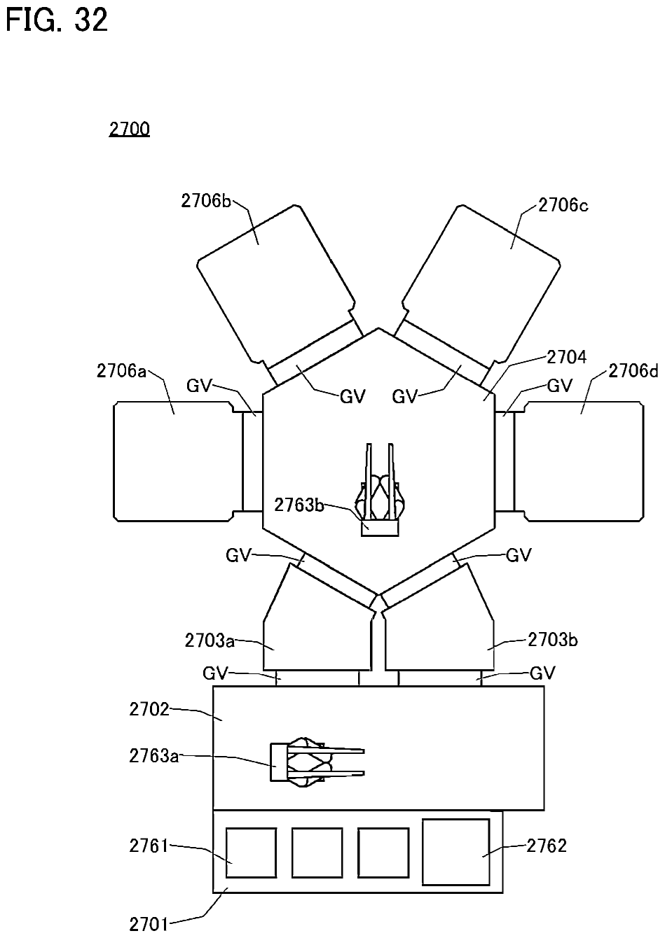

First, a structure of a manufacturing apparatus that hardly allows entry of impurities in manufacturing a semiconductor device or the like is described with reference to FIG. 32 to FIG. 35.

FIG. 32 schematically illustrates a top view of a single wafer multi-chamber manufacturing apparatus 2700. The manufacturing apparatus 2700 includes an atmosphere-side substrate supply chamber 2701 including a cassette port 2761 for storing a substrate and an alignment port 2762 for performing alignment of a substrate; an atmosphere-side substrate transfer chamber 2702 for transferring a substrate from the atmosphere-side substrate supply chamber 2701; a load lock chamber 2703a for carrying in a substrate and switching the pressure inside the chamber from atmospheric pressure to reduced pressure or from reduced pressure to atmospheric pressure; an unload lock chamber 2703b for carrying out a substrate and switching the pressure inside the chamber from reduced pressure to atmospheric pressure or from atmospheric pressure to reduced pressure; a transfer chamber 2704 for transferring a substrate in a vacuum; a chamber 2706a; a chamber 2706b; a chamber 2706c; and a chamber 2706d.

Furthermore, the atmosphere-side substrate transfer chamber 2702 is connected to the load lock chamber 2703a and the unload lock chamber 2703b, the load lock chamber 2703a and the unload lock chamber 2703b are connected to the transfer chamber 2704, and the transfer chamber 2704 is connected to the chamber 2706a, the chamber 2706b, the chamber 2706c, and the chamber 2706d.

Note that gate valves GV are provided in connecting portions between the chambers so that the chambers other than the atmosphere-side substrate supply chamber 2701 and the atmosphere-side substrate transfer chamber 2702 can be each independently kept in a vacuum state. Furthermore, the atmosphere-side substrate transfer chamber 2702 is provided with a transfer robot 2763a, and the transfer chamber 2704 is provided with a transfer robot 2763b. With the transfer robot 2763a and the transfer robot 2763b, a substrate can be transferred inside the manufacturing apparatus 2700.

The back pressure (total pressure) in the transfer chamber 2704 and each of the chambers is, for example, lower than or equal to 1×10⁻⁴ Pa, preferably lower than or equal to 3×10⁻⁵ Pa, further preferably lower than or equal to 1×10⁻⁵ Pa. Furthermore, the partial pressure of a gas molecule (atom) having a mass-to-charge ratio (m/z) of 18 in the transfer chamber 2704 and each of the chambers is, for example, lower than or equal to 3×10⁻⁵ Pa, preferably lower than or equal to 1×10⁻⁵ Pa, further preferably lower than or equal to 3×10⁻⁶ Pa. Furthermore, the partial pressure of a gas molecule (atom) having m/z of 28 in the transfer chamber 2704 and each of the chambers is, for example, lower than or equal to 3×10⁻⁵ Pa, preferably lower than or equal to 1×10⁻⁵ Pa, further preferably lower than or equal to 3×10⁻⁶ Pa. Furthermore, the partial pressure of a gas molecule (atom) having m/z of 44 in the transfer chamber 2704 and each of the chambers is, for example, lower than or equal to 3×10⁻⁵ Pa, preferably lower than or equal to 1×10⁻⁵ Pa, further preferably lower than or equal to 3×10⁻⁶ Pa.

Note that the total pressure and the partial pressure in the transfer chamber 2704 and each of the chambers can be measured using an ionization vacuum gauge, a mass analyzer, or the like.

Furthermore, the transfer chamber 2704 and the chambers each desirably have a structure in which the amount of external leakage or internal leakage is small. For example, the leakage rate in the transfer chamber 2704 is less than or equal to 1×10⁰ Pa/min, preferably less than or equal to 5×10⁻¹ Pa/min. Furthermore, the leakage rate in each chamber is less than or equal to 1×10⁻¹ Pa/min, preferably less than or equal to 5×10⁻² Pa/min.

Note that a leakage rate is derived from the total pressure and partial pressure measured using the ionization vacuum gauge, the mass analyzer, or the like. For example, the leakage rate is preferably derived from the total pressure at the time when 10 minutes have passed from the start of evacuation to a vacuum using a vacuum pump such as a turbo molecular pump and the total pressure at the time when 10 minutes have passed from the operation of closing the valve. Note that the total pressure at the time when 10 minutes have passed from the start of evacuation to a vacuum is preferably an average value of the total pressures measured a plurality of times.

The leakage rate depends on external leakage and internal leakage. The external leakage refers to inflow of gas from the outside of a vacuum system through a minute hole, a sealing defect, or the like. The internal leakage is due to leakage through a partition, such as a valve, in a vacuum system or released gas from an internal member. Measures need to be taken from both aspects of external leakage and internal leakage in order that the leakage rate can be set to less than or equal to the above-described value.

For example, open/close portions of the transfer chamber 2704 and each of the chambers are preferably sealed with a metal gasket. For the metal gasket, metal covered with iron fluoride, aluminum oxide, or chromium oxide is preferably used. The metal gasket achieves higher adhesion than an O-ring and can reduce the external leakage. Furthermore, with the use of passive metal covered with iron fluoride, aluminum oxide, chromium oxide, or the like, the release of gas containing impurities released from the metal gasket is inhibited, so that the internal leakage can be reduced.

Furthermore, for a member of the manufacturing apparatus 2700, aluminum, chromium, titanium, zirconium, nickel, or vanadium, which releases a small amount of gas containing impurities, is used. Furthermore, an alloy containing any of iron, chromium, nickel, and the like and covered with the above-described metal, which releases a small amount of gas containing impurities, may be used. The alloy containing any of iron, chromium, nickel, and the like is rigid, resistant to heat, and suitable for processing. Here, when surface unevenness of the member is reduced by polishing or the like to reduce the surface area, the release of gas can be reduced.

Alternatively, the above-described member of the manufacturing apparatus 2700 may be covered with iron fluoride, aluminum oxide, chromium oxide, or the like.

The member of the manufacturing apparatus 2700 is preferably formed using only metal when possible, and in the case where a viewing window formed of quartz or the like is provided, for example, the surface is preferably thinly covered with iron fluoride, aluminum oxide, chromium oxide, or the like to inhibit release of gas.

An adsorbed substance present in the transfer chamber 2704 and each of the chambers does not affect the pressure in the transfer chamber 2704 and each of the chambers because it is adsorbed onto an inner wall or the like; however, it causes a release of gas when the transfer chamber 2704 and each of the chambers are evacuated. Thus, although there is no correlation between the leakage rate and the exhaust rate, it is important that the adsorbed substance present in the transfer chamber 2704 and each of the chambers be desorbed as much as possible and exhaust be performed in advance with the use of a pump having high exhaust capability. Note that the transfer chamber 2704 and each of the chambers may be subjected to baking to promote desorption of the adsorbed substance. By the baking, the desorption rate of the adsorbed substance can be increased about tenfold. The baking is performed at higher than or equal to 100° C. and lower than or equal to 450° C. At this time, when the adsorbed substance is removed while an inert gas is introduced into the transfer chamber 2704 and each of the chambers, the desorption rate of water or the like, which is difficult to desorb simply by exhaust, can be further increased. Note that when the inert gas to be introduced is heated to substantially the same temperature as the baking temperature, the desorption rate of the adsorbed substance can be further increased. Here, a noble gas is preferably used as the inert gas.

Alternatively, treatment for evacuating the transfer chamber 2704 and each of the chambers is preferably performed after a certain period of time after a heated inert gas such as a noble gas, heated oxygen, or the like is introduced to increase the pressure in the transfer chamber 2704 and each of the chambers. The introduction of the heated gas can desorb the adsorbed substance in the transfer chamber 2704 and each of the chambers, and impurities present in the transfer chamber 2704 and each of the chambers can be reduced. Note that this treatment is effective when repeated more than or equal to 2 times and less than or equal to 30 times, preferably more than or equal to 5 times and less than or equal to 15 times. Specifically, an inert gas, oxygen, or the like at a temperature higher than or equal to 40° C. and lower than or equal to 400° C., preferably higher than or equal to 50° C. and lower than or equal to 200° C. is introduced, so that the pressure in the transfer chamber 2704 and each of the chambers can be kept to be higher than or equal to 0.1 Pa and lower than or equal to 10 kPa, preferably higher than or equal to 1 Pa and lower than or equal to 1 kPa, further preferably higher than or equal to 5 Pa and lower than or equal to 100 Pa within the time range of 1 minute to 300 minutes, preferably 5 minutes to 120 minutes. After that, the transfer chamber 2704 and each of the chambers are evacuated within the time range of 5 minutes to 300 minutes, preferably 10 minutes to 120 minutes.

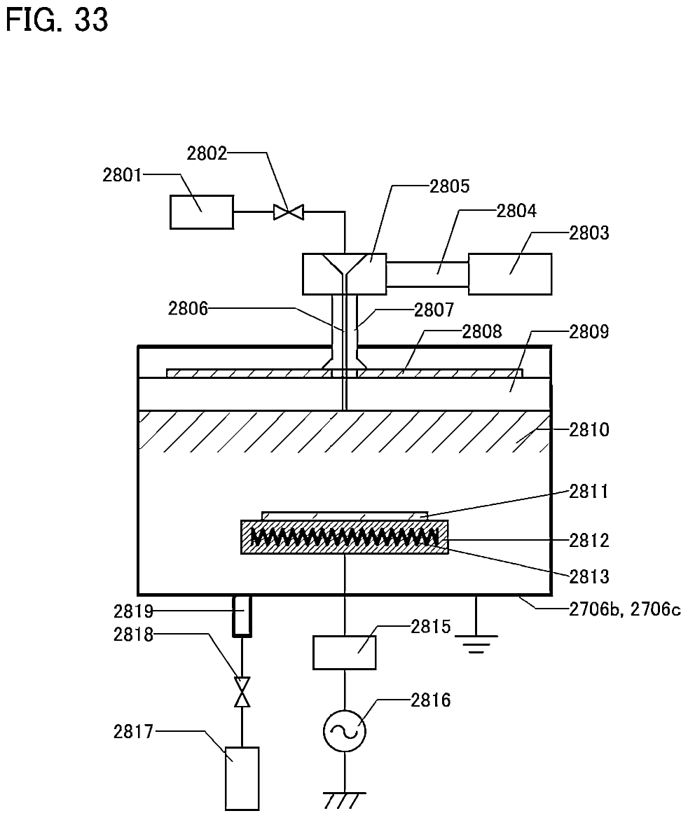

Next, the chamber 2706b and the chamber 2706c are described with reference to a schematic cross-sectional view in FIG. 33.

The chamber 2706b and the chamber 2706c are chambers in which microwave treatment can be performed on an object, for example. Note that the chamber 2706b is different from the chamber 2706c only in the atmosphere in performing the microwave treatment. The other structures are common and thus collectively described below.

The chamber 2706b and the chamber 2706c each include a slot antenna plate 2808, a dielectric plate 2809, a substrate holder 2812, and an exhaust port 2819. Furthermore, a gas supply source 2801, a valve 2802, a high-frequency generator 2803, a waveguide 2804, a mode converter 2805, a gas pipe 2806, a waveguide 2807, a matching box 2815, a high-frequency power source 2816, a vacuum pump 2817, and a valve 2818 are provided outside the chamber 2706b and the chamber 2706c, for example.

The high-frequency generator 2803 is connected to the mode converter 2805 through the waveguide 2804. The mode converter 2805 is connected to the slot antenna plate 2808 through the waveguide 2807. The slot antenna plate 2808 is placed in contact with the dielectric plate 2809. Furthermore, the gas supply source 2801 is connected to the mode converter 2805 through the valve 2802. Then, gas is transferred to the chamber 2706b and the chamber 2706c through the gas pipe 2806 that runs through the mode converter 2805, the waveguide 2807, and the dielectric plate 2809. Furthermore, the vacuum pump 2817 has a function of exhausting gas or the like from the chamber 2706b and the chamber 2706c through the valve 2818 and the exhaust port 2819. Furthermore, the high-frequency power source 2816 is connected to the substrate holder 2812 through the matching box 2815.

The substrate holder 2812 has a function of holding a substrate 2811. For example, the substrate holder 2812 has a function of an electrostatic chuck or a mechanical chuck for holding the substrate 2811. Furthermore, the substrate holder 2812 has a function of an electrode to which electric power is supplied from the high-frequency power source 2816. Furthermore, the substrate holder 2812 includes a heating mechanism 2813 therein and has a function of heating the substrate 2811.

As the vacuum pump 2817, a dry pump, a mechanical booster pump, an ion pump, a titanium sublimation pump, a cryopump, or a turbomolecular pump can be used, for example. Furthermore, in addition to the vacuum pump 2817, a cryotrap may be used. The cryopump and the cryotrap are particularly preferably used, in which case water can be efficiently exhausted.

Furthermore, for example, the heating mechanism 2813 is a heating mechanism that uses a resistance heater or the like for heating. Alternatively, a heating mechanism that uses heat conduction or heat radiation from a medium such as a heated gas for heating may be used. For example, RTA (Rapid Thermal Annealing) such as GRTA (Gas Rapid Thermal Annealing) or LRTA (Lamp Rapid Thermal Annealing) can be used. In GRTA, heat treatment is performed using a high-temperature gas. An inert gas is used as the gas.

Furthermore, the gas supply source 2801 may be connected to a purifier through a mass flow controller. As the gas, a gas whose dew point is lower than or equal to −80° C., preferably lower than or equal to −100° C. is preferably used. For example, an oxygen gas, a nitrogen gas, or a noble gas (an argon gas or the like) is used.

As the dielectric plate 2809, silicon oxide (quartz), aluminum oxide (alumina), or yttrium oxide (yttria) is used, for example. Furthermore, another protective layer may be further formed on a surface of the dielectric plate 2809. For the protective layer, magnesium oxide, titanium oxide, chromium oxide, zirconium oxide, hafnium oxide, tantalum oxide, silicon oxide, aluminum oxide, yttrium oxide, or the like is used. The dielectric plate 2809 is exposed to an especially high-density region of high-density plasma 2810 described later; thus, provision of the protective layer can reduce the damage. Consequently, an increase in the number of particles or the like during the treatment can be suppressed.

The high-frequency generator 2803 has a function of generating a microwave at, for example, higher than or equal to 0.3 GHz and lower than or equal to 3.0 GHZ, higher than or equal to 0.7 GHZ and lower than or equal to 1.1 GHZ, or higher than or equal to 2.2 GHz and lower than or equal to 2.8 GHz. The microwave generated by the high-frequency generator 2803 is propagated to the mode converter 2805 through the waveguide 2804. The mode converter 2805 converts the microwave propagated in the TE (Transverse Electric) mode into the microwave in the TEM (Transverse Electric and Magnetic) mode. Then, the microwave is propagated to the slot antenna plate 2808 through the waveguide 2807. The slot antenna plate 2808 is provided with a plurality of slot holes, and the microwave passes through the slot holes and the dielectric plate 2809. Then, an electric field is generated below the dielectric plate 2809, and the high-density plasma 2810 can be generated. In the high-density plasma 2810, ions and radicals based on the gas species supplied from the gas supply source 2801 are present. For example, oxygen radicals are present.

At this time, the quality of a film or the like over the substrate 2811 can be modified by the ions and radicals generated in the high-density plasma 2810. Note that it is preferable in some cases to apply a bias to the substrate 2811 side using the high-frequency power source 2816. As the high-frequency power source 2816, an RF (Radio Frequency) power source with a frequency of 13.56 MHZ, 27.12 MHz, or the like is used, for example. The application of a bias to the substrate side allows ions in the high-density plasma 2810 to efficiently reach a deep portion of an opening portion of the film or the like over the substrate 2811.

For example, in the chamber 2706b or the chamber 2706c, oxygen radical treatment using the high-density plasma 2810 can be performed by introducing oxygen from the gas supply source 2801.

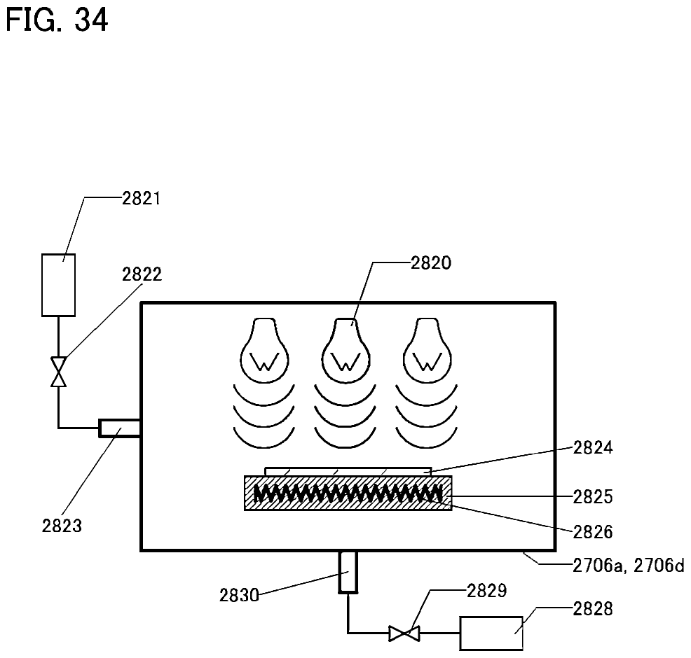

Next, the chamber 2706a and the chamber 2706d are described with reference to a schematic cross-sectional view in FIG. 34.

The chamber 2706a and the chamber 2706d are chambers in which an object can be irradiated with an electromagnetic wave, for example. Note that the chamber 2706a is different from the chamber 2706d only in the kind of the electromagnetic wave. The other structures have many common portions and thus are collectively described below.

The chamber 2706a and the chamber 2706d each include one or more lamps 2820, a substrate holder 2825, a gas inlet 2823, and an exhaust port 2830. Furthermore, a gas supply source 2821, a valve 2822, a vacuum pump 2828, and a valve 2829 are provided outside the chamber 2706a and the chamber 2706d, for example.

The gas supply source 2821 is connected to the gas inlet 2823 through the valve 2822. The vacuum pump 2828 is connected to the exhaust port 2830 through the valve 2829. The lamp 2820 is placed to face the substrate holder 2825. The substrate holder 2825 has a function of holding a substrate 2824. Furthermore, the substrate holder 2825 includes a heating mechanism 2826 therein and has a function of heating the substrate 2824.

As the lamp 2820, a light source having a function of emitting an electromagnetic wave such as visible light or ultraviolet light is used, for example. For example, a light source having a function of emitting an electromagnetic wave which has a peak at a wavelength longer than or equal to 10 nm and shorter than or equal to 2500 nm, longer than or equal to 500 nm and shorter than or equal to 2000 nm, or longer than or equal to 40 nm and shorter than or equal to 340 nm is used.

As the lamp 2820, a light source such as a halogen lamp, a metal halide lamp, a xenon arc lamp, a carbon arc lamp, a high-pressure sodium lamp, or a high-pressure mercury lamp is used, for example.

For example, part or the whole of electromagnetic wave emitted from the lamp 2820 is absorbed by the substrate 2824, so that the quality of a film or the like over the substrate 2824 can be modified. For example, generation or reduction of defects or removal of impurities can be performed. Note that generation or reduction of defects, removal of impurities, or the like can be efficiently performed while the substrate 2824 is heated.

Alternatively, for example, the electromagnetic wave emitted from the lamp 2820 may allow the substrate holder 2825 to generate heat for heating the substrate 2824. In that case, the substrate holder 2825 does not need to include the heating mechanism 2826 therein.

For the vacuum pump 2828, refer to the description of the vacuum pump 2817. Furthermore, for the heating mechanism 2826, refer to the description of the heating mechanism 2813. Furthermore, for the gas supply source 2821, refer to the description of the gas supply source 2801.

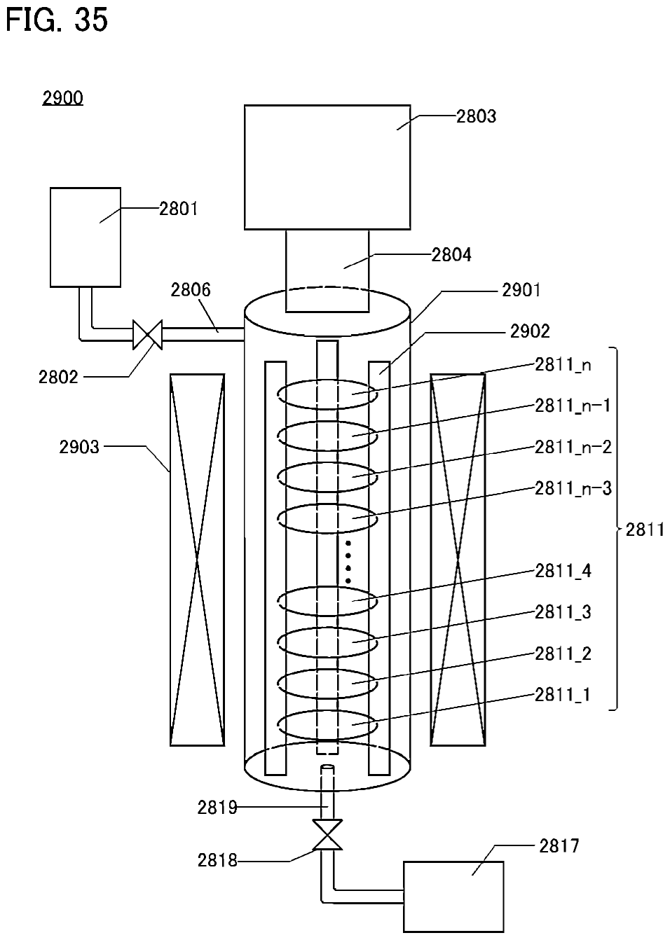

A microwave treatment apparatus that can be used in this embodiment is not limited to the above. A microwave treatment apparatus 2900 illustrated in FIG. 35 can be used. The microwave treatment apparatus 2900 includes a quartz tube 2901, the exhaust port 2819, the gas supply source 2801, the valve 2802, the high-frequency generator 2803, the waveguide 2804, the gas pipe 2806, the vacuum pump 2817, and the valve 2818. Furthermore, the microwave treatment apparatus 2900 includes a substrate holder 2902 that holds a plurality of substrates 2811 (2811_1 to 2811_n, n is an integer greater than or equal to 2) in the quartz tube 2901. The microwave treatment apparatus 2900 may further include a heating means 2903 outside the quartz tube 2901.

The substrate provided in the quartz tube 2901 is irradiated with the microwave generated by the high-frequency generator 2803, through the waveguide 2804. The vacuum pump 2817 is connected to the exhaust port 2819 through the valve 2818 and can adjust the pressure inside the quartz tube 2901. The gas supply source 2801 is connected to the gas pipe 2806 through the valve 2802 and can introduce a desired gas into the quartz tube 2901. The heating means 2903 can heat the substrate 2811 in the quartz tube 2901 to a desired temperature. Alternatively, the heating means 2903 may heat the gas which is supplied from the gas supply source 2801. With the use of the microwave treatment apparatus 2900, the substrate 2811 can be subjected to heat treatment and microwave treatment at the same time. Alternatively, the substrate 2811 can be heated and then subjected to microwave treatment. Alternatively, the substrate 2811 can be subjected to microwave treatment and then heat treatment.

All of the substrate 2811_1 to the substrate 2811_n may be substrates to be treated where a semiconductor device or a storage device is to be formed, or some of the substrates may be dummy substrates. For example, the substrate 2811_1 and the substrate 2811_n may be dummy substrates, and the substrate 2811_2 to the substrate 2811_n−1 may be substrates to be treated. Alternatively, the substrate 2811_1, the substrate 2811_2, the substrate 2811_n−1, and the substrate 2811_n may be dummy substrates, and the substrate 2811_3 to the substrate 2811_n−2 may be substrates to be treated. A dummy substrate is preferably used, in which case a plurality of substrates to be treated can be uniformly treated at the time of microwave treatment or heat treatment and a variation between the substrates to be treated can be reduced. For example, a dummy substrate is preferably placed over the substrate to be treated which is the closest to the high-frequency generator 2803 and the waveguide 2804, in which case the substrate to be treated is inhibited from being directly exposed to a microwave.

With the use of the above-described manufacturing apparatus, the quality of a film or the like can be modified while the entry of impurities into an object is inhibited.

### Modification Example of Semiconductor Device

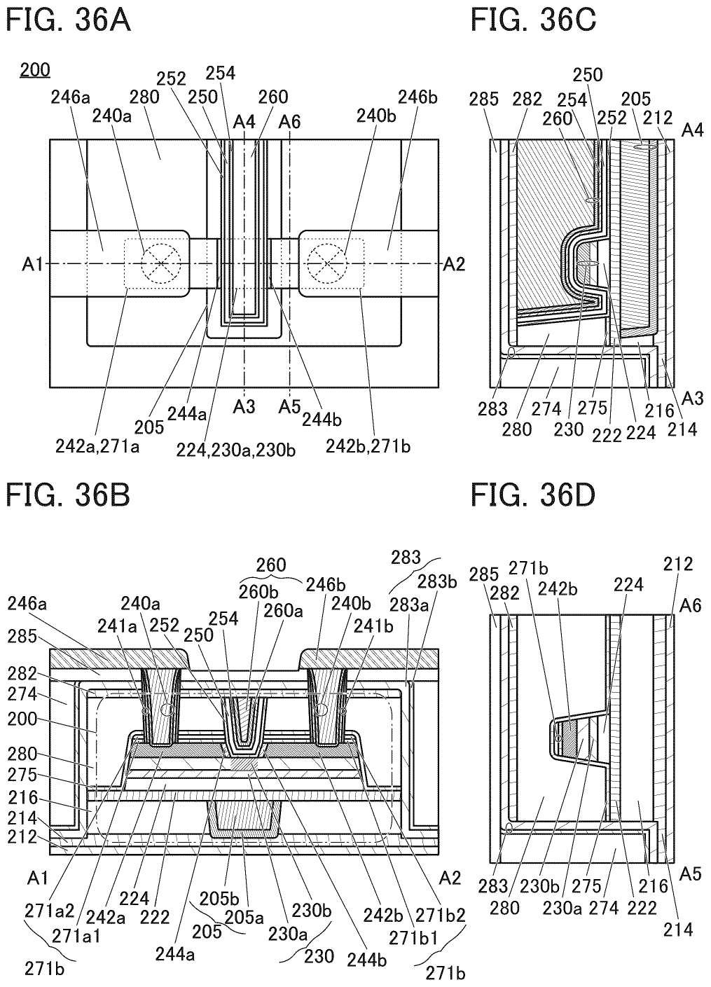

Examples of the semiconductor device of one embodiment of the present invention are described below with reference to FIG. 36A to FIG. 39D.

In FIG. 36A to FIG. 39D, A of each drawing is a top view of the semiconductor device. Moreover, B of each drawing is a cross-sectional view corresponding to a portion indicated by dashed-dotted line A1-A2 in A of each drawing. Furthermore, C of each drawing is a cross-sectional view corresponding to a portion indicated by dashed-dotted line A3-A4 in A of each drawing. Furthermore, D of each drawing is a cross-sectional view corresponding to a portion indicated by dashed-dotted line A5-A6 in A of each drawing. For clarity of the drawing, some components are omitted in the top view of A of each drawing.

Note that in the semiconductor device illustrated in A to D of each drawing in FIG. 36A to FIG. 39D, components having the same functions as the components included in the semiconductor device described in <Structure example of semiconductor device> are denoted by the same reference numerals. Note that the materials described in detail in <Structure example of semiconductor device> can be used as component materials of the semiconductor devices also in this section.

### Modification Example 1 of Semiconductor Device

A semiconductor device illustrated in FIG. 36A to FIG. 36D is a modification example of the semiconductor device illustrated in FIG. 14A to FIG. 14D. The semiconductor device illustrated in FIG. 36A to FIG. 36D differs from the semiconductor device illustrated in FIG. 14A to FIG. 14D in that the insulator 271 and the insulator 283 each have a stacked-layer structure of two layers.

The insulator 271a includes an insulator 271a1 and an insulator 271a2 over the insulator 271al. The insulator 271b includes an insulator 271b1 and an insulator 271b2 over the insulator 271b1.

The insulator 271a1 and the insulator 271b1 preferably function as at least a barrier insulating film against oxygen. Thus, the insulator 271a1 and the insulator 271b1 preferably have a function of inhibiting oxygen diffusion. Accordingly, oxygen included in the insulator 280 can be prevented from diffusing into the conductor 242a and the conductor 242b. Thus, the conductor 242a and the conductor 242b can be inhibited from being oxidized by oxygen included in the insulator 280, so that an increase in resistivity and a reduction in on-state current can be inhibited.

The insulator 271a2 and the insulator 271b2 function as protective layers for making the insulator 271a1 and the insulator 271b1 remain. When the hard mask is removed after the conductive film 242A, the oxide film 230B, and the like are processed into an island shape, an insulating layer to be the insulator 271a1 and the insulator 271b1 might be removed. Thus, an insulating layer to be the insulator 271a2 and the insulator 271b2 is provided between the hard mask and the insulating layer to be the insulator 271a1 and the insulator 271b1, whereby the insulating layer to be the insulator 271a1 and the insulator 271b1 can remain. For example, in the case where tungsten is used for the hard mask, silicon oxide or the like is preferably used for the insulator 271a2 and the insulator 271b2.

The insulator 283 includes an insulator 283a and an insulator 283b over the insulator 283a. The insulator 283a and the insulator 283b are preferably formed using the same material by different methods. For example, a film of silicon nitride may be formed by a sputtering method as the insulator 283a, and a film of silicon nitride may be formed by an ALD method as the insulator 283b. By using a sputtering method that does not need to use a molecule containing hydrogen as a film formation gas, the hydrogen concentration in the insulator 283a can be reduced. Furthermore, in the case where a pinhole, disconnection, or the like is formed in the film formed by a sputtering method, a portion overlapping with the pinhole, the disconnection, or the like can be filled with the film formed by an ALD method with excellent coverage.

When the insulating film to be the insulator 274 is polished by CMP treatment, the top surface of the insulator 283b is partly removed as illustrated in FIG. 36B in some cases. The boundary between the insulator 283a and the insulator 283b is difficult to detect clearly in some cases.

Without limitation to a stacked-layer structure formed of the same material, the insulator 283a and the insulator 283b may have a stacked-layer structure formed of different materials.

### Modification Example 2 of Semiconductor Device

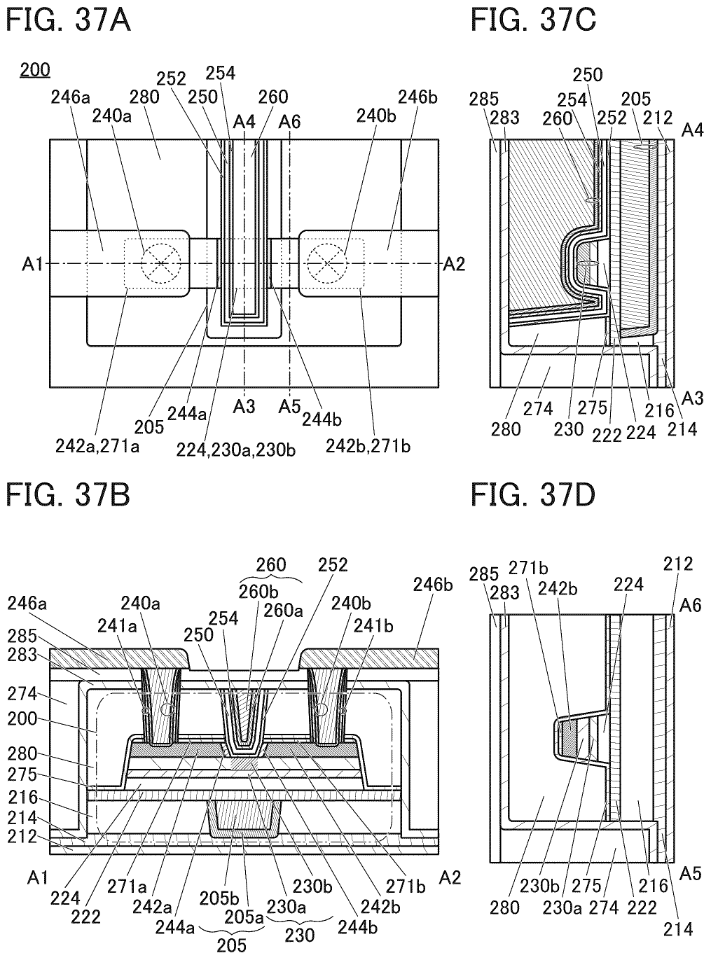

A semiconductor device illustrated in FIG. 37A to FIG. 37D is a modification example of the semiconductor device illustrated in FIG. 14A to FIG. 14D. The semiconductor device illustrated in FIG. 37A to FIG. 37D differs from the semiconductor device illustrated in FIG. 14A to FIG. 14D in that the insulator 282 is not provided. Thus, in the semiconductor device illustrated in FIG. 37A to FIG. 37D, the insulator 283 is in contact with the top surface of the conductor 260, the top surface of the insulator 280, the uppermost portion of the insulator 254, the uppermost portion of the insulator 250, and the uppermost portion of the insulator 252.

For example, in the case where oxygen can be supplied sufficiently to the oxide 230 by the microwave treatment or the like as illustrated in FIG. 26, the region 230bc can be substantially i-type without the insulator 282 for adding oxygen to the insulator 280. In such a case, the structure without the insulator 282 as illustrated in FIG. 37A to FIG. 37D enables the simplification of the manufacturing process and the improvement in productivity of the semiconductor device.

### Modification Example 3 of Semiconductor Device

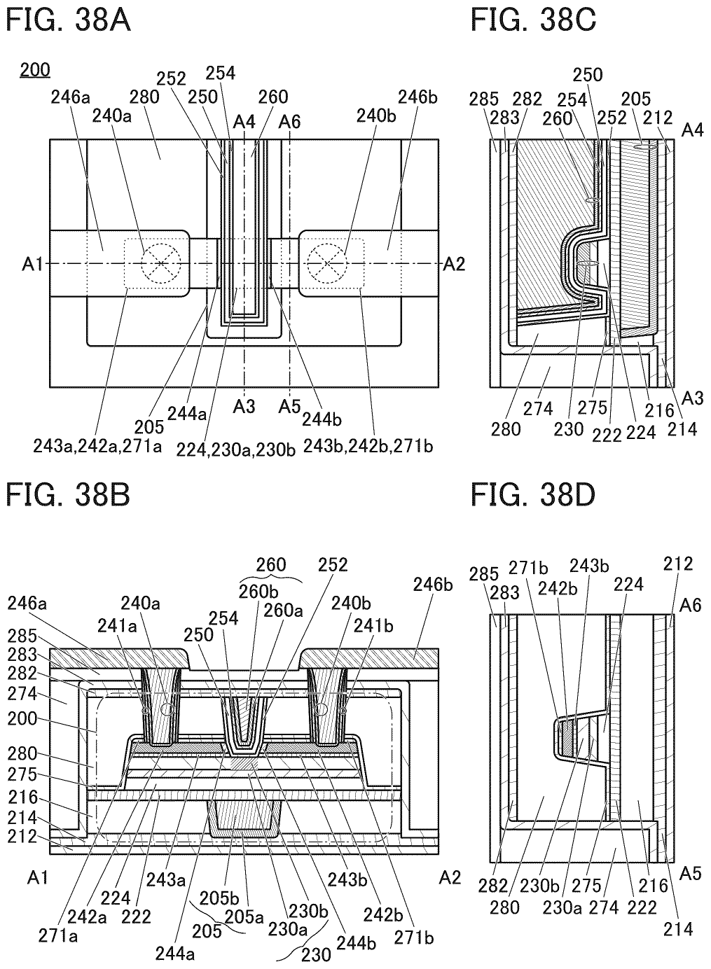

A semiconductor device illustrated in FIG. 38A to FIG. 38D is a modification example of the semiconductor device illustrated in FIG. 14A to FIG. 14D. The semiconductor device illustrated in FIG. 38A to FIG. 38D differs from the semiconductor device illustrated in FIG. 14A to FIG. 14D in that an oxide 243 (an oxide 243a and an oxide 243b) is provided. The oxide 243a is provided between the oxide 230b and the conductor 242a, and the oxide 243b is provided between the oxide 230b and the conductor 242b. Here, the oxide 243a is preferably in contact with the top surface of the oxide 230b and the bottom surface of the conductor 242a. The oxide 243b is preferably in contact with the top surface of the oxide 230b and the bottom surface of the conductor 242b.

The oxide 243 preferably has a function of inhibiting passage of oxygen. The oxide 243 having a function of inhibiting passage of oxygen is preferably placed between the oxide 230b and the conductor 242 functioning as the source electrode or the drain electrode, in which case oxidation of the conductor 242 is inhibited and the electric resistance between the conductor 242 and the oxide 230b is reduced. Such a structure can improve the electrical characteristics, the field-effect mobility, and the reliability of the transistor 200 in some cases.

A metal oxide containing the element M may be used as the oxide 243. In particular, aluminum, gallium, yttrium, or tin is preferably used as the element M. The concentration of the element M in the oxide 243 is preferably higher than that in the oxide 230b. Furthermore, gallium oxide may be used for the oxide 243. A metal oxide such as an In-M-Zn oxide may be used as the oxide 243. Specifically, the atomic ratio of the element M to In in the metal oxide used as the oxide 243 is preferably higher than the atomic ratio of the element M to In in the metal oxide used as the oxide 230b. The thickness of the oxide 243 is preferably greater than or equal to 0.5 nm and less than or equal to 5 nm, further preferably greater than or equal to 1 nm and less than or equal to 3 nm, still further preferably greater than or equal to 1 nm and less than or equal to 2 nm. The oxide 243 preferably has crystallinity. In the case where the oxide 243 has crystallinity, release of oxygen from the oxide 230 can be favorably inhibited. When the oxide 243 has a hexagonal crystal structure, for example, release of oxygen from the oxide 230 can sometimes be inhibited.

### Modification Example 4 of Semiconductor Device

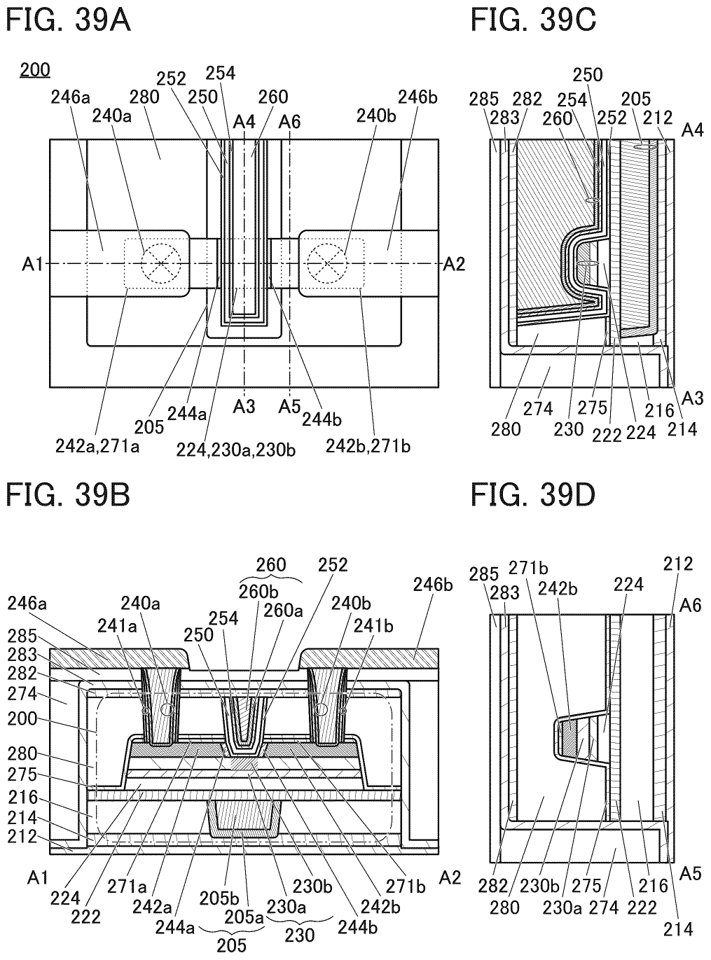

A semiconductor device illustrated in FIG. 39A to FIG. 39D is a modification example of the semiconductor device illustrated in FIG. 14A to FIG. 14D. The semiconductor device illustrated in FIG. 39A to FIG. 39D differs from the semiconductor device illustrated in FIG. 14A to FIG. 14D in that the insulator 283 is in contact with part of the top surface of the insulator 212. Accordingly, the transistor 200 is placed in a region sealed with the insulator 283 and the insulator 212. With this structure, entry of hydrogen included in a region outside the sealed region into the sealed region can be inhibited. Although FIG. 39A to FIG. 39D illustrate the transistor 200 having a structure in which the insulator 212 and the insulator 283 are each provided to have a single-layer structure, the present invention is not limited thereto. For example, one or both of the insulator 212 and the insulator 283 may be provided to have a stacked-layer structure of two or more layers.

A change in electrical characteristics of an OS transistor such as the transistor 200 due to exposure to radiation is small, i.e., an OS transistor is highly resistant to radiation; thus, an OS transistor can be suitably used even in an environment where radiation might enter. For example, OS transistors can be suitably used in outer space. Specifically, OS transistors can be used as transistors included in semiconductor devices provided in a space shuttle, an artificial satellite, a space probe, and the like. Examples of radiation include X-rays and a neutron beam. Outer space refers to, for example, space at an altitude greater than or equal to 100 km, and outer space in this specification may also include thermosphere, mesosphere, and stratosphere.

Alternatively, for example, OS transistors can be used as transistors included in semiconductor devices provided in working robots in a nuclear power plant and a treatment plant or a disposal plant for radioactive wastes. In particular, OS transistors can be suitably used as transistors included in semiconductor devices provided in remote control robots that are controlled remotely in demolishment of a reactor facility, taking out of a nuclear fuel or a fuel debris, a field investigation on a space with a large amount of radioactive substance, and the like.

### Application Example of Semiconductor Device

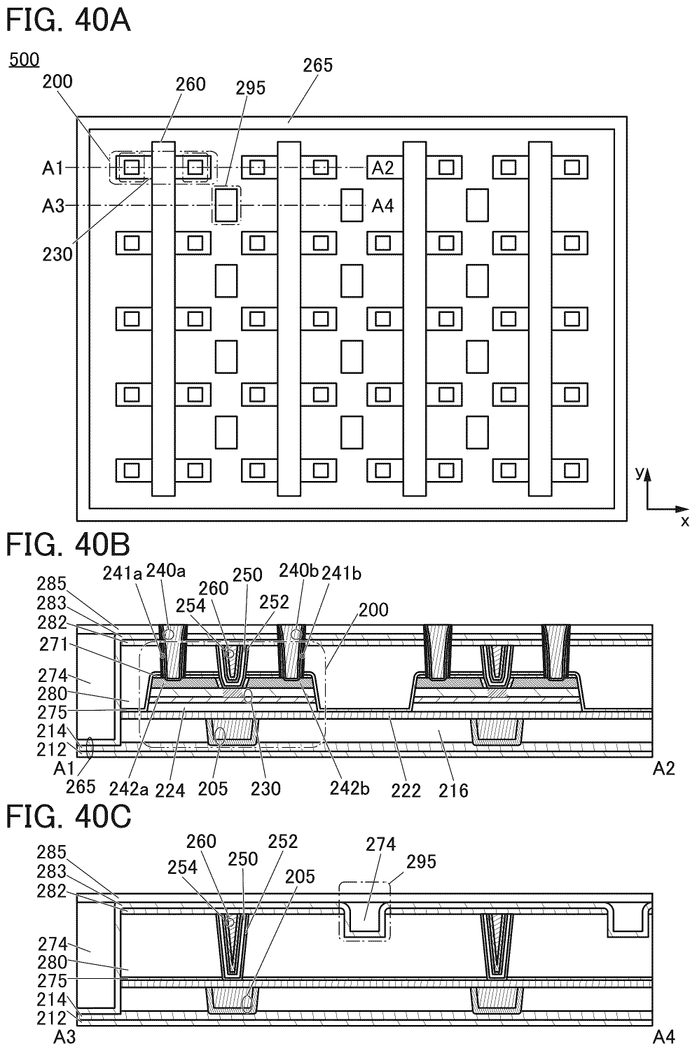

An example of the semiconductor device of one embodiment of the present invention is described below with reference to FIG. 40.

FIG. 40A is a top view of a semiconductor device 500. In FIG. 40A, the x-direction is parallel to the channel length direction of the transistor 200, and the y-direction is perpendicular to the x-direction. FIG. 40B is a cross-sectional view corresponding to a portion indicated by dashed-dotted line A1-A2 in FIG. 40A, and is also a cross-sectional view of the transistor 200 in the channel length direction. FIG. 40C is a cross-sectional view corresponding to a portion indicated by dashed-dotted line A3-A4 in FIG. 40A, and is also a cross-sectional view of an opening region 295 and the vicinity thereof. Note that for clarity of the drawing, some components are omitted in the top view of FIG. 40A.

Note that in the semiconductor device illustrated in FIG. 40A to FIG. 40C, components having the same functions as the components included in the semiconductor device described in <Structure example of semiconductor device> are denoted by the same reference numerals. Note that the materials described in detail in <Structure example of semiconductor device> can be used as component materials of the semiconductor devices also in this section.

The semiconductor device 500 illustrated in FIG. 40A to FIG. 40C is an application example of the semiconductor device illustrated in FIG. 14A to FIG. 14D. The semiconductor device 500 illustrated in FIG. 40A to FIG. 40C differs from the semiconductor device illustrated in FIG. 14A to FIG. 14D in that the opening region 295 is formed in the insulator 282 and the insulator 280. Moreover, a sealing portion 265 is formed to surround the plurality of transistors 200, which is a different point from the semiconductor device illustrated in FIG. 14A to FIG. 14D.

The semiconductor device 500 includes the plurality of transistors 200 and a plurality of the opening regions 295 arranged in a matrix. In addition, a plurality of the conductors 260 functioning as gate electrodes of the transistors 200 are provided to extend in the y-direction. The opening regions 295 are provided in regions not overlapping with the oxide 230 or the conductor 260. The sealing portion 265 is formed to surround the plurality of transistors 200, the plurality of conductors 260, and the plurality of opening regions 295. Note that the number, the position, and the size of the transistors 200, the conductors 260, and the opening regions 295 are not limited to those illustrated in FIG. 40 and is set as appropriate in accordance with the design of the semiconductor device 500.

As illustrated in FIG. 40B and FIG. 40C, the sealing portion 265 is provided to surround the plurality of transistors 200, the insulator 216, the insulator 222, the insulator 275, the insulator 280, and the insulator 282. In other words, the insulator 283 is provided to cover the insulator 216, the insulator 222, the insulator 275, the insulator 280, and the insulator 282. In the sealing portion 265, the insulator 283 is in contact with the top surface of the insulator 214. Over the sealing portion 265, the insulator 274 is provided between the insulator 283 and the insulator 285. The top surface of the insulator 274 is level or substantially level with the uppermost surface of the insulator 283. As the insulator 274, an insulator similar to the insulator 280 can be used.

With such a structure, the plurality of transistors 200 can be surrounded by the insulator 283, the insulator 214, and the insulator 212. Here, one or more of the insulator 283, the insulator 214, and the insulator 212 preferably function as a barrier insulating film against hydrogen. Accordingly, entry of hydrogen included in the region outside the sealing portion 265 into a region in the sealing portion 265 can be inhibited.

As illustrated in FIG. 40C, the insulator 282 in the opening region 295 has an opening portion. In the opening region 295, the insulator 280 may have a groove portion to overlap with the opening portion in the insulator 282. The depth of the groove portion of the insulator 280 is less than or equal to the depth at which the top surface of the insulator 275 is exposed and is, for example, approximately greater than or equal to ¼ and less than or equal to ½ of the maximum thickness of the insulator 280.

As illustrated in FIG. 40C, the insulator 283 inside the opening region 295 is in contact with the side surface of the insulator 282, the side surface of the insulator 280, and the top surface of the insulator 280. Part of the insulator 274 is formed in the opening region 295 to fill the depressed portion formed in the insulator 283 in some cases. At this time, the top surface of the insulator 274 formed in the opening region 295 is level or substantially level with the uppermost surface of the insulator 283, in some cases.

When heat treatment is performed in such a state that the opening region 295 is formed and the insulator 280 is exposed in the opening portion of the insulator 282, part of oxygen included in the insulator 280 can be made to diffuse outwardly from the opening region 295 while oxygen is supplied to the oxide 230. This enables oxygen to be sufficiently supplied to the region functioning as the channel formation region and its vicinity in the oxide semiconductor layer from the insulator 280 including excess oxygen, and also prevents an excess amount of oxygen from being supplied thereto.

At this time, hydrogen included in the insulator 280 can be bonded to oxygen and released to the outside through the opening region 295. The hydrogen bonded to oxygen is released as water. Thus, the amount of hydrogen included in the insulator 280 can be reduced, and hydrogen included in the insulator 280 can be inhibited from entering the oxide 230.

In FIG. 40A, the shape of the opening region 295 in the top view is substantially rectangular; however, the present invention is not limited to the shape. For example, the shape of the opening region 295 in the top view can be a rectangular shape, an elliptical shape, a circular shape, a rhombus shape, or a shape obtained by combining any of the above shapes. The area and arrangement interval of the opening regions 295 can be set as appropriate in accordance with the design of the semiconductor device including the transistor 200. For example, in the region where the density of the transistors 200 is low, the area of the opening region 295 is increased, or the arrangement interval of the opening regions 295 is narrowed. For example, in the region where the density of the transistors 200 is high, the area of the opening region 295 is reduced, or the arrangement interval of the opening regions 295 is increased.

As described above, the semiconductor device of one embodiment of the present invention employs a junction-less transistor structure or a transistor structure including a metal oxide with a large hole effective mass in a channel formation region. The semiconductor device of one embodiment of the present invention employs a transistor structure in which a drain electric field is relieved or a transistor structure in which the controllability of a top gate electrode is high. Employing any of these structures is expected to reduce a short-channel effect.

According to one embodiment of the present invention, a novel transistor can be provided. Alternatively, a semiconductor device in which a short-channel effect does not appear or does not substantially appear can be provided. Alternatively, a semiconductor device with a small variation in transistor characteristics can be provided. Alternatively, a semiconductor device having favorable electrical characteristics can be provided. Alternatively, a semiconductor device with favorable reliability can be provided. Alternatively, a semiconductor device with a high on-state current can be provided. Alternatively, a semiconductor device with a high field-effect mobility can be provided. Alternatively, a semiconductor device with favorable frequency characteristics can be provided. Alternatively, a semiconductor device that can be miniaturized or highly integrated can be provided. Alternatively, a semiconductor device with low power consumption can be provided.

At least part of the structure, method, and the like described in this embodiment can be implemented in an appropriate combination with any of those in the other embodiments, the other examples, and the like described in this specification.

### Embodiment 4

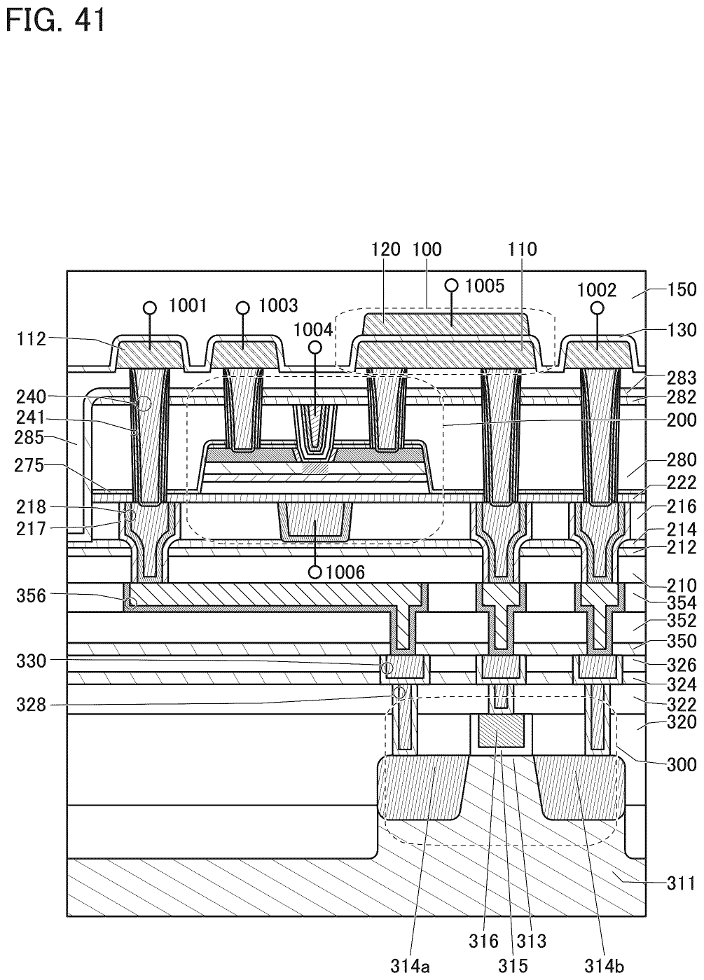

In this embodiment, one embodiment of a semiconductor device is described with reference to FIG. 41 to FIG. 45.

### [Storage Device 1]

FIG. 41 illustrates an example of a semiconductor device (a storage device) of one embodiment of the present invention. In the semiconductor device of one embodiment of the present invention, the transistor 200 is provided above a transistor 300, and a capacitor 100 is provided above the transistor 300 and the transistor 200. The transistor 200 described in the above embodiment can be used as the transistor 200.

The transistor 200 is a transistor in which a channel is formed in a semiconductor layer including an oxide semiconductor. Since the transistor 200 has a low off-state current, a storage device that uses the transistor 200 can retain stored contents for a long time. In other words, the storage device does not require refresh operation or has extremely low frequency of the refresh operation, which leads to a sufficient reduction in power consumption of the storage device.

In the semiconductor device illustrated in FIG. 41, a wiring 1001 is electrically connected to a source of the transistor 300, and a wiring 1002 is electrically connected to a drain of the transistor 300. In addition, a wiring 1003 is electrically connected to one of the source and the drain of the transistor 200, a wiring 1004 is electrically connected to the first gate of the transistor 200, and a wiring 1006 is electrically connected to the second gate of the transistor 200. A gate of the transistor 300 and the other of the source and the drain of the transistor 200 are electrically connected to one electrode of the capacitor 100, and a wiring 1005 is electrically connected to the other electrode of the capacitor 100.

The storage device illustrated in FIG. 41 can form a memory cell array when arranged in a matrix.

### <Transistor 300>

The transistor 300 is provided on a substrate 311 and includes a conductor 316 functioning as a gate, an insulator 315 functioning as a gate insulator, a semiconductor region 313 formed of part of the substrate 311, and a low-resistance region 314a and a low-resistance region 314b functioning as a source region and a drain region. The transistor 300 may be a p-channel transistor or an n-channel transistor.

Here, in the transistor 300 illustrated in FIG. 41, the semiconductor region 313 (part of the substrate 311) where a channel is formed has a protruding shape. In addition, the conductor 316 is provided to cover the side surface and the top surface of the semiconductor region 313 with the insulator 315 therebetween. Note that a material adjusting the work function may be used for the conductor 316. Such a transistor 300 is also referred to as a FIN-type transistor because it utilizes a protruding portion of a semiconductor substrate. Note that an insulator functioning as a mask for forming the protruding portion may be included in contact with an upper portion of the protruding portion. Furthermore, although the case where the protruding portion is formed by processing part of the semiconductor substrate is described here, a semiconductor film having a protruding shape may be formed by processing an SOI substrate.

Note that the transistor 300 illustrated in FIG. 41 is an example and the structure is not limited thereto; an appropriate transistor is used in accordance with a circuit structure or a driving method.

### <Capacitor 100>

The capacitor 100 is provided above the transistor 200. The capacitor 100 includes a conductor 110 functioning as a first electrode, a conductor 120 functioning as a second electrode, and an insulator 130 functioning as a dielectric. Here, for the insulator 130, the insulator that can be used as the insulator 283 described in the above embodiment is preferably used.

For example, a conductor 112 and the conductor 110 provided over a conductor 246 can be formed at the same time. Note that the conductor 112 functions as a plug or a wiring that is electrically connected to the capacitor 100, the transistor 200, or the transistor 300.

Although the conductor 112 and the conductor 110 having a single-layer structure are illustrated in FIG. 41, a stacked-layer structure of two or more layers may be employed without being limited to the single-layer structure. For example, between a conductor having a barrier property and a conductor having high conductivity, a conductor that is highly adhesive to the conductor having a barrier property and the conductor having high conductivity may be formed.

The insulator 130 can be provided as stacked layers or a single layer using, for example, silicon oxide, silicon oxynitride, silicon nitride oxide, silicon nitride, aluminum oxide, aluminum oxynitride, aluminum nitride oxide, aluminum nitride, hafnium oxide, hafnium oxynitride, hafnium nitride oxide, or hafnium nitride.

For example, for the insulator 130, a stacked-layer structure of a material with high dielectric strength such as silicon oxynitride and a high-permittivity (high-k) material is preferably used. In the capacitor 100 having this structure, a sufficient capacitance can be ensured owing to the high-permittivity (high-k) insulator, and the dielectric strength can be increased owing to the insulator with high dielectric strength, so that the electrostatic breakdown of the capacitor 100 can be inhibited.

Examples of the high-permittivity (high-k) material (a material having a high relative permittivity) include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of a material with high dielectric strength (a material with a low relative permittivity) include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

### <Wiring Layer>

Wiring layers provided with an interlayer film, a wiring, a plug, and the like may be provided between the components. A plurality of wiring layers can be provided in accordance with design. Here, a plurality of conductors functioning as plugs or wirings are collectively denoted by the same reference numeral in some cases. Furthermore, in this specification and the like, a wiring and a plug electrically connected to the wiring may be a single component. That is, there are cases where part of a conductor functions as a wiring and part of a conductor functions as a plug.

For example, an insulator 320, an insulator 322, an insulator 324, and an insulator 326 are sequentially stacked over the transistor 300 as interlayer films. A conductor 328, a conductor 330, and the like that are electrically connected to the capacitor 100 or the transistor 200 are embedded in the insulator 320, the insulator 322, the insulator 324, and the insulator 326. Note that the conductor 328 and the conductor 330 function as plugs or wirings.

The insulators functioning as interlayer films may also function as planarization films that cover uneven shapes therebelow. For example, the top surface of the insulator 322 may be planarized by planarization treatment using a chemical mechanical polishing (CMP) method or the like to improve planarity.

A wiring layer may be provided over the insulator 326 and the conductor 330. For example, in FIG. 41, an insulator 350, an insulator 352, and an insulator 354 are stacked sequentially. Furthermore, a conductor 356 is formed in the insulator 350, the insulator 352, and the insulator 354. The conductor 356 functions as a plug or a wiring.

Similarly, a conductor 218, a conductor (the conductor 205) included in the transistor 200, and the like are embedded in an insulator 210, the insulator 212, the insulator 214, and the insulator 216. Note that the conductor 218 has a function of a plug or a wiring that is electrically connected to the capacitor 100 or the transistor 300. In addition, an insulator 150 is provided over the conductor 120 and the insulator 130.

Here, like the insulator 241 described in the above embodiment, an insulator 217 is provided in contact with the side surface of the conductor 218 functioning as a plug. The insulator 217 is provided in contact with an inner wall of an opening formed in the insulator 210, the insulator 212, the insulator 214, and the insulator 216. That is, the insulator 217 is provided between the conductor 218 and each of the insulator 210, the insulator 212, the insulator 214, and the insulator 216. Note that the conductor 205 and the conductor 218 can be formed in parallel; thus, the insulator 217 is sometimes formed in contact with the side surface of the conductor 205.

As the insulator 217, an insulator such as silicon nitride, aluminum oxide, or silicon nitride oxide may be used, for example. Since the insulator 217 is provided in contact with the insulator 210, the insulator 212, the insulator 214, and the insulator 222, entry of an impurity such as water or hydrogen into the oxide 230 through the conductor 218 from the insulator 210, the insulator 216, or the like can be inhibited. In particular, silicon nitride is suitable because of its high blocking property against hydrogen. Moreover, oxygen included in the insulator 210 or the insulator 216 can be prevented from being absorbed by the conductor 218.

The insulator 217 can be formed in a manner similar to that of the insulator 241. For example, a film of silicon nitride is formed by a PEALD method and an opening reaching the conductor 356 is formed by anisotropic etching.

Examples of an insulator that can be used as an interlayer film include an insulating oxide, an insulating nitride, an insulating oxynitride, an insulating nitride oxide, an insulating metal oxide, an insulating metal oxynitride, and an insulating metal nitride oxide.

For example, when a material with a low relative permittivity is used for the insulator functioning as an interlayer film, parasitic capacitance generated between wirings can be reduced. Thus, a material is preferably selected depending on the function of the insulator.

For example, as the insulator 150, the insulator 210, the insulator 352, the insulator 354, and the like, an insulator with a low relative permittivity is preferably included. For example, the insulator preferably includes silicon oxide to which fluorine is added, silicon oxide to which carbon is added, silicon oxide to which carbon and nitrogen are added, porous silicon oxide, a resin, or the like. Alternatively, the insulator preferably has a stacked-layer structure of a resin and silicon oxide, silicon oxynitride, silicon nitride oxide, silicon nitride, silicon oxide to which fluorine is added, silicon oxide to which carbon is added, silicon oxide to which carbon and nitrogen are added, or porous silicon oxide. When silicon oxide or silicon oxynitride, which is thermally stable, is combined with a resin, the stacked-layer structure can have thermal stability and a low relative permittivity. Examples of the resin include polyester, polyolefin, polyamide (e.g., nylon and aramid), polyimide, polycarbonate, and acrylic.

When a transistor including an oxide semiconductor is surrounded by an insulator having a function of inhibiting passage of oxygen and impurities such as hydrogen, the electrical characteristics of the transistor can be stable. Thus, the insulator having a function of inhibiting passage of oxygen and impurities such as hydrogen is used for the insulator 214, the insulator 212, the insulator 350, and the like.

As the insulator having a function of inhibiting passage of oxygen and impurities such as hydrogen, a single layer or stacked layers of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum are used. Specifically, as the insulator having a function of inhibiting passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; silicon nitride oxide; silicon nitride; or the like can be used.

As the conductor that can be used for a wiring or a plug, a material containing one or more kinds of metal elements selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, and the like can be used. Alternatively, a semiconductor having high electrical conductivity, typified by polycrystalline silicon containing an impurity element such as phosphorus, or silicide such as nickel silicide may be used.

For example, for the conductor 328, the conductor 330, the conductor 356, the conductor 218, the conductor 112, and the like, a single layer or stacked layers of a conductive material such as a metal material, an alloy material, a metal nitride material, or a metal oxide material that is formed using the above materials can be used. It is preferable to use a high-melting-point material that has both heat resistance and conductivity, such as tungsten or molybdenum, and it is preferable to use tungsten. Alternatively, it is preferable to use a low-resistance conductive material such as aluminum or copper. The use of a low-resistance conductive material can reduce wiring resistance.

<Wiring or Plug in Layer Provided with Oxide Semiconductor>

In the case where an oxide semiconductor is used in the transistor 200, an insulator including an excess-oxygen region is provided in the vicinity of the oxide semiconductor in some cases. In that case, an insulator having a barrier property is preferably provided between the insulator including the excess-oxygen region and a conductor provided in the insulator including the excess-oxygen region.

For example, in FIG. 41, the insulator 241 is preferably provided between the insulator 280 including excess oxygen and the conductor 240. Since the insulator 241 is provided in contact with the insulator 222, the insulator 282, and the insulator 283, the transistor 200 can be sealed with the insulators having a barrier property.

That is, providing the insulator 241 can inhibit excess oxygen included in the insulator 280 from being absorbed by the conductor 240. In addition, providing the insulator 241 can inhibit diffusion of hydrogen, which is an impurity, into the transistor 200 through the conductor 240.

The insulator 241 is preferably formed using an insulating material having a function of inhibiting diffusion of oxygen and an impurity such as water or hydrogen. For example, silicon nitride, silicon nitride oxide, aluminum oxide, hafnium oxide, or the like is preferably used. In particular, silicon nitride is preferable because of its high blocking property against hydrogen. Other than that, a metal oxide such as magnesium oxide, gallium oxide, germanium oxide, yttrium oxide, zirconium oxide, lanthanum oxide, neodymium oxide, or tantalum oxide can be used, for example.

As described in the above embodiment, the transistor 200 may be sealed with the insulator 212, the insulator 214, the insulator 282, and the insulator 283. Such a structure can inhibit entry of hydrogen included in the insulator 274, the insulator 150, or the like into the insulator 280 or the like.

Here, the conductor 240 penetrates the insulator 283 and the insulator 282, and the conductor 218 penetrates the insulator 214 and the insulator 212; however, as described above, the insulator 241 is provided in contact with the conductor 240, and the insulator 217 is provided in contact with the conductor 218. This can reduce the amount of hydrogen entering the inside of the insulator 212, the insulator 214, the insulator 282, and the insulator 283 through the conductor 240 and the conductor 218. In this manner, the transistor 200 is sealed with the insulator 212, the insulator 214, the insulator 282, the insulator 283, the insulator 241, and the insulator 217, so that impurities such as hydrogen included in the insulator 274 or the like can be inhibited from entering from the outside.

### <Dicing Line>

A dicing line (sometimes referred to as a scribe line, a dividing line, or a cutting line) which is provided when a large-sized substrate is divided into semiconductor elements so that a plurality of semiconductor devices are each taken as a chip is described below. Examples of a dividing method include the case where a groove (a dicing line) for dividing the semiconductor elements is formed on the substrate first, and then the substrate is cut along the dicing line to divide (split) it into a plurality of semiconductor devices.

Here, for example, as illustrated in FIG. 41, a region where the insulator 283 and the insulator 214 are in contact with each other is preferably designed to overlap with the dicing line. That is, an opening is provided in the insulator 282, the insulator 280, the insulator 275, the insulator 222, and the insulator 216 in the vicinity of a region to be the dicing line that is provided on an outer edge of the memory cell including the plurality of transistors 200.

That is, in the opening provided in the insulator 282, the insulator 280, the insulator 275, the insulator 222, and the insulator 216, the insulator 214 is in contact with the insulator 283.

For example, an opening may be provided in the insulator 282, the insulator 280, the insulator 275, the insulator 222, the insulator 216, and the insulator 214. With such a structure, in the opening provided in the insulator 282, the insulator 280, the insulator 275, the insulator 222, the insulator 216, and the insulator 214, the insulator 212 is in contact with the insulator 283. Here, the insulator 212 and the insulator 283 may be formed using the same material and the same method. When the insulator 212 and the insulator 283 are formed using the same material and the same method, the adhesion therebetween can be increased. For example, silicon nitride is preferably used.

With the structure, the transistors 200 can be surrounded by the insulator 212, the insulator 214, the insulator 282, and the insulator 283. Since at least one of the insulator 212, the insulator 214, the insulator 282, and the insulator 283 has a function of inhibiting diffusion of oxygen, hydrogen, and water, even when the substrate is divided into circuit regions each of which is provided with the semiconductor elements described in this embodiment to be processed into a plurality of chips, entry and diffusion of an impurity such as hydrogen or water from the side surface direction of the divided substrate into the transistor 200 can be prevented.

With the structure, excess oxygen in the insulator 280 and the insulator 224 can be prevented from being diffused to the outside. Accordingly, excess oxygen in the insulator 280 and the insulator 224 is efficiently supplied to the oxide where the channel is formed in the transistor 200. The oxygen can reduce oxygen vacancies in the oxide where the channel is formed in the transistor 200. Thus, the oxide where the channel is formed in the transistor 200 can be an oxide semiconductor with a low density of defect states and stable characteristics. That is, the transistor 200 can have a small variation in the electrical characteristics and higher reliability.

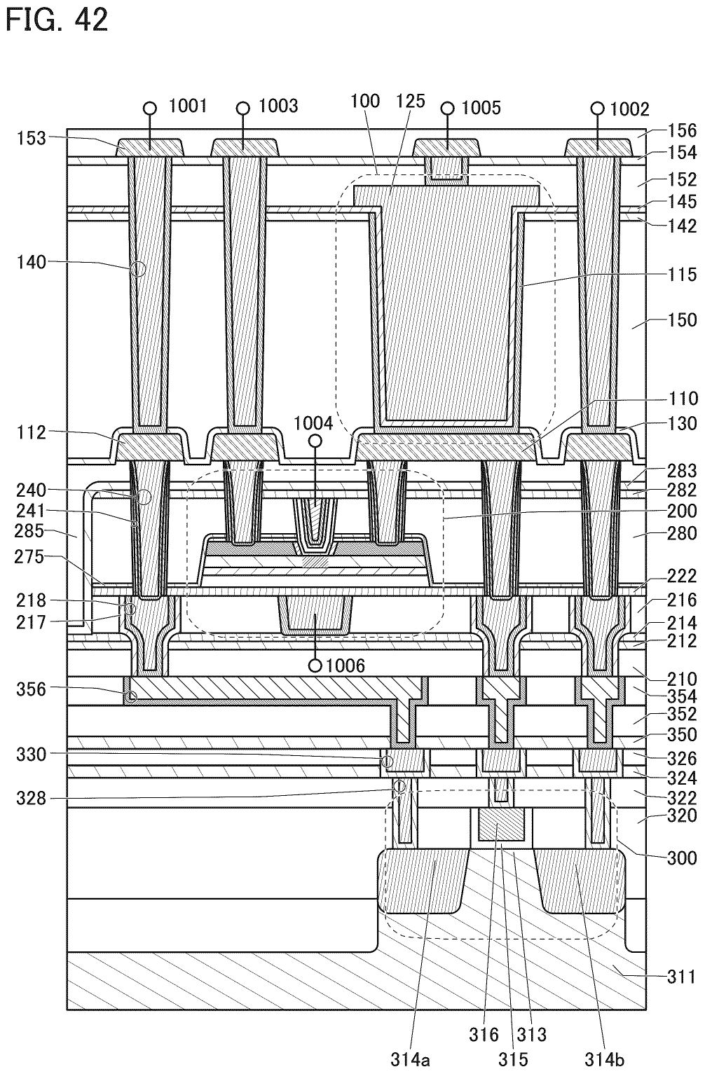

Note that although the capacitor 100 of the storage device illustrated in FIG. 41 has a planar shape, the storage device described in this embodiment is not limited thereto. For example, the capacitor 100 may have a cylindrical shape as illustrated in FIG. 42. Note that the structure below and including the insulator 150 of a storage device illustrated in FIG. 42 is similar to that of the semiconductor device illustrated in FIG. 41.

The capacitor 100 illustrated in FIG. 42 includes the insulator 150 over the insulator 130, an insulator 142 over the insulator 150, a conductor 115 placed in an opening formed in the insulator 150 and the insulator 142, an insulator 145 over the conductor 115 and the insulator 142, a conductor 125 over the insulator 145, and an insulator 152 over the conductor 125 and the insulator 145. Here, at least parts of the conductor 115, the insulator 145, and the conductor 125 are placed in the opening formed in the insulator 150 and the insulator 142.

The conductor 115 functions as a lower electrode of the capacitor 100, the conductor 125 functions as an upper electrode of the capacitor 100, and the insulator 145 functions as a dielectric of the capacitor 100. The capacitor 100 has a structure in which the upper electrode and the lower electrode face each other with the dielectric sandwiched therebetween on the side surface as well as the bottom surface of the opening in the insulator 150 and the insulator 142; thus, the capacitance per unit area can be increased. Thus, the deeper the opening is, the larger the capacitance of the capacitor 100 can be. Increasing the capacitance per unit area of the capacitor 100 in this manner can promote miniaturization or higher integration of the semiconductor device.

An insulator that can be used as the insulator 280 can be used as the insulator 152. The insulator 142 preferably functions as an etching stopper at the time of forming the opening in the insulator 150 and is formed using an insulator that can be used as the insulator 214.

The shape of the opening formed in the insulator 150 and the insulator 142 when seen from above may be a tetragonal shape, a polygonal shape other than a tetragonal shape, a polygonal shape with rounded corners, or a circular shape including an elliptical shape. Here, the area where the opening and the transistor 200 overlap with each other is preferably large in the top view. Such a structure can reduce the area occupied by the semiconductor device including the capacitor 100 and the transistor 200.

The conductor 115 is placed in contact with the opening formed in the insulator 142 and the insulator 150. The top surface of the conductor 115 is preferably level or substantially level with the top surface of the insulator 142. Furthermore, the bottom surface of the conductor 115 is in contact with the conductor 110 through an opening in the insulator 130. The conductor 115 is preferably formed by an ALD method, a CVD method, or the like; for example, a conductor that can be used as the conductor 205 is used.

The insulator 145 is placed to cover the conductor 115 and the insulator 142. The insulator 145 is preferably formed by an ALD method or a CVD method, for example. The insulator 145 can be provided as stacked layers or a single layer using, for example, silicon oxide, silicon oxynitride, silicon nitride oxide, silicon nitride, zirconium oxide, aluminum oxide, aluminum oxynitride, aluminum nitride oxide, aluminum nitride, hafnium oxide, hafnium oxynitride, hafnium nitride oxide, or hafnium nitride. As the insulator 145, an insulating film in which zirconium oxide, aluminum oxide, and zirconium oxide are stacked in this order can be used, for example.

For the insulator 145, a material with high dielectric strength, such as silicon oxynitride, or a high-permittivity (high-k) material is preferably used. Alternatively, a stacked-layer structure of a material with high dielectric strength and a high-permittivity (high-k) material may be used.

Examples of the high-permittivity (high-k) material (a material having a high relative permittivity) include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium. The use of such a high-k material can ensure sufficient capacitance of the capacitor 100 even when the insulator 145 has a large thickness. When the insulator 145 has a large thickness, generation of a leakage current between the conductor 115 and the conductor 125 can be inhibited.

Examples of a material with high dielectric strength include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin. For example, it is possible to use an insulating film in which a film of silicon nitride (SiNx) formed by a PEALD method, a film of silicon oxide (SiOx) formed by a PEALD method, and a film of silicon nitride (SiNx) formed by a PEALD method are stacked in this order. Alternatively, an insulating film in which zirconium oxide, a film of silicon oxide formed by an ALD method, and zirconium oxide are stacked in this order can be used. The use of such an insulator with high dielectric strength can increase the dielectric strength and inhibit electrostatic breakdown of the capacitor 100.

The conductor 125 is placed to fill the opening formed in the insulator 142 and the insulator 150. The conductor 125 is electrically connected to the wiring 1005 through a conductor 140 and a conductor 153. The conductor 125 is preferably formed by an ALD method, a CVD method, or the like; for example, a conductor that can be used as the conductor 205 is used.

The conductor 153 is provided over an insulator 154 and is covered with an insulator 156. The conductor 153 is formed using a conductor that can be used as the conductor 112, and the insulator 156 is formed using an insulator that can be used as the insulator 152. Here, the conductor 153 is in contact with the top surface of the conductor 140 and functions as a terminal of the capacitor 100, the transistor 200, or the transistor 300.

### [Storage Device 2]

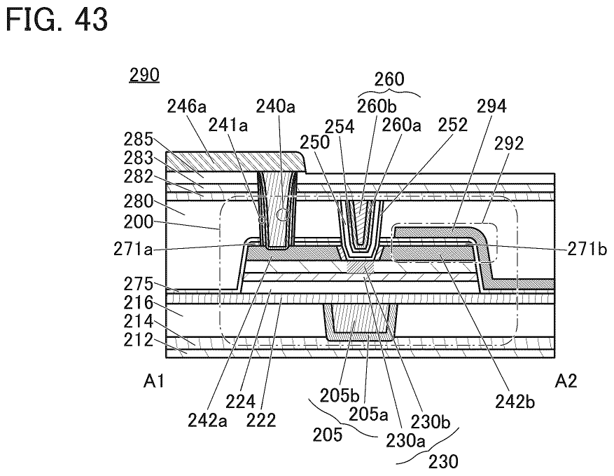

FIG. 43 illustrates an example of a semiconductor device (a storage device) of one embodiment of the present invention.

### Structure Example of Memory Device

FIG. 43 is a cross-sectional view of a semiconductor device including a memory device 290. The memory device 290 illustrated in FIG. 43 includes a capacitor device 292 besides the transistor 200 illustrated in FIG. 14A to FIG. 14D. FIG. 43 corresponds to a cross-sectional view of the transistor 200 in the channel length direction.

The capacitor device 292 includes the conductor 242b; the insulator 271b provided over the conductor 242b; the insulator 275 provided in contact with the top surface of the insulator 271b, the side surface of the insulator 271b, and the side surface of the conductor 242b; and a conductor 294 over the insulator 275. In other words, the capacitor device 292 forms a MIM (Metal-Insulator-Metal) capacitor. Note that one of a pair of electrodes included in the capacitor device 292, i.e., the conductor 242b, can also serve as the source electrode of the transistor 200. The dielectric layer included in the capacitor device 292 can also serve as a protective layer provided in the transistor 200, i.e., the insulator 271 and the insulator 275. Thus, the manufacturing process of the capacitor device 292 can also serve as part of the manufacturing process of the transistor 200, improving the productivity of the semiconductor device. Furthermore, the one of the pair of electrodes included in the capacitor device 292, that is, the conductor 242b, also serves as the source electrode or the drain electrode of the transistor 200; therefore, the area in which the transistor and the capacitor device are placed can be reduced. Note that the conductor 294 is formed using, for example, a material that can be used for the conductor 242.

### Modification Example of Memory Device

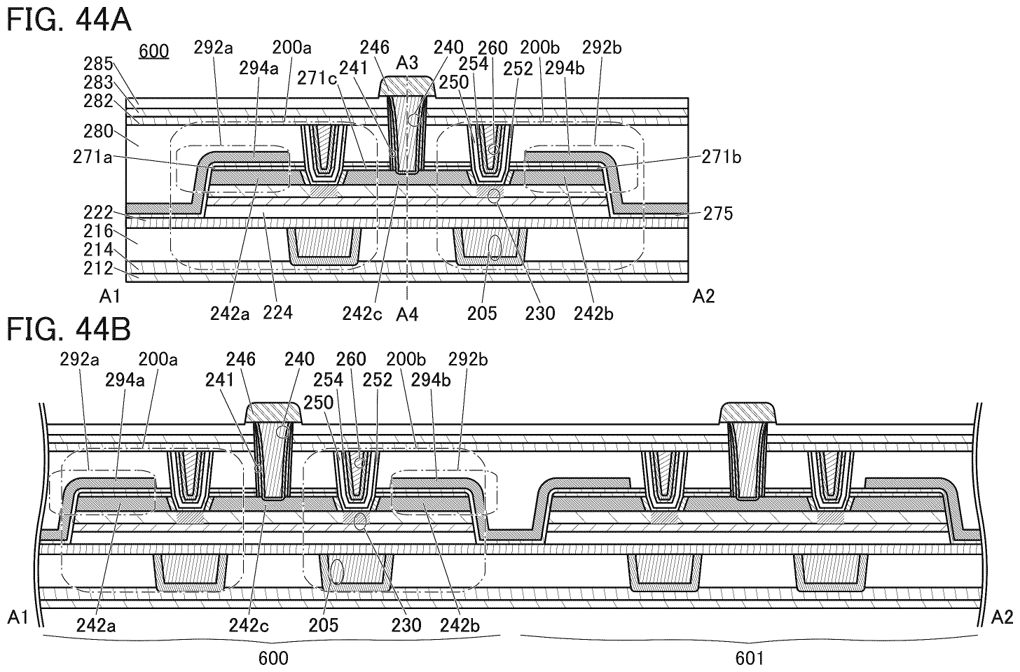

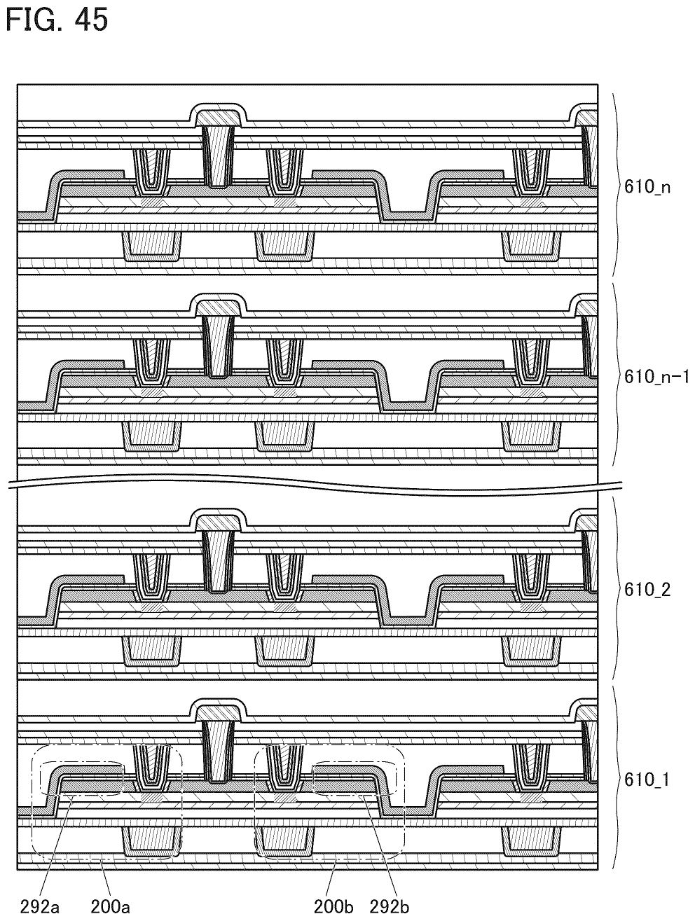

Examples of a semiconductor device of one embodiment of the present invention including the transistor 200 and the capacitor device 292, which are different from the example described above in <Structure example of memory device>, are described below with reference to FIG. 44A, FIG. 44B, and FIG. 45. Note that in the semiconductor devices illustrated in FIG. 44A, FIG. 44B, and FIG. 45, structures having the same function as those included in the semiconductor devices described in the above embodiment and <Structure example of memory device> (see FIG. 43) are denoted by the same reference numerals. Note that the materials described in detail in the above embodiment and <Structure example of memory device> can be used as component materials of the transistor 200 and the capacitor device 292 in this section. The memory devices in FIG. 44A, FIG. 44B, FIG. 45, and the like are, but not limited to, the memory device illustrated in FIG. 43.

### Modification Example 1 of Memory Device

An example of a semiconductor device 600 of one embodiment of the present invention including a transistor 200a, a transistor 200b, a capacitor device 292a, and a capacitor device 292b is described below with reference to FIG. 44A.

FIG. 44A is a cross-sectional view of the semiconductor device 600 including the transistor 200a, the transistor 200b, the capacitor device 292a, and the capacitor device 292b in the channel length direction. Here, the capacitor device 292a includes the conductor 242a; the insulator 271a over the conductor 242a; the insulator 275 in contact with the top surface of the insulator 271a, the side surface of the insulator 271a, and the side surface of the conductor 242a; and a conductor 294a over the insulator 275. The capacitor device 292b includes the conductor 242b; the insulator 271b over the conductor 242b; the insulator 275 in contact with the top surface of the insulator 271b, the side surface of the insulator 271b, and the side surface of the conductor 242b; and a conductor 294b over the insulator 275.

The semiconductor device 600 has a line-symmetric structure with respect to dashed-dotted line A3-A4 as illustrated in FIG. 44A. A conductor 242c serves as one of a source electrode and a drain electrode of the transistor 200a and one of a source electrode and a drain electrode of the transistor 200b. An insulator 271c is provided over the conductor 242c. The conductor 240 functioning as a plug connects the conductor 246 functioning as a wiring and the transistor 200a to each other, and also connects the conductor 246 functioning as a wiring and the transistor 200b to each other. With the above connection structure between the two transistors, the two capacitor devices, the wiring, and the plug, a semiconductor device that can be miniaturized or highly integrated can be provided.

The structure examples of the semiconductor device illustrated in FIG. 44A can be referred to for the structures and the effects of the transistor 200a, the transistor 200b, the capacitor device 292a, and the capacitor device 292b.

### Modification Example 2 of Memory Device

In the above description, the transistor 200a, the transistor 200b, the capacitor device 292a, and the capacitor device 292b are given as examples of components of the semiconductor device; however, the semiconductor device described in this embodiment is not limited thereto. For example, as illustrated in FIG. 44B, a structure may be employed in which the semiconductor device 600 and a semiconductor device having a structure similar to that of the semiconductor device 600 are connected through a capacitor portion. In this specification, the semiconductor device including the transistor 200a, the transistor 200b, the capacitor device 292a, and the capacitor device 292b is referred to as a cell. For the structures of the transistor 200a, the transistor 200b, the capacitor device 292a, and the capacitor device 292b, the above description of the transistor 200a, the transistor 200b, the capacitor device 292a, and the capacitor device 292b can be referred to.

FIG. 44B is a cross-sectional view in which the semiconductor device 600 including the transistor 200a, the transistor 200b, the capacitor device 292a, and the capacitor device 292b, and a cell having a structure similar to that of the semiconductor device 600 are connected through a capacitor portion.

As illustrated in FIG. 44B, the conductor 294b functioning as one electrode of the capacitor device 292b included in the semiconductor device 600 also serves as one electrode of a capacitor device included in a semiconductor device 601 having a structure similar to that of the semiconductor device 600. Although not illustrated, the conductor 294a functioning as one electrode of the capacitor device 292a included in the semiconductor device 600 also serves as one electrode of a capacitor device included in a semiconductor device on the left side of the semiconductor device 600, that is, a semiconductor device adjacent to the semiconductor device 600 in the A1 direction in FIG. 44B. The cell on the right side of the semiconductor device 601, that is, the cell in the A2 direction in FIG. 44B, has a similar structure. That is, a cell array (also referred to as a memory device layer) can be formed. With such a structure of the cell array, the space between adjacent cells can be reduced; thus, the projected area of the cell array can be reduced and high integration can be achieved. When matrix arrangement is employed in the cell array illustrated in FIG. 44B, a matrix-shape cell array can be formed.

When the transistor 200a, the transistor 200b, the capacitor device 292a, and the capacitor device 292b are formed to have the structures described in this embodiment as described above, the area of the cell can be reduced and the semiconductor device including a cell array can be miniaturized or highly integrated.

Furthermore, the cell array may have a stacked-layer structure instead of a single-layer structure. FIG. 45 is a cross-sectional view of n layers of cell arrays 610 that are stacked. When a plurality of cell arrays (a cell array 610_1 to a cell array 610_n) are stacked as illustrated in FIG. 45, cells can be integrally placed without increasing the area occupied by the cell arrays. In other words, a 3D cell array can be formed.

At least part of the structure, method, and the like described in this embodiment can be implemented in an appropriate combination with any of those in the other embodiments, the other examples, and the like described in this specification.

### Embodiment 5

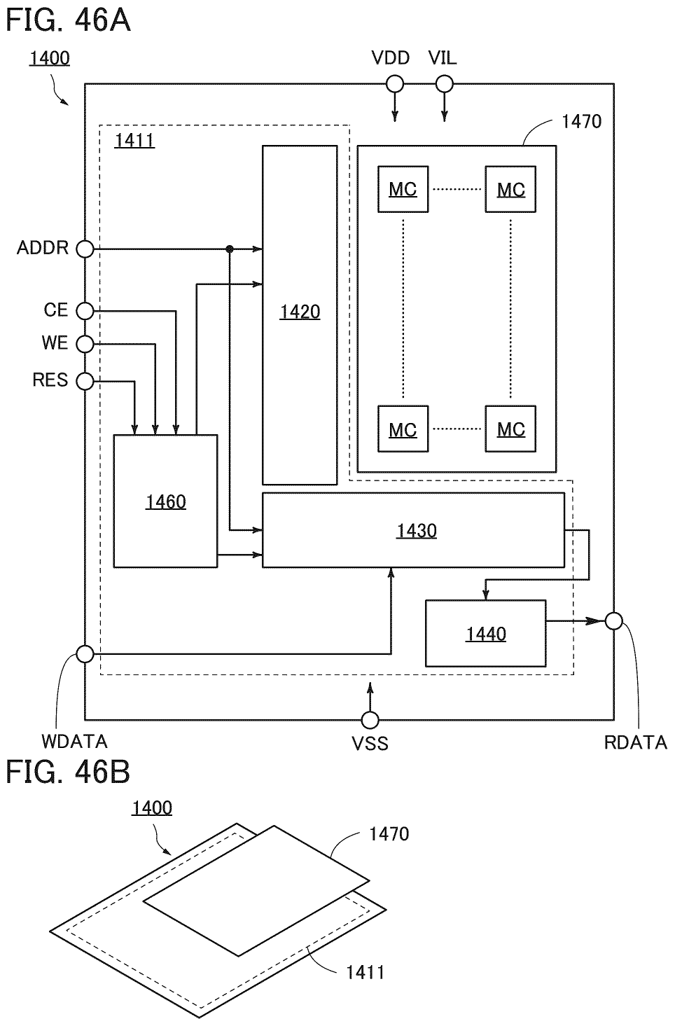

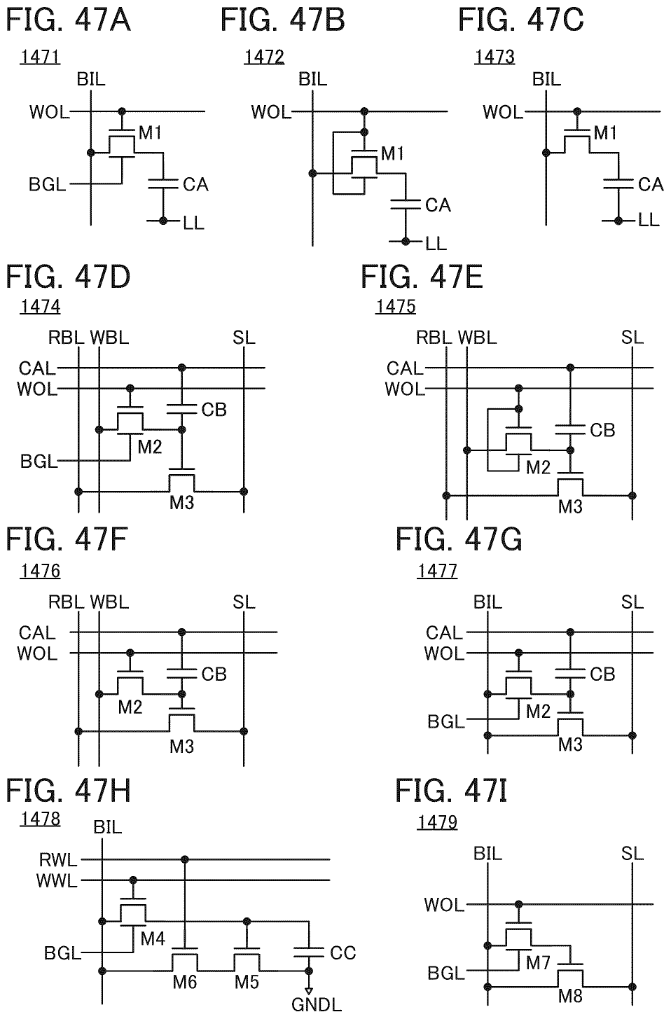

In this embodiment, a storage device (hereinafter, sometimes referred to as an OS memory apparatus) of one embodiment of the present invention including a transistor (hereinafter, sometimes referred to as an OS transistor) in which an oxide is used as a semiconductor and a capacitor is described with reference to FIG. 46A, FIG. 46B, and FIG. 47A to FIG. 47I. The OS memory apparatus is a storage device that includes at least a capacitor and an OS transistor that controls the charging and discharging of the capacitor. Since the OS transistor has an extremely low off-state current, the OS memory apparatus has excellent retention characteristics and thus can function as a nonvolatile memory.

### Structure Example of Storage Device

FIG. 46A illustrates a structure example of the OS memory apparatus. A storage device 1400 includes a peripheral circuit 1411 and a memory cell array 1470. The peripheral circuit 1411 includes a row circuit 1420, a column circuit 1430, an output circuit 1440, and a control logic circuit 1460.

The column circuit 1430 includes, for example, a column decoder, a precharge circuit, a sense amplifier, a write circuit, and the like. The precharge circuit has a function of precharging wirings. The sense amplifier has a function of amplifying a data signal read from a memory cell. Note that the wirings are connected to the memory cell included in the memory cell array 1470, and are described later in detail. The amplified data signal is output as a data signal RDATA to the outside of the storage device 1400 through the output circuit 1440. The row circuit 1420 includes, for example, a row decoder and a word line driver circuit, and can select a row to be accessed.

As power supply voltages from the outside, a low power supply voltage (VSS), a high power supply voltage (VDD) for the peripheral circuit 1411, and a high power supply voltage (VIL) for the memory cell array 1470 are supplied to the storage device 1400. Control signals (CE, WE, and RES), an address signal ADDR, and a data signal WDATA are also input to the storage device 1400 from the outside. The address signal ADDR is input to the row decoder and the column decoder, and the data signal WDATA is input to the write circuit.

The control logic circuit 1460 processes the control signals (CE, WE, and RES) input from the outside, and generates control signals for the row decoder and the column decoder. The control signal CE is a chip enable signal, the control signal WE is a write enable signal, and the control signal RES is a read enable signal. Signals processed by the control logic circuit 1460 are not limited thereto, and other control signals are input as necessary.

The memory cell array 1470 includes a plurality of memory cells MC arranged in a matrix and a plurality of wirings. Note that the number of wirings that connect the memory cell array 1470 to the row circuit 1420 depends on the structure of the memory cell MC, the number of memory cells MC in a column, and the like. The number of wirings that connect the memory cell array 1470 to the column circuit 1430 depends on the structure of the memory cell MC, the number of memory cells MC in a row, and the like.

Note that FIG. 46A illustrates an example where the peripheral circuit 1411 and the memory cell array 1470 are formed on the same plane; however, this embodiment is not limited to the example. For example, as illustrated in FIG. 46B, the memory cell array 1470 may be provided to overlap with part of the peripheral circuit 1411. For example, the sense amplifier may be provided below the memory cell array 1470 so that they overlap with each other.

FIG. 47A to FIG. 47I illustrate structure examples of a memory cell that can be used as the memory cell MC.

### [DOSRAM]

FIG. 47A to FIG. 47C illustrate circuit structure examples of a memory cell of a DRAM. In this specification and the like, a DRAM using a memory cell including one OS transistor and one capacitor is referred to as a DOSRAM (Dynamic Oxide Semiconductor Random Access Memory) in some cases. A memory cell 1471 illustrated in FIG. 47A includes a transistor M1 and a capacitor CA. Note that the transistor M1 includes a gate (sometimes referred to as a top gate) and a back gate.

A first terminal of the transistor M1 is connected to a first terminal of the capacitor CA. A second terminal of the transistor M1 is connected to a wiring BIL. The gate of the transistor M1 is connected to a wiring WOL. The back gate of the transistor M1 is connected to a wiring BGL. A second terminal of the capacitor CA is connected to a wiring LL.

The wiring BIL functions as a bit line, and the wiring WOL functions as a word line. The wiring LL functions as a wiring for applying a predetermined potential to the second terminal of the capacitor CA. In the time of data writing and data reading, the wiring LL may be at a ground potential or a low-level potential. The wiring BGL functions as a wiring for applying a potential to the back gate of the transistor M1. When a given potential is applied to the wiring BGL, the threshold voltage of the transistor M1 can be increased or decreased.

Here, a memory cell 1471 illustrated in FIG. 47A corresponds to the storage device illustrated in FIG. 43. That is, the transistor M1 and the capacitor CA correspond to the transistor 200 and the capacitor device 292, respectively.

The circuit structure of the memory cell MC is not limited to that of the memory cell 1471 and can be changed. For example, as in a memory cell 1472 illustrated in FIG. 47B, the back gate of the transistor M1 may be connected not to the wiring BGL but to the wiring WOL in the memory cell MC. Alternatively, for example, the transistor M1 may be a single-gate transistor, i.e., a transistor without a back gate, in the memory cell MC as in a memory cell 1473 illustrated in FIG. 47C.

In the case where the semiconductor device described in any of the above embodiments is used in the memory cell 1471 and the like, the transistor 200 can be used as the transistor M1, and the capacitor 100 can be used as the capacitor CA. When an OS transistor is used as the transistor M1, the off-state current of the transistor M1 can be extremely low. That is, with the use of the transistor M1, written data can be retained for a long time, and thus the frequency of the refresh operation for the memory cell can be reduced. Alternatively, refresh operation for the memory cell can be unnecessary. In addition, since the transistor M1 has an extremely low off-state current, multi-level data or analog data can be retained in the memory cell 1471, the memory cell 1472, and the memory cell 1473.

In the DOSRAM, when the sense amplifier is provided below the memory cell array 1470 so that they overlap with each other as described above, the bit line can be shortened. This reduces bit line capacitance, which can reduce the storage capacitance of the memory cell.

### [NOSRAM]

FIG. 47D to FIG. 47G each illustrate a circuit structure example of a gain-cell memory cell including two transistors and one capacitor. A memory cell 1474 illustrated in FIG. 47D includes a transistor M2, a transistor M3, and a capacitor CB. Note that the transistor M2 includes a top gate (simply referred to as a gate in some cases) and a back gate. In this specification and the like, a storage device including a gain-cell memory cell using an OS transistor as the transistor M2 is referred to as a NOSRAM (Nonvolatile Oxide Semiconductor RAM) in some cases.

A first terminal of the transistor M2 is connected to a first terminal of the capacitor CB. A second terminal of the transistor M2 is connected to a wiring WBL. The gate of the transistor M2 is connected to the wiring WOL. The back gate of the transistor M2 is connected to the wiring BGL. A second terminal of the capacitor CB is connected to a wiring CAL. A first terminal of the transistor M3 is connected to a wiring RBL. A second terminal of the transistor M3 is connected to a wiring SL. A gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. In the time of data writing and data reading, a high-level potential is preferably applied to the wiring CAL. In the time of data retaining, a low-level potential is preferably applied to the wiring CAL. The wiring BGL functions as a wiring for applying a potential to the back gate of the transistor M2. When a given potential is applied to the wiring BGL, the threshold voltage of the transistor M2 can be increased or decreased.

Here, the memory cell 1474 illustrated in FIG. 47D corresponds to the storage device illustrated in FIG. 41 and FIG. 42. That is, the transistor M2, the capacitor CB, the transistor M3, the wiring WBL, the wiring WOL, the wiring BGL, the wiring CAL, the wiring RBL, and the wiring SL correspond to the transistor 200, the capacitor 100, the transistor 300, the wiring 1003, the wiring 1004, the wiring 1006, the wiring 1005, the wiring 1002, and the wiring 1001, respectively.

The circuit structure of the memory cell MC is not limited to that of the memory cell 1474 and can be changed as appropriate. For example, as in a memory cell 1475 illustrated in FIG. 47E, the back gate of the transistor M2 may be connected not to the wiring BGL but to the wiring WOL in the memory cell MC. Alternatively, for example, the transistor M2 may be a single-gate transistor, i.e., a transistor without a back gate, in the memory cell MC as in a memory cell 1476 illustrated in FIG. 47F. For example, the memory cell MC may have a structure in which the wiring WBL and the wiring RBL are combined into one wiring BIL as in a memory cell 1477 illustrated in FIG. 47G.

In the case where the semiconductor device described in any of the above embodiments is used in the memory cell 1474 and the like, the transistor 200 can be used as the transistor M2, the transistor 300 can be used as the transistor M3, and the capacitor 100 can be used as the capacitor CB. When an OS transistor is used as the transistor M2, the off-state current of the transistor M2 can be extremely low. Consequently, with the use of the transistor M2, written data can be retained for a long time, and thus the frequency of the refresh operation for the memory cell can be reduced. Alternatively, refresh operation for the memory cell can be unnecessary. In addition, since the transistor M2 has an extremely low off-state current, multi-level data or analog data can be retained in the memory cell 1474. The same applies to the memory cell 1475 to the memory cell 1477.

Note that the transistor M3 may be a transistor including silicon in a channel formation region (hereinafter, sometimes referred to as a Si transistor). The Si transistor may be either an n-channel transistor or a p-channel transistor. A Si transistor has higher field-effect mobility than an OS transistor in some cases. Therefore, a Si transistor may be used as the transistor M3 functioning as a reading transistor. Furthermore, the transistor M2 can be stacked over the transistor M3 when a Si transistor is used as the transistor M3, in which case the area occupied by the memory cell can be reduced, leading to high integration of the storage device.

Alternatively, the transistor M3 may be an OS transistor. When an OS transistor is used as each of the transistor M2 and the transistor M3, the circuit of the memory cell array 1470 can be formed using only n-channel transistors.

FIG. 47H illustrates an example of a gain-cell memory cell including three transistors and one capacitor. A memory cell 1478 illustrated in FIG. 47H includes a transistor M4 to a transistor M6 and a capacitor CC. The capacitor CC is provided as appropriate. The memory cell 1478 is electrically connected to the wiring BIL, a wiring RWL, a wiring WWL, the wiring BGL, and a wiring GNDL. The wiring GNDL is a wiring for supplying a low-level potential. Note that the memory cell 1478 may be electrically connected to the wiring RBL and the wiring WBL instead of the wiring BIL.

The transistor M4 is an OS transistor with a back gate, and the back gate is electrically connected to the wiring BGL. Note that the back gate and the gate of the transistor M4 may be electrically connected to each other. Alternatively, the transistor M4 does not necessarily include the back gate.

Note that each of the transistor M5 and the transistor M6 may be an n-channel Si transistor or a p-channel Si transistor. Alternatively, the transistor M4 to the transistor M6 may be OS transistors. In this case, the circuit of the memory cell array 1470 can be formed using only n-channel transistors.

In the case where the semiconductor device described in any of the above embodiments is used in the memory cell 1478, the transistor 200 can be used as the transistor M4, the transistors 300 can be used as the transistor M5 and the transistor M6, and the capacitor 100 can be used as the capacitor CC. When an OS transistor is used as the transistor M4, the off-state current of the transistor M4 can be extremely low.

FIG. 47I illustrates an example of a gain-cell memory cell including two transistors. A memory cell 1479 illustrated in FIG. 47I includes a transistor M7 and a transistor M8. The memory cell 1479 is electrically connected to the wiring BIL, the wiring WWL, the wiring BGL, and the wiring SL.

The transistor M7 is an OS transistor with a back gate, and the back gate is electrically connected to the wiring BGL. Note that the back gate and the gate of the transistor M7 may be electrically connected to each other. Alternatively, the transistor M7 does not necessarily include the back gate.

In the memory cell 1479 illustrated in FIG. 47I, the gate capacitance of the transistor M8 is used as storage capacitance. That is, the memory cell 1479 can be regarded as a capacitor-less memory cell. The memory cell 1479 can be regarded as the memory cell 1477 illustrated in FIG. 47G from which the capacitor CB is omitted, and can be regarded as a gain-cell memory cell with two transistors and no capacitor.

When the OS transistor is used as the transistor M7 and the transistor M7 is turned off, charge at a node where one of a source electrode and a drain electrode of the transistor M7 is electrically connected to a gate electrode of the transistor M8 can be retained for an extremely long time. Accordingly, a nonvolatile memory cell can be obtained.

The transistor M8 may be an n-channel Si transistor or a p-channel Si transistor.

In the case where the semiconductor device described in any of the above embodiments is used in the memory cell 1479, the transistor 200 can be used as the transistor M7, and the transistor 300 can be used as the transistor M8. When an OS transistor is used as the transistor M7, the off-state current of the transistor M7 can be extremely low.

Alternatively, the transistor M8 may be an OS transistor. In this case, the circuit of the memory cell array 1470 can be formed using only n-channel transistors.

In the case where the semiconductor device described in any of the above embodiments is used in the memory cell 1479, the transistor 200 can be used as the transistor M7 and the transistor M8. With this structure, the transistor M7 and the transistor M8 can be formed in the same layer. Accordingly, a fabrication process at the time of stacking layers each including the memory cell 1479 can be simple and the productivity can be high as compared with the case where the transistor M7 and the transistor M8 are formed in different layers.

In the case where the transistor 200 is used as each of the transistor M7 and the transistor M8, the components (including a channel length, a channel width, a cross-sectional shape, and the like) of the transistor can be determined as appropriate in accordance with the characteristics required for the transistor M7 and the transistor M8.

Note that there is no particular limitation on the structure of the transistor M8 regardless of the semiconductor material used for the transistor M8. For example, a planar transistor, a staggered transistor, an inverted staggered transistor, or the like can be used. In addition, either of a top-gate transistor structure and a bottom-gate transistor structure may be employed. Alternatively, gates may be provided above and below a semiconductor layer where a channel is formed.

Note that the structures of the peripheral circuit 1411, the memory cell array 1470, and the like described in this embodiment are not limited to the above. The arrangement and functions of these circuits and the wirings, circuit components, and the like connected to the circuits can be changed, removed, or added as needed.

The structure, method, and the like described in this embodiment can be used in an appropriate combination with any of other structures, methods, and the like described in this embodiment or any of structures, methods, and the like described in the other embodiments.

### Embodiment 6

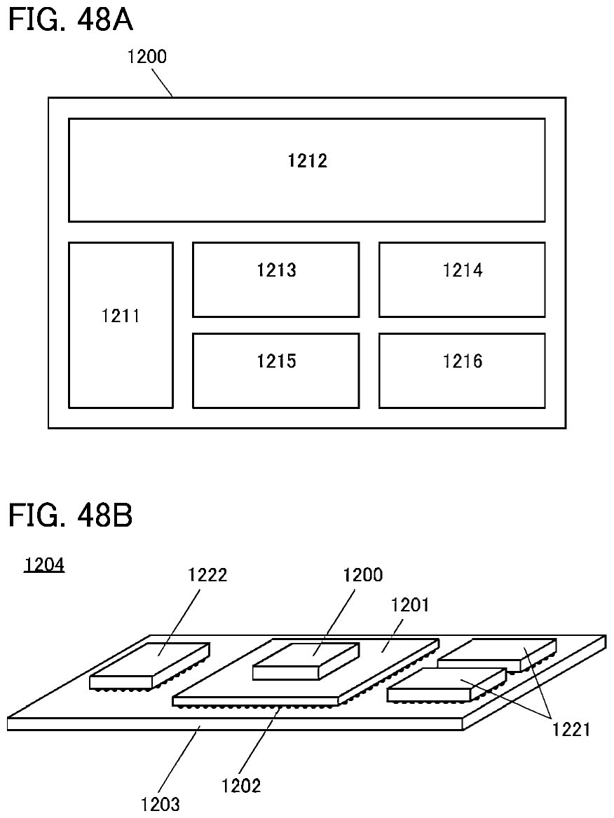

In this embodiment, an example of a chip 1200 on which the semiconductor device of the present invention is mounted is described with reference to FIG. 48A and FIG. 48B. A plurality of circuits (systems) are mounted on the chip 1200. A technique for integrating a plurality of circuits (systems) into one chip is referred to as system on chip (SoC) in some cases.

As illustrated in FIG. 48A, the chip 1200 includes a CPU 1211, a GPU 1212, one or more analog arithmetic units 1213, one or more memory controllers 1214, one or more interfaces 1215, one or more network circuits 1216, and the like.

A bump (not illustrated) is provided on the chip 1200, and as illustrated in FIG. 48B, the chip 1200 is connected to a first surface of a package substrate 1201. In addition, a plurality of bumps 1202 are provided on a rear side of the first surface of the package substrate 1201, and the package substrate 1201 is connected to a motherboard 1203.

Storage devices such as DRAMs 1221 and a flash memory 1222 may be provided over the motherboard 1203. For example, the DOSRAM described in the above embodiment can be used as the DRAM 1221. In addition, for example, the NOSRAM described in the above embodiment can be used as the flash memory 1222.

The CPU 1211 preferably includes a plurality of CPU cores. In addition, the GPU 1212 preferably includes a plurality of GPU cores. Furthermore, the CPU 1211 and the GPU 1212 may each include a memory for temporarily storing data. Alternatively, a common memory for the CPU 1211 and the GPU 1212 may be provided in the chip 1200. The NOSRAM or the DOSRAM described above can be used as the memory. Moreover, the GPU 1212 is suitable for parallel computation of a number of data and thus can be used for image processing or product-sum operation. When an image processing circuit or a product-sum operation circuit including an oxide semiconductor of the present invention is provided in the GPU 1212, image processing and product-sum operation can be performed with low power consumption.

In addition, since the CPU 1211 and the GPU 1212 are provided on the same chip, a wiring between the CPU 1211 and the GPU 1212 can be shortened, and the data transfer from the CPU 1211 to the GPU 1212, the data transfer between memories included in the CPU 1211 and the GPU 1212, and the transfer of arithmetic operation results from the GPU 1212 to the CPU 1211 after the arithmetic operation in the GPU 1212 can be performed at high speed.

The analog arithmetic unit 1213 includes one or both of an A/D (analog/digital) converter circuit and a D/A (digital/analog) converter circuit. Furthermore, the product-sum operation circuit may be provided in the analog arithmetic unit 1213.

The memory controller 1214 includes a circuit functioning as a controller of the DRAM 1221 and a circuit functioning as an interface of the flash memory 1222.

The interface 1215 includes an interface circuit for an external connection device such as a display device, a speaker, a microphone, a camera, or a controller. Examples of the controller include a mouse, a keyboard, and a game controller. As such an interface, a USB (Universal Serial Bus), an HDMI (registered trademark) (High-Definition Multimedia Interface), or the like can be used.

The network circuit 1216 includes a network circuit such as a LAN (Local Area Network). The network circuit 1216 may further include a circuit for network security.

The circuits (systems) can be formed in the chip 1200 through the same manufacturing process. Therefore, even when the number of circuits needed for the chip 1200 increases, there is no need to increase the number of steps in the manufacturing process; thus, the chip 1200 can be manufactured at low cost.

The motherboard 1203 provided with the package substrate 1201 on which the chip 1200 including the GPU 1212 is mounted, the DRAMs 1221, and the flash memory 1222 can be referred to as a GPU module 1204.

The GPU module 1204 includes the chip 1200 using SoC technology, and thus can have a small size. In addition, the GPU module 1204 is excellent in image processing, and thus is suitably used in a portable electronic appliance such as a smartphone, a tablet terminal, a laptop PC, or a portable (mobile) game machine. Furthermore, the product-sum operation circuit using the GPU 1212 can perform a method such as a deep neural network (DNN), a convolutional neural network (CNN), a recurrent neural network (RNN), an autoencoder, a deep Boltzmann machine (DBM), or a deep belief network (DBN); hence, the chip 1200 can be used as an AI chip or the GPU module 1204 can be used as an AI system module.

At least part of the structure, method, and the like described in this embodiment can be implemented in an appropriate combination with any of those in the other embodiments, the other examples, and the like described in this specification.

### Embodiment 7

In this embodiment, examples of electronic components and electronic appliances in which the storage device or the like described in the above embodiment is incorporated are described.

### <Electronic Component>

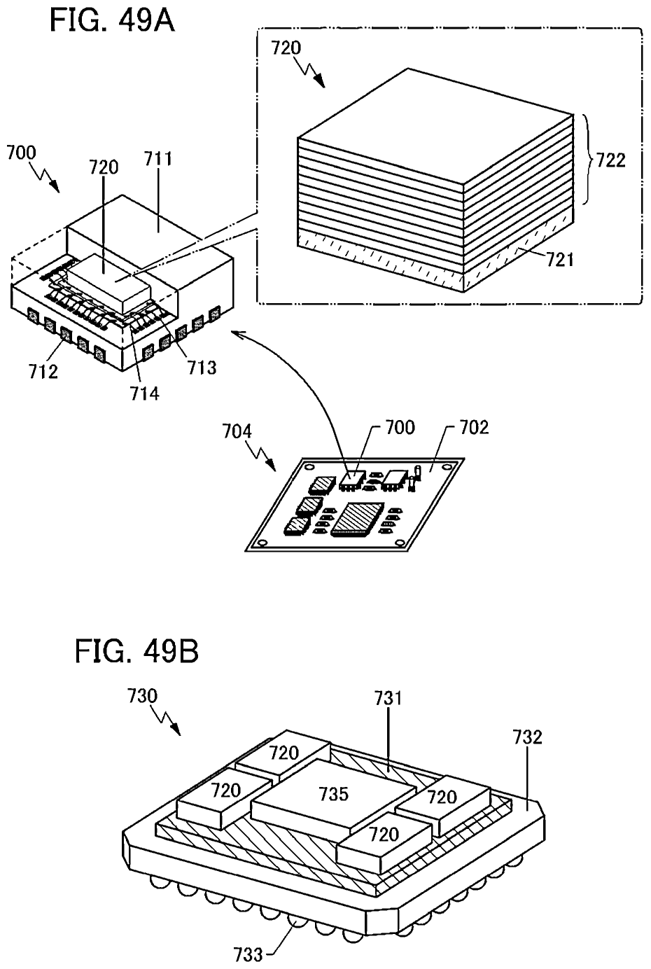

First, examples of an electronic component including a storage device 720 are described with reference to FIG. 49A and FIG. 49B.

FIG. 49A is a perspective view of an electronic component 700 and a substrate (mounting board 704) on which the electronic component 700 is mounted. The electronic component 700 illustrated in FIG. 49A includes the storage device 720 in a mold 711. FIG. 49A omits part of the electronic component to show the inside of the electronic component 700. The electronic component 700 includes a land 712 outside the mold 711. The land 712 is electrically connected to an electrode pad 713, and the electrode pad 713 is electrically connected to the storage device 720 via a wire 714. The electronic component 700 is mounted on a printed circuit board 702, for example. A plurality of such electronic components are combined and electrically connected to each other on the printed circuit board 702, which forms the mounting board 704.

The storage device 720 includes a driver circuit layer 721 and a storage circuit layer 722.

FIG. 49B is a perspective view of an electronic component 730. The electronic component 730 is an example of a SiP (System in package) or an MCM (Multi Chip Module). In the electronic component 730, an interposer 731 is provided over a package substrate 732 (printed circuit board) and a semiconductor device 735 and a plurality of storage devices 720 are provided over the interposer 731.

The electronic component 730 using the storage device 720 as a high bandwidth memory (HBM) is illustrated as an example. An integrated circuit (a semiconductor device) such as a CPU, a GPU, or an FPGA can be used as the semiconductor device 735.

As the package substrate 732, a ceramic substrate, a plastic substrate, a glass epoxy substrate, or the like can be used. As the interposer 731, a silicon interposer, a resin interposer, or the like can be used.

The interposer 731 includes a plurality of wirings and has a function of electrically connecting a plurality of integrated circuits with different terminal pitches. The plurality of wirings have a single-layer structure or a layered structure. The interposer 731 has a function of electrically connecting an integrated circuit provided on the interposer 731 to an electrode provided on the package substrate 732. Accordingly, the interposer is sometimes referred to as a “redistribution substrate” or an “intermediate substrate”. A through electrode may be provided in the interposer 731 to be used for electrically connecting the integrated circuit and the package substrate 732. In the case of using a silicon interposer, a TSV (Through Silicon Via) can also be used as the through electrode.

A silicon interposer is preferably used as the interposer 731. The silicon interposer can be manufactured at lower cost than an integrated circuit because it is not necessary to provide an active element. Meanwhile, since wirings of the silicon interposer can be formed through a semiconductor process, the formation of minute wirings, which is difficult for a resin interposer, is easily achieved.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in expansion coefficient between an integrated circuit and the interposer is less likely to occur. Furthermore, a surface of a silicon interposer has high planarity, and a poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

A heat sink (radiator plate) may be provided to overlap with the electronic component 730. In the case of providing a heat sink, the heights of integrated circuits provided on the interposer 731 are preferably the same. In the electronic component 730 of this embodiment, the heights of the storage device 720 and the semiconductor device 735 are preferably the same, for example.

An electrode 733 may be provided on the bottom portion of the package substrate 732 to mount the electronic component 730 on another substrate. FIG. 49B illustrates an example where the electrode 733 is formed of a solder ball. Solder balls are provided in a matrix on the bottom portion of the package substrate 732, whereby a BGA (Ball Grid Array) mounting can be achieved. Alternatively, the electrode 733 may be formed of a conductive pin. When conductive pins are provided in a matrix on the bottom portion of the package substrate 732, a PGA (Pin Grid Array) mounting can be achieved.

The electronic component 730 can be mounted on another substrate by various mounting methods not limited to BGA and PGA. For example, a mounting method such as SPGA (Staggered Pin Grid Array), LGA (Land Grid Array), QFP (Quad Flat Package), QFJ (Quad Flat J-leaded package), or QFN (Quad Flat Non-leaded package) can be employed.

The structure, method, and the like described in this embodiment can be used in an appropriate combination with any of other structures, methods, and the like described in this embodiment or any of structures, methods, and the like described in the other embodiments.

### Embodiment 8

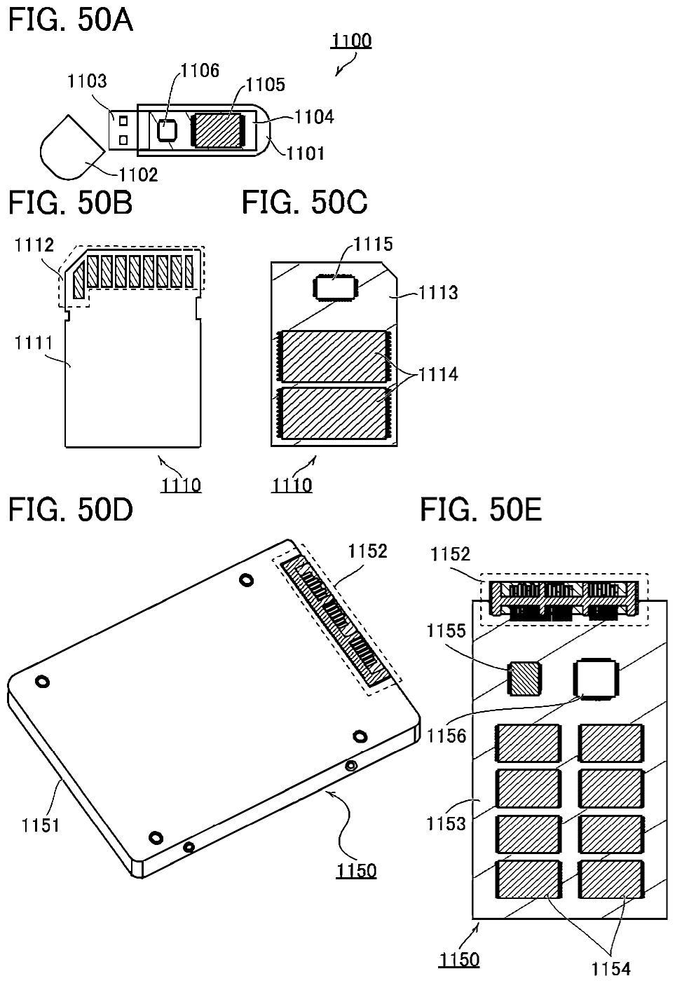

In this embodiment, application examples of the storage device using the semiconductor device described in the above embodiment are described. The semiconductor device described in the above embodiment can be applied to, for example, storage devices of a variety of electronic appliances (e.g., information terminals, computers, smartphones, e-book readers, digital cameras (including video cameras), video recording/reproducing devices, and navigation systems). Here, the computers refer not only to tablet computers, notebook computers, and desktop computers, but also to large computers such as server systems. Alternatively, the semiconductor device described in the above embodiment is applied to a variety of removable storage devices such as memory cards (e.g., SD cards), USB memories, and SSDs (solid state drives). FIG. 50A to FIG. 50E schematically illustrate some structure examples of removable storage devices. The semiconductor device described in the above embodiment is processed into a packaged memory chip and used in a variety of storage devices and removable memories, for example.

FIG. 50A is a schematic view of a USB memory. A USB memory 1100 includes a housing 1101, a cap 1102, a USB connector 1103, and a substrate 1104. The substrate 1104 is held in the housing 1101. The substrate 1104 is provided with a memory chip 1105 and a controller chip 1106, for example. The semiconductor device described in the above embodiment can be incorporated in the memory chip 1105 or the like.

FIG. 50B is a schematic external view of an SD card, and FIG. 50C is a schematic view of the internal structure of the SD card. An SD card 1110 includes a housing 1111, a connector 1112, and a substrate 1113. The substrate 1113 is held in the housing 1111. The substrate 1113 is provided with a memory chip 1114 and a controller chip 1115, for example. When the memory chip 1114 is also provided on the back side of the substrate 1113, the capacity of the SD card 1110 can be increased. In addition, a wireless chip with a radio communication function may be provided on the substrate 1113. This enables data reading and writing of the memory chip 1114 by wireless communication between a host device and the SD card 1110. The semiconductor device described in the above embodiment can be incorporated in the memory chip 1114 or the like.

FIG. 50D is a schematic external view of an SSD, and FIG. 50E is a schematic view of the internal structure of the SSD. An SSD 1150 includes a housing 1151, a connector 1152, and a substrate 1153. The substrate 1153 is held in the housing 1151. The substrate 1153 is provided with a memory chip 1154, a memory chip 1155, and a controller chip 1156, for example. The memory chip 1155 is a work memory of the controller chip 1156, and a DOSRAM chip can be used, for example. When the memory chip 1154 is also provided on the back side of the substrate 1153, the capacity of the SSD 1150 can be increased. The semiconductor device described in the above embodiment can be incorporated in the memory chip 1154 or the like.

At least part of the structure, method, and the like described in this embodiment can be implemented in an appropriate combination with any of those in the other embodiments, the other examples, and the like described in this specification.

### Embodiment 9

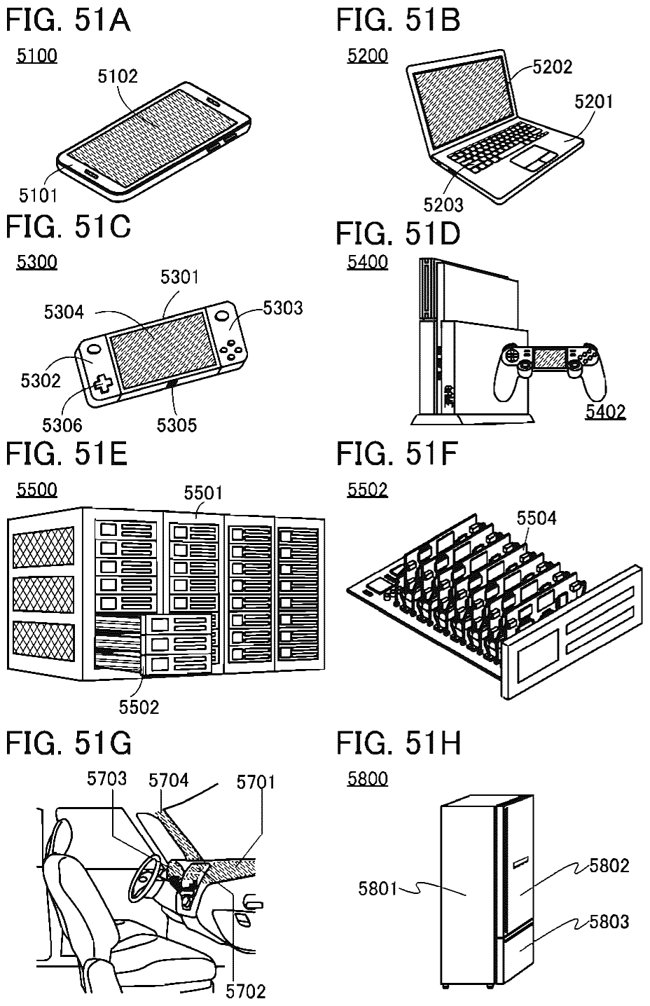

The semiconductor device of one embodiment of the present invention can be used as a processor such as a CPU and a GPU, a storage device, or a chip. FIG. 51A to FIG. 51H illustrate specific examples of electronic appliances including a storage device, a chip, or a processor such as a CPU or a GPU of one embodiment of the present invention.

### <Electronic Appliance and System>

The GPU, the storage device, or the chip of one embodiment of the present invention can be mounted on a variety of electronic appliances. Examples of electronic appliances include a digital camera, a digital video camera, a digital photo frame, an e-book reader, a mobile phone, a portable game machine, a portable information terminal, and an audio reproducing device in addition to electronic appliances provided with a relatively large screen, such as a television device, a monitor for a desktop or notebook information terminal or the like, digital signage, and a large game machine like a pachinko machine. When the GPU, the storage device, or the chip of one embodiment of the present invention is provided in the electronic appliance, the electronic appliance can include artificial intelligence.

The electronic appliance of one embodiment of the present invention may include an antenna. When a signal is received by the antenna, the electronic appliance can display a video, data, or the like on a display portion. When the electronic appliance includes the antenna and a secondary battery, the antenna may be used for contactless power transmission.

The electronic appliance of one embodiment of the present invention may include a sensor (a sensor having a function of measuring force, displacement, position, speed, acceleration, angular velocity, rotational frequency, distance, light, liquid, magnetism, temperature, a chemical substance, sound, time, hardness, an electric field, current, voltage, power, radioactive rays, flow rate, humidity, a gradient, oscillation, odor, or infrared rays).

The electronic appliance of one embodiment of the present invention can have a variety of functions. For example, the electronic appliance can have a function of displaying a variety of data (a still image, a moving image, a text image, and the like) on the display portion, a touch panel function, a function of displaying a calendar, date, time, or the like, a function of executing a variety of software (programs), a wireless communication function, and a function of reading out a program or data stored in a recording medium. FIG. 51A to FIG. 51H illustrate examples of electronic appliances.

### [Information Terminal]

FIG. 51A illustrates a mobile phone (smartphone), which is a type of information terminal. An information terminal 5100 includes a housing 5101 and a display portion 5102. As input interfaces, a touch panel is provided in the display portion 5102 and a button is provided in the housing 5101.

When the chip of one embodiment of the present invention is applied to the information terminal 5100, the information terminal 5100 can execute an application utilizing artificial intelligence. Examples of the application utilizing artificial intelligence include an application for recognizing a conversation and displaying the contents of the conversation on the display portion 5102; an application for recognizing letters, figures, and the like input to the touch panel of the display portion 5102 by a user and displaying them on the display portion 5102; and an application for performing biometric authentication using fingerprints, voice prints, or the like.

FIG. 51B illustrates a notebook information terminal 5200. The notebook information terminal 5200 includes a main body 5201 of the information terminal, a display portion 5202, and a keyboard 5203.

Like the information terminal 5100 described above, when the chip of one embodiment of the present invention is applied to the notebook information terminal 5200, the notebook information terminal 5200 can execute an application utilizing artificial intelligence. Examples of the application utilizing artificial intelligence include design-support software, text correction software, and software for automatic menu generation. Furthermore, with the use of the notebook information terminal 5200, novel artificial intelligence can be developed.

Note that although FIG. 51A and FIG. 51B illustrate a smartphone and a notebook information terminal, respectively, as examples of the electronic appliance in the above description, an information terminal other than a smartphone and a notebook information terminal can be used. Examples of information terminals other than a smartphone and a notebook information terminal include a PDA (Personal Digital Assistant), a desktop information terminal, and a workstation.

### [Game Machine]

FIG. 51C illustrates a portable game machine 5300 as an example of a game machine. The portable game machine 5300 includes a housing 5301, a housing 5302, a housing 5303, a display portion 5304, a connection portion 5305, an operation key 5306, and the like. The housing 5302 and the housing 5303 can be detached from the housing 5301. When the connection portion 5305 provided in the housing 5301 is attached to another housing (not illustrated), an image to be output to the display portion 5304 can be output to another video device (not illustrated). In this case, the housing 5302 and the housing 5303 can each function as an operating unit. Thus, a plurality of players can play a game at the same time. The chip described in the above embodiment can be incorporated into the chip provided on a substrate in the housing 5301, the housing 5302, and the housing 5303.

FIG. 51D illustrates a stationary game machine 5400 as an example of a game machine. A controller 5402 is wired or connected wirelessly to the stationary game machine 5400.

Using the GPU, the storage device, or the chip of one embodiment of the present invention in a game machine such as the portable game machine 5300 and the stationary game machine 5400 achieves a low-power-consumption game machine. Moreover, heat generation from a circuit can be reduced owing to low power consumption; thus, the influence of heat generation on the circuit, a peripheral circuit, and a module can be reduced.

Furthermore, when the GPU, the storage device, or the chip of one embodiment of the present invention is applied to the portable game machine 5300, the portable game machine 5300 including artificial intelligence can be achieved.

In general, the progress of a game, the actions and words of game characters, and expressions of an event and the like occurring in the game are determined by the program in the game; however, the use of artificial intelligence in the portable game machine 5300 enables expressions not limited by the game program. For example, it becomes possible to change expressions such as questions posed by the player, the progress of the game, time, and actions and words of game characters.

In addition, when a game requiring a plurality of players is played on the portable game machine 5300, the artificial intelligence can create a virtual game player; thus, the game can be played alone with the game player created by the artificial intelligence as an opponent.

Although the portable game machine and the stationary game machine are illustrated as examples of game machines in FIG. 51C and FIG. 51D, the game machine using the GPU, the storage device, or the chip of one embodiment of the present invention is not limited thereto. Examples of the game machine to which the GPU, the storage device, or the chip of one embodiment of the present invention is applied include an arcade game machine installed in entertainment facilities (a game center, an amusement park, and the like), and a throwing machine for batting practice installed in sports facilities.

### [Large Computer]

The GPU, the storage device, or the chip of one embodiment of the present invention can be used in a large computer.

FIG. 51E is a diagram illustrating a supercomputer 5500 as an example of a large computer. FIG. 51F is a diagram illustrating a rack-mount computer 5502 included in the supercomputer 5500.

The supercomputer 5500 includes a rack 5501 and a plurality of rack-mount computers 5502. The plurality of computers 5502 are stored in the rack 5501. The computer 5502 includes a plurality of substrates 5504, on which the GPU, the storage device, or the chip described in the above embodiment can be mounted.

The supercomputer 5500 is a large computer mainly used for scientific computation. In scientific computation, an enormous amount of arithmetic operation needs to be processed at a high speed; hence, power consumption is large and chips generate a large amount of heat. Using the GPU, the storage device, or the chip of one embodiment of the present invention in the supercomputer 5500 achieves a low-power-consumption supercomputer. Moreover, heat generation from a circuit can be reduced owing to low power consumption; thus, the influence of heat generation on the circuit, a peripheral circuit, and a module can be reduced.

Although a supercomputer is illustrated as an example of a large computer in FIG. 51E and FIG. 51F, a large computer using the GPU, the storage device, or the chip of one embodiment of the present invention is not limited thereto. Other examples of large computers in which the GPU, the storage device, or the chip of one embodiment of the present invention is usable include a computer that provides service (a server) and a large general-purpose computer (a mainframe).

### [Moving Vehicle]

The GPU, the storage device, or the chip of one embodiment of the present invention can be applied to an automobile, which is a moving vehicle, and the periphery of a driver's seat in the automobile.

FIG. 51G is a diagram illustrating an area around a windshield inside an automobile, which is an example of a moving vehicle. FIG. 51G illustrates a display panel 5701, a display panel 5702, and a display panel 5703 that are attached to a dashboard and a display panel 5704 that is attached to a pillar.

The display panel 5701 to the display panel 5703 can provide a variety of kinds of information by displaying a speedometer, a tachometer, mileage, a fuel gauge, a gear state, air-condition setting, and the like. In addition, the content, layout, or the like of the display on the display panels can be changed as appropriate to suit the user's preference, so that the design quality can be increased. The display panel 5701 to the display panel 5703 can also be used as lighting devices.

The display panel 5704 can compensate for view obstructed by the pillar (a blind spot) by showing an image taken by an image capturing device (not illustrated) provided for the automobile. That is, displaying an image taken by the image capturing device provided outside the automobile leads to compensation for the blind spot and an increase in safety. In addition, displaying an image to compensate for a portion that cannot be seen makes it possible for the driver to confirm the safety more naturally and comfortably. The display panel 5704 can also be used as a lighting device.

Since the GPU, the storage device, or the chip of one embodiment of the present invention can be applied to a component of artificial intelligence, the chip can be used for an automatic driving system of the automobile, for example. The chip can also be used for a system for navigation, risk prediction, or the like. A structure may be employed in which the display panel 5701 to the display panel 5704 display navigation information, risk prediction information, or the like.

Note that although an automobile is described above as an example of a moving vehicle, the moving vehicle is not limited to an automobile. Examples of the moving vehicle include a train, a monorail train, a ship, and a flying vehicle (a helicopter, an unmanned aircraft (a drone), an airplane, and a rocket), and these moving vehicles can each include a system utilizing artificial intelligence when the chip of one embodiment of the present invention is applied to each of these moving vehicles.

### [Household Appliance]

FIG. 51H illustrates an electric refrigerator-freezer 5800 as an example of a household appliance. The electric refrigerator-freezer 5800 includes a housing 5801, a refrigerator door 5802, a freezer door 5803, and the like.

When the chip of one embodiment of the present invention is applied to the electric refrigerator-freezer 5800, the electric refrigerator-freezer 5800 including artificial intelligence can be achieved. Utilizing the artificial intelligence enables the electric refrigerator-freezer 5800 to have a function of automatically making a menu based on foods stored in the electric refrigerator-freezer 5800, expiration dates of the foods, or the like, a function of automatically adjusting temperature to be appropriate for the foods stored in the electric refrigerator-freezer 5800, and the like.

Although the electric refrigerator-freezer is described as an example of a household appliance, examples of other household appliances include a vacuum cleaner, a microwave oven, an electric oven, a rice cooker, a water heater, an IH cooker, a water server, a heating-cooling combination appliance such as an air conditioner, a washing machine, a drying machine, and an audio visual appliance.

The electronic appliances, the functions of the electronic appliances, the application examples of artificial intelligence, their effects, and the like described in this embodiment can be combined as appropriate with the description of another electronic appliance.

At least part of the structure, method, and the like described in this embodiment can be implemented in an appropriate combination with any of those in the other embodiments, the other examples, and the like described in this specification.

### Embodiment 10

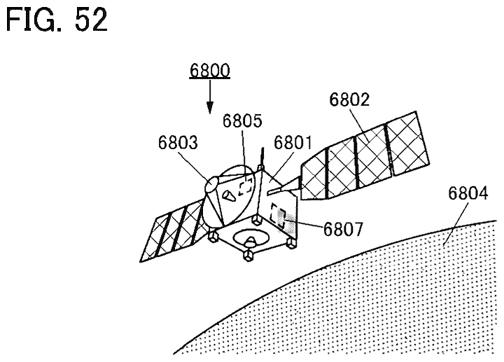

The semiconductor device of one embodiment of the present invention includes an OS transistor. A change in electrical characteristics of the OS transistor due to radiation irradiation is small. That is, the OS transistor is highly resistant to radiation, and thus can be suitably used even in an environment where radiation can enter. For example, OS transistors can be suitably used in outer space. In this embodiment, a specific example of using the semiconductor device of one embodiment of the present invention in a device for space will be described with reference to FIG. 52.

FIG. 52 illustrates an artificial satellite 6800 as an example of a device for space. The artificial satellite 6800 includes a body 6801, a solar panel 6802, an antenna 6803, a secondary battery 6805, and a control device 6807. In FIG. 52, a planet 6804 in outer space is illustrated as an example. Note that outer space refers to, for example, space at an altitude greater than or equal to 100 km, and outer space described in this specification may include thermosphere, mesosphere, and stratosphere.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beam, proton beam, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a storage device, for example. Note that the OS transistor of one embodiment of the present invention is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can be configured to include a sensor. For example, when configured to include a visible light sensor, the artificial satellite 6800 can have a function of sensing sunlight reflected by a ground-based object. Alternatively, when configured to include a thermal infrared sensor, the artificial satellite 6800 can have a function of sensing thermal infrared rays emitted from the surface of the earth. Thus, the artificial satellite 6800 can have a function of an earth observing satellite, for example.

Although the artificial satellite is described as an example of a device for space in this embodiment, one embodiment of the present invention is not limited thereto. The semiconductor device of one embodiment of the present invention can be suitably used for a device for space such as a spacecraft, a space capsule, or a space probe, for example.

### Example 1

In this example, the fundamental physical properties of metal oxides were evaluated. Specifically, the relationship between the composition and the band gap of each metal oxide and a change in carrier concentration of each metal oxide by heat treatment in an oxygen atmosphere were evaluated. The relationship between the carrier concentration of a metal oxide and the thickness of a conductor was evaluated.

### <Relationship Between Composition and Band Gap of Metal Oxide>

First, results of evaluating the relationship between the composition and the band gap of metal oxides are described.

Here, four samples (Sample 1A to Sample 1D) were prepared. In each sample, a 100-nm-thick In—Ga—Zn oxide film was formed over a silicon substrate by an RF sputtering method. Note that the In—Ga—Zn oxide films of Sample 1A to Sample 1D were formed using different oxide targets.

Next, the compositions of the metal oxides included in the samples were evaluated by inductively coupled plasma-mass spectrometry (ICP-MS). For ICP-MS, “Agilent 8900” manufactured by Agilent Technologies was used.

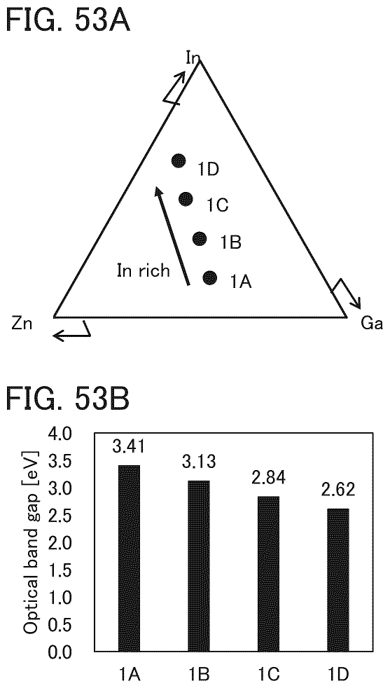

FIG. 53A is a phase diagram of In—Ga—Zn oxides. In FIG. 53A, the compositions of the metal oxides included in the samples that were evaluated by ICP-MS are plotted.

Next, the optical band gaps of the metal oxides included in the samples were evaluated by spectroscopic ellipsometry. The optical band gap of each metal oxide was calculated by creating a Tauc plot with an optical absorption coefficient obtained by spectroscopic ellipsometry. For spectroscopic ellipsometry, “UT-300” manufactured by HORIBA, Ltd. was used.

FIG. 53B shows the optical band gaps of the metal oxides included in the samples, which were calculated by spectroscopic ellipsometry. In FIG. 53B, the vertical axis represents the optical band gap (Optical band gap) [eV].

FIG. 53A and FIG. 53B show that the band gaps of the metal oxides slightly depend on their compositions. Specifically, it is found that the metal oxides included in Sample 1A to Sample 1D each have a band gap wider than or equal to 2.5 eV. Furthermore, it is found that the metal oxide (e.g., the metal oxide included in Sample 1B) whose composition is in the neighborhood of In:Ga:Zn=1:1:1 [atomic ratio] and the metal oxide (e.g., the metal oxide included in Sample 1A) having a composition with an atomic ratio of gallium higher than that in the metal oxide whose composition is in the neighborhood of In:Ga:Zn=1:1:1 [atomic ratio] each have a band gap wider than 3.0 eV.

From the above, it is found that metal oxides (typically, In—Ga—Zn oxides) have a wide band gap. A transistor that includes a metal oxide with a wide band gap can have features such as an extremely low off-state current and a high breakdown voltage between a source and a drain.

The above is the description of the results of evaluating the relationship between the composition and the band gap of each metal oxide.

### <Change in Carrier Concentration of Metal Oxide by Heat Treatment in Oxygen Atmosphere>

Next, results of evaluating a change in carrier concentration of metal oxides by heat treatment in an oxygen atmosphere are described. Specifically, Hall effect measurement was performed on samples each including a metal oxide, and the result was used to calculate the carrier concentration of the metal oxide.

Here, the Hall effect measurement is a method in which electrical characteristics such as carrier concentration, mobility, and resistivity are measured with the use of the Hall effect, which is a phenomenon where, when a magnetic field is applied to an element through which a current flows in a direction perpendicular to the direction of the current, an electromotive force is produced in directions perpendicular to both the current and the magnetic field. Here, the Hall effect measurement using the Van der Pauw method was performed.

Here, Sample 2A to Sample 2F were fabricated. Note that the methods for fabricating Sample 2A to Sample 2F are the same except for the conditions of the heat treatment in an oxygen atmosphere.

A quartz substrate was prepared, and a 35-nm-thick metal oxide film was formed over the quartz substrate by a sputtering method. Note that the metal oxide of the formed film is an In—Ga—Zn oxide. After the metal oxide film was formed, treatment was performed at a temperature of 450° C. in an oxygen atmosphere for one hour.

Next, treatment was performed at a temperature of 400° C. under reduced pressure (in a vacuum) for one hour. This treatment is referred to as first treatment. The first treatment can increase the carrier concentration in the metal oxide.

After the first treatment was performed, treatment was performed in an oxygen atmosphere for one hour. This treatment is referred to as second treatment. The temperature of the second treatment differed from sample to sample. Specifically, the temperature of the second treatment was 200° C. for Sample 2B, 250° C. for Sample 2C, 300° C. for Sample 2D, 350° C. for Sample 2E, and 400° C. for Sample 2F. Note that the second treatment was not performed on Sample 2A.

In the above-described manner, Sample 2A to Sample 2F were fabricated.

Note that a 200-nm-thick titanium-aluminum alloy film was formed over each sample by a sputtering method in order to perform the Hall effect measurement. Note that a metal mask was used to form the titanium-aluminum alloy film at each of the four corners of the sample.

For the Hall effect measurement, “ResiTest 8400” produced by TOYO Corporation was used.

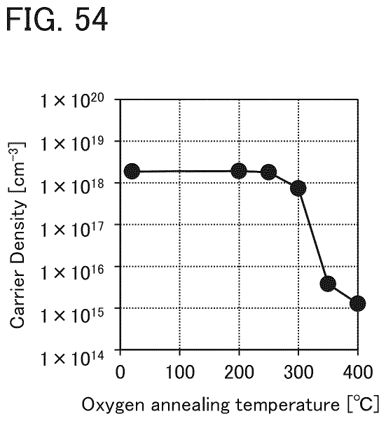

FIG. 54 shows the carrier concentrations of the metal oxides included in the samples. FIG. 54 is a diagram showing the dependence of the carrier concentration of each metal oxide on the treatment temperature. In FIG. 54, the vertical axis represents the carrier concentration (Carrier Density) [cm⁻³] of each metal oxide, and the horizontal axis represents the temperature of the second treatment (Oxygen annealing temperature) [° C.].

From FIG. 54, it is found that performing the second treatment leads to a lower carrier concentration of the metal oxide. This is probably because the heat treatment performed in an oxygen atmosphere supplies oxygen to the metal oxide and repairs oxygen vacancies and VoH.

From the above, it is found that the heat treatment in an oxygen atmosphere is effective in reducing the carrier concentration of the metal oxide.

### <Relationship Between Carrier Concentration of Metal Oxide and Thickness of Conductor>

Next, results of evaluating the relationship between the carrier concentration of a metal oxide and the thickness of a conductor are described. Specifically, Hall effect measurement was performed on samples each including the metal oxide, and the result was used to calculate the carrier concentration of the metal oxide.

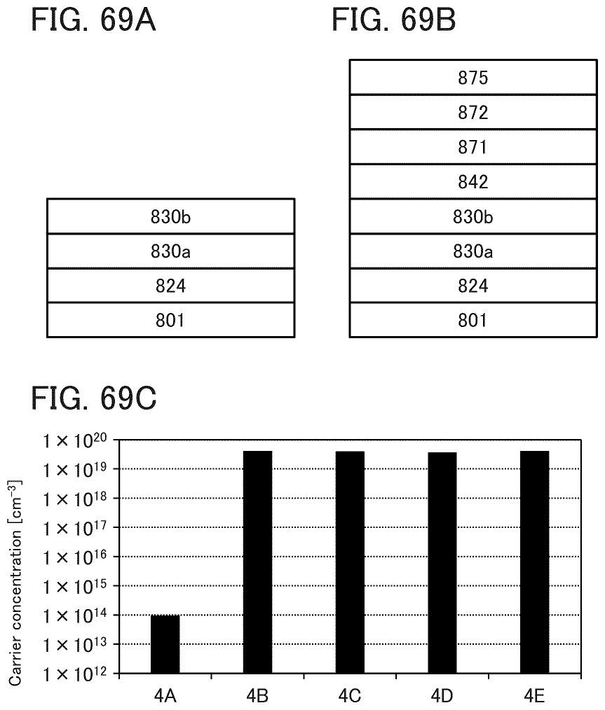

Here, Sample 4A to Sample 4E were fabricated. Methods for fabricating Sample 4A to Sample 4E are described with reference to FIG. 69A and FIG. 69B.

First, the fabrication method of Sample 4A is described below. As Sample 4A, a stack illustrated in FIG. 69A was fabricated. The stack illustrated in FIG. 69A includes a substrate 801, an insulator 824 over the substrate 801, a metal oxide 830a over the insulator 824, and a metal oxide 830b over the metal oxide 830a.

Note that the insulator 824 corresponds to the insulator 224 described in Embodiment 3, the metal oxide 830a corresponds to the oxide 230a described in Embodiment 3, and the metal oxide 830b corresponds to the oxide 230b described in Embodiment 3.

A quartz substrate was prepared as the substrate 801. As the insulator 824, a 20-nm-thick silicon oxide film formed by a sputtering method was used.

As the metal oxide 830a, a 10-nm-thick In—Ga—Zn oxide film formed by an RF sputtering method was used. For the formation of the metal oxide 830a, an oxide target with In:Ga:Zn=1:3:2 [atomic ratio] was used.

As the metal oxide 830b, a 15-nm-thick In—Ga—Zn oxide film formed by an RF sputtering method was used. For the formation of the metal oxide 830b, an oxide target with In:Ga:Zn=1:1:1.2 [atomic ratio] was used.

After the metal oxide 830b was formed, heat treatment was performed at a substrate temperature of 450° C. for one hour in a mixed atmosphere of a nitrogen gas at 4 slm and an oxygen gas at 1 slm.

In the above-described manner, Sample 4A was fabricated.

Next, methods for fabricating Sample 4B to Sample 4E are described. First, a stack illustrated in FIG. 69B was fabricated. The stack illustrated in FIG. 69B includes the substrate 801, the insulator 824 over the substrate 801, the metal oxide 830a over the insulator 824, the metal oxide 830b over the metal oxide 830a, a conductor 842 over the metal oxide 830b, an insulator 871 over the conductor 842, an insulator 872 over the insulator 871, and an insulator 875 over the insulator 872.

Note that the conductor 842 corresponds to the conductor 242a or the conductor 242b described in Embodiment 3, the insulator 871 corresponds to the insulator 271a1 or the insulator 271b1 described in Embodiment 3, the insulator 872 corresponds to the insulator 271a2 or the insulator 271b2 described in Embodiment 3, and the insulator 875 corresponds to the insulator 275 described in Embodiment 3.

The substrate 801 was prepared, the insulator 824, the metal oxide 830a, and the metal oxide 830b were formed in this order, and the above heat treatment was performed. The materials, formation methods, and heat treatment conditions employed for the substrate 801, the insulator 824, the metal oxide 830a, and the metal oxide 830b are the same as those for Sample 4A.

As the conductor 842, a tantalum nitride film formed by a sputtering method was used. The conductor 842 was formed using a metallic tantalum target in an atmosphere containing nitrogen. Note that Sample 4B to Sample 4E differed in the thickness of the conductor 842. Specifically, the thickness of the conductor 842 was 5 nm in Sample 4B, 10 nm in Sample 4C, 15 nm in Sample 4D, and 20 nm in Sample 4E.

As the insulator 871, a 5-nm-thick silicon nitride film was used. As the insulator 872, a 10-nm-thick silicon oxide film was used.

As the insulator 875, a 5-nm-thick silicon nitride film formed by an ALD method was used.

The insulator 875, the insulator 872, the insulator 871, and the conductor 842 included in the stack illustrated in FIG. 69B were removed by dry etching. Thus, the stack in FIG. 69A, in which the metal oxide 830b was exposed, was fabricated.

In the above-described manner, Sample 4B to Sample 4E were fabricated.

The above is the description of the fabrication methods of Sample 4A to Sample 4E each including the stack illustrated in FIG. 69A. As described above, in Sample 4A, the conductor 842 and the like were not formed over the metal oxide 830b. In other words, the thickness of the conductor 842 in Sample 4A can be regarded as 0 nm.

Note that a 200-nm-thick titanium-aluminum alloy film was formed over each sample by a sputtering method in order to perform the Hall effect measurement. Note that a metal mask was used to form the titanium-aluminum alloy film at each of the four corners of the sample. For the Hall effect measurement, “ResiTest 8400” produced by TOYO Corporation was used.

FIG. 69C shows the carrier concentrations of the metal oxides included in the samples. FIG. 69C is a diagram showing the carrier concentrations of the metal oxides. In FIG. 69C, the vertical axis represents the carrier concentration [cm⁻³] of the metal oxide 830b, and the horizontal axis shows the name of the sample.

As shown in FIG. 69C, the carrier concentration of the metal oxide 830b included in each sample was as follows: 9.6×10¹³ cm⁻³ for Sample 4A, 4.1×10¹⁹ cm⁻³ for Sample 4B, 4.0×10¹⁹ cm⁻³ for Sample 4C, 3.7×10¹⁹ cm⁻³ for Sample 4D, and 4.1×10¹⁹ cm⁻³ for Sample 4E.

From the above, it is found that providing the conductor 842 over the metal oxide 830b increases the carrier concentration of the metal oxide 830b. Furthermore, it is found that the carrier concentration of the metal oxide 830b does not depend on the thickness of the conductor 842 when the thickness of the conductor 842 is greater than or equal to 5 nm. It is thus found that the carrier concentration of the metal oxide increases even when the thickness of the conductor (here, tantalum nitride) provided over the metal oxide is small.

Although not shown in FIG. 69C, the carrier concentration of the metal oxide 830b included in a sample formed using a stack including the conductor 842 with a thickness of 1 nm was 1.1×10¹⁹ cm⁻³. It is thus found that the carrier concentration of the metal oxide increases even when the thickness of the conductor 842 is 1 nm.

As described in Embodiment 3, a region having a carrier concentration equal to, substantially equal to, or higher than 5×10¹⁸ cm⁻³ can be regarded as an n+-type region. Thus, it is found that when the thickness of each of the conductor 242a and the conductor 242b is greater than or equal to 1 nm or greater than or equal to 5 nm, the oxide 230b in a region overlapping with the conductor 242a or the conductor 242b can be an n+-type region.

The structure, configuration, method, or the like described in this example can be used in an appropriate combination with any of the structures, configurations, methods, and the like described in the other embodiments and the like.

### Example 2

In this example, the transistor described in Embodiment 3 was verified through device simulation, and the verification results are described. Note that the device simulation was performed using “Sentaurus Device” manufactured by Synopsys Inc.

### <Transistor Structure>

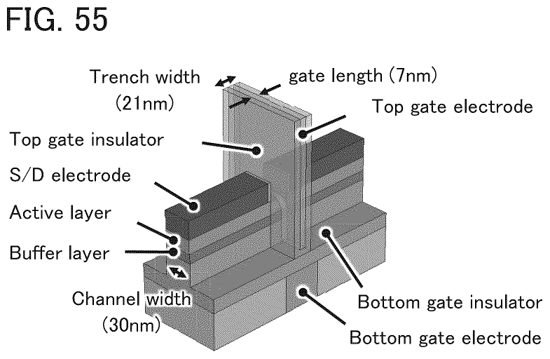

In this section, the structure of the transistor used in the device simulation is described. FIG. 55 is a bird's eye view of the transistor used for the device simulation.

The transistor used for the device simulation includes a bottom gate electrode (Bottom gate electrode), a bottom gate insulating film (Bottom gate insulator) over the bottom gate electrode, a first metal oxide (Buffer layer) over the bottom gate insulating film, a second metal oxide (Active layer) over the first metal oxide, a source electrode and a drain electrode (S/D electrode) over the second metal oxide, a top gate electrode (Top gate electrode) overlapping with the second metal oxide, and a top gate insulating film (Top gate insulator) located between the second metal oxide and the top gate electrode. The transistor also includes a first oxide located between the top gate insulating film and one of the source electrode and the drain electrode and a second oxide located between the top gate insulating film and the other of the source electrode and the drain electrode.

In the second metal oxide, a region between the source electrode and the drain electrode is a channel formation region, a region overlapping with at least part of the source electrode is a source region, and a region overlapping with at least part of the drain electrode is a drain region. In the second metal oxide, a first LDD (Lightly Doped Drain) region is provided between the channel formation region and the source region, and a second LDD region is provided between the channel formation region and the drain region. Note that the first LDD region includes a region overlapping with the first oxide, and the second LDD region includes a region overlapping with the second oxide.

Note that the transistor in FIG. 55 used for the device simulation corresponds to the transistor 200 described in Embodiment 3. Specifically, the bottom gate electrode corresponds to the conductor 205, the bottom gate insulating film corresponds to the insulator 222 and the insulator 224, the first metal oxide and the second metal oxide respectively correspond to the oxide 230a and the oxide 230b, the source electrode and the drain electrode correspond to the conductor 242a and the conductor 242b, the top gate insulating film corresponds to the insulator 252, the insulator 250, and the insulator 254, and the top gate electrode corresponds to the conductor 260. The first oxide and the second oxide correspond to the insulator 244a and the insulator 244b, respectively.

The gate length (the width of the top gate electrode in the channel length direction; “gate length” in FIG. 55) was set to 7 nm. The shortest distance between the side surface of the first oxide and the side surface of the second oxide (“Trench width” in FIG. 55) was set to 21 nm. The length of the second metal oxide in the channel width direction (“Channel width” in FIG. 55) was set to 30 nm. The length of the first oxide in the channel length direction and the length of the second oxide in the channel length direction were each set to 3 nm. Note that the length of the first oxide in the channel length direction and the length of the second oxide in the channel length direction correspond to the length D1 described in Embodiment 3.

In this example, the first LDD region and the second LDD region are sometimes collectively referred to as an LDD region. The length of the LDD region in the channel length direction is referred to as the length of the LDD region in some cases.

Parameters set for the later-described device simulation are shown in Table 1.

TABLE 1

| | | | |
|---|---|---|---|
| Top gate | Work function | 4.7 | eV |
| electrode | Thickness | 43 | nm |
| Top gate | Relative permittivity | 5.6 | |
| insulator | Physical thickness | 7 | nm |
| | EOT | 5.1 | nm |
| S/D electrode | Work function | 4.5 | eV |
| | Thickness | 20 | nm |
| Active layer | Electron affinity | 4.7 | eV |
| | Band gap (300K) | 3.2 | eV |
| | Relative permittivity | 15 | |
| | Electron mobility | 6 | cm²/Vs |
| | Hole mobility | 0.01 | cm²/Vs |
| | Density of states in conduction | 5.0 × 10¹⁸ | cm⁻³ |
| | band (300K) | | |
| | Density of states in valence band | 5.0 × 10¹⁸ | cm⁻³ |
| | (300K) | | |
| | Thickness | 15 | nm |
| | Donor concentration | (1.0 × 10¹⁶) | cm⁻³ |
| | (channel formation region) | | |
| | Donor concentration (S/D | 1.0 × 10²⁰ | cm⁻³ |
| | region) | | |
| Buffer layer | Electron affinity | (4.5) | eV |
| | Band gap (300K) | (3.4) | eV |
| | Relative permittivity | 15 | |
| | Electron mobility | 1.5 | cm²/Vs |
| | Hole mobility | 0.01 | cm²/Vs |
| | Density of states in conduction | 5.0 × 10¹⁸ | cm⁻³ |
| | band (300K) | | |
| | Density of states in valence | 5.0 × 10¹⁸ | cm⁻³ |
| | band (300K) | | |
| | Thickness | 10 | nm |
| | Donor concentration | 1.0 × 10¹⁰ | cm⁻³ |
| | (channel formation region) | | |
| | Donor concentration (S/D | 1.0 × 10¹⁰ | cm⁻³ |
| | region) | | |
| Bottom gate | Relative permittivity | 6.6 | |
| insulator | Physical thickness | 40 | nm |
| | EOT | 25 | nm |
| Bottom gate | Work function | 5.0 | eV |
| electrode | Thickness | 40 | nm |

Note that the donor concentration of the channel formation region of the second metal oxide and the electron affinity of the first metal oxide were set to the values shown in Table 1 unless otherwise specified. The band gap of the first metal oxide was changed in accordance with the value of the electron affinity of the first metal oxide.

As shown in Table 1, the physical thickness of the top gate insulating film is 7 nm and the EOT of the top gate insulating film is 5.1 nm. The physical thickness of the bottom gate insulating film is 40 nm, and the EOT of the bottom gate insulating film is 25 nm.

In this example, a top gate-source voltage is referred to as Vgs or Vg, and a drain-source voltage is referred to as Vds. A bottom gate voltage is referred to as Vbg and a drain current is referred to as Id. Note that a top gate-source voltage is simply referred to as a top gate voltage in some cases. Furthermore, a drain-source voltage is simply referred to as a drain voltage in some cases.

### <Comparison of Id-Vgs Characteristics Depending on Donor Concentration>

In this section, results of comparing Id-Vgs characteristics depending on the donor concentration of the channel formation region and the LDD region are described. Note that in this section, the donor concentration of the channel formation region and the LDD region is simply referred to as a donor concentration in some cases.

Here, the length of the LDD region was set to 3 nm. At this time, in the second metal oxide, the source region overlaps with the source electrode, the first LDD region overlaps with the first oxide, the second LDD region overlaps with the second oxide, and the drain region overlaps with the drain electrode. The donor concentration of the channel formation region and the LDD region was set to 1×10¹⁶ cm⁻³, 1×10¹⁷ cm⁻³, 1×10¹⁸ cm⁻³, 5×10¹⁸ cm⁻³, or 1×10¹⁹ cm⁻³.

Device simulation was performed to calculate the Id-Vgs characteristics. In the calculation of the Id-Vgs characteristics, Vds was set to 0.1 V and Vbg was set to 0 V.

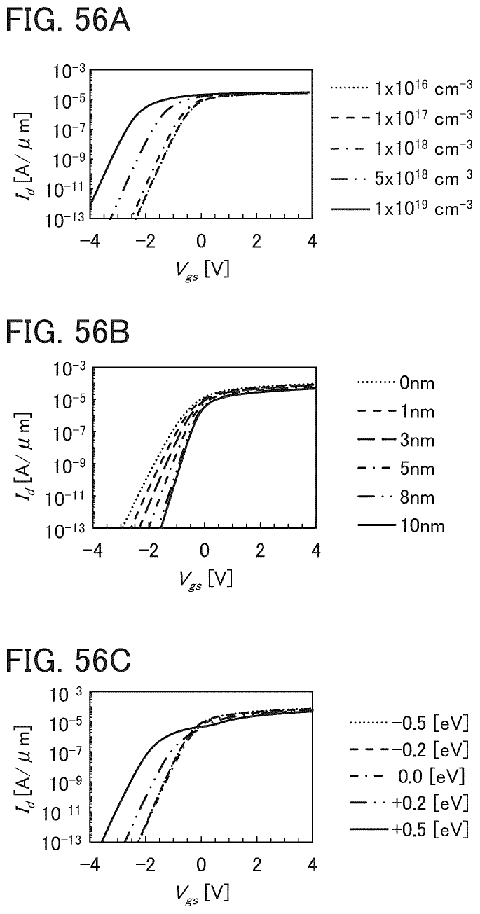

FIG. 56A shows the results of the device simulation. FIG. 56A shows the calculated Id-Vgs characteristics. In FIG. 56A, the vertical axis represents the drain current Id per micrometer of channel width [A/μm], and the horizontal axis represents the top gate voltage Vgs [V].

The dotted line in FIG. 56A shows the results of the case where the donor concentration was set to 1×10¹⁶ cm⁻³, the dashed line in FIG. 56A shows the results of the case where the donor concentration was set to 1×10¹⁷ cm⁻³, the dashed-dotted line in FIG. 56A shows the results of the case where the donor concentration was set to 1×10¹⁸ cm⁻³, the dashed-two dotted line in FIG. 56A shows the results of the case where the donor concentration was set to 5×10¹⁸ cm⁻³, and the solid line in FIG. 56A shows the results of the case where the donor concentration was set to 1×10¹⁹ cm⁻³.

As shown in FIG. 56A, the Id-Vgs characteristics of the case where the donor concentration of the channel formation region and the LDD region was set to 1×10¹⁶ cm⁻³ are substantially the same as the Id-Vgs characteristics of the case where the donor concentration of the channel formation region and the LDD region was set to 1×10¹⁷ cm⁻³. Furthermore, it is confirmed that the threshold voltage shifts in the negative direction with increasing donor concentration of the channel formation region and the LDD region.

From the above, it is confirmed that reducing the donor concentration of the channel formation region and the LDD region can inhibit a negative shift in threshold voltage.

### <Comparison of Id-Vgs Characteristics Depending on Length of LDD Region>

In this section, results of comparing Id-Vgs characteristics depending on the length of the LDD region are described.

Here, the length of the LDD region was set to 0 nm, 1 nm, 3 nm, 5 nm, 8 nm, or 10 nm. Note that a transistor in which the length of the LDD region is 0 nm is a transistor that includes no LDD region. That is, in the second metal oxide, the source region overlaps with the source electrode and the drain region overlaps with the drain electrode. When the length of the LDD region is greater than 3 nm, in the second metal oxide, the first LDD region overlaps with the first oxide and part of the source electrode, and the second LDD region overlaps with the second oxide and part of the drain electrode. The donor concentration of the channel formation region and the LDD region was set to 1×10¹⁶ cm⁻³.

Device simulation was performed to calculate the Id-Vgs characteristics. In the calculation of the Id-Vgs characteristics, Vds was set to 0.1 V and Vbg was set to 0 V.

FIG. 56B shows the results of the device simulation. FIG. 56B shows the calculated Id-Vgs characteristics. In FIG. 56B, the vertical axis represents the drain current Id per micrometer of channel width [A/μm], and the horizontal axis represents the top gate voltage Vgs [V].

The dotted line in FIG. 56B shows the results of the case where the length of the LDD region was set to 0 nm, the dashed line in FIG. 56B shows the results of the case where the length of the LDD region was set to 1 nm, the long dashed line in FIG. 56B shows the results of the case where the length of the LDD region was set to 3 nm, the dashed-dotted line in FIG. 56B shows the results of the case where the length of the LDD region was set to 5 nm, the dashed-two dotted line in FIG. 56B shows the results of the case where the length of the LDD region was set to 8 nm, and the solid line in FIG. 56B shows the results of the case where the length of the LDD region was set to 10 nm.

It is found from FIG. 56B that a larger length of the LDD region leads to a smaller S value. It is also confirmed that the threshold voltage shifts positively as the S value decreases.

This is probably because the presence of the LDD region relieves the drain electric field.

### <Comparison of Id-Vgs Characteristics Depending on ΔEc>

In this section, results of comparing Id-Vgs characteristics depending on the difference (ΔEc) in electron affinity between the first metal oxide and the second metal oxide are described. Here, ΔEc is defined as the value obtained by subtracting the electron affinity of the second metal oxide from the electron affinity of the first metal oxide.

Here, the length of the LDD region was set to 3 nm. The donor concentration of the channel formation region and the LDD region was set to 1×10¹⁶ cm⁻³. Furthermore, ΔEc was set to −0.5 eV, −0.2 eV, 0 eV, +0.2 eV, or +0.5 eV.

Device simulation was performed to calculate the Id-Vgs characteristics. In the calculation of the Id-Vgs characteristics, Vds was set to 0.1 V and Vbg was set to 0 V.

FIG. 56C shows the results of the device simulation. FIG. 56C shows the calculated Id-Vgs characteristics. In FIG. 56C, the vertical axis represents the drain current Id per micrometer of channel width [A/μm], and the horizontal axis represents the top gate voltage Vgs [V].

The dotted line in FIG. 56C shows the results of the case where ΔEc was set to −0.5 eV, the dashed line in FIG. 56C shows the results of the case where ΔEc was set to −0.2 eV, the dashed-dotted line in FIG. 56C shows the results of the case where ΔEc was set to 0 eV, the dashed-two dotted line in FIG. 56C shows the results of the case where ΔEc was set to +0.2 eV, and the solid line in FIG. 56C shows the results of the case where ΔEc was set to +0.5 eV. It is confirmed from FIG. 56C that the Id-Vgs characteristics shift more negatively and a hump is more likely to be formed when ΔEc is larger.

Next, electron density distributions in the first metal oxide and the second metal oxide were calculated. Note that in the calculation of the electron density distributions, Vgs was set to −1 V, Vds was set to 0.1 V, and Vbg was set to 0 V.

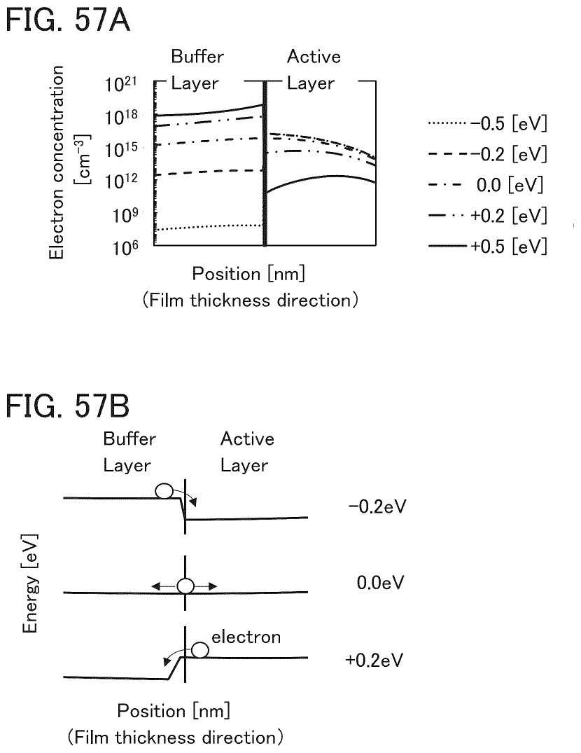

FIG. 57A shows the calculated electron density distributions. In FIG. 57A, the vertical axis represents the electron density (Electron concentration) [cm⁻³] and the horizontal axis represents the position (Position) [nm] in the film thickness direction (Film thickness direction). Note that the center of FIG. 57A corresponds to the interface between the first metal oxide and the second metal oxide, the left side of FIG. 57A is the first metal oxide (Buffer Layer), and the right side of FIG. 57A is the second metal oxide (Active Layer).

The dotted line in FIG. 57A shows the results of the case where ΔEc was set to −0.5 eV, the dashed line in FIG. 57A shows the results of the case where ΔEc was set to −0.2 eV, the dashed-dotted line in FIG. 57A shows the results of the case where ΔEc was set to 0 eV, the dashed-two dotted line in FIG. 57A shows the results of the case where ΔEc was set to +0.2 eV, and the solid line in FIG. 57A shows the results of the case where ΔEc was set to +0.5 eV.

It is found from FIG. 57A that in the case where ΔEc is larger than 0 eV, the electron density of the first metal oxide is higher than that of the second metal oxide.

Here, the phenomenon in which the Id-Vgs characteristics shift negatively as ΔEc increases and the phenomenon in which the electron density of the first metal oxide is higher than the electron density of the second metal oxide in the case where ΔEc is larger than 0 eV are described with reference to FIG. 57B.

FIG. 57B is a diagram showing comparison of energy at the conduction band minimum depending on ΔEc. In FIG. 57B, the vertical axis represents the energy (Energy) [eV] and the horizontal axis represents the position (Position) [nm] in the film thickness direction (Film thickness direction). The circles in FIG. 57B denote electrons, and the arrows in FIG. 57B denote the direction in which the electrons (electron) move easily.

The upper part of FIG. 57B illustrates the energy at the conduction band minimum at the center of the channel formation region at the time when ΔEc is −0.2 eV, the middle part of FIG. 57B illustrates the energy at the conduction band minimum at the center of the channel formation region at the time when ΔEc is 0 eV, and the lower part of FIG. 57B illustrates the energy at the conduction band minimum at the center of the channel formation region at the time when ΔEc is +0.2 eV.

The center of each diagram in FIG. 57B corresponds to the interface between the first metal oxide and the second metal oxide, the left side of each diagram in FIG. 57B is the first metal oxide (Buffer Layer), and the right side of each diagram in FIG. 57B is the second metal oxide (Active Layer).

In the case where the first metal oxide and the second metal oxide form a heterojunction, electrons easily move to the metal oxide that has higher electron affinity as illustrated in FIG. 57B. Thus, electrons can be efficiently transferred to the second metal oxide when ΔEc is smaller than 0 eV, i.e., when the electron affinity of the first metal oxide is lower than the electron affinity of the second metal oxide. Thus, the carrier control of the metal oxide by the electric field of the top gate electrode is performed on the second metal oxide, and the top gate controllability can be increased. In that case, the interface between the insulating film and the metal oxide, at which an electron trap is easily formed, can be limited only to the top gate insulating film side, so that the influence of the electron trap during circuit operation can be small.

### <Comparison of Id-Vg Characteristics Depending on Fixed Charge>

In this section, results of comparing Id-Vgs characteristics depending on fixed charge provided at the interface between the bottom gate insulating film and the first metal oxide are described. Note that in this section, the fixed charge provided at the interface between the bottom gate insulating film and the first metal oxide is simply referred to as fixed charge in some cases. Fixed charge smaller than 0 cm⁻² is referred to as negative fixed charge in some cases.

Here, the length of the LDD region was set to 3 nm. The donor concentration of the channel formation region and the LDD region was set to 1×10¹⁶ cm⁻³. The fixed charge provided at the interface between the bottom gate insulating film and the first metal oxide was set to 0 cm⁻², −1×10¹³ cm⁻², −3×10¹³ cm⁻², or −5×10¹³ cm⁻².

Device simulation was performed to calculate the Id-Vgs characteristics. In the calculation of the Id-Vgs characteristics, Vds was set to 0.1 V or 1.2 V and Vbg was set to 0 V.

An S value, Vth, and DIBL were calculated from the calculated Id-Vgs characteristics. Note that Vth was calculated using linear extrapolation. Furthermore, DIBL was calculated using Formula (2) below.

$$\begin{matrix}[ Formula 2 ] & \\ DIBL = \frac{Vth ( Vds = 0.1 V ) - Vth ( Vds = 1.2 V )}{Δ Vds} & ( 2 )\end{matrix}$$

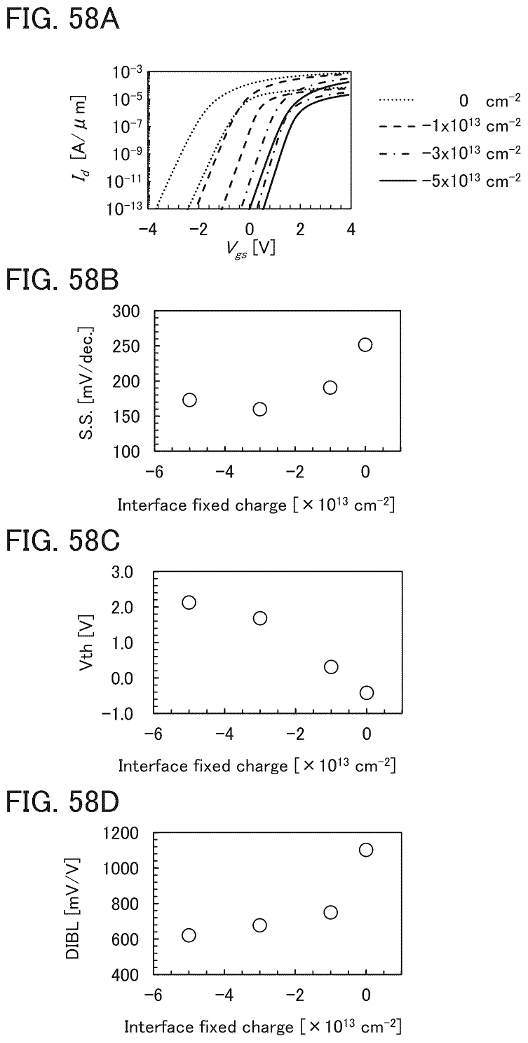

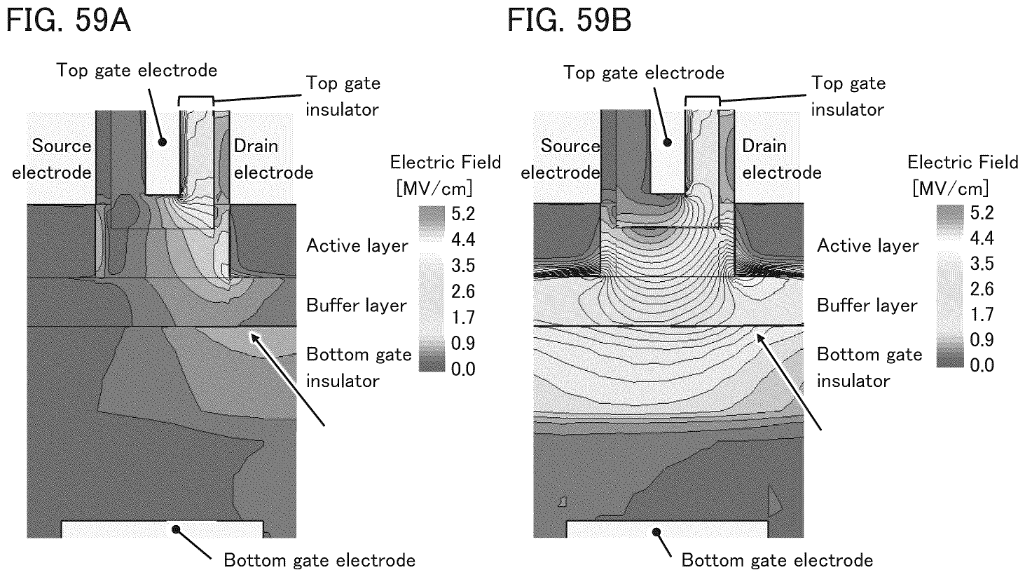

FIG. 58A to FIG. 59B show the results of the device simulation. FIG. 58A to FIG. 58D each show electrical characteristics obtained by the device simulation. FIG. 59A and FIG. 59B each show an electric-field strength distribution obtained by the device simulation.

FIG. 58A shows the calculated Id-Vgs characteristics. In FIG. 58A, the vertical axis represents the drain current Id per micrometer of channel width [A/μm], and the horizontal axis represents the top gate voltage Vgs [V]. The dotted line in FIG. 58A shows the results of the case where the fixed charge was set to 0 cm⁻², the dashed line in FIG. 58A shows the results of the case where the fixed charge was set to −1×10¹³ cm⁻², the dashed-dotted line in FIG. 58A shows the results of the case where the fixed charge was set to −3×10¹³ cm⁻³, and the solid line in FIG. 58A shows the results of the case where the fixed charge was set to −5×10¹³ cm⁻³.

FIG. 58B shows the S values calculated from the Id-Vgs characteristics at the time when Vds was set to 0.1 V. In FIG. 58B, the vertical axis represents the S value (S.S.) [mV/dec.] and the horizontal axis represents the fixed charge (Interface fixed charge) [cm⁻²].

FIG. 58C shows Vth calculated from the Id-Vgs characteristics at the time when Vds was set to 0.1 V. In FIG. 58C, the vertical axis represents Vth [V] and the horizontal axis represents the fixed charge (Interface fixed charge) [cm⁻²].

FIG. 58D shows DIBL calculated from the Id-Vgs characteristics. In FIG. 58D, the vertical axis represents DIBL [mV/V] and the horizontal axis represents the fixed charge (Interface fixed charge) [cm⁻²].

From FIG. 58A to FIG. 58D, it is confirmed that providing negative fixed charge at the interface between the bottom gate insulating film and the first metal oxide positively shifts the Id-Vgs characteristics and Vth, reduces the S value, and reduces DIBL. Thus, it is found that providing negative fixed charge can increase the controllability of the gate electrode and inhibit the influence of DIBL.

FIG. 59A and FIG. 59B show electric-field strength distributions at the time when Vds was set to 1.2 V and Vgs was set to 0 V. FIG. 59A shows the electric-field strength distribution of the case where the fixed charge was set to 0 cm⁻², and FIG. 59B shows the electric-field strength distribution of the case where the fixed charge was set to −3×10¹³ cm⁻². The arrow in each of FIG. 59A and FIG. 59B denotes the interface between the bottom gate insulating film and the first metal oxide, and the scale bar in each of FIG. 59A and FIG. 59B represents an electric field strength (Electric Field) [MV/cm].

From FIG. 59A and FIG. 59B, it is found that providing negative fixed charge at the interface between the bottom gate insulating film (Bottom gate insulator) and the first metal oxide (Buffer layer) blocks a lower drain electric field. Thus, it is found that providing negative fixed charge can block the lower drain electric field even when the thickness of the bottom gate insulating film is large, enabling fabrication of a transistor that is highly resistant to a short-channel effect. In each of FIG. 59A and FIG. 59B, “Bottom gate electrode” denotes the bottom gate electrode, “Active layer” denotes the second metal oxide, “Source electrode” denotes the source electrode, “Drain electrode” denotes the drain electrode, “Top gate electrode” denotes the top gate electrode, and “Top gate insulator” denotes the top gate insulating film.

### <Comparison of Id-Vgs Characteristics Depending on Vbg>

In this section, results of comparing Id-Vgs characteristics depending on the bottom gate voltage Vbg are described.

Here, device simulation was performed using the transistor illustrated in FIG. 55 and a transistor having a structure different from that of the transistor illustrated in FIG. 55. Hereinafter, the transistor illustrated in FIG. 55 is referred to as a transistor TrS1, and the transistor having a structure different from that of the transistor TrS1 is referred to as a transistor TrS2.

In the transistor TrS2, an opening is provided in the top gate insulator and the bottom gate insulator in a region not overlapping with the second metal oxide but overlapping with the top gate electrode and the bottom gate electrode. The top gate electrode and the bottom gate electrode are in contact with each other in the opening. That is, the transistor TrS2 has a structure similar to the GAA structure.

The transistor TrS1 in which voltages are independently applied to the top gate electrode and the bottom gate electrode is referred to as a transistor TrS1-1, and the transistor TrS1 in which the same voltage is applied to the top gate electrode and the bottom gate electrode is referred to as a transistor TrS1-2. It can be said that the transistor TrS1-2 is a Dual Gate driven transistor in which the top gate electrode and the bottom gate electrode have the same potential.

Here, in each of the transistor TrS1-1, the transistor TrS1-2, and the transistor TrS2, the length of the LDD region was set to 3 nm, the donor concentration of the channel formation region and the LDD region was set to 1×10¹⁶ cm⁻³, and the fixed charge provided at the interface between the bottom gate insulating film and the first metal oxide was set to −3×10¹³ cm⁻².

The device simulation was performed to calculate the Id-Vgs characteristics. In the calculation of the Id-Vgs characteristics, Vd was set to 0.1 V or 1.2 V. In the device simulation using the transistor TrS1-1, Vbg was set to −4 V, −2 V, 0 V, +2 V, or +4 V.

An S value, Vth, and DIBL were calculated from the calculated Id-Vgs characteristics. Note that Vth was calculated using linear extrapolation. Furthermore, DIBL was calculated using Formula (2) above.

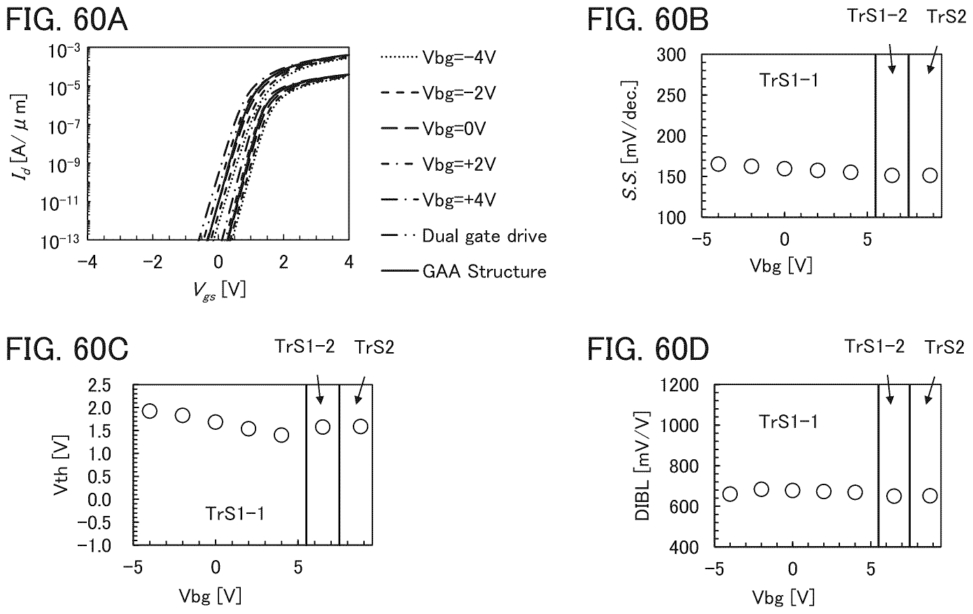

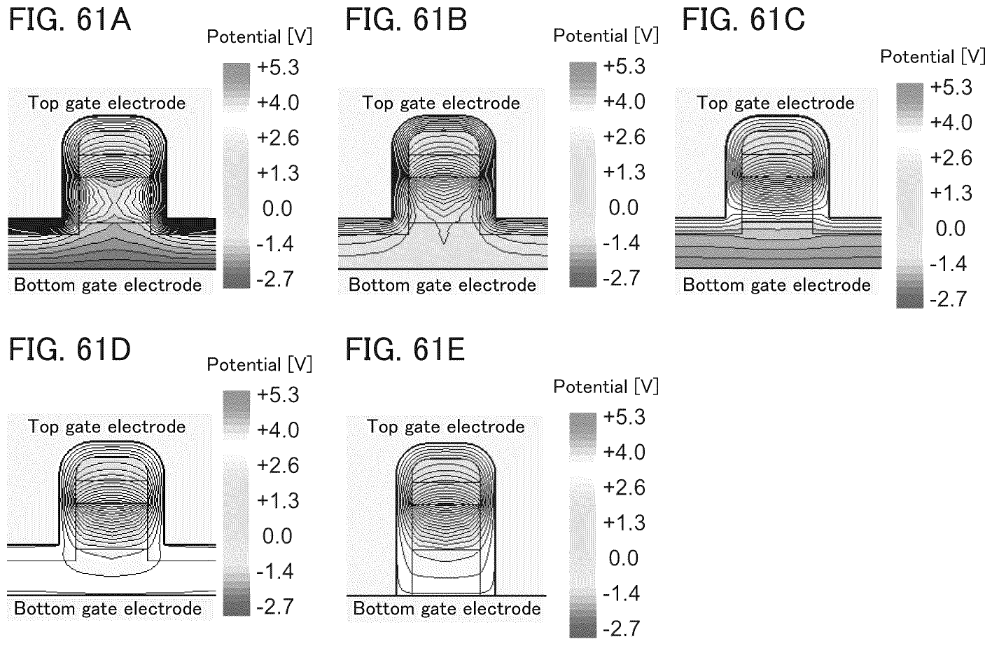

FIG. 60A to FIG. 61E show the results of the device simulation.

FIG. 60A shows the calculated Id-Vgs characteristics. In FIG. 60A, the vertical axis represents the drain current Id per micrometer of channel width [A/μm], and the horizontal axis represents the top gate voltage Vgs [V]. The dotted line in FIG. 60A shows the results of the case where the transistor TrS1-1 was used and Vbg was set to −4 V, the dashed line in FIG. 60A shows the results of the case where the transistor TrS1-1 was used and Vbg was set to −2 V, the long dashed line in FIG. 60A shows the results of the case where the transistor TrS1-1 was used and Vbg was set to 0 V, the dashed-dotted line in FIG. 60A shows the results of the case where the transistor TrS1-1 was used and Vbg was set to +2 V, the long dashed-dotted line in FIG. 60A shows the results of the case where the transistor TrS1-1 was used and Vbg was set to +4 V, the dashed-two dotted line in FIG. 60A shows the results of the case where the transistor TrS1-2 was used (Dual gate drive), and the solid line in FIG. 60A shows the results of the case where the transistor TrS2 was used (GAA Structure).

FIG. 60B shows the S values calculated from the Id-Vg characteristics at the time when Vds was set to 0.1 V. In FIG. 60B, the vertical axis represents the S value (S.S.) [m V/dec.] and the horizontal axis represents the bottom gate voltage Vbg [V].

FIG. 60C shows Vth calculated from the Id-Vg characteristics at the time when Vds was set to 0.1 V. In FIG. 60C, the vertical axis represents Vth [V] and the horizontal axis represents the bottom gate voltage Vbg [V].

FIG. 60D shows the calculated DIBL. In FIG. 60D, the vertical axis represents DIBL [mV/V] and the horizontal axis represents the bottom gate voltage Vbg [V].

FIG. 61A to FIG. 61E show potential distributions at the time when Vds was set to 1.2 V and Vgs was set to Vth+1 [V]. FIG. 61A to FIG. 61E are cross-sectional views of the transistors in the channel width direction. The scale bar in each of FIG. 61A to FIG. 61E represents a potential (Potential) [V].

FIG. 61A shows the potential distribution in the transistor TrS1-1 at the time when Vbg was set to −4 V, FIG. 61B shows the potential distribution in the transistor TrS1-1 at the time when Vbg was set to 0 V, FIG. 61C shows the potential distribution in the transistor TrS1-1 at the time when Vbg was set to +4 V, FIG. 61D shows the potential distribution in the transistor TrS1-2, and FIG. 61E shows the potential distribution in the transistor TrS2. Note that in FIG. 61A to FIG. 61E, “Bottom gate electrode” denotes the bottom gate electrode and “Top gate electrode” denotes the top gate electrode.

From FIG. 60A to FIG. 61E, it is confirmed that Vth changes depending on the bottom gate voltage in the case where certain voltages are applied as the bottom gate voltage as in the transistor TrS1-1. Specifically, it is confirmed that Vth shifts positively as the bottom gate voltage decreases. Furthermore, it is found that a Dual Gate driven transistor like the transistor TrS1-2 has a smaller S value. Note that the electrical characteristics of the transistor TrS1-2 are substantially the same as those of the transistor TrS2.

From the above, it can be said that a short-channel effect does not occur or is inhibited in the transistor 200 described in Embodiment 3. By changing the setting of the bottom gate electrode, the operation mode can be switched depending on the purpose.

This example can be used in an appropriate combination with any of the structures, configurations, methods, and the like described in the embodiments or other examples.

### Example 3

In this example, a sample including a plurality of the transistors illustrated in FIG. 36A to FIG. 36D was fabricated, and the structure of the transistors and the electrical characteristics of the transistors were evaluated.

In this example, Sample 3A was fabricated. FIG. 36A to FIG. 36D can be referred to for the cross-sectional structure of the transistors included in Sample 3A. Note that Sample 3A includes two kinds of transistors (a transistor 900A and a transistor 900B) with different design values. Specifically, the designed channel length and channel width values of the transistor 900A were 20 nm and 20 nm, respectively. The designed channel length and channel width values of the transistor 900B were 30 nm and 30 nm, respectively. In this example, the design value of the channel width refers to the design value of an apparent channel width. Thus, the design value of the channel width can be rephrased as the design value of the gate width.

A fabrication method of Sample 3A is described below. Note that Embodiment 3 can be referred to for details of the fabrication method.

As the insulator 212, 60-nm-thick silicon nitride was used. The insulator 212 was formed by a pulsed DC sputtering method using a silicon target.

As the insulator 214, 40-nm-thick aluminum oxide was used. The insulator 214 was formed by a pulsed DC sputtering method using an aluminum target.

As the insulator 216, 130-nm-thick silicon oxide was used. The insulator 216 was formed by a pulsed DC sputtering method using a silicon target.

Note that the insulator 212, the insulator 214, and the insulator 216 were successively formed without exposure to the outside air using a multi-chamber sputtering apparatus.

The conductor 205a was formed using a titanium nitride film formed by a metal CVD method. The conductor 205b was formed using a tungsten film formed by a metal CVD method.

As the insulator 222, a stack of a 3-nm-thick silicon nitride film formed by an ALD method and a 17-nm-thick hafnium oxide film formed over the silicon nitride film by an ALD method was used.

As the insulator 224, a 20-nm-thick silicon oxide film formed by a sputtering method was used.

As the oxide 230a, a 10-nm-thick In—Ga—Zn oxide film formed by an RF sputtering method was used. For the formation of the oxide 230a, an oxide target with In:Ga:Zn=1:3:2 [atomic ratio] was used.

As the oxide 230b, a 15-nm-thick In—Ga—Zn oxide film formed by an RF sputtering method was used. For the formation of the oxide 230b, an oxide target with In:Ga:Zn=1:1:1.2 [atomic ratio] was used.

The conductor 242a and the conductor 242b were formed using a 20-nm-thick tantalum nitride film formed by a sputtering method. Note that the conductive film to be the conductor 242a and the conductor 242b was formed using a metallic tantalum target under an atmosphere containing nitrogen.

The insulator 271a1 and the insulator 271b1 were formed using a 5-nm-thick silicon nitride film. The insulator 271a2 and the insulator 271b2 were formed using a silicon oxide film. Note that the silicon nitride film and the silicon oxide film were successively formed without exposure to the outside air using a multi-chamber sputtering apparatus.

As the insulator 275, a 5-nm-thick silicon nitride film formed by an ALD method was used.

As the insulator 280, a silicon oxide film formed by a sputtering method was used.

The insulator 252 was formed using a 1-nm-thick aluminum oxide film formed by an ALD method. The insulator 250 was formed using a 3-nm-thick silicon oxide film formed by an ALD method. The insulator 254 was formed using a 3-nm-thick silicon nitride film formed by an ALD method.

The conductor 260a was formed using a 5-nm-thick titanium nitride film formed by a metal CVD method. The conductor 260b was formed using a 75-nm-thick tungsten film formed by a metal CVD method.

As the insulator 282, aluminum oxide was used. The insulator 282 was formed by a pulsed DC sputtering method using an aluminum target.

In the above manner, Sample 3A including the transistors was fabricated.

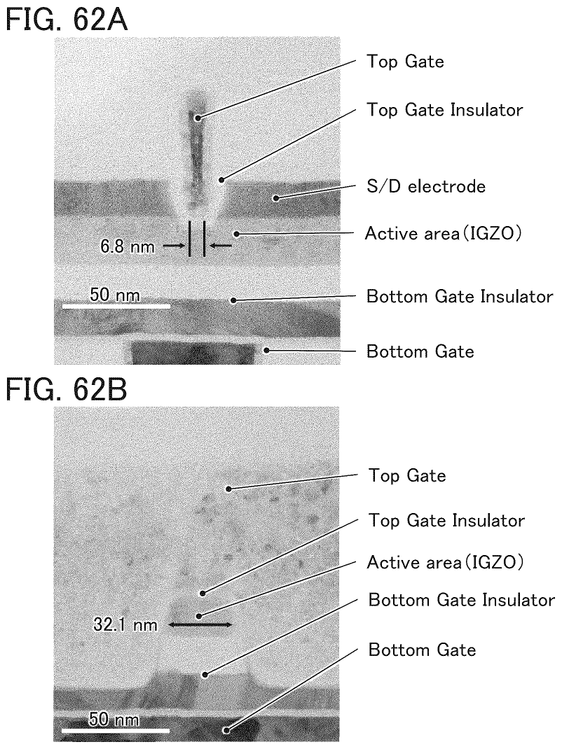

Next, a cross-sectional STEM (Scanning Transmission Electron Microscope) image of Sample 3A fabricated was taken with “HD-2700” produced by Hitachi High-Technologies Corporation. FIG. 62A shows a cross-sectional STEM image of the transistor 900A included in Sample 3A in the channel length direction, and FIG. 62B shows a cross-sectional STEM image of the transistor 900A included in Sample 3A in the channel width direction. Note that in FIG. 62A and FIG. 62B, “Bottom Gate” corresponds to the conductor 205a and the conductor 205b, “Bottom Gate Insulator” corresponds to the insulator 222 and the insulator 224, “Active area (IGZO)” corresponds to the oxide 230a and the oxide 230b, “S/D electrode” corresponds to the conductor 242a or the conductor 242b, “Top Gate Insulator” corresponds to the insulator 252, the insulator 250, and the insulator 254, and “Top Gate” corresponds to the conductor 260a and the conductor 260b.

Note that in FIG. 62A and FIG. 62B, the length of each component was measured on the basis of the observation results of the cross-sectional STEM images. As a result of the measurement using FIG. 62A, the gate length of the transistor 900A in the channel length direction (the width Lg illustrated in FIG. 17A) is 6.8 nm. As a result of the measurement using FIG. 62B, the length of the interface between the oxide 230a and the oxide 230b included in the transistor 900A in the channel width direction is 32.1 nm.

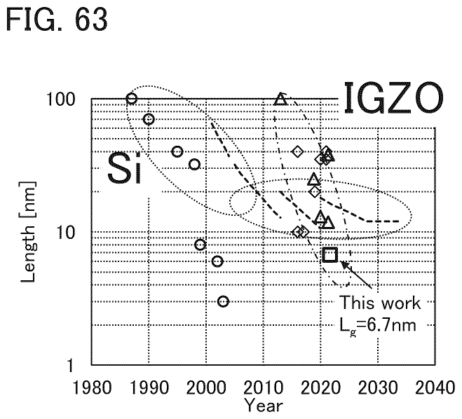

Here, FIG. 63 shows the transition of channel lengths or gate lengths of the transistors prototyped in this example (This work), the transistors that have been reported, and the transistors included in commercially available processors and the like. In FIG. 63, the vertical axis represents the channel length or gate length (Length) [nm], and the horizontal axis represents the reporting year (Year). Plots shown as circles in FIG. 63 denote the transition of channel lengths of Si transistors; the dashed lines in FIG. 63 denote the transition of gate lengths of Si transistors; plots shown as rhombi in FIG. 63 denote the transition of gate lengths of transistors using molybdenum sulfide (MoS₂); plots shown as triangles in FIG. 63 denote the transition of gate lengths of OS transistors; and a plot shown as a square in FIG. 63 denotes the gate length of the transistor 900A included in Sample 3A of this example.

FIG. 63 shows that the transistor included in the sample fabricated in this example has an extremely minute structure.

Next, plan-view observation was performed on the transistor 900B included in Sample 3A fabricated. Note that the plan-view observation was performed on the thin-sliced samples with a scanning transmission electron microscope (STEM). As an apparatus for the observation, HD-2700 produced by Hitachi High-Technologies Corporation was used.

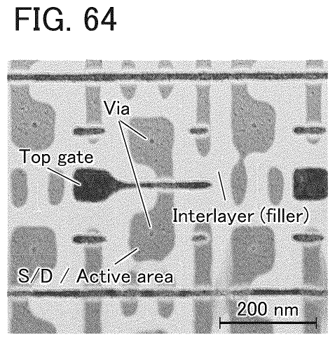

FIG. 64 shows a plan-view STEM image of the transistor 900B included in Sample 3A fabricated. FIG. 64 is a plan-view STEM image allowing for overall observation of the transistor 900B. “Top gate” in FIG. 64 corresponds to the conductor 260 described in Embodiment 3. Furthermore, “S/D Active area” in FIG. 64 denotes a stack of an oxide semiconductor (Active area) and a source electrode and a drain electrode (SD), which corresponds to the stack of the oxide 230 and the conductor 242a and the conductor 242b described in Embodiment 3. Furthermore, “Via” in FIG. 64 corresponds to the conductor 240a and the conductor 240b described in Embodiment 3. “Interlayer (filler)” in FIG. 64 corresponds to the insulator 280 described in Embodiment 3.

It is confirmed from FIG. 64 that by reducing the contact area, the pitch between the gate electrodes, or the like, a 127/μm² density rule is satisfied.

Next, the electrical characteristics of the transistors 900A included in Sample 3A fabricated were evaluated. Here, drain current-top gate voltage (Id-Vgs) characteristics were measured as the electrical characteristics. The measurement of the Id-Vgs characteristics was performed under the conditions where the drain-source voltage Vds was 0.1 V or 1.2 V; the bottom gate voltage Vbg was 0 V; and the top gate voltage Vgs was swept from −4 V to +4 V in increments of 0.1 V. The measurement was performed at room temperature (27° C.) in dry air under atmospheric pressure.

For evaluation of the electrical characteristics, a semi-automatic prober produced by Hi-SOL, Inc. was used. As a measuring instrument, B1500A produced by Keysight Technologies, Inc. was used.

Furthermore, Vth, an S value, and DIBL were calculated from the calculated Id-Vgs characteristics. Note that Vth was calculated using linear extrapolation. Furthermore, DIBL was calculated using Formula (2) shown in Example 2 above.

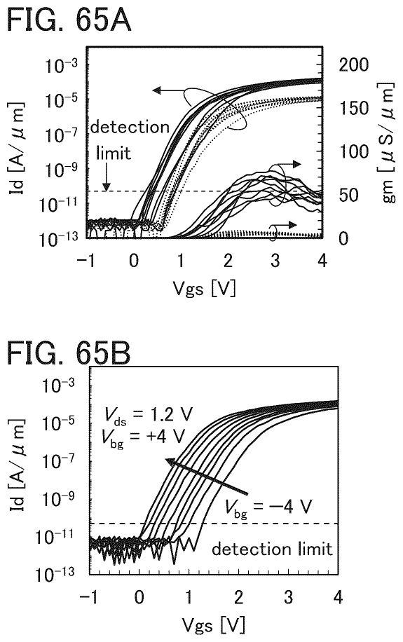

FIG. 65A shows the Id-Vgs characteristics of nine of the transistors 900A included in Sample 3A. In FIG. 65A, the first vertical axis (the vertical axis on the left side of the diagram) represents the drain current Id per micrometer of channel width [A/μm], the second vertical axis (the vertical axis on the right side of the diagram) represents mutual conductance (gm) per micrometer of channel width [μS/μm], and the horizontal axis represents the top gate voltage Vgs [V]. In FIG. 65A, the solid lines denote the drain current Id and mutual conductance at the time when the drain-source voltage Vds was 1.2 V, and the dotted lines denote the drain current Id and mutual conductance at the time when the drain-source voltage Vds was 0.1 V. The dashed line in FIG. 65A denotes the lower detection limit (detection limit) of the drain current Id per micrometer of channel width.

FIG. 65A confirms that the transistors 900A have normally-off characteristics and favorable switching characteristics. Specifically, when the drain-source voltage Vds was 1.2 V, Vth was 1.86 V (σ=0.169 V), the S value was 172 mV/dec. (σ=18 mV/dec.), and gm was 66 μS/μm (σ=10 μS/μm). The DIBL coefficient was 370 mV/V (σ=134 mV/V). Note that the above values are each a median value of characteristic values obtained from the nine transistors 900A, and σ is a standard deviation. Accordingly, the transistors fabricated by the method described in Embodiment 3 had a gate length less than or equal to 10 nm and achieved favorable switching characteristics. Furthermore, the transistors achieved normally-off characteristics.

The Id-Vgs characteristics of the transistor 900A were measured under conditions different from those described above. The measurement of the Id-Vgs characteristics was performed under the conditions where the drain-source voltage Vds was 1.2 V; the bottom gate voltage Vbg was −4 V, −3 V, −2 V, −1 V, 0 V, 1 V, 2 V, 3 V, or 4 V; and the top gate voltage Vgs was swept from −4 V to +4 V in increments of 0.1 V. The measurement was performed in an environment at room temperature.

FIG. 65B shows the Id-Vgs characteristics of the transistor 900A. In FIG. 65B, the vertical axis represents the drain current Id per micrometer of channel width [A/μm], and the horizontal axis represents the top gate voltage Vgs [V]. The dashed line in FIG. 65B denotes the lower detection limit (detection limit) of the drain current Id per micrometer of channel width.

It is confirmed from FIG. 65B that the Id-Vgs characteristics of the transistor 900A shift substantially equidistantly in parallel owing to the bottom gate voltage Vbg, and only Vth varies. Thus, it is found that when the top gate and the bottom gate are separate power sources, the top gate and the bottom gate can have separate functions; for example, a control signal is input from the top gate and Vth is controlled using the bottom gate.

Note that the transistors included in Sample 3A have a structure similar to that of the transistor (see FIG. 55) used in the device simulation described above in Example 2. As described above, it is confirmed that the transistors included in Sample 3A have normally-off characteristics and favorable switching characteristics. In other words, each of the transistors included in Sample 3A is a transistor in which negative fixed charge is provided at the interface between the bottom gate insulating film and the oxide 230a. It is presumable that providing negative fixed charge at the interface between the bottom gate insulating film and the oxide 230a blocks the lower drain electric field even when the thickness of the bottom gate insulating film is large, and that the transistors can be fabricated to be highly resistant to a short-channel effect.

The structure, configuration, method, or the like described in this example can be used in an appropriate combination with any of the structures, configurations, methods, and the like described in the other embodiments and the like.

### Example 4

In this example, a ring oscillator including the transistor of one embodiment of the present invention was prototyped, and the oscillation frequency and the delay time were evaluated.

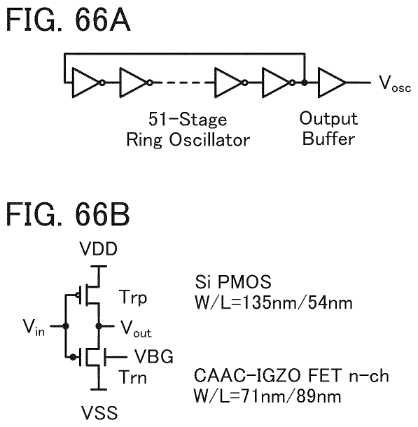

FIG. 66A is a circuit diagram of the ring oscillator. As illustrated in FIG. 66A, the ring oscillator has a structure in which an odd number of inverters are connected in series.

FIG. 66B is a circuit diagram of the inverter. In the inverter illustrated in FIG. 66B, a transistor Trp and a transistor Trn are connected in series and their gates are connected to each other.

As illustrated in FIG. 66B, a first terminal of the transistor Trp is connected to a high power supply potential VDD, and a first terminal of the transistor Trn is connected to a low power supply potential VSS. A second terminal of the transistor Trp and a second terminal of the transistor Trn are connected to an output terminal. A gate of the transistor Trp and a first gate of the transistor Trn are connected to an input terminal. A signal Vin is input to the input terminal, and a signal Vout is output to the output terminal. A second gate of the transistor Trn is connected to a power supply potential VBG.

The transistor Trp is a p-channel Si transistor (Si PMOS). The transistor Trn is an n-channel transistor using CAAC-IGZO (CAAC-IGZO FET n-ch), which is an example of the transistor described in Embodiment.

Note that the sample fabricated in this example has a structure in which the transistor Trn is monolithically stacked over the transistor Trp.

The transistor Trp was fabricated by a 55-nm process. The transistor Trp was fabricated to have a channel length of 54 nm and a channel width of 135 nm.

Over a silicon wafer including the transistor Trp, a 400-nm-thick silicon oxide film functioning as a planarization film was formed, and a wiring layer was formed over the silicon oxide film. Next, the transistor Trn was fabricated over the wiring layer.

The transistor Trn is different from the transistor included in Sample 3A fabricated in Example 3 in part of the structure. Specifically, the transistor Trn is different from the transistor included in Sample 3A fabricated in Example 3 in the structure of the insulator 222. Thus, for the fabrication method of the transistor Trn, the description of the transistor included in Sample 3A fabricated in Example 3, except for the description of the insulator 222, can be referred to.

As the insulator 222 of the transistor Trn, a 20-nm-thick hafnium oxide film formed by an ALD method was used.

The transistor Trn was fabricated to have a channel length of 89 nm and a channel width of 71 nm.

Through the above steps, the sample in which the CAAC-IGZO FET was monolithically stacked over the Si transistor was fabricated.

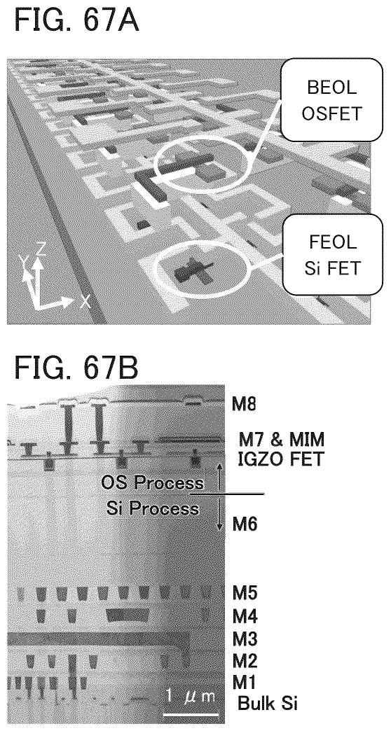

In this example, the inverter with the structure in which the CAAC-IGZO FET was monolithically stacked over the Si transistor was fabricated. FIG. 67A schematically illustrates a 3D layout of the ring oscillator; FIG. 67B is a cross-sectional TEM image of the sample with the structure in which the CAAC-IGZO FET was monolithically stacked over the Si transistor. In FIG. 67A, “OSFET” denotes the CAAC-IGZO FET and “Si FET” denotes the Si transistor. Note that the Si transistor is provided over a silicon substrate (“Bulk Si” in FIG. 67B). In FIG. 67B, a BEOL (Back End Of Line) process is denoted as “OS Process”, and a process before the BEOL process is denoted as “Si Process”.

FIG. 67B shows that the ring oscillator was obtained by monolithic stacking of the CAAC-IGZO FET (“IGZO FET” in FIG. 67B) over the Si transistor fabricated in a Front End of Line (FEOL) process.

Next, an output signal V_{OSC} of a 51-stage ring oscillator (51-Stage Ring Oscillator) was observed with an oscilloscope.

For evaluation of the ring oscillator, a semi-automatic prober produced by Hi-SOL, Inc. was used. The evaluation was performed in an indoor environment (an atmospheric pressure and a humidity of 50%) at room temperature (27° C.). As a measuring instrument, B1500A produced by Keysight Technologies, Inc. was used. Furthermore, a voltage of 1.2 V was applied to the high power supply potential VDD and a voltage of 0 V was applied to the low power supply potential VSS. The readout of the output waveform of the ring oscillator was observed with an oscilloscope (GDS-3504 GW Instek) using a pico probe (MODEL 28) manufactured by GGB Industries, Inc. to minimize the output load.

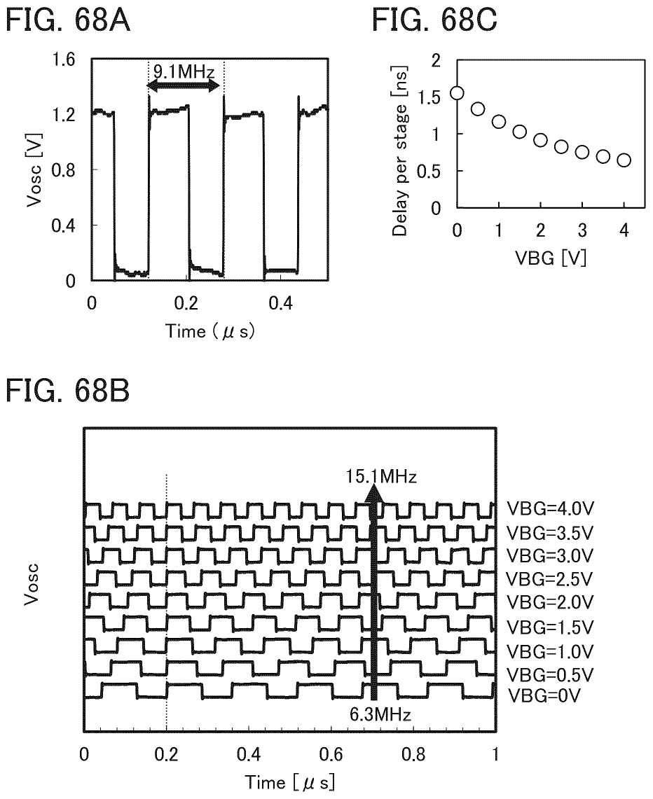

FIG. 68A shows the output waveform of the ring oscillator. In FIG. 68A, the vertical axis represents V_{OSC} [V] and the horizontal axis represents time (Time) [μs]. As shown in FIG. 68A, the oscillation frequency is 9.1 MHz, which is 1.1 ns when converted into delay time per stage.

Next, a change in delay time depending on a difference in the voltage applied to the power supply potential VBG was observed. Specifically, an output signal was observed while voltages were applied to the power supply potential VBG from 0 V to 4 V in increments of 0.5 V.

FIG. 68B shows the output waveforms of the ring oscillator. In FIG. 68B, the vertical axis represents V_{OSC} and the horizontal axis represents time (Time) [μs]. As shown in FIG. 68B, the oscillation frequency at the time when a voltage of 0 V was applied to the power supply potential VBG was 6.3 MHz, and the oscillation frequency at the time when a voltage of 4 V was applied to the power supply potential VBG was 15.1 MHz.

FIG. 68C shows dependence of the delay time per stage on the voltage applied to the power supply potential VBG. In FIG. 68C, the vertical axis represents the delay time [ns] per stage and the horizontal axis represents the power supply voltage VBG [V].

As shown in FIG. 68B and FIG. 68C, the oscillation frequency increased by approximately 2.4 times when the voltages were applied to the power supply potential VBG from 0 V to 4 V. Conversion showed that the delay time per stage decreased to approximately 0.6 ns.

It is thus found that the transistor described in Embodiment can be fabricated through a BEOL process and that logic application by the combination of the transistor with a Si transistor is possible.

The structure, configuration, method, or the like described in this example can be used in an appropriate combination with any of the structures, configurations, methods, and the like described in the other embodiments and the like.

### Example 5

In this example, the electrical characteristics of an OS transistor of one embodiment of the present invention were evaluated. In this example, a layout of a standard cell including the OS transistor was formed and the layout area was evaluated. Furthermore, in this example, ring oscillators each including the OS transistor were prototyped, and the oscillation frequency and the delay time were evaluated.

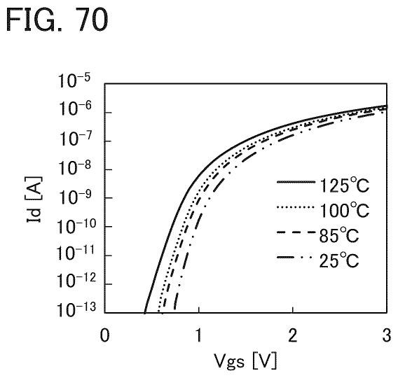

FIG. 70 shows the Id-Vgs characteristics of the OS transistor fabricated in this example at environment temperatures of 25° C., 85° C., 100° C., and 125° C. Here, the OS transistor was a CAAC-IGZO FET. The drain-source voltage was set to 1.2 V.

FIG. 70 shows that the S value is smaller than 100 mV/dec. even at an ambient temperature of 125° C. and that favorable switching characteristics can be achieved even in a high-temperature environment.

Next, an inverter, a NAND circuit, and a NOR circuit were fabricated as standard cells. P-channel transistors included in the inverter, the NAND circuit, and the NOR circuit were Si transistors. Furthermore, for each of the inverter, the NAND circuit, and the NOR circuit, a standard cell including a Si transistor as an n-channel transistor and a standard cell including an OS transistor as an n-channel transistor were fabricated. A CAAC-IGZO FET was used as the OS transistor. In the case where Si transistors were used as both the p-channel transistor and the n-channel transistor, the p-channel transistor and the n-channel transistor were formed in the same layer. In the case where a Si transistor was used as the p-channel transistor and an OS transistor was used as the n-channel transistor, the n-channel transistor was monolithically stacked over the p-channel transistor.

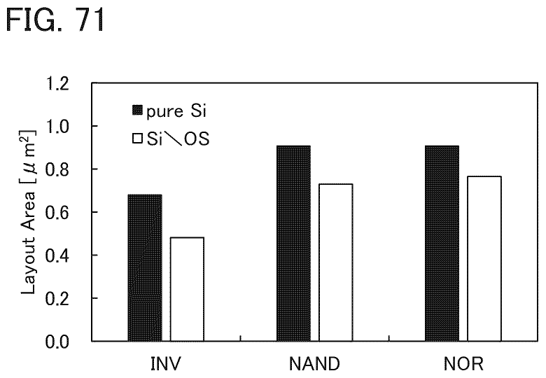

FIG. 71 illustrates the layout areas (Layout Area) [μm²] of an inverter (INV), a NAND circuit (NAND), and a NOR circuit (NOR). In FIG. 71, “pure Si” indicates that both the p-channel transistor and the n-channel transistor included in the standard cell are Si transistors. Furthermore, “Si\OS” indicates that the p-channel transistor included in the standard cell is a Si transistor and the n-channel transistor included in the standard cell is an OS transistor.

As shown in FIG. 71, in the inverter, the layout area of “pure Si” was 0.680 μm², and the layout area of “Si\OS” was 0.482 μm², so that the layout area of “Si\OS” was 29% smaller than the layout area of “pure Si”. In the NAND circuit, the layout area of “pure Si” was 0.907 μm², and the layout area of “Si\OS” was 0.729 μm², so that the layout area of “Si\OS” was 20% smaller than the layout area of “pure Si”. In the NOR circuit, the layout area of “pure Si” was 0.907 μm², and the layout area of “Si\OS” was 0.765 μm², so that the layout area of “Si\OS” was 16% smaller than the layout area of “pure Si”.

From the above, it is confirmed that the layout area of each of the inverter, the NAND circuit, and the NOR circuit is smaller in the case where an OS transistor is monolithically stacked over a Si transistor than in the case where only OS transistors are included.

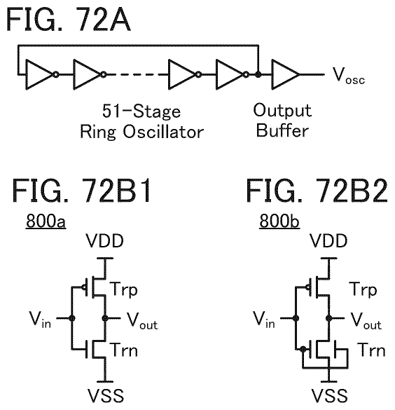

FIG. 72A is a circuit diagram of the ring oscillators. As illustrated in FIG. 72A, the ring oscillators fabricated in this example each have a structure in which 51 inverters are connected in series. A ring oscillator having this structure is referred to as a 51-stage ring oscillator (51-Stage Ring Oscillator). An input terminal of the inverter in the initial stage (the first stage) and an output terminal of the inverter in the final stage (the 51st stage) are connected to an input terminal of a buffer (Output Buffer). The output signal V_{OSC} is output from an output terminal of the buffer.

FIG. 72B1 and FIG. 72B2 are circuit diagrams of inverters. In an inverter 800a illustrated in FIG. 72B1, the transistor Trp and the transistor Trn are connected in series and their gates are connected to each other.

As illustrated in FIG. 72B1, the first terminal of the transistor Trp is connected to the high power supply potential VDD, and the first terminal of the transistor Trn is connected to the low power supply potential VSS. The second terminal of the transistor Trp and the second terminal of the transistor Trn are connected to an output terminal. The gate of the transistor Trp and the first gate of the transistor Trn are connected to an input terminal. The signal Vin is input to the input terminal, and the signal Vout is output to the output terminal.

The transistor Trp is a p-channel transistor and the transistor Trn is an n-channel transistor.

In this example, ring oscillators having Structure 1, Structure 2, and Structure 3 shown in Table 2 were prototyped, and the oscillation frequency and the delay time were evaluated.

TABLE 2

| | Circuit structure | Transistor type | | L/W (nm) | |
|---|---|---|---|---|---|
| | of inverter | Trn | Trp | Trn | Trp |
| Structure 1 | 800a | Si | Si | 54/117 | 54/135 |
| Structure 2 | 800b | OS | Si | 60/60 | 54/108 |
| Structure 3 | 800b | OS | Si | 60/180 | 54/108 |

As shown in Table 2, the inverter 800a was included in the ring oscillator having Structure 1, and an inverter 800b was included in the ring oscillators having Structure 2 and Structure 3. In Structure 1, both the transistor Trn and the transistor Trp were Si transistors; a channel length L and a channel width W of the transistor Trn were respectively 54 nm and 117 nm, and the channel length L and the channel width W of the transistor Trp were respectively 54 nm and 135 nm. In Structure 2, the transistor Trn was an OS transistor and the transistor Trp was a Si transistor; both the channel length L and the channel width W of the transistor Trn were 60 nm, and the channel length L and the channel width W of the transistor Trp were respectively 54 nm and 108 nm. The transistor Trn and the transistor Trp in Structure 3 were different from those in Structure 2 in that the channel width W of the transistor Trn was 180 nm. Here, in Structure 2 and Structure 3, CAAC-IGZO FETs were used as the OS transistors.

Here, in Structure 1, the transistor Trp and the transistor Trn, which were Si transistors, were formed in the same layer. Meanwhile, in Structure 2 and Structure 3, the transistor Trn, which was an OS transistor, was monolithically stacked over the transistor Trp, which was a Si transistor.

For evaluation of the ring oscillators, a semi-automatic prober produced by Hi-SOL, Inc. was used. The evaluation was performed at room temperature (27° C.). Furthermore, a voltage of 1.2 V was applied to the high power supply potential VDD and a voltage of 0 V was applied to the low power supply potential VSS.

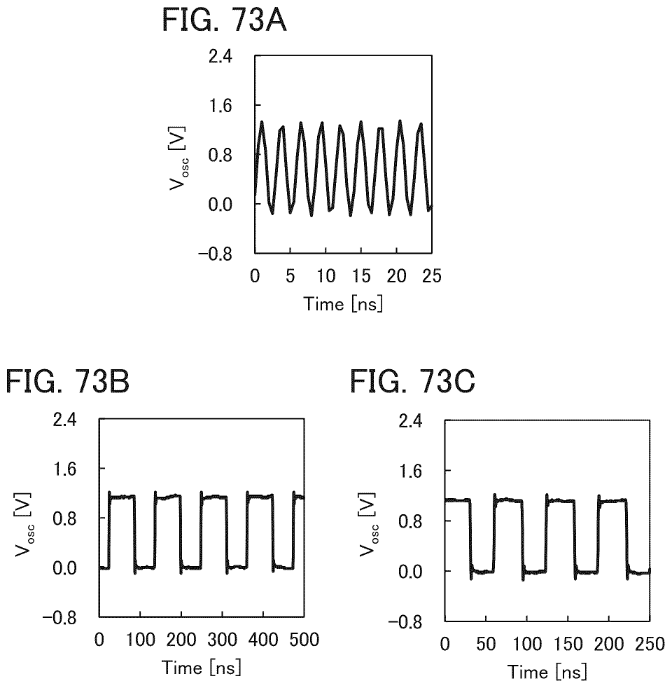

FIG. 73A shows the output waveform of the ring oscillator having Structure 1. FIG. 73B shows the output waveform of the ring oscillator having Structure 2. FIG. 73C shows the output waveform of the ring oscillator having Structure 3. In FIG. 73A, FIG. 73B, and FIG. 73C, the vertical axis represents V_{OSC} [V] and the horizontal axis represents time (Time) [ns].

In Structure 1, the oscillation frequency was 366 MHz, and the delay time per stage was 0.027 ns. In Structure 2, the oscillation frequency was 8.5 MHZ, and the delay time per stage was 1.33 ns. In Structure 3, the oscillation frequency was 16.2 MHZ, and the delay time per stage was 0.64 ns.

It is thus confirmed that the ring oscillators are driven even in the case where the inverter includes an OS transistor as an n-channel transistor and a Si transistor as a p-channel transistor.

### REFERENCE NUMERALS

10A: transistor, 10B: transistor, 10C: transistor, 10: transistor, 11D: transistor, 12: insulator, 16: insulator, 20a: insulator, 20b: insulator, 20: insulator, 25: conductor, 30_1: semiconductor layer, 30_2: semiconductor layer, 30_n: semiconductor layer, 30a: semiconductor layer, 30b: semiconductor layer, 30D: semiconductor layer, 30: semiconductor layer, 35_1: channel formation region, 35_n: channel formation region, 40a: conductor, 40b: conductor, 42a: conductor, 42b: conductor, 42: conductor, 44a: insulator, 44b: insulator, 50: insulator, 60: conductor, 75: insulator, 80: insulator, 90a: dashed line, 90b: dotted line, 100: capacitor, 110: conductor, 112: conductor, 115: conductor, 120: conductor, 125: conductor, 130: insulator, 140: conductor, 142: insulator, 145: insulator, 150: insulator, 152: insulator, 153: conductor, 154: insulator, 156: insulator, 200a: transistor, 200b: transistor, 200: transistor, 205a: conductor, 205b: conductor, 205: conductor, 210: insulator, 212: insulator, 214: insulator, 216: insulator, 217: insulator, 218: conductor, 222: insulator, 224A: insulating film, 224: insulator, 230a: oxide, 230A: oxide film, 230b: oxide, 230B: oxide film, 230ba: region, 230bb: region, 230bc: region, 230bd: region, 230be: region, 230: oxide, 240a: conductor, 240b: conductor, 240: conductor, 241a: insulator, 241b: insulator, 241: insulator, 242a: conductor, 242a1: conductor, 242a2: conductor, 242A: conductive film, 242b: conductor, 242b1: conductor, 242b2: conductor, 242B: conductive layer, 242c: conductor, 242: conductor, 243a: oxide, 243b: oxide, 243: oxide, 244a: insulator, 244b: insulator, 246a: conductor, 246b: conductor, 246: conductor, 250a: insulator, 250A: insulating film, 250b: insulator, 250: insulator, 252A: insulating film, 252: insulator, 254A: insulating film, 254: insulator, 256: insulator, 260a: conductor, 260b: conductor, 260: conductor, 265: sealing portion, 271a: insulator, 271al: insulator, 271a2: insulator, 271A: insulating film, 271b: insulator, 271b1: insulator, 271b2: insulator, 271B: insulating layer, 271c: insulator, 271: insulator, 274: insulator, 275: insulator, 280: insulator, 282a: insulator, 282b: insulator, 282: insulator, 283a: insulator, 283b: insulator, 283: insulator, 285: insulator, 290: memory device, 292a: capacitor device, 292b: capacitor device, 292: capacitor device, 294a: conductor, 294b: conductor, 294: conductor, 295: opening region, 300: transistor, 311: substrate, 313: semiconductor region, 314a: low-resistance region, 314b: low-resistance region, 315: insulator, 316: conductor, 320: insulator, 322: insulator, 324: insulator, 326: insulator, 328: conductor, 330: conductor, 350: insulator, 352: insulator, 354: insulator, 356: conductor, 500: semiconductor device, 600: semiconductor device, 601: semiconductor device, 610_1: cell array, 610_n: cell array, 610: cell array, 700: electronic component, 702: printed circuit board, 704: mounting board, 711: mold, 712: land, 713: electrode pad, 714: wire, 720: storage device, 721: driver circuit layer, 722: storage circuit layer, 730: electronic component, 731: interposer, 732: package substrate, 733: electrode, 735: semiconductor device, 800a: inverter, 800b: inverter, 801: substrate, 824: insulator, 830a: metal oxide, 830b: metal oxide, 842: conductor, 871: insulator, 872: insulator, 875: insulator, 900A: transistor, 900B: transistor, 1001: wiring, 1002: wiring, 1003: wiring, 1004: wiring, 1005: wiring, 1006: wiring, 1100: USB memory, 1101: housing, 1102: cap, 1103: USB connector, 1104: substrate, 1105: memory chip, 1106: controller chip, 1110: SD card, 1111: housing, 1112: connector, 1113: substrate, 1114: memory chip, 1115: controller chip, 1150: SSD, 1151: housing, 1152: connector, 1153: substrate, 1154: memory chip, 1155: memory chip, 1156: controller chip, 1200: chip, 1201: package substrate, 1202: bump, 1203: motherboard, 1204: GPU module, 1211: CPU, 1212: GPU, 1213: analog arithmetic unit, 1214: memory controller, 1215: interface, 1216: network circuit, 1221: DRAM, 1222: flash memory, 1400: storage device, 1411: peripheral circuit, 1420: row circuit, 1430: column circuit, 1440: output circuit, 1460: control logic circuit, 1470: memory cell array, 1471: memory cell, 1472: memory cell, 1473: memory cell, 1474: memory cell, 1475: memory cell, 1476: memory cell, 1477: memory cell, 1478: memory cell, 2700: manufacturing apparatus, 2701: atmosphere-side substrate supply chamber, 2702: atmosphere-side substrate transfer chamber, 2703a: load lock chamber, 2703b: unload lock chamber, 2704: transfer chamber, 2706a: chamber, 2706b: chamber, 2706c: chamber, 2706d: chamber, 2761: cassette port, 2762: alignment port, 2763a: transfer robot, 2763b: transfer robot, 2801: gas supply source, 2802: valve, 2803: high-frequency generator, 2804: waveguide, 2805: mode converter, 2806: gas pipe, 2807: waveguide, 2808: slot antenna plate, 2809: dielectric plate, 2810: high-density plasma, 2811_1: substrate, 2811_2: substrate, 2811_3: substrate, 2811_n: substrate, 2811: substrate, 2812: substrate holder, 2813: heating mechanism, 2815: matching box, 2816: high-frequency power source, 2817: vacuum pump, 2818: valve, 2819: exhaust port, 2820: lamp, 2821: gas supply source, 2822: valve, 2823: gas inlet, 2824: substrate, 2825: substrate holder, 2826: heating mechanism, 2828: vacuum pump, 2829: valve, 2830: exhaust port, 2900: microwave treatment apparatus, 2901: quartz tube, 2902: substrate holder, 2903: heating means, 5100: information terminal, 5101: housing, 5102: display portion, 5200: notebook information terminal, 5201: main body, 5202: display portion, 5203: keyboard, 5300: portable game machine, 5301: housing, 5302: housing, 5303: housing, 5304: display portion, 5305: connection portion, 5306: operation key, 5400: stationary game machine, 5402: controller, 5500: supercomputer, 5501: rack, 5502: computer, 5504: substrate, 5701: display panel, 5702: display panel, 5703: display panel, 5704: display panel, 5800: electric refrigerator-freezer, 5801: housing, 5802: refrigerator door, 5803: freezer door, 6800: artificial satellite, 6801: body, 6802: solar panel, 6803: antenna, 6804: planet, 6805: secondary battery, 6807: control device

1. A semiconductor device comprising a transistor, the transistor comprising:
a first insulator;
a first semiconductor layer over the first insulator;
a second semiconductor layer over the first semiconductor layer;
a first conductor and a second conductor over the second semiconductor layer;
a second insulator over the second semiconductor layer and between the first conductor and the second conductor; and
a third conductor over the second insulator,
wherein the second semiconductor layer comprises a channel formation region,
wherein in a cross-sectional view in a channel width direction of the transistor, the third conductor covers a side surface and a top surface of the second semiconductor layer,
wherein a permittivity of the second semiconductor layer is higher than a permittivity of the first semiconductor layer,
wherein in the cross-sectional view in the channel width direction of the transistor, a length of an interface between the first semiconductor layer and the second semiconductor layer is greater than or equal to 1 nm and less than or equal to 20 nm,
wherein the third conductor comprises a first region not overlapping with the second semiconductor layer, and
wherein in the cross-sectional view in the channel width direction of the transistor, a length from a bottom surface of the second semiconductor layer to a bottom surface of the first region of the third conductor is larger than a thickness of the second semiconductor layer.

2. (canceled)

3. A semiconductor device comprising a transistor, the transistor comprising:
a first conductor;
a first insulator over the first conductor;
a first semiconductor layer over the first insulator;
a second semiconductor layer over the first semiconductor layer;
a second conductor and a third conductor over the second semiconductor layer;
a second insulator over the second semiconductor layer and between the second conductor and the third conductor; and
a fourth conductor over the second insulator,
wherein the fourth conductor comprises a first region overlapping with the second semiconductor layer with the second insulator therebetween,
wherein the first conductor overlaps with the second semiconductor layer and the fourth conductor,
wherein the fourth conductor comprises a second region not overlapping with the second semiconductor layer,
wherein in a cross-sectional view in a channel width direction of the transistor, with reference to a bottom surface of the first insulator, a level of a bottom surface of the second region of the fourth conductor is lower than a level of a bottom surface of the second semiconductor layer,
wherein a permittivity of the second semiconductor layer is higher than a permittivity of the first semiconductor layer,
wherein in the cross-sectional view in the channel width direction of the transistor, a length of an interface between the first semiconductor layer and the second semiconductor layer is greater than or equal to 1 nm and less than or equal to 20 nm, and
wherein in the cross-sectional view in the channel width direction of the transistor, a length from the bottom surface of the second semiconductor layer to the bottom surface of the second region of the fourth conductor is larger than a thickness of the second semiconductor layer.

4. The semiconductor device according to claim 1,
wherein each of the first conductor and the second conductor comprises titanium and nitrogen, and
wherein a thickness of each of the first conductor and the second conductor is greater than or equal to 5 nm and less than or equal to 30 nm.

5. The semiconductor device according to claim 1,
wherein a band gap of the second semiconductor layer is wider than a band gap of silicon.

6. The semiconductor device according to claim 1,
wherein each of the first semiconductor layer and the second semiconductor layer comprises indium, zinc, and one or more selected from gallium, aluminum, and tin.

7. A semiconductor device comprising:
a first insulator;
a first semiconductor layer and a second semiconductor layer over the first insulator;
a third semiconductor layer over the first semiconductor layer;
a first conductor and a second conductor over the third semiconductor layer;
a fourth semiconductor layer over the second semiconductor layer;
a third conductor and a fourth conductor over the fourth semiconductor layer;
a second insulator over the third semiconductor layer and between the first conductor and the second conductor; and
a fifth conductor over the second insulator,
wherein the fifth conductor comprises a first region overlapping with the third semiconductor layer with the second insulator therebetween,
wherein the second insulator and the fifth conductor extend in a direction in which the third semiconductor layer and the fourth semiconductor layer extend,
wherein the second insulator is over the fourth semiconductor layer and between the third conductor and the fourth conductor,
wherein the fifth conductor comprises a second region overlapping with the fourth semiconductor layer with the second insulator therebetween,
wherein the fifth conductor comprises a third region not overlapping with the third semiconductor layer,
wherein in a cross-sectional view, with reference to a bottom surface of the first insulator, a level of a bottom surface of the third region of the fifth conductor is lower than a level of a bottom surface of the third semiconductor layer,
wherein a permittivity of the third semiconductor layer is higher than a permittivity of the first semiconductor layer,
wherein in the cross-sectional view, a length of an interface between the first semiconductor layer and the third semiconductor layer is greater than or equal to 1 nm and less than or equal to 20 nm, and
wherein in the cross-sectional view, a length from the bottom surface of the third semiconductor layer to the bottom surface of the third region of the fifth conductor is larger than a thickness of the third semiconductor layer.

8. The semiconductor device according to claim 7,
wherein the first conductor is electrically connected to one of the third conductor and the fourth conductor.

9. The semiconductor device according to claim 7,
wherein the first conductor is not electrically connected to the third conductor, and
wherein the first conductor is not electrically connected to the fourth conductor.

10. (canceled)

11. The semiconductor device according to claim 1,
wherein the first conductor functions as one of a source electrode and a drain electrode,
wherein the second conductor functions as the other of the source electrode and the drain electrode,
wherein the second insulator functions as a gate insulator, and
wherein the third conductor functions as a gate electrode.

12. The semiconductor device according to claim 1, further comprising a third insulator over the first conductor and the second conductor,
wherein the third insulator comprises an opening overlapping with the second semiconductor layer, and
wherein the second insulator and the third conductor are located in the opening.

13. The semiconductor device according to claim 3,
wherein a band gap of the second semiconductor layer is wider than a band gap of silicon.

14. The semiconductor device according to claim 3,
wherein each of the first semiconductor layer and the second semiconductor layer comprises indium, zinc, and one or more selected from gallium, aluminum, and tin.

15. The semiconductor device according to claim 3,
wherein the second conductor functions as one of a source electrode and a drain electrode,
wherein the third conductor functions as the other of the source electrode and the drain electrode,
wherein the second insulator functions as a gate insulator,
wherein the fourth conductor functions as a first gate electrode, and
wherein the first conductor functions as a second gate electrode.
